(19) United States
(12) Patent Application Publication
(10) Pub. No.: US 2026/0028497 A1
(43) Pub. Date: Jan. 29, 2026

(54) Conductive Dispersions And Methods Of Manufacture

(71) Applicant: Nanotech Energy, Inc., Sunny Isles Beach, FL (US)

(72) Inventors: Maher F. El-Kady, Los Angeles, CA (US); Shannon Price, Los Angeles, CA (US); Thai Yang, Oroville, CA (US)

(21) Appl. No.: 19/348,684

(22) Filed: Oct. 2, 2025

Related U.S. Application Data
(63) Continuation of application No. PCT/US2024/023114, filed on Apr. 4, 2024.
(60) Provisional application No. 63/494,437, filed on Apr. 5, 2023.

(51) Int. Cl. C09D 11/52; C09D 11/037; C09D 11/106; H05K 1/09

(52) U.S. Cl. CPC C09D 11/52; C09D 11/037; C09D 11/106; H05K 1/097; H05K 2201/0245; H05K 2201/0257; H05K 2201/0272; H05K 2201/0323

(57) ABSTRACT

Provided herein are conductive inks and methods of formulation thereof, whose electric and mechanical properties (e.g., viscosity and surface tension) enable its use in a wide array of printing techniques. The outstanding conductivity, thermal stability, chemical stability, and flexibility of graphene in the inks herein enable the production of low-cost electronics with tunable electrochemical properties.

### CROSS REFERENCE TO OTHER APPLICATION(S)

This application is a continuation of PCT Application No. PCT/US2024/023114, filed on 2024 Apr. 4, which claims the benefit of U.S. Provisional Application No. 63/494,437, filed 2023 Apr. 5, both of which are incorporated herein in their entirety by reference.

### BACKGROUND

Printing conductive patterns on flexible substrates enables the manufacture of micro-scale low-cost flexible electronics. Improved printing inks are required to keep up with the increased demand for such devices. Printed electronics are used in such devices as touchscreens, solar cells, sensors, flexible displays, foldable displays, electronic paper, sensors, radio-frequency identification (RFID) tags, batteries, and supercapacitors.

### SUMMARY

One aspect provided herein is a conductive ink comprising: reduced graphene oxide sheets, wherein: at least about 90% of the graphene sheets consist of a single layer; the graphene sheets have an oxygen content of at most about 6% wt.; or both; silver nanoflakes; a solvent; a dispersing agent; and a binder.

In some embodiments, the conductive ink further comprises a softening agent. In some embodiments, the softening agent increases the flexibility of the cured ink. In some embodiments, the softening agent reduces the brittleness of the cured ink. In some embodiments, the softening agent comprises diethylene glycol. In some embodiments, the softening agent comprises diethylene glycol in an amount of 8% wt. to 12% wt. In some embodiments, the softening agent comprises diethylene glycol in an amount of about 10.5% wt. In some embodiments, the softening agent comprises diethylene glycol in an amount from about 5% wt. to about 80% wt. In some embodiments, the softening agent comprises diethylene glycol in an amount of at least 5% wt. In some embodiments, the softening agent comprises diethylene glycol in an amount of up to 80% wt. In some embodiments, the dispersing agent is a solid at room temperature. In some embodiments, the dispersing agent increases the viscosity of the ink. In some embodiments, the dispersing agent stabilizes the reduced graphene oxide sheets in the ink. In some embodiments, the dispersing agent prevents agglomeration of the reduced graphene oxide sheets in the ink. In some embodiments, the dispersing agent prevents cracking of the ink when cured. In some embodiments, the dispersing agent prevents the formation of agglomerated particles of reduced graphene oxide sheets or silver nanoflakes when the ink is cured. In some embodiments, the dispersing agent increases the flexibility of the ink when cured. In some embodiments, the dispersing agent increases the elasticity of polymer chains in the ink. In some embodiments, the dispersing agent comprises Poly THF, C7GOL, Cerol 601 wax, ethyl cellulose, or combinations thereof. In some embodiments, the dispersing agent comprises Poly THF. In some embodiments, the dispersing agent comprises Poly THF in an amount of about 0.5% wt. to about 20% wt. In some embodiments, the dispersing agent comprises Poly THF in an amount of about 0.5% wt. to about 2% wt. In some embodiments, the dispersing agent comprises Poly THF in an amount of about 1% wt. In some embodiments, the dispersing agent comprises Poly THF in an amount of at least 1% wt. In some embodiments, the dispersing agent comprises Poly THF in an amount up to 10% wt. In some embodiments, the dispersing agent comprises Poly THF in an amount up to 20% wt. In some embodiments, the dispersing agent comprises Poly THF 2k, referring to the average molecular weight of the polymer. In some embodiments, the silver nanoflakes are comprised in an amount of about 30% wt. to about 70% wt. In some embodiments, the silver nanoflakes are comprised in an amount of at least 30% wt. In some embodiments, the silver nanoflakes are comprised in an amount up to 70% wt. In some embodiments, the silver nanoflakes are comprised in an amount of about 55% wt. to about 65% wt. In some embodiments, the silver nanoflakes are comprised in an amount of about 62.5% wt. In some embodiments, the ink comprises silver content of about 84% wt. when cured. In some embodiments, the ink comprises silver content of about 80% wt. to about 90% wt. when cured. In some embodiments, the ink comprises silver content of at least 80% wt. when cured. In some embodiments, the ink comprises silver content of up to 90% wt. when cured. In some embodiments, the silver nanoflakes range from about 8 μm to about 21 μm in diameter. In some embodiments, the silver nanoflakes comprise an average particle diameter distribution of 12 μm to 16 μm. In some embodiments, the silver nanoflakes comprise an average particle diameter distribution of about 14.34 μm. In some embodiments, the silver nanoflakes comprise a median particle diameter of about 14.6 μm. In some embodiments, the silver nanoflakes comprise a D10 diameter of about 8.14 μm. In some embodiments, the silver nanoflakes comprise a D90 diameter of about 20.3 μm. In some embodiments, the ink does not show streaks when printed with a diameter of up to 20 μm. In some embodiments, the binder comprises Poly Vinyl Pyrrolidone, a thermoplastic copolymer, Paraloid B72, Paraloid B66, or combinations thereof. In some embodiments, the binder comprises Poly Vinyl Pyrrolidone, and at least one of Paraloid B72, and Paraloid B66. In some embodiments, the binder comprises Poly Vinyl Pyrrolidone, and Paraloid B72, and Paraloid B66. In some embodiments, the binder comprises Poly Vinyl Pyrrolidone 10k, Poly Vinyl Pyrrolidone 15k, Poly Vinyl Pyrrolidone 29k, Poly Vinyl Pyrrolidone 360k, or Poly Vinyl Pyrrolidone 120k, referring to the average molecular weight to the Poly Vinyl Pyrrolidone polymer. In some embodiments, the binder comprises Poly Vinyl Pyrrolidone in an amount of about 10.5% wt. In some embodiments, the binder comprises Poly Vinyl Pyrrolidone 15k in an amount of about 10.5% wt. In some embodiments, the binder comprises Poly Vinyl Pyrrolidone in an amount of about 8% wt. to about 12% wt. In some embodiments, the binder comprises Poly Vinyl Pyrrolidone 15k in an amount of about 8% wt. to about 12% wt. In some embodiments, the binder comprises Poly Vinyl Pyrrolidone in an amount of at least 5% wt. In some embodiments, the binder comprises Poly Vinyl Pyrrolidone in an amount up to 20% wt. In some embodiments, the Poly Vinyl Pyrrolidone is PVP 15k. In some embodiments, the solvent comprises Dowanol PnP, 2-ethyl-1-hexanol, DEGBE, 2-ethyl-1-butanol, 2-methyl-1-pentanol, PGMEA, Hexamine, Cycloheptylamine, Isoamyl amine, 3-Methoxypropylamine, PCBTF, ethylene glycol, isopropanol, ethyl acetate, chloroform, DMF, NMP, THF, dichlorobenzene, or combinations thereof. In some embodiments, the solvent comprises Propylene glycol propyl ether. In some embodiments, the solvent comprises 2-ethyl-1-hexanol. In some embodiments, the solvent comprises Propylene glycol propyl ether, and 2-ethyl-1-hexanol. In some embodiments, the solvent is comprised in an amount of about 10% wt. to about 90% wt. In some embodiments, the solvent comprises Propylene glycol propyl ether in an amount of about 15% wt. In some embodiments, the solvent comprises Propylene glycol propyl ether in an amount of about 13% wt. to 17% wt. In some embodiments, the solvent comprises Propylene glycol propyl ether in an amount of at least 10% wt. In some embodiments, the solvent comprises Propylene glycol propyl ether in an amount up to 20% wt. In some embodiments, the solvent comprises Propylene glycol propyl ether in an amount up to 90% wt. In some embodiments, the reduced graphene oxide sheets are comprised in an amount of about 0.5% wt. In some embodiments, the reduced graphene oxide sheets are comprised in an amount from about 0.1% wt. to about 2% wt. In some embodiments, the reduced graphene oxide sheets are comprised in an amount from about 0.3% wt. to about 0.7% wt. In some embodiments, the reduced graphene oxide sheets are comprised in an amount of at least 0.3% wt. In some embodiments, the reduced graphene oxide sheets are comprised in an amount of up to about 1% wt. In some embodiments, the ink comprises a solid content of about 75% wt. In some embodiments, the ink comprises a solid content of about 70% wt. to 80% wt. In some embodiments, the ink comprises a solid content of at least 70% wt. In some embodiments, the ink comprises a solid content up to 80% wt. In some embodiments, the ink comprises a viscosity from about 1000 cP to about 10000 cP. In some embodiments, the ink comprises a viscosity of 4000 cP to about 10000 cP. In some embodiments, the ink comprises a viscosity of at least 4500 cP. In some embodiments, the ink comprises a viscosity of at least 4500 cP at 200 s\hat{ }−1 at 25° C. In some embodiments, the ink comprises a viscosity of at least 10000 cP at 100 s\hat{ }−1 at 25° C. In some embodiments, the ink comprises a viscosity of at least 12000 cP at 100 s\hat{ }−1 at 25° C. In some embodiments, the ink is a shear thinning fluid. In some embodiments, the ink is suitable for screen printing, extruder printing, flexography application, slot-die application, knife-over-edge coating application. In some embodiments, the ink is suitable for screen printing. In some embodiments, the ink does not leave pin holes when applied. In some embodiments, the ink does not separate when cured. In some embodiments, the ink does not shrink when cured. In some embodiments, the ink does not reduce its surface area when cured. In some embodiments, the ink has a wet film thickness that is less than a wet film thickness. In some embodiments, a change in dry film thickness correlates to a change in wet film thickness with a differential of about 0.5. In some embodiments, the ink is adhesive. In some embodiments, the ink comprises a 5B adhesion on PET, PI, Kapton, or glass. In some embodiments, the ink is stable at room temperature. In some embodiments, the ink cures at 300° C. In some embodiments, the ink cures at 300° C. within about 30 minutes. In some embodiments, the ink comprises a sheet resistance of at least 0.017 ohms/sq. In some embodiments, the ink comprises a sheet resistance of up to 0.084 ohms/sq. In some embodiments, the ink comprises a sheet resistance of up to 0.08 ohms/sq at a dry film thickness of about 20 μm. In some embodiments, the ink comprises a sheet resistance of up to 0.025 ohms/sq at a dry film thickness of about 30 μm. In some embodiments, the ink comprises a sheet resistance of up to 0.028 ohms/sq at a dry film thickness of about 36 μm. In some embodiments, the ink comprises a sheet resistance of up to 0.027 ohms/sq at a dry film thickness of about 40 μm. In some embodiments, the ink comprises a sheet resistance of up to 0.023 ohms/sq at a dry film thickness of about 65 μm. In some embodiments, the ink comprises a sheet resistance of up to 0.017 ohms/sq at a dry film thickness of about 90 μm. In some embodiments, the ink comprises a sheet resistance of up to 90 ohms/sq at a dry film thickness of about 200 μm. In some embodiments, the ink comprises a sheet resistance of about 0.025 at a range of dry film thicknesses from about 30 μm to about 36 μm. In some embodiments, the ink comprises a conductivity of about 6300 S/cm to about 15000 S/cm. In some embodiments, the ink comprises a conductivity of at least 6300 S/cm at a dry film thickness of about 10 μm. In some embodiments, the ink comprises a conductivity of about 10000 S/cm at a dry film thickness of from about 10 μm to about 50 μm. In some embodiments, the ink comprises an average conductivity of about 10000 S/cm at a dry film thickness of from about 10 μm to about 50 μm. In some embodiments, the ink comprises a conductivity of at least 10000 S/cm at a dry film thickness of from about 10 μm to about 50 μm. In some embodiments, the ink comprises the claimed conductivity when cured at 110° C. In some embodiments, the ink comprises the claimed conductivity when cured at 110 C for about 30 min. In some embodiments, the ink comprises a conductivity of up to 54000 S/cm at a dry film thickness of about 100 μm. In some embodiments, the ink comprises a conductivity of about 15000 S/cm to about 54000 S/cm. In some embodiments, the ink comprises a conductivity of about 40000 S/cm. In some embodiments, the ink comprises a conductivity of at least 15000 S/cm at a dry film thickness of about 10 μm. In some embodiments, the ink comprises a conductivity of about 40000 S/cm at a dry film thickness of from about 10 μm to about 50 μm. In some embodiments, the ink comprises an average conductivity of about 40000 S/cm at a dry film thickness of from about 10 μm to about 50 μm. In some embodiments, the ink comprises a conductivity of at least 40000 S/cm at a dry film thickness of from about 10 μm to about 50 μm. In some embodiments, the ink comprises the claimed conductivity when cured at 300° C. In some embodiments, the ink comprises the claimed conductivity when cured at 300° C. for about 30 min. In some embodiments, the ink comprises the conductivity of any of the preceding claims when applied with a film thickness of 10, 20, 50, 100, or 200 μm. In some embodiments, the ink is applied at 110 C into trace lines with a width from 300 μm to 3000 um, and comprises an average conductivity of about 750000 S. In some embodiments, the ink is applied at 110 C into trace lines with a width of at least 300 μm and comprises a conductivity of at least 666000 S. In some embodiments, the ink is applied at 110° C. into trace lines with a width of up to 3000 μm and comprises a conductivity of at least 830000 S. In some embodiments, the ink is applied at 300° C. into trace lines with a width from 300 μm to 3000 μm, and comprises an average conductivity of about 1.42*10\hat{ }6 S. In some embodiments, the ink is applied at 300° C. into trace lines with a width of at least 300 μm and comprises a conductivity of at least 10\hat{ }6 S. In some embodiments, the ink is applied at 300° C. into trace lines with a width of up to 3000 μm and comprises a conductivity of at least 2*10\hat{ }6 S. In some embodiments, the ink comprises flat morphology when screen printed, with an average deviation from the edge of the cured ink not exceeding 10 μm. In some embodiments, the ink comprises pores up to about 5 μm in average diameter. In some embodiments, the ink comprises pores from about 2 μm to about 7 μm in diameter. In some embodiments, the ink comprises channels throughout the cured ink connected by the pores. In some embodiments, the is applied as a continuous film. In some embodiments, the is applied as a continuous film or as a trace line on a substrate. In some embodiments, the substrate comprises silicon, PET, PI, Kapton, glass, or combinations thereof. In some embodiments, the ink comprises pores up to about 5 μm in average diameter when cured. In some embodiments, the ink comprises pores from about 2 μm to about 7 μm in diameter when cured. In some embodiments, the ink comprises channels throughout the cured ink connected by the pores when cured. In some embodiments, the ink comprises a conductivity that is substantially unchanged after at least about 24 hours of storage. In some embodiments, the ink comprises a conductivity that is substantially unchanged after at least about one year of storage. In some embodiments, the ink comprises a conductivity that has decreased by less than about 5% after at least about 24 hours of storage. In some embodiments, the ink comprises a conductivity that has decreased by less than about 5% after at least about one year of storage. In some embodiments, the silver nanoflakes comprise a D10 diameter that has increased by less than about 10% after at least about 24 hours of storage. In some embodiments, the silver nanoflakes comprise a D10 diameter that has increased by less than about 10% after at least about one year of storage. In some embodiments, the silver nanoflakes comprise a D50 diameter that has increased by less than about 5% after at least about 24 hours of storage. In some embodiments, the silver nanoflakes comprise a D50 diameter that has increased by less than about 5% after at least about one year of storage. In some embodiments, the silver nanoflakes comprise a D90 diameter that has increased by less than about 10% after at least about 24 hours of storage. In some embodiments, the silver nanoflakes comprise a D90 diameter that has increased by less than about 10% after at least about one year of storage. In some embodiments, the ink comprises a viscosity of at least about 4,000 cP after at least about 24 hours of storage. In some embodiments, the ink comprises a viscosity of at least about 4,000 cP after at least about one year of storage. In some embodiments, the ink comprises a conductivity of at least 10000 S/cm at a dry film thickness of from about 10 μm to about 50 μm, wherein the conductive ink has been stored for at least about 24 hours. In some embodiments, the ink comprises a conductivity of at least 10000 S/cm at a dry film thickness of from about 10 μm to about 50 μm, wherein the conductive ink has been stored for at least about one year.

Another aspect provided herein is method of preparing a conductive ink, the method comprising: preparing a mixture comprising: reduced graphene oxide sheets, wherein: at least about 90% of the graphene sheets consist of a single layer; the graphene sheets have an oxygen content of at most about 6% wt; or both; silver nanoflakes; a solvent; a dispersing agent; and a binder; and mixing the mixture at a high shear rate as to exfoliate the graphene oxide sheets and form a substantially uniform dispersion between the reduced graphene oxide sheets and the silver nanoflakes to form the conductive ink.

In some embodiments, the method further comprises applying the conductive ink as a continuous film or as a trace line on a substrate. In some embodiments, the substrate comprises silicon, PET, PI, Kapton, glass, or combinations thereof. In some embodiments, mixing the dispersion at a high shear rate comprises mixing the mixture at a rate of at least 200 Hz. In some embodiments, mixing the dispersion at a high shear rate comprises mixing the mixture at a rate of at least 200 Hz for at least 30 minutes. In some embodiments, the method further comprises curing the conductive ink at a temperature of 110° C. for up to 30 minutes. In some embodiments, the method further comprises curing the conductive ink at a temperature of 300° C. for up to 30 minutes. In some embodiments, curing the conductive ink at a temperature exceeding 100° C. increases the conductivity of the cured ink. In some embodiments, curing the conductive ink at a temperature of 300° C. increases the conductivity of the cured ink. In some embodiments, the mixture further comprises a softening agent. In some embodiments, the softening agent increases the flexibility of the cured ink. In some embodiments, the softening agent reduces the brittleness of the cured ink. In some embodiments, the softening agent comprises diethylene glycol. In some embodiments, the softening agent comprises diethylene glycol in an amount of 8% wt. to 12% wt. In some embodiments, the softening agent comprises diethylene glycol in an amount of about 10.5% wt. In some embodiments, the softening agent comprises diethylene glycol in an amount from about 5% wt. to about 80% wt. In some embodiments, the softening agent comprises diethylene glycol in an amount of at least 5% wt. In some embodiments, the softening agent comprises diethylene glycol in an amount of up to 80% wt. In some embodiments, the dispersing agent is a solid at room temperature. In some embodiments, the dispersing agent increases the viscosity of the ink. In some embodiments, the dispersing agent stabilizes the reduced graphene oxide sheets in the ink. In some embodiments, the dispersing agent prevents agglomeration of the reduced graphene oxide sheets in the ink. In some embodiments, the dispersing agent prevents cracking of the ink when cured. In some embodiments, the dispersing agent prevents the formation of agglomerated particles of reduced graphene oxide sheets or silver nanoflakes when the ink is cured. In some embodiments, the dispersing agent increases the flexibility of the ink when cured. In some embodiments, the dispersing agent increases the elasticity of polymer chains in the ink. In some embodiments, the dispersing agent comprises Poly THF, C7GOL, Cerol 601 wax, ethyl cellulose, or combinations thereof. In some embodiments, the dispersing agent comprises Poly THF. In some embodiments, the dispersing agent comprises Poly THF in an amount of about 0.5% wt. to about 20% wt. In some embodiments, the dispersing agent comprises Poly THF in an amount about 0.5% wt. to about 2% wt. In some embodiments, the dispersing agent comprises Poly THF in an amount of about 1% wt. In some embodiments, the dispersing agent comprises Poly THF in an amount of at least 1% wt. In some embodiments, the dispersing agent comprises Poly THF in an amount up to 10% wt. In some embodiments, the dispersing agent comprises Poly THF in an amount up to 20% wt. In some embodiments, the dispersing agent comprises Poly THF 2k, referring to the average molecular weight of the polymer. In some embodiments, the silver nanoflakes are comprised in an amount of about 30% wt. to about 70% wt. In some embodiments, the silver nanoflakes are comprised in an amount of at least 30% wt. In some embodiments, the silver nanoflakes are comprised in an amount up to 70% wt. In some embodiments, the silver nanoflakes are comprised in an amount of about 55% wt. to about 65% wt. In some embodiments, the silver nanoflakes are comprised in an amount of about 62.5% wt. In some embodiments, the ink comprises silver content of about 84% wt. when cured. In some embodiments, the ink comprises silver content of about 80% wt. to about 90% wt. when cured. In some embodiments, the ink comprises silver content of at least 80% wt. when cured. In some embodiments, the ink comprises silver content of up to 90% wt. when cured. In some embodiments, the silver nanoflakes range from about 8 μm to about 21 μm in diameter. In some embodiments, the silver nanoflakes comprise an average particle diameter distribution of 12 μm to 16 μm. In some embodiments, the silver nanoflakes comprise an average particle diameter distribution of about 14.34 μm. In some embodiments, the silver nanoflakes comprise a median particle diameter of about 14.6 μm. In some embodiments, the silver nanoflakes comprise a D10 diameter of about 8.14 μm. In some embodiments, the silver nanoflakes comprise a D90 diameter of about 20.3 μm. In some embodiments, the ink does not show streaks when printed with a diameter of up to 20 μm. In some embodiments, the binder comprises Poly Vinyl Pyrrolidone, a thermoplastic copolymers, Paraloid B72, Paraloid B66, or combinations thereof. In some embodiments, the binder comprises Poly Vinyl Pyrrolidone, and at least one of Paraloid B72, and Paraloid B66. In some embodiments, the binder comprises Poly Vinyl Pyrrolidone, and Paraloid B72, and Paraloid B66. In some embodiments, the binder comprises Poly Vinyl Pyrrolidone 10k, Poly Vinyl Pyrrolidone 15k, Poly Vinyl Pyrrolidone 29k, Poly Vinyl Pyrrolidone 360k, or Poly Vinyl Pyrrolidone 120k, referring to the average molecular weight to the Poly Vinyl Pyrrolidone polymer. In some embodiments, the binder comprises Poly Vinyl Pyrrolidone in an amount of about 10.5% wt. In some embodiments, the binder comprises Poly Vinyl Pyrrolidone 15k in an amount of about 10.5% wt. In some embodiments, the binder comprises Poly Vinyl Pyrrolidone in an amount of about 8% wt. to about 12% wt. In some embodiments, the binder comprises Poly Vinyl Pyrrolidone 15k in an amount of about 8% wt. to about 12% wt. In some embodiments, the binder comprises Poly Vinyl Pyrrolidone in an amount of at least 5% wt. In some embodiments, the binder comprises Poly Vinyl Pyrrolidone in an amount up to 20% wt. In some embodiments, the Poly Vinyl Pyrrolidone is PVP 15k. In some embodiments, the solvent comprises Dowanol PnP, 2-ethyl-1-hexanol, DEGBE, 2-ethyl-1-butanol, 2-methyl-1-pentanol, PGMEA, Hexamine, Cycloheptylamine, Isoamyl amine, 3-Methoxypropylamine, PCBTF, ethylene glycol, isopropanol, ethyl acetate, chloroform, DMF, NMP, THF, dichlorobenzene, or combinations thereof. In some embodiments, the solvent comprises Propylene glycol propyl ether. In some embodiments, the solvent comprises 2-ethyl-1-hexanol. In some embodiments, the solvent comprises Propylene glycol propyl ether, and 2-ethyl-1-hexanol. In some embodiments, the solvent is comprised in an amount of about 10% wt. to about 90% wt. In some embodiments, the solvent comprises Propylene glycol propyl ether in an amount of about 15% wt. In some embodiments, the solvent comprises Propylene glycol propyl ether in an amount of about 13% wt. to 17% wt. In some embodiments, the solvent comprises Propylene glycol propyl ether in an amount of at least 10% wt. In some embodiments, the solvent comprises Propylene glycol propyl ether in an amount up to 20% wt. In some embodiments, the solvent comprises Propylene glycol propyl ether in an amount up to 90% wt. In some embodiments, the reduced graphene oxide sheets are comprised in an amount of about 0.5% wt. In some embodiments, the reduced graphene oxide sheets are comprised in an amount from about 0.1% wt. to about 2% wt. In some embodiments, the reduced graphene oxide sheets are comprised in an amount from about 0.3% wt. to about 0.7% wt. In some embodiments, the reduced graphene oxide sheets are comprised in an amount of at least 0.3% wt. In some embodiments, the reduced graphene oxide sheets are comprised in an amount of up to about 1% wt. In some embodiments, the ink comprises a solid content of about 75% wt. In some embodiments, the ink comprises a solid content of about 70% wt. to 80% wt. In some embodiments, the ink comprises a solid content of at least 70% wt. In some embodiments, the ink comprises a solid content up to 80% wt. In some embodiments, the ink comprises a viscosity from about 1000 cP to about 10000 cP. In some embodiments, the ink comprises a viscosity of 4000 cP to about 10000 cP. In some embodiments, the ink comprises a viscosity of at least 4500 cP. In some embodiments, the ink comprises a viscosity of at least 4500 cP at 200 s\hat{ }−1 at 25° C. In some embodiments, the ink comprises a viscosity of at least 10000 cP at 100 s\hat{ }−1 at 25° C. In some embodiments, the ink comprises a viscosity of at least 12000 cP at 100 s\hat{ }−1 at 25° C. In some embodiments, the ink is a shear-thinning fluid. In some embodiments, the method further comprises applying the conductive ink to a substrate via screen printing, extruder printing, flexography application, slot-die application, or knife-over-edge coating application. In some embodiments, the method further comprises applying the conductive ink to a substrate via screen printing. In some embodiments, the ink does not leave pin holes when applied. In some embodiments, the ink does not separate when cured. In some embodiments, the ink does not shrink when cured. In some embodiments, the ink does not reduce its surface area when cured. In some embodiments, the ink has a wet film thickness that is less than a wet film thickness. In some embodiments, a change in dry film thickness correlates to a change in wet film thickness with a differential of about 0.5. In some embodiments, the ink is adhesive. In some embodiments, the ink comprises a 5B adhesion on PET, PI, Kapton, or glass. In some embodiments, the ink is stable at room temperature for at least about 24 hours. In some embodiments, the ink is stable at room temperature for at least about one week. In some embodiments, the ink is stable at room temperature for at least about one month. In some embodiments, the ink is stable at room temperature for at least about one year. In some embodiments, the ink is stable at room temperature. In some embodiments, the ink cures at 300° C. In some embodiments, the ink cures at 300° C. within about 30 minutes. In some embodiments, the ink comprises a sheet resistance of at least 0.017 ohms/sq. In some embodiments, the ink comprises a sheet resistance of up to 0.084 ohms/sq. In some embodiments, the ink comprises a sheet resistance of up to 0.08 ohms/sq at a dry film thickness of about 20 μm. In some embodiments, the ink comprises a sheet resistance of up to 0.025 ohms/sq at a dry film thickness of about 30 μm. In some embodiments, the ink comprises a sheet resistance of up to 0.028 ohms/sq at a dry film thickness of about 36 μm. In some embodiments, the ink comprises a sheet resistance of up to 0.027 ohms/sq at a dry film thickness of about 40 μm. In some embodiments, the ink comprises a sheet resistance of up to 0.023 ohms/sq at a dry film thickness of about 65 μm. In some embodiments, the ink comprises a sheet resistance of up to 0.017 ohms/sq at a dry film thickness of about 90 μm. In some embodiments, the ink comprises a sheet resistance of up to 90 ohms/sq at a dry film thickness of about 200 μm. In some embodiments, the ink comprises a sheet resistance of about 0.025 at a range of dry film thicknesses from about 30 μm to about 36 μm. In some embodiments, the ink comprises a conductivity of about 6300 S/cm to about 15000 S/cm. In some embodiments, the ink comprises a conductivity of at least 6300 S/cm at a dry film thickness of about 10 μm. In some embodiments, the ink comprises a conductivity of about 10000 S/cm at a dry film thickness of from about 10 μm to about 50 μm. In some embodiments, the ink comprises an average conductivity of about 10000 S/cm at a dry film thickness of from about 10 μm to about 50 μm. In some embodiments, the ink comprises a conductivity of at least 10000 S/cm at a dry film thickness of from about 10 μm to about 50 μm. In some embodiments, the ink comprises the claimed conductivity when cured at 110° C. In some embodiments, the ink comprises the claimed conductivity when cured at 110° C. for about 30 min. In some embodiments, the ink comprises a conductivity of up to 54000 S/cm at a dry film thickness of about 100 μm. In some embodiments, the ink comprises a conductivity of about 15000 S/cm to about 54000 S/cm. In some embodiments, the ink comprises a conductivity of about 40000 S/cm. In some embodiments, the ink comprises a conductivity of at least 15000 S/cm at a dry film thickness of about 10 μm. In some embodiments, the ink comprises a conductivity of about 40000 S/cm at a dry film thickness of from about 10 μm to about 50 μm. In some embodiments, the ink comprises an average conductivity of about 40000 S/cm at a dry film thickness of from about 10 μm to about 50 μm. In some embodiments, the ink comprises a conductivity of at least 40000 S/cm at a dry film thickness of from about 10 μm to about 50 μm. In some embodiments, the ink comprises the claimed conductivity when cured at 300° C. In some embodiments, the ink comprises the claimed conductivity when cured at 300° C. for about 30 min. In some embodiments, the ink comprises the conductivity of any of the preceding claims when applied with a film thickness of 10, 20, 50, 100, or 200 μm. In some embodiments, the ink is applied at 110° C. into trace lines with a width from 300 μm to 3000 μm, and comprises an average conductivity of about 750000 S. In some embodiments, the ink is applied at 110° C. into trace lines with a width of at least 300 μm and comprises a conductivity of at least 666000 S. In some embodiments, the ink is applied at 110° C. into trace lines with a width of up to 3000 μm and comprises a conductivity of at least 830000 S. In some embodiments, the ink is applied at 300° C. into trace lines with a width from 300 μm to 3000 μm, and comprises an average conductivity of about 1.42*10\hat{ }6 S. In some embodiments, the ink is applied at 300° C. into trace lines with a width of at least 300 μm and comprises a conductivity of at least 10\hat{ }6 S. In some embodiments, the ink is applied at 300° C. into trace lines with a width of up to 3000 μm and comprises a conductivity of at least 2*10\hat{ }6 S. In some embodiments, the ink comprises flat morphology when screen printed, with an average deviation from the edge of the cured ink not exceeding 10 μm. In some embodiments, the ink comprises pores up to about 5 μm in average diameter upon curing. In some embodiments, the ink comprises pores from about 2 μm to about 7 μm in diameter upon curing. In some embodiments, the ink comprises channels throughout the cured ink connected by the pores upon curing.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings of which:

FIG. 1A First SEM image of solution processed graphene sheets of an exemplary conductive ink #1, per one or more embodiments, herein;

FIG. 1B Second SEM image of solution processed graphene sheets of an exemplary conductive ink #1, per one or more embodiments, herein;

FIG. 2A First AFM image of solution processed graphene sheets of an exemplary conductive ink #1, per one or more embodiments, herein;

FIG. 2B Second AFM image of solution processed graphene sheets of an exemplary conductive ink #1, per one or more embodiments, herein;

FIG. 3A shows image of an exemplary conductive ink with silver nanoflakes, per one or more embodiments, herein;

FIG. 3B shows image of an exemplary conductive ink with silver nanoflakes and graphene, per one or more embodiments, herein;

FIG. 4A shows image of an exemplary conductive ink with silver nanoflakes 24 hours after mixing, per one or more embodiments, herein;

FIG. 4B shows image of an exemplary conductive ink with silver nanoflakes and graphene 24 hours after mixing, per one or more embodiments, herein;

FIG. 5A is torque vs. speed graph of an exemplary conductive ink #1, per one or more embodiments, herein;

FIG. 5B is a shear rate vs viscosity graph of an exemplary conductive ink #1, per one or more embodiments, herein;

FIG. 6A is a particle size distribution of an exemplary conductive ink #1, per one or more embodiments, herein;

FIG. 6B is an image of an exemplary conductive ink #1 on a Hegman gauge, per one or more embodiments, herein;

FIG. 7A show photographs of exemplary conductive ink #1 screen printed onto a dog and bone structure on Polyethylene terephthalate (PET), per one or more embodiments, herein;

FIG. 7B shows photograph of exemplary conductive ink #1 screen pattern printed with Nova extruder print on polyimide (PI), per one or more embodiments, herein;

FIG. 7C shows photograph of exemplary conductive ink #1 screen pattern printed with Nova extruder print on PCB, per one or more embodiments, herein;

FIG. 8A shows a photograph of adhesion test result of an exemplary conductive ink #1, per one or more embodiments, herein;

FIG. 9A is a graph of the dry film thickness vs the wet film resistance of a substate coated with the exemplary conductive ink #1 and cured at 110° C., per one or more embodiments, herein;

FIG. 9B is a graph of the dry film thickness vs the sheet resistance of a substrate coated with an exemplary conductive ink #1 and cured at 110° C., per one or more embodiments, herein;

FIG. 10A is a graph of the dry thickness vs the sheet resistance of a substate coated with the exemplary conductive ink #1 and cured at 300° C., per one or more embodiments, herein;

FIG. 10B is a graph of the dry film thickness vs the sheet resistance of a substrate coated with an exemplary conductive ink #1 and cured at 300° C., per one or more embodiments, herein;

FIG. 11A, shows a trace width vs resistivity for a substrate covered with the exemplary conductive ink #1 and cured at 110° C., per one or more embodiments, herein;

FIG. 11B shows an image of the exemplary conductive ink #1 cured at 110° C. on a Hegman gauge, per one or more embodiments, herein;

FIG. 12A, shows a trace width vs resistivity for a substrate covered with the exemplary conductive ink #1 and cured at 300° C., per one or more embodiments, herein;

FIG. 12B shows an image of the exemplary conductive ink #1 cured at 300° C. on a Hegman gauge, per one or more embodiments, herein;

FIG. 13A shows a photograph of traces of different widths of the exemplary conductive ink #1 screen printed onto a silicon wafer and a high magnification photograph of a trace, per one or more embodiments, herein;

FIG. 13B shows a photograph of traces of different widths of the exemplary conductive ink #1 screen printed onto a silicon wafer and a high magnification photograph of a printed electrical contact point, per one or more embodiments, herein;

FIG. 14A is a 1000× magnification SEM image of a substrate coated with the exemplary conductive ink #1, per one or more embodiments, herein;

FIG. 14B is a 2500× magnification SEM image of a substrate coated with the exemplary conductive ink #1, per one or more embodiments, herein;

FIG. 14C is a 5000× magnification SEM image of a substrate coated with the exemplary conductive ink #1, per one or more embodiments, herein;

FIG. 15A is a 7500× magnification SEM image of a gold substrate coated with the exemplary conductive ink #1, per one or more embodiments, herein;

FIG. 15B is a 10,000× magnification SEM image of a gold substrate coated with the exemplary conductive ink #1, per one or more embodiments, herein;

FIG. 15C is a 20,000× magnification SEM image of a gold substrate coated with the exemplary conductive ink #1, per one or more embodiments, herein;

FIG. 16A shows image of an exemplary conductive ink with silver nanoflakes 24 hours after mixing, per one or more embodiments, herein;

FIG. 16B shows image of an exemplary conductive ink with silver nanoflakes and graphene 24 hours after mixing, per one or more embodiments, herein;

FIG. 17 shows a photograph of an adhesion test result of an exemplary conductive ink after storage for about one year, per one or more embodiments, herein;

FIG. 18 is a particle size distribution of an exemplary conductive ink after storage for about one year, per one or more embodiments, herein;

FIG. 19A shows a photograph of screen printed conductive inks in a variety of shapes on PET, per one or more embodiments, herein; and

FIG. 19B shows a photograph of screen printed conductive inks in a variety of shapes on PET, per one or more embodiments, herein.

### DETAILED DESCRIPTION

Currently, limited methods are available to manufacture printed electronics due to the limitations of conductive inks used therein. Current silver and copper-based inks are often too expensive for large scale device production. Further, such inks agglomerate during storage or printing to form uneven and inconsistent components, have viscosities and surface tensions that cannot be tuned for specific printing methods, and suffer from poor adhesion to substrates and low flexibility. As such, economically manufacturing durable, stable, and highly conductive printed components with such inks is often difficult or ineffective.

To improve the performance of such printed electronics and to enable the fabrication of a broader range of such electronics, improved inks are required. As such, provided herein are conductive inks and methods of preparation thereof, whose electric and mechanical properties (e.g., viscosity and surface tension) enable its use in a wide array of printing techniques. The outstanding conductivity, thermal stability, chemical stability, and flexibility of graphene in the inks herein enable the production of low-cost electronics with tunable electrochemical properties. Further, the inks herein enable the manufacture and storage of stable conductive inks by demonstrating negligible degradation (e.g., loss of conductivity, agglomeration) for at least about one year. Finally, while many current conductive inks require multiple layers for proper adhesion and conductibility, the inks herein can form electronic circuits with sufficient thickness using a reduced number of layers, such as even in a single print.

### Conductive Inks

The embodiments disclosed herein comprise an ink formulation that works for roll-to-roll coating, screen printing, extruder printing, flexography, slot-die, and knife-over-edge printing.

In some embodiments, the conductive ink comprises reduced graphene oxide sheets, silver nanoflakes, a solvent, a dispersing agent, and a binder. In some embodiments, the conductive ink consists essentially of reduced graphene oxide sheets, silver nanoflakes, a solvent, a dispersing agent, and a binder. In some embodiments, the conductive ink comprises a softener.

The specific components of the conductive ink herein enable its unexpectedly improved elasticity, adhesion, thermal stability, coating uniformity, chemical stability, tunable viscosity, and conductivity. The ink exhibits superior stability and coats evenly without leaving holes, and has a smooth surface.

In some embodiments, the graphene comprises reduced graphene oxide. In some embodiments, the graphene comprises activated reduced graphene oxide. In some embodiments, at least about 85%, 86%, 87%, 88%, 89%, 90%, 91%, 92%, 93%, 94%, 95%, 96%, 97%, 98% or more of the graphene sheets consist of a single layer of graphene. In some embodiments, the high content of single-layer graphene sheets within the conductive ink improves the conductivity of the conductive ink when dry. In some embodiments, a percentage of the reduced graphene oxide that consists of a single layer is determined by atomic force microscopy (AFM). In some embodiments, the graphene sheets have an oxygen content of at most about 2%, 3%, 4%, 5%, 6%, 7%, 8%, 9%, or 10%, including increments therein. In some embodiments, the low oxygen content of the graphene sheets within the conductive ink improves the conductivity of the conductive ink when dry.

In some cases, the silver nanoflakes disclosed herein contribute to one or more of the unexpectedly improved conductivity and viscosity of the formulation. Furthermore, the combination of silver flakes, graphene, solvents, binders, and softeners unexpectedly improves one or more of elasticity, adhesion, thermal stability, chemical stability, conductivity, and viscosity of the formulation. In some embodiments, the silver nanoflakes comprise 11-F material. In some embodiments, the combination of silver flakes and ultragraphene results in an increase in conductivity of the conductive ink. In some embodiments, the combination of silver flakes and graphene results in an increase in viscosity of the conductive ink. In some embodiments, the graphene may decrease the agglomeration of silver nanoflakes. In some embodiments, the decrease in agglomeration of silver nanoflakes can improve the stability of the conductive ink (e.g., for at least about one year).

In some embodiments, the solvent comprises propylene glycol n-propyl ether (Dowanol PnP), 2-ethyl-1-hexanol, diethylene glycol butyl ether (DEGBE), 2-ethyl-1-butanol, 2-methyl-1-pentanol, propylene glycol methyl ether acetate (PGMEA), hexamine, cycloheptylamine, isoamyl amine, 3-methoxypropylamine, and Parachlorobenzotrifluoride (PCBTF), or any combination thereof. In some embodiments, the solvent comprises ethylene glycol, isopropanol, ethyl acetate, chloroform, dimethylformamide (DMF), N-methyl-2-pyrrolidone (NMP), tetrahydrofuran (THF), and dichlorobenzene, or any combination thereof. In some embodiments, the solvent comprises propylene glycol n-propyl ether (PNP) or 2-ethyl-1-hexanol. In some embodiments, the solvent increases the stability of the graphene within the inks herein. In some embodiments, the solvent is volatile. In some embodiments, the solvent has a vapor pressure at 20° C. of about 20 Pa to about 250 Pa. In some embodiments, the solvent has a boiling point of about 110° C. to about 200° C. In some embodiments, the vapor pressure and the boiling point of the solvent enable the inks herein to dry slowly and thus prevent cracking. In some embodiments, the high boiling point of the solvent increases the drying time of the conductive ink, increases the time for coating a substrate with the conductive ink, and may permit for even drying of the conductive ink across the surface of the ink applied to the substrate. In some embodiments, the even drying of the ink across the surface of the ink applied to the substrate may prevent the edges from drying may prevent the edges from drying prior to the bulk of the conductive ink, and may prevent capillary flow of suspend reduced graphene oxide particles outward from the bulk of the conductive ink to the edges of the conductive ink as applied to the substrate, and may permit for an even coating of the conductive ink on a substrate with a uniform or substantially uniform dispersion of graphene oxide particles throughout the conductive ink applied to the substrate. In some embodiments, the slow, even drying of the ink across the surface of the ink applied to the substrate may allow for a highly uniform coating of the conductive ink applied to a substrate, improving the conductivity of the final product produced with the conductive ink applied to a substrate.

The specific dispersing agents herein may permit for the unexpectedly improved elasticity, adhesion, thermal stability, and chemical stability, or a combination thereof. In some embodiments, the dispersing agent is a solid at room temperature, e.g., 20° C.-30° C. In some embodiments, the dispersing agent increases the viscosity of the ink. In some embodiments, the dispersing agent stabilizes the reduced graphene oxide sheets in the ink. In some embodiments, the dispersing agent prevents agglomeration of the reduced graphene oxide sheets in the ink. In some embodiments, the dispersing agent prevents cracking of the ink when cured. In some embodiments, the dispersing agent prevents the formation of agglomerated particles of reduced graphene oxide sheets or silver nanoflakes when the ink is cured. In some embodiments, the dispersing agent increases the flexibility of the ink when cured. In some embodiments, the dispersing agent increases the elasticity of polymer chains in the ink. In some embodiments, the dispersing agent comprises the dispersing agent at room temperature, which helps thicken the ink, the dispersing agent helps to stabilize reduced graphene oxide in solution, and the dispersing agent helps to slow down drying at room temperature to prevent cracking and island formation, or a combination thereof. In some embodiments, the dispersing agent serves as a long and soft segment to give flexibility and elasticity to polymer chains. In some embodiments, the dispersing agent comprises polytetrahydrofuran (Poly THF), C7GOL, Cerol 601 wax, and ethyl cellulose. In some embodiments, the dispersing agent comprises Poly THF.

The specific binders herein enable the unexpectedly improved elasticity, adhesion, thermal stability, and chemical stability, or a combination thereof. In some embodiments, the binder is a polymeric binder. In some embodiments, the polymeric binder is a thermoplastic copolymer. In some embodiments, the binder comprises Poly Vinyl Pyrrolidone, a thermoplastic copolymer, Paraloid B72, Paraloid B66, or combinations thereof. In some embodiments, the binder comprises Poly Vinyl Pyrrolidone 10k, Poly Vinyl Pyrrolidone 15k, Poly Vinyl Pyrrolidone 29k, Poly Vinyl Pyrrolidone 360k, or Poly Vinyl Pyrrolidone 120k. In some embodiments, Poly Vinyl Pyrrolidone 120k comprises the average molecular weight of the Poly Vinyl Pyrrolidone polymer. In some embodiments, the binder comprises Poly Vinyl Pyrrolidone. In some embodiments, the binder comprises polyvinylpyrrolidone, ethyl methacrylate, butyl methacrylate, or any combination thereof. In some embodiments, the binder is polyvinylpyrrolidone (PVP) with different molecular weights, including at least one of PVP 10k, PVP 29k, PVP 360k, and PVP 120k, or a combination thereof. In some embodiments, the binder comprises at least one of PVP 10k, PVP 29k, PVP 360k, and PVP 120k, and at least one thermoplastic copolymer. In some embodiments, the binder comprises at least one of PVP 10k, PVP 29k, PVP 360k, and PVP 120k, and at least one of Paraloid B72 and Paraloid B66, or a combination thereof.

The specific softeners provided herein enable the unexpectedly improved elasticity, adhesion, thermal stability, and chemical stability, or a combination thereof. In some embodiments, the conductive ink further comprises a softening agent. In some embodiments, the softening agent increases the flexibility of the cured ink. In some embodiments, the softening agent reduces the brittleness of the cured ink. In some embodiments, the softener maintains the flexibility of the formulation by keeping the binder (e.g., PVP) from becoming brittle once cured. In some embodiments, the softener comprises diethylene glycol.

In some embodiments, the conductive ink has a particle size of about 8 μm to about 20.5 μm. In some embodiments, the conductive ink has a particle size of about 8 μm to about 21 μm. In some embodiments, the conductive ink has a particle size of about 8 μm to about 9 μm, about 8 μm to about 10 μm, about 8 μm to about 11 μm, about 8 μm to about 12 μm, about 8 μm to about 13 μm, about 8 μm to about 14 μm, about 8 μm to about 16 μm, about 8 μm to about 18 μm, about 8 μm to about 19 μm, about 8 μm to about 20 μm, about 8 μm to about 21 μm, about 9 μm to about 10 μm, about 9 μm to about 11 μm, about 9 μm to about 12 μm, about 9 μm to about 13 μm, about 9 μm to about 14 μm, about 9 μm to about 16 μm, about 9 μm to about 18 μm, about 9 μm to about 19 μm, about 9 μm to about 20 μm, about 9 μm to about 21 μm, about 10 μm to about 11 μm, about 10 μm to about 12 μm, about 10 μm to about 13 μm, about 10 μm to about 14 μm, about 10 μm to about 16 μm, about 10 μm to about 18 μm, about 10 μm to about 19 μm, about 10 μm to about 20 μm, about 10 μm to about 21 μm, about 11 μm to about 12 μm, about 11 μm to about 13 μm, about 11 μm to about 14 μm, about 11 μm to about 16 μm, about 11 μm to about 18 μm, about 11 μm to about 19 μm, about 11 μm to about 20 μm, about 11 μm to about 21 μm, about 12 μm to about 13 μm, about 12 μm to about 14 μm, about 12 μm to about 16 μm, about 12 μm to about 18 μm, about 12 μm to about 19 μm, about 12 μm to about 20 μm, about 12 μm to about 21 μm, about 13 μm to about 14 μm, about 13 μm to about 16 μm, about 13 μm to about 18 μm, about 13 μm to about 19 μm, about 13 μm to about 20 μm, about 13 μm to about 21 μm, about 14 μm to about 16 μm, about 14 μm to about 18 μm, about 14 μm to about 19 μm, about 14 μm to about 20 μm, about 14 μm to about 21 μm, about 16 μm to about 18 μm, about 16 μm to about 19 μm, about 16 μm to about 20 μm, about 16 μm to about 21 μm, about 18 μm to about 19 μm, about 18 μm to about 20 μm, about 18 μm to about 21 μm, about 19 μm to about 20 μm, about 19 μm to about 21 μm, or about 20 μm to about 21 μm, including increments therein. In some embodiments, the conductive ink has a particle size of about 8 μm, about 9 μm, about 10 μm, about 11 μm, about 12 μm, about 13 μm, about 14 μm, about 16 μm, about 18 μm, about 19 μm, about 20 μm, or about 21 μm. In some embodiments, the conductive ink has a particle size of at least about 8 μm, about 9 μm, about 10 μm, about 11 μm, about 12 μm, about 13 μm, about 14 μm, about 16 μm, about 18 μm, about 19 μm, or about 20 μm. In some embodiments, the conductive ink has a particle size of at most about 9 μm, about 10 μm, about 11 μm, about 12 μm, about 13 μm, about 14 μm, about 16 μm, about 18 μm, about 19 μm, about 20 μm, or about 21 μm.

In some cases, the viscosity of the conductive ink can be tuned by adjusting the shear mixing time, wherein longer shearing times reduce viscosity.

In some embodiments, the conductive ink has a viscosity of about 1,000 cP to about 100,000 cP. In some embodiments, the conductive ink has a viscosity of about about 1,000 cP to about 4,000 cP, about 1,000 cP to about 4,500 cP, about 1,000 cP to about 10,000 cP, about 1,000 cP to about 20,000 cP, about 1,000 cP to about 30,000 cP, about 1,000 cP to about 40,000 cP, about 1,000 cP to about 50,000 cP, about 1,000 cP to about 60,000 cP, about 1,000 cP to about 75,000 cP, about 1,000 cP to about 90,000 cP, about 1,000 cP to about 100,000 cP, about 4,000 cP to about 4,500 cP, about 4,000 cP to about 10,000 cP, about 4,000 cP to about 20,000 cP, about 4,000 cP to about 30,000 cP, about 4,000 cP to about 40,000 cP, about 4,000 cP to about 50,000 cP, about 4,000 cP to about 60,000 cP, about 4,000 cP to about 75,000 cP, about 4,000 cP to about 90,000 cP, about 4,000 cP to about 100,000 cP, about 4,500 cP to about 10,000 cP, about 4,500 cP to about 20,000 cP, about 4,500 cP to about 30,000 cP, about 4,500 cP to about 40,000 cP, about 4,500 cP to about 50,000 cP, about 4,500 cP to about 60,000 cP, about 4,500 cP to about 75,000 cP, about 4,500 cP to about 90,000 cP, about 4,500 cP to about 100,000 cP, about 10,000 cP to about 20,000 cP, about 10,000 cP to about 30,000 cP, about 10,000 cP to about 40,000 cP, about 10,000 cP to about 50,000 cP, about 10,000 cP to about 60,000 cP, about 10,000 cP to about 75,000 cP, about 10,000 cP to about 90,000 cP, about 10,000 cP to about 100,000 cP, about 20,000 cP to about 30,000 cP, about 20,000 cP to about 40,000 cP, about 20,000 cP to about 50,000 cP, about 20,000 cP to about 60,000 cP, about 20,000 cP to about 75,000 cP, about 20,000 cP to about 90,000 cP, about 20,000 cP to about 100,000 cP, about 30,000 cP to about 40,000 cP, about 30,000 cP to about 50,000 cP, about 30,000 cP to about 60,000 cP, about 30,000 cP to about 75,000 cP, about 30,000 cP to about 90,000 cP, about 30,000 cP to about 100,000 cP, about 40,000 cP to about 50,000 cP, about 40,000 cP to about 60,000 cP, about 40,000 cP to about 75,000 cP, about 40,000 cP to about 90,000 cP, about 40,000 cP to about 100,000 cP, about 50,000 cP to about 60,000 cP, about 50,000 cP to about 75,000 cP, about 50,000 cP to about 90,000 cP, about 50,000 cP to about 100,000 cP, about 60,000 cP to about 75,000 cP, about 60,000 cP to about 90,000 cP, about 60,000 cP to about 100,000 cP, about 75,000 cP to about 90,000 cP, about 75,000 cP to about 100,000 cP, or about 90,000 cP to about 100,000 cP, including increments therein. In some embodiments, the conductive ink has a viscosity of about 1,000 cP, about 4,000 cP, about 4,500 cP, about 10,000 cP, about 20,000 cP, about 30,000 cP, about 40,000 cP, about 50,000 cP, about 60,000 cP, about 75,000 cP, about 90,000 cP, or about 100,000 cP. In some embodiments, the conductive ink has a viscosity of at least about 1,000 cP, about 4,000 cP, about 4,500 cP, about 10,000 cP, about 20,000 cP, about 30,000 cP, about 40,000 cP, about 50,000 cP, about 60,000 cP, about 75,000 cP, or about 90,000 cP. In some embodiments, the conductive ink has a viscosity of about at most about 4,000 cP, about 4,500 cP, about 10,000 cP, about 20,000 cP, about 30,000 cP, about 40,000 cP, about 50,000 cP, about 60,000 cP, about 75,000 cP, about 90,000 cP, or about 100,000 cP. In some embodiments, the viscosity is measured at a shear rate of 100 s\hat{ }−1 at 25° C. In some embodiments, viscosity is measured with a spindle 52z, wherein the conductive ink is mixed for at least 0, 1, 2, 3, or 4 hours, and is mixed in accordance with method AE6-80 mm, TMI1.

In some embodiments, the conductive ink, when wet, has a w/w concentration of the graphene of about 0.1% to about 10%. In some embodiments, the conductive ink, when wet, has a w/w concentration of the graphene of about 0.1% to about 0.5%, about 0.1% to about 1%, about 0.1% to about 2%, about 0.1% to about 3%, about 0.1% to about 4%, about 0.1% to about 5%, about 0.1% to about 6%, about 0.1% to about 7%, about 0.1% to about 8%, about 0.1% to about 9%, about 0.1% to about 10%, about 0.5% to about 1%, about 0.5% to about 2%, about 0.5% to about 3%, about 0.5% to about 4%, about 0.5% to about 5%, about 0.5% to about 6%, about 0.5% to about 7%, about 0.5% to about 8%, about 0.5% to about 9%, about 0.5% to about 10%, about 1% to about 2%, about 1% to about 3%, about 1% to about 4%, about 1% to about 5%, about 1% to about 6%, about 1% to about 7%, about 1% to about 8%, about 1% to about 9%, about 1% to about 10%, about 2% to about 3%, about 2% to about 4%, about 2% to about 5%, about 2% to about 6%, about 2% to about 7%, about 2% to about 8%, about 2% to about 9%, about 2% to about 10%, about 3% to about 4%, about 3% to about 5%, about 3% to about 6%, about 3% to about 7%, about 3% to about 8%, about 3% to about 9%, about 3% to about 10%, about 4% to about 5%, about 4% to about 6%, about 4% to about 7%, about 4% to about 8%, about 4% to about 9%, about 4% to about 10%, about 5% to about 6%, about 5% to about 7%, about 5% to about 8%, about 5% to about 9%, about 5% to about 10%, about 6% to about 7%, about 6% to about 8%, about 6% to about 9%, about 6% to about 10%, about 7% to about 8%, about 7% to about 9%, about 7% to about 10%, about 8% to about 9%, about 8% to about 10%, or about 9% to about 10%, including increments therein. In some embodiments, the conductive ink, when wet, has a w/w concentration of the graphene of about 0.1%, about 0.5%, about 1%, about 2%, about 3%, about 4%, about 5%, about 6%, about 7%, about 8%, about 9%, or about 10%. In some embodiments, the conductive ink, when wet, has a w/w concentration of the graphene of at least about 0.1%, about 0.5%, about 1%, about 2%, about 3%, about 4%, about 5%, about 6%, about 7%, about 8%, or about 9%. In some embodiments, the conductive ink, when wet, has a w/w concentration of the graphene of at most about 0.5%, about 1%, about 2%, about 3%, about 4%, about 5%, about 6%, about 7%, about 8%, about 9%, or about 10%. In some embodiments, the low concentration of the graphene oxide herein, in addition to the additional elements of the conductive ink, reduces the cost of the conductive inks herein while maintaining a high conductivity and low resistance.

In some embodiments, the conductive ink, when wet, has a w/w concentration of the binder of about 5% to about 60%. In some embodiments, the conductive ink, when wet, has a w/w concentration of the binder of about 5% to about 10%, about 5% to about 15%, about 5% to about 20%, about 5% to about 25%, about 5% to about 30%, about 5% to about 35%, about 5% to about 40%, about 5% to about 45%, about 5% to about 50%, about 5% to about 55%, about 5% to about 60%, about 10% to about 15%, about 10% to about 20%, about 10% to about 25%, about 10% to about 30%, about 10% to about 35%, about 10% to about 40%, about 10% to about 45%, about 10% to about 50%, about 10% to about 55%, about 10% to about 60%, about 15% to about 20%, about 15% to about 25%, about 15% to about 30%, about 15% to about 35%, about 15% to about 40%, about 15% to about 45%, about 15% to about 50%, about 15% to about 55%, about 15% to about 60%, about 20% to about 25%, about 20% to about 30%, about 20% to about 35%, about 20% to about 40%, about 20% to about 45%, about 20% to about 50%, about 20% to about 55%, about 20% to about 60%, about 25% to about 30%, about 25% to about 35%, about 25% to about 40%, about 25% to about 45%, about 25% to about 50%, about 25% to about 55%, about 25% to about 60%, about 30% to about 35%, about 30% to about 40%, about 30% to about 45%, about 30% to about 50%, about 30% to about 55%, about 30% to about 60%, about 35% to about 40%, about 35% to about 45%, about 35% to about 50%, about 35% to about 55%, about 35% to about 60%, about 40% to about 45%, about 40% to about 50%, about 40% to about 55%, about 40% to about 60%, about 45% to about 50%, about 45% to about 55%, about 45% to about 60%, about 50% to about 55%, about 50% to about 60%, or about 55% to about 60%, including increments therein. In some embodiments, the conductive ink, when wet, has a w/w concentration of the binder of about 5%, about 10%, about 15%, about 20%, about 25%, about 30%, about 35%, about 40%, about 45%, about 50%, about 55%, or about 60%. In some embodiments, the conductive ink, when wet, has a w/w concentration of the binder of at least about 5%, about 10%, about 15%, about 20%, about 25%, about 30%, about 35%, about 40%, about 45%, about 50%, or about 55%. In some embodiments, the conductive ink, when wet, has a w/w concentration of the binder of at most about 10%, about 15%, about 20%, about 25%, about 30%, about 35%, about 40%, about 45%, about 50%, about 55%, or about 60%.

In some embodiments, the conductive ink, when wet, has a w/w concentration of the dispersing agent of about 1% to about 20%. In some embodiments, the conductive ink, when wet, has a w/w concentration of the dispersing agent of about 1% to about 3%, about 1% to about 5%, about 1% to about 7%, about 1% to about 9%, about 1% to about 11%, about 1% to about 13%, about 1% to about 15%, about 1% to about 17%, about 1% to about 18%, about 1% to about 19%, about 1% to about 20%, about 3% to about 5%, about 3% to about 7%, about 3% to about 9%, about 3% to about 11%, about 3% to about 13%, about 3% to about 15%, about 3% to about 17%, about 3% to about 18%, about 3% to about 19%, about 3% to about 20%, about 5% to about 7%, about 5% to about 9%, about 5% to about 11%, about 5% to about 13%, about 5% to about 15%, about 5% to about 17%, about 5% to about 18%, about 5% to about 19%, about 5% to about 20%, about 7% to about 9%, about 7% to about 11%, about 7% to about 13%, about 7% to about 15%, about 7% to about 17%, about 7% to about 18%, about 7% to about 19%, about 7% to about 20%, about 9% to about 11%, about 9% to about 13%, about 9% to about 15%, about 9% to about 17%, about 9% to about 18%, about 9% to about 19%, about 9% to about 20%, about 11% to about 13%, about 11% to about 15%, about 11% to about 17%, about 11% to about 18%, about 11% to about 19%, about 11% to about 20%, about 13% to about 15%, about 13% to about 17%, about 13% to about 18%, about 13% to about 19%, about 13% to about 20%, about 15% to about 17%, about 15% to about 18%, about 15% to about 19%, about 15% to about 20%, about 17% to about 18%, about 17% to about 19%, about 17% to about 20%, about 18% to about 19%, about 18% to about 20%, or about 19% to about 20%, including increments therein. In some embodiments, the conductive ink, when wet, has a w/w concentration of the dispersing agent of about 1%, about 3%, about 5%, about 7%, about 9%, about 11%, about 13%, about 15%, about 17%, about 18%, about 19%, or about 20%. In some embodiments, the conductive ink, when wet, has a w/w concentration of the dispersing agent of at least about 1%, about 3%, about 5%, about 7%, about 9%, about 11%, about 13%, about 15%, about 17%, about 18%, or about 19%. In some embodiments, the conductive ink, when wet, has a w/w concentration of the dispersing agent of at most about 3%, about 5%, about 7%, about 9%, about 11%, about 13%, about 15%, about 17%, about 18%, about 19%, or about 20%.

In some embodiments, the conductive ink, when wet, has a w/w concentration of the solvent of about 20% to about 90%. In some embodiments, the conductive ink, when wet, has a w/w concentration of the solvent of about 20% to about 30%, about 20% to about 40%, about 20% to about 50%, about 20% to about 60%, about 20% to about 70%, about 20% to about 80%, about 20% to about 90%, about 30% to about 40%, about 30% to about 50%, about 30% to about 60%, about 30% to about 70%, about 30% to about 80%, about 30% to about 90%, about 40% to about 50%, about 40% to about 60%, about 40% to about 70%, about 40% to about 80%, about 40% to about 90%, about 50% to about 60%, about 50% to about 70%, about 50% to about 80%, about 50% to about 90%, about 60% to about 70%, about 60% to about 80%, about 60% to about 90%, about 70% to about 80%, about 70% to about 90%, or about 80% to about 90%, including increments therein. In some embodiments, the conductive ink, when wet, has a w/w concentration of the solvent of about 20%, about 30%, about 40%, about 50%, about 60%, about 70%, about 80%, or about 90%. In some embodiments, the conductive ink, when wet, has a w/w concentration of the solvent of at least about 20%, about 30%, about 40%, about 50%, about 60%, about 70%, or about 80%. In some embodiments, the conductive ink, when wet, has a w/w concentration of the solvent of at most about 30%, about 40%, about 50%, about 60%, about 70%, about 80%, or about 90%.

In some embodiments, the conductive ink further comprises a softening agent. In some embodiments, the softening agent increases the flexibility of the cured ink. In some embodiments, the softening agent reduces the brittleness of the cured ink. In some embodiments, the softening agent comprises diethylene glycol. In some embodiments, the conductive ink, when wet, has a w/w concentration of the softening agent of about 5% to about 80%. In some embodiments, the conductive ink, when wet, has a w/w concentration of the softening agent of about 5% to about 15%, about 5% to about 25%, about 5% to about 35%, about 5% to about 45%, about 5% to about 55%, about 5% to about 65%, about 5% to about 75%, about 5% to about 80%, about 15% to about 25%, about 15% to about 35%, about 15% to about 45%, about 15% to about 55%, about 15% to about 65%, about 15% to about 75%, about 15% to about 80%, about 25% to about 35%, about 25% to about 45%, about 25% to about 55%, about 25% to about 65%, about 25% to about 75%, about 25% to about 80%, about 35% to about 45%, about 35% to about 55%, about 35% to about 65%, about 35% to about 75%, about 35% to about 80%, about 45% to about 55%, about 45% to about 65%, about 45% to about 75%, about 45% to about 80%, about 55% to about 65%, about 55% to about 75%, about 55% to about 80%, about 65% to about 75%, about 65% to about 80%, or about 75% to about 80%, including increments therein. In some embodiments, the conductive ink, when wet, has a w/w concentration of the softening agent of about 5%, about 15%, about 25%, about 35%, about 45%, about 55%, about 65%, about 75%, or about 80%. In some embodiments, the conductive ink, when wet, has a w/w concentration of the softening agent of at least about 5%, about 15%, about 25%, about 35%, about 45%, about 55%, about 65%, or about 75%. In some embodiments, the conductive ink, when wet, has a w/w concentration of the softening agent of at most about 15%, about 25%, about 35%, about 45%, about 55%, about 65%, about 75%, or about 80%.

### Characterization of Conductive Inks

The embodiments disclosed herein comprise an ink formulation that is suitable for application with roll-to-roll coating, screen printing, extruder printing, flexography, slot-die, and knife-over-edge printing.

In some embodiments, the conductive inks herein exhibit level 5B adhesion (ideal adhesion), enabling their use on a wide array of substrates, such as, for example, polyimide (PI or Kaptan), glass, aluminum, and polyethylene terephthalate (PET). Further, while the components in many current conductive inks separate and form non-dispersible clumps, the conductive inks herein exhibit a shelf life of over 1 year, wherein the components of the ink remain in solution. Further, unlike many current conductive inks, the conductive inks herein inks can be produced and supplied in large volumes. Additionally, the conductive inks herein improve the efficiency and speed of forming printed conductive materials, as they can be cured at any temperature, and at curing times as low as 30 minutes or less at temperatures below 300° C., and in some cases can be cured within 30 minutes at a temperature of 100° C. Finally, the conductive inks herein are water-soluble, and produce consistent, continuous coatings when dried.

In some embodiments, the conductive ink has a solid content of about 70% wt to about 80% wt. In some embodiments, the conductive ink has a solid content of about 70% wt to about 71% wt, about 70% wt to about 72% wt, about 70% wt to about 73% wt, about 70% wt to about 74% wt, about 70% wt to about 75% wt, about 70% wt to about 76% wt, about 70% wt to about 77% wt, about 70% wt to about 78% wt, about 70% wt to about 79% wt, about 70% wt to about 80% wt, about 71% wt to about 72% wt, about 71% wt to about 73% wt, about 71% wt to about 74% wt, about 71% wt to about 75% wt, about 71% wt to about 76% wt, about 71% wt to about 77% wt, about 71% wt to about 78% wt, about 71% wt to about 79% wt, about 71% wt to about 80% wt, about 72% wt to about 73% wt, about 72% wt to about 74% wt, about 72% wt to about 75% wt, about 72% wt to about 76% wt, about 72% wt to about 77% wt, about 72% wt to about 78% wt, about 72% wt to about 79% wt, about 72% wt to about 80% wt, about 73% wt to about 74% wt, about 73% wt to about 75% wt, about 73% wt to about 76% wt, about 73% wt to about 77% wt, about 73% wt to about 78% wt, about 73% wt to about 79% wt, about 73% wt to about 80% wt, about 74% wt to about 75% wt, about 74% wt to about 76% wt, about 74% wt to about 77% wt, about 74% wt to about 78% wt, about 74% wt to about 79% wt, about 74% wt to about 80% wt, about 75% wt to about 76% wt, about 75% wt to about 77% wt, about 75% wt to about 78% wt, about 75% wt to about 79% wt, about 75% wt to about 80% wt, about 76% wt to about 77% wt, about 76% wt to about 78% wt, about 76% wt to about 79% wt, about 76% wt to about 80% wt, about 77% wt to about 78% wt, about 77% wt to about 79% wt, about 77% wt to about 80% wt, about 78% wt to about 79% wt, about 78% wt to about 80% wt, or about 79% wt to about 80% wt, including increments therein. In some embodiments, the conductive ink has a solid content of about 70% wt, about 71% wt, about 72% wt, about 73% wt, about 74% wt, about 75% wt, about 76% wt, about 77% wt, about 78% wt, about 79% wt, or about 80% wt. In some embodiments, the conductive ink has a solid content of at least about 70% wt, about 71% wt, about 72% wt, about 73% wt, about 74% wt, about 75% wt, about 76% wt, about 77% wt, about 78% wt, or about 79% wt. In some embodiments, the conductive ink has a solid content of about at most about 71% wt, about 72% wt, about 73% wt, about 74% wt, about 75% wt, about 76% wt, about 77% wt, about 78% wt, about 79% wt, or about 80% wt. In some embodiments, the conductive ink has a solid content of about 75% wt. In some embodiments, the conductive ink has a solid content of at least 70% wt. In some embodiments, the conductive ink has a solid content of up to 80% wt.

In some embodiments, the ink is a shear-thinning fluid. In some embodiments, the ink is suitable for screen printing, extruder printing, flexography application, slot-die application, and knife-over-edge coating application. In some embodiments, the ink is suitable for screen printing. In some embodiments, the ink does not leave pin holes when applied. In some embodiments, the ink does not separate when cured. In some embodiments, the ink does not shrink when cured. In some embodiments, the ink does not reduce its surface area when cured. In some embodiments, the ink has a dry film thickness that is less than a wet film thickness. In some embodiments, a change in dry film thickness correlates to a change in wet film thickness with a differential of about 0.5. In some embodiments, the ink is adhesive. In some embodiments, the ink comprises a 5B adhesion on PET, PI, Kapton, or glass. In some embodiments, the ink is stable at room temperature, e.g., 20° C.-25° C.

In some embodiments, the ink cures at 300° C. In some embodiments, the ink cures at 300° C. within about 30 minutes. In some embodiments, the ink cures at 300° C. within about 1, 2, 3, 4, 5, 6, 7, 8, 9, 10, 11, 12, 13, 14, 15, 16, 17, 18, 19, 20, 21, 22, 23, 24, 25, 26, 27, 28, 29 or 30 minutes.

In some embodiments, the ink cures at 300° C. In some embodiments, the ink cures at 110° C. within about 30 minutes. In some embodiments, the ink cures at 110° C. within about 1, 2, 3, 4, 5, 6, 7, 8, 9, 10, 11, 12, 13, 14, 15, 16, 17, 18, 19, 20, 21, 22, 23, 24, 25, 26, 27, 28, 29 or 30 minutes.

In some embodiments, the conductive ink comprises a sheet resistance of at least about 0.017 ohms/sq.

In some embodiments, the conductive ink comprises a sheet resistance of up to about 0.006 ohms/sq to about 0.084 ohms/sq. In some embodiments, the conductive ink comprises a sheet resistance of up to about 0.006 ohms/sq to about 0.012 ohms/sq, about 0.006 ohms/sq to about 0.018 ohms/sq, about 0.006 ohms/sq to about 0.024 ohms/sq, about 0.006 ohms/sq to about 0.03 ohms/sq, about 0.006 ohms/sq to about 0.036 ohms/sq, about 0.006 ohms/sq to about 0.042 ohms/sq, about 0.006 ohms/sq to about 0.048 ohms/sq, about 0.006 ohms/sq to about 0.054 ohms/sq, about 0.006 ohms/sq to about 0.06 ohms/sq, about 0.006 ohms/sq to about 0.072 ohms/sq, about 0.006 ohms/sq to about 0.084 ohms/sq, about 0.012 ohms/sq to about 0.018 ohms/sq, about 0.012 ohms/sq to about 0.024 ohms/sq, about 0.012 ohms/sq to about 0.03 ohms/sq, about 0.012 ohms/sq to about 0.036 ohms/sq, about 0.012 ohms/sq to about 0.042 ohms/sq, about 0.012 ohms/sq to about 0.048 ohms/sq, about 0.012 ohms/sq to about 0.054 ohms/sq, about 0.012 ohms/sq to about 0.06 ohms/sq, about 0.012 ohms/sq to about 0.072 ohms/sq, about 0.012 ohms/sq to about 0.084 ohms/sq, about 0.018 ohms/sq to about 0.024 ohms/sq, about 0.018 ohms/sq to about 0.03 ohms/sq, about 0.018 ohms/sq to about 0.036 ohms/sq, about 0.018 ohms/sq to about 0.042 ohms/sq, about 0.018 ohms/sq to about 0.048 ohms/sq, about 0.018 ohms/sq to about 0.054 ohms/sq, about 0.018 ohms/sq to about 0.06 ohms/sq, about 0.018 ohms/sq to about 0.072 ohms/sq, about 0.018 ohms/sq to about 0.084 ohms/sq, about 0.024 ohms/sq to about 0.03 ohms/sq, about 0.024 ohms/sq to about 0.036 ohms/sq, about 0.024 ohms/sq to about 0.042 ohms/sq, about 0.024 ohms/sq to about 0.048 ohms/sq, about 0.024 ohms/sq to about 0.054 ohms/sq, about 0.024 ohms/sq to about 0.06 ohms/sq, about 0.024 ohms/sq to about 0.072 ohms/sq, about 0.024 ohms/sq to about 0.084 ohms/sq, about 0.03 ohms/sq to about 0.036 ohms/sq, about 0.03 ohms/sq to about 0.042 ohms/sq, about 0.03 ohms/sq to about 0.048 ohms/sq, about 0.03 ohms/sq to about 0.054 ohms/sq, about 0.03 ohms/sq to about 0.06 ohms/sq, about 0.03 ohms/sq to about 0.072 ohms/sq, about 0.03 ohms/sq to about 0.084 ohms/sq, about 0.036 ohms/sq to about 0.042 ohms/sq, about 0.036 ohms/sq to about 0.048 ohms/sq, about 0.036 ohms/sq to about 0.054 ohms/sq, about 0.036 ohms/sq to about 0.06 ohms/sq, about 0.036 ohms/sq to about 0.072 ohms/sq, about 0.036 ohms/sq to about 0.084 ohms/sq, about 0.042 ohms/sq to about 0.048 ohms/sq, about 0.042 ohms/sq to about 0.054 ohms/sq, about 0.042 ohms/sq to about 0.06 ohms/sq, about 0.042 ohms/sq to about 0.072 ohms/sq, about 0.042 ohms/sq to about 0.084 ohms/sq, about 0.048 ohms/sq to about 0.054 ohms/sq, about 0.048 ohms/sq to about 0.06 ohms/sq, about 0.048 ohms/sq to about 0.072 ohms/sq, about 0.048 ohms/sq to about 0.084 ohms/sq, about 0.054 ohms/sq to about 0.06 ohms/sq, about 0.054 ohms/sq to about 0.072 ohms/sq, about 0.054 ohms/sq to about 0.084 ohms/sq, about 0.06 ohms/sq to about 0.072 ohms/sq, about 0.06 ohms/sq to about 0.084 ohms/sq, or about 0.072 ohms/sq to about 0.084 ohms/sq, including increments therein. In some embodiments, the conductive ink comprises a sheet resistance of up to about 0.006 ohms/sq, about 0.012 ohms/sq, about 0.018 ohms/sq, about 0.024 ohms/sq, about 0.03 ohms/sq, about 0.036 ohms/sq, about 0.042 ohms/sq, about 0.048 ohms/sq, about 0.054 ohms/sq, about 0.06 ohms/sq, about 0.072 ohms/sq, or about 0.084 ohms/sq. In some embodiments, the conductive ink comprises a sheet resistance of up to about at least about 0.006 ohms/sq, about 0.012 ohms/sq, about 0.018 ohms/sq, about 0.024 ohms/sq, about 0.03 ohms/sq, about 0.036 ohms/sq, about 0.042 ohms/sq, about 0.048 ohms/sq, about 0.054 ohms/sq, about 0.06 ohms/sq, or about 0.072 ohms/sq. In some embodiments, the conductive ink comprises a sheet resistance of up to about at most about 0.012 ohms/sq, about 0.018 ohms/sq, about 0.024 ohms/sq, about 0.03 ohms/sq, about 0.036 ohms/sq, about 0.042 ohms/sq, about 0.048 ohms/sq, about 0.054 ohms/sq, about 0.06 ohms/sq, about 0.072 ohms/sq, or about 0.084 ohms/sq.

In some embodiments, the conductive ink comprises a sheet resistance of up to about 0.01 ohms/sq at a dry film thickness of about 20 μm to about 0.08 ohms/sq at a dry film thickness of about 20 μm. In some embodiments, the conductive ink comprises a sheet resistance of up to about 0.01 ohms/sq at a dry film thickness of about 20 μm to about 0.02 ohms/sq at a dry film thickness of about 20 μm, about 0.01 ohms/sq at a dry film thickness of about 20 μm to about 0.03 ohms/sq at a dry film thickness of about 20 μm, about 0.01 ohms/sq at a dry film thickness of about 20 μm to about 0.04 ohms/sq at a dry film thickness of about 20 μm, about 0.01 ohms/sq at a dry film thickness of about 20 μm to about 0.05 ohms/sq at a dry film thickness of about 20 μm, about 0.01 ohms/sq at a dry film thickness of about 20 μm to about 0.06 ohms/sq at a dry film thickness of about 20 μm, about 0.01 ohms/sq at a dry film thickness of about 20 μm to about 0.07 ohms/sq at a dry film thickness of about 20 μm, about 0.01 ohms/sq at a dry film thickness of about 20 μm to about 0.08 ohms/sq at a dry film thickness of about 20 μm, about 0.02 ohms/sq at a dry film thickness of about 20 μm to about 0.03 ohms/sq at a dry film thickness of about 20 μm, about 0.02 ohms/sq at a dry film thickness of about 20 μm to about 0.04 ohms/sq at a dry film thickness of about 20 μm, about 0.02 ohms/sq at a dry film thickness of about 20 μm to about 0.05 ohms/sq at a dry film thickness of about 20 μm, about 0.02 ohms/sq at a dry film thickness of about 20 μm to about 0.06 ohms/sq at a dry film thickness of about 20 μm, about 0.02 ohms/sq at a dry film thickness of about 20 μm to about 0.07 ohms/sq at a dry film thickness of about 20 μm, about 0.02 ohms/sq at a dry film thickness of about 20 μm to about 0.08 ohms/sq at a dry film thickness of about 20 μm, about 0.03 ohms/sq at a dry film thickness of about 20 μm to about 0.04 ohms/sq at a dry film thickness of about 20 μm, about 0.03 ohms/sq at a dry film thickness of about 20 μm to about 0.05 ohms/sq at a dry film thickness of about 20 μm, about 0.03 ohms/sq at a dry film thickness of about 20 μm to about 0.06 ohms/sq at a dry film thickness of about 20 μm, about 0.03 ohms/sq at a dry film thickness of about 20 μm to about 0.07 ohms/sq at a dry film thickness of about 20 μm, about 0.03 ohms/sq at a dry film thickness of about 20 μm to about 0.08 ohms/sq at a dry film thickness of about 20 μm, about 0.04 ohms/sq at a dry film thickness of about 20 μm to about 0.05 ohms/sq at a dry film thickness of about 20 μm, about 0.04 ohms/sq at a dry film thickness of about 20 μm to about 0.06 ohms/sq at a dry film thickness of about 20 μm, about 0.04 ohms/sq at a dry film thickness of about 20 μm to about 0.07 ohms/sq at a dry film thickness of about 20 μm, about 0.04 ohms/sq at a dry film thickness of about 20 μm to about 0.08 ohms/sq at a dry film thickness of about 20 μm, about 0.05 ohms/sq at a dry film thickness of about 20 μm to about 0.06 ohms/sq at a dry film thickness of about 20 μm, about 0.05 ohms/sq at a dry film thickness of about 20 μm to about 0.07 ohms/sq at a dry film thickness of about 20 μm, about 0.05 ohms/sq at a dry film thickness of about 20 μm to about 0.08 ohms/sq at a dry film thickness of about 20 μm, about 0.06 ohms/sq at a dry film thickness of about 20 μm to about 0.07 ohms/sq at a dry film thickness of about 20 μm, about 0.06 ohms/sq at a dry film thickness of about 20 μm to about 0.08 ohms/sq at a dry film thickness of about 20 μm, or about 0.07 ohms/sq at a dry film thickness of about 20 μm to about 0.08 ohms/sq at a dry film thickness of about 20 μm, including increments therein. In some embodiments, the conductive ink comprises a sheet resistance of up to about 0.01 ohms/sq at a dry film thickness of about 20 μm, about 0.02 ohms/sq at a dry film thickness of about 20 μm, about 0.03 ohms/sq at a dry film thickness of about 20 μm, about 0.04 ohms/sq at a dry film thickness of about 20 μm, about 0.05 ohms/sq at a dry film thickness of about 20 μm, about 0.06 ohms/sq at a dry film thickness of about 20 μm, about 0.07 ohms/sq at a dry film thickness of about 20 μm, or about 0.08 ohms/sq at a dry film thickness of about 20 μm. In some embodiments, the conductive ink comprises a sheet resistance of up to at least about 0.01 ohms/sq at a dry film thickness of about 20 μm, about 0.02 ohms/sq at a dry film thickness of about 20 μm, about 0.03 ohms/sq at a dry film thickness of about 20 μm, about 0.04 ohms/sq at a dry film thickness of about 20 μm, about 0.05 ohms/sq at a dry film thickness of about 20 μm, about 0.06 ohms/sq at a dry film thickness of about 20 μm, or about 0.07 ohms/sq at a dry film thickness of about 20 μm. In some embodiments, the conductive ink comprises a sheet resistance of up to at most about 0.02 ohms/sq at a dry film thickness of about 20 μm, about 0.03 ohms/sq at a dry film thickness of about 20 μm, about 0.04 ohms/sq at a dry film thickness of about 20 μm, about 0.05 ohms/sq at a dry film thickness of about 20 μm, about 0.06 ohms/sq at a dry film thickness of about 20 μm, about 0.07 ohms/sq at a dry film thickness of about 20 μm, or about 0.08 ohms/sq at a dry film thickness of about 20 μm. In some embodiments, the conductive ink comprises a sheet resistance of up to about 0.01 ohms/sq at a dry film thickness of about 30 μm to about 0.025 ohms/sq at a dry film thickness of about 30 μm. In some embodiments, the conductive ink comprises a sheet resistance of up to about 0.01 ohms/sq at a dry film thickness of about 30 μm to about 0.015 ohms/sq at a dry film thickness of about 30 μm, about 0.01 ohms/sq at a dry film thickness of about 30 μm to about 0.02 ohms/sq at a dry film thickness of about 30 μm, about 0.01 ohms/sq at a dry film thickness of about 30 μm to about 0.025 ohms/sq at a dry film thickness of about 30 μm, about 0.015 ohms/sq at a dry film thickness of about 30 μm to about 0.02 ohms/sq at a dry film thickness of about 30 μm, about 0.015 ohms/sq at a dry film thickness of about 30 μm to about 0.025 ohms/sq at a dry film thickness of about 30 μm, or about 0.02 ohms/sq at a dry film thickness of about 30 μm to about 0.025 ohms/sq at a dry film thickness of about 30 μm, including increments therein. In some embodiments, the conductive ink comprises a sheet resistance of up to about 0.01 ohms/sq at a dry film thickness of about 30 μm, about 0.015 ohms/sq at a dry film thickness of about 30 μm, about 0.02 ohms/sq at a dry film thickness of about 30 μm, or about 0.025 ohms/sq at a dry film thickness of about 30 μm. In some embodiments, the conductive ink comprises a sheet resistance of up to at least about 0.01 ohms/sq at a dry film thickness of about 30 μm, about 0.015 ohms/sq at a dry film thickness of about 30 μm, or about 0.02 ohms/sq at a dry film thickness of about 30 μm. In some embodiments, the conductive ink comprises a sheet resistance of up to at most about 0.015 ohms/sq at a dry film thickness of about 30 μm, about 0.02 ohms/sq at a dry film thickness of about 30 μm, or about 0.025 ohms/sq at a dry film thickness of about 30 μm.

In some embodiments, the conductive ink comprises a sheet resistance of up to about 0.01 ohms/sq at a dry film thickness of about 36 μm to about 0.028 ohms/sq at a dry film thickness of about 36 μm. In some embodiments, the conductive ink comprises a sheet resistance of up to about 0.01 ohms/sq at a dry film thickness of about 36 μm to about 0.015 ohms/sq at a dry film thickness of about 36 μm, about 0.01 ohms/sq at a dry film thickness of about 36 μm to about 0.02 ohms/sq at a dry film thickness of about 36 μm, about 0.01 ohms/sq at a dry film thickness of about 36 μm to about 0.025 ohms/sq at a dry film thickness of about 36 μm, about 0.01 ohms/sq at a dry film thickness of about 36 μm to about 0.026 ohms/sq at a dry film thickness of about 36 μm, about 0.01 ohms/sq at a dry film thickness of about 36 μm to about 0.027 ohms/sq at a dry film thickness of about 36 μm, about 0.01 ohms/sq at a dry film thickness of about 36 μm to about 0.028 ohms/sq at a dry film thickness of about 36 μm, about 0.015 ohms/sq at a dry film thickness of about 36 μm to about 0.02 ohms/sq at a dry film thickness of about 36 μm, about 0.015 ohms/sq at a dry film thickness of about 36 μm to about 0.025 ohms/sq at a dry film thickness of about 36 μm, about 0.015 ohms/sq at a dry film thickness of about 36 μm to about 0.026 ohms/sq at a dry film thickness of about 36 μm, about 0.015 ohms/sq at a dry film thickness of about 36 μm to about 0.027 ohms/sq at a dry film thickness of about 36 μm, about 0.015 ohms/sq at a dry film thickness of about 36 μm to about 0.028 ohms/sq at a dry film thickness of about 36 μm, about 0.02 ohms/sq at a dry film thickness of about 36 μm to about 0.025 ohms/sq at a dry film thickness of about 36 μm, about 0.02 ohms/sq at a dry film thickness of about 36 μm to about 0.026 ohms/sq at a dry film thickness of about 36 μm, about 0.02 ohms/sq at a dry film thickness of about 36 μm to about 0.027 ohms/sq at a dry film thickness of about 36 μm, about 0.02 ohms/sq at a dry film thickness of about 36 μm to about 0.028 ohms/sq at a dry film thickness of about 36 μm, about 0.025 ohms/sq at a dry film thickness of about 36 μm to about 0.026 ohms/sq at a dry film thickness of about 36 μm, about 0.025 ohms/sq at a dry film thickness of about 36 μm to about 0.027 ohms/sq at a dry film thickness of about 36 μm, about 0.025 ohms/sq at a dry film thickness of about 36 μm to about 0.028 ohms/sq at a dry film thickness of about 36 μm, about 0.026 ohms/sq at a dry film thickness of about 36 μm to about 0.027 ohms/sq at a dry film thickness of about 36 μm, about 0.026 ohms/sq at a dry film thickness of about 36 μm to about 0.028 ohms/sq at a dry film thickness of about 36 μm, or about 0.027 ohms/sq at a dry film thickness of about 36 μm to about 0.028 ohms/sq at a dry film thickness of about 36 μm, including increments therein. In some embodiments, the conductive ink comprises a sheet resistance of up to about 0.01 ohms/sq at a dry film thickness of about 36 μm, about 0.015 ohms/sq at a dry film thickness of about 36 μm, about 0.02 ohms/sq at a dry film thickness of about 36 μm, about 0.025 ohms/sq at a dry film thickness of about 36 μm, about 0.026 ohms/sq at a dry film thickness of about 36 μm, about 0.027 ohms/sq at a dry film thickness of about 36 μm, or about 0.028 ohms/sq at a dry film thickness of about 36 μm. In some embodiments, the conductive ink comprises a sheet resistance of up to at least about 0.01 ohms/sq at a dry film thickness of about 36 μm, about 0.015 ohms/sq at a dry film thickness of about 36 μm, about 0.02 ohms/sq at a dry film thickness of about 36 μm, about 0.025 ohms/sq at a dry film thickness of about 36 μm, about 0.026 ohms/sq at a dry film thickness of about 36 μm, or about 0.027 ohms/sq at a dry film thickness of about 36 μm. In some embodiments, the conductive ink comprises a sheet resistance of up to at most about 0.015 ohms/sq at a dry film thickness of about 36 μm, about 0.02 ohms/sq at a dry film thickness of about 36 μm, about 0.025 ohms/sq at a dry film thickness of about 36 μm, about 0.026 ohms/sq at a dry film thickness of about 36 μm, about 0.027 ohms/sq at a dry film thickness of about 36 μm, or about 0.028 ohms/sq at a dry film thickness of about 36 μm.

In some embodiments, the conductive ink comprises a sheet resistance of up to about 0.01 ohms/sq at a dry film thickness of about 40 μm to about 0.027 ohms/sq at a dry film thickness of about 40 μm. In some embodiments, the conductive ink comprises a sheet resistance of up to about 0.01 ohms/sq at a dry film thickness of about 40 μm to about 0.015 ohms/sq at a dry film thickness of about 40 μm, about 0.01 ohms/sq at a dry film thickness of about 40 μm to about 0.02 ohms/sq at a dry film thickness of about 40 μm, about 0.01 ohms/sq at a dry film thickness of about 40 μm to about 0.025 ohms/sq at a dry film thickness of about 40 μm, about 0.01 ohms/sq at a dry film thickness of about 40 μm to about 0.026 ohms/sq at a dry film thickness of about 40 μm, about 0.01 ohms/sq at a dry film thickness of about 40 μm to about 0.027 ohms/sq at a dry film thickness of about 40 μm, about 0.015 ohms/sq at a dry film thickness of about 40 μm to about 0.02 ohms/sq at a dry film thickness of about 40 μm, about 0.015 ohms/sq at a dry film thickness of about 40 μm to about 0.025 ohms/sq at a dry film thickness of about 40 μm, about 0.015 ohms/sq at a dry film thickness of about 40 μm to about 0.026 ohms/sq at a dry film thickness of about 40 μm, about 0.015 ohms/sq at a dry film thickness of about 40 μm to about 0.027 ohms/sq at a dry film thickness of about 40 μm, about 0.02 ohms/sq at a dry film thickness of about 40 μm to about 0.025 ohms/sq at a dry film thickness of about 40 μm, about 0.02 ohms/sq at a dry film thickness of about 40 μm to about 0.026 ohms/sq at a dry film thickness of about 40 μm, about 0.02 ohms/sq at a dry film thickness of about 40 μm to about 0.027 ohms/sq at a dry film thickness of about 40 μm, about 0.025 ohms/sq at a dry film thickness of about 40 μm to about 0.026 ohms/sq at a dry film thickness of about 40 μm, about 0.025 ohms/sq at a dry film thickness of about 40 μm to about 0.027 ohms/sq at a dry film thickness of about 40 μm, or about 0.026 ohms/sq at a dry film thickness of about 40 μm to about 0.027 ohms/sq at a dry film thickness of about 40 μm, including increments therein. In some embodiments, the conductive ink comprises a sheet resistance of up to about 0.01 ohms/sq at a dry film thickness of about 40 μm, about 0.015 ohms/sq at a dry film thickness of about 40 μm, about 0.02 ohms/sq at a dry film thickness of about 40 μm, about 0.025 ohms/sq at a dry film thickness of about 40 μm, about 0.026 ohms/sq at a dry film thickness of about 40 μm, or about 0.027 ohms/sq at a dry film thickness of about 40 μm. In some embodiments, the conductive ink comprises a sheet resistance of up to at least about 0.01 ohms/sq at a dry film thickness of about 40 μm, about 0.015 ohms/sq at a dry film thickness of about 40 μm, about 0.02 ohms/sq at a dry film thickness of about 40 μm, about 0.025 ohms/sq at a dry film thickness of about 40 μm, or about 0.026 ohms/sq at a dry film thickness of about 40 μm. In some embodiments, the conductive ink comprises a sheet resistance of up to at most about 0.015 ohms/sq at a dry film thickness of about 40 μm, about 0.02 ohms/sq at a dry film thickness of about 40 μm, about 0.025 ohms/sq at a dry film thickness of about 40 μm, about 0.026 ohms/sq at a dry film thickness of about 40 μm, or about 0.027 ohms/sq at a dry film thickness of about 40 μm.

In some embodiments, the conductive ink comprises a sheet resistance of up to about 0.01 ohms/sq at a dry film thickness of about 65 μm to about 0.023 ohms/sq at a dry film thickness of about 65 μm. In some embodiments, the conductive ink comprises a sheet resistance of up to about 0.01 ohms/sq at a dry film thickness of about 65 μm to about 0.015 ohms/sq at a dry film thickness of about 65 μm, about 0.01 ohms/sq at a dry film thickness of about 65 μm to about 0.02 ohms/sq at a dry film thickness of about 65 μm, about 0.01 ohms/sq at a dry film thickness of about 65 μm to about 0.021 ohms/sq at a dry film thickness of about 65 μm, about 0.01 ohms/sq at a dry film thickness of about 65 μm to about 0.022 ohms/sq at a dry film thickness of about 65 μm, about 0.01 ohms/sq at a dry film thickness of about 65 μm to about 0.023 ohms/sq at a dry film thickness of about 65 μm, about 0.015 ohms/sq at a dry film thickness of about 65 μm to about 0.02 ohms/sq at a dry film thickness of about 65 μm, about 0.015 ohms/sq at a dry film thickness of about 65 μm to about 0.021 ohms/sq at a dry film thickness of about 65 μm, about 0.015 ohms/sq at a dry film thickness of about 65 μm to about 0.022 ohms/sq at a dry film thickness of about 65 μm, about 0.015 ohms/sq at a dry film thickness of about 65 μm to about 0.023 ohms/sq at a dry film thickness of about 65 μm, about 0.02 ohms/sq at a dry film thickness of about 65 μm to about 0.021 ohms/sq at a dry film thickness of about 65 μm, about 0.02 ohms/sq at a dry film thickness of about 65 μm to about 0.022 ohms/sq at a dry film thickness of about 65 μm, about 0.02 ohms/sq at a dry film thickness of about 65 μm to about 0.023 ohms/sq at a dry film thickness of about 65 μm, about 0.021 ohms/sq at a dry film thickness of about 65 μm to about 0.022 ohms/sq at a dry film thickness of about 65 μm, about 0.021 ohms/sq at a dry film thickness of about 65 μm to about 0.023 ohms/sq at a dry film thickness of about 65 μm, or about 0.022 ohms/sq at a dry film thickness of about 65 μm to about 0.023 ohms/sq at a dry film thickness of about 65 μm, including increments therein. In some embodiments, the conductive ink comprises a sheet resistance of up to about 0.01 ohms/sq at a dry film thickness of about 65 μm, about 0.015 ohms/sq at a dry film thickness of about 65 μm, about 0.02 ohms/sq at a dry film thickness of about 65 μm, about 0.021 ohms/sq at a dry film thickness of about 65 μm, about 0.022 ohms/sq at a dry film thickness of about 65 μm, or about 0.023 ohms/sq at a dry film thickness of about 65 μm. In some embodiments, the conductive ink comprises a sheet resistance of up to at least about 0.01 ohms/sq at a dry film thickness of about 65 μm, about 0.015 ohms/sq at a dry film thickness of about 65 μm, about 0.02 ohms/sq at a dry film thickness of about 65 μm, about 0.021 ohms/sq at a dry film thickness of about 65 μm, or about 0.022 ohms/sq at a dry film thickness of about 65 μm. In some embodiments, the conductive ink comprises a sheet resistance of up to at most about 0.015 ohms/sq at a dry film thickness of about 65 μm, about 0.02 ohms/sq at a dry film thickness of about 65 μm, about 0.021 ohms/sq at a dry film thickness of about 65 μm, about 0.022 ohms/sq at a dry film thickness of about 65 μm, or about 0.023 ohms/sq at a dry film thickness of about 65 μm.

In some embodiments, the conductive ink comprises a sheet resistance of up to about 0.001 ohms/sq at a dry film thickness of about 90 μm to about 0.017 ohms/sq at a dry film thickness of about 90 μm. In some embodiments, the conductive ink comprises a sheet resistance of up to about 0.001 ohms/sq at a dry film thickness of about 90 μm to about 0.003 ohms/sq at a dry film thickness of about 90 μm, about 0.001 ohms/sq at a dry film thickness of about 90 μm to about 0.005 ohms/sq at a dry film thickness of about 90 μm, about 0.001 ohms/sq at a dry film thickness of about 90 μm to about 0.007 ohms/sq at a dry film thickness of about 90 μm, about 0.001 ohms/sq at a dry film thickness of about 90 μm to about 0.009 ohms/sq at a dry film thickness of about 90 μm, about 0.001 ohms/sq at a dry film thickness of about 90 μm to about 0.011 ohms/sq at a dry film thickness of about 90 μm, about 0.001 ohms/sq at a dry film thickness of about 90 μm to about 0.012 ohms/sq at a dry film thickness of about 90 μm, about 0.001 ohms/sq at a dry film thickness of about 90 μm to about 0.013 ohms/sq at a dry film thickness of about 90 μm, about 0.001 ohms/sq at a dry film thickness of about 90 μm to about 0.014 ohms/sq at a dry film thickness of about 90 μm, about 0.001 ohms/sq at a dry film thickness of about 90 μm to about 0.015 ohms/sq at a dry film thickness of about 90 μm, about 0.001 ohms/sq at a dry film thickness of about 90 μm to about 0.016 ohms/sq at a dry film thickness of about 90 μm, about 0.001 ohms/sq at a dry film thickness of about 90 μm to about 0.017 ohms/sq at a dry film thickness of about 90 μm, about 0.003 ohms/sq at a dry film thickness of about 90 μm to about 0.005 ohms/sq at a dry film thickness of about 90 μm, about 0.003 ohms/sq at a dry film thickness of about 90 μm to about 0.007 ohms/sq at a dry film thickness of about 90 μm, about 0.003 ohms/sq at a dry film thickness of about 90 μm to about 0.009 ohms/sq at a dry film thickness of about 90 μm, about 0.003 ohms/sq at a dry film thickness of about 90 μm to about 0.011 ohms/sq at a dry film thickness of about 90 μm, about 0.003 ohms/sq at a dry film thickness of about 90 μm to about 0.012 ohms/sq at a dry film thickness of about 90 μm, about 0.003 ohms/sq at a dry film thickness of about 90 μm to about 0.013 ohms/sq at a dry film thickness of about 90 μm, about 0.003 ohms/sq at a dry film thickness of about 90 μm to about 0.014 ohms/sq at a dry film thickness of about 90 μm, about 0.003 ohms/sq at a dry film thickness of about 90 μm to about 0.015 ohms/sq at a dry film thickness of about 90 μm, about 0.003 ohms/sq at a dry film thickness of about 90 μm to about 0.016 ohms/sq at a dry film thickness of about 90 μm, about 0.003 ohms/sq at a dry film thickness of about 90 μm to about 0.017 ohms/sq at a dry film thickness of about 90 μm, about 0.005 ohms/sq at a dry film thickness of about 90 μm to about 0.007 ohms/sq at a dry film thickness of about 90 μm, about 0.005 ohms/sq at a dry film thickness of about 90 μm to about 0.009 ohms/sq at a dry film thickness of about 90 μm, about 0.005 ohms/sq at a dry film thickness of about 90 μm to about 0.011 ohms/sq at a dry film thickness of about 90 μm, about 0.005 ohms/sq at a dry film thickness of about 90 μm to about 0.012 ohms/sq at a dry film thickness of about 90 μm, about 0.005 ohms/sq at a dry film thickness of about 90 μm to about 0.013 ohms/sq at a dry film thickness of about 90 μm, about 0.005 ohms/sq at a dry film thickness of about 90 μm to about 0.014 ohms/sq at a dry film thickness of about 90 μm, about 0.005 ohms/sq at a dry film thickness of about 90 μm to about 0.015 ohms/sq at a dry film thickness of about 90 μm, about 0.005 ohms/sq at a dry film thickness of about 90 μm to about 0.016 ohms/sq at a dry film thickness of about 90 μm, about 0.005 ohms/sq at a dry film thickness of about 90 μm to about 0.017 ohms/sq at a dry film thickness of about 90 μm, about 0.007 ohms/sq at a dry film thickness of about 90 μm to about 0.009 ohms/sq at a dry film thickness of about 90 μm, about 0.007 ohms/sq at a dry film thickness of about 90 μm to about 0.011 ohms/sq at a dry film thickness of about 90 μm, about 0.007 ohms/sq at a dry film thickness of about 90 μm to about 0.012 ohms/sq at a dry film thickness of about 90 μm, about 0.007 ohms/sq at a dry film thickness of about 90 μm to about 0.013 ohms/sq at a dry film thickness of about 90 μm, about 0.007 ohms/sq at a dry film thickness of about 90 μm to about 0.014 ohms/sq at a dry film thickness of about 90 μm, about 0.007 ohms/sq at a dry film thickness of about 90 μm to about 0.015 ohms/sq at a dry film thickness of about 90 μm, about 0.007 ohms/sq at a dry film thickness of about 90 μm to about 0.016 ohms/sq at a dry film thickness of about 90 μm, about 0.007 ohms/sq at a dry film thickness of about 90 μm to about 0.017 ohms/sq at a dry film thickness of about 90 μm, about 0.009 ohms/sq at a dry film thickness of about 90 μm to about 0.011 ohms/sq at a dry film thickness of about 90 μm, about 0.009 ohms/sq at a dry film thickness of about 90 μm to about 0.012 ohms/sq at a dry film thickness of about 90 μm, about 0.009 ohms/sq at a dry film thickness of about 90 μm to about 0.013 ohms/sq at a dry film thickness of about 90 μm, about 0.009 ohms/sq at a dry film thickness of about 90 μm to about 0.014 ohms/sq at a dry film thickness of about 90 μm, about 0.009 ohms/sq at a dry film thickness of about 90 μm to about 0.015 ohms/sq at a dry film thickness of about 90 μm, about 0.009 ohms/sq at a dry film thickness of about 90 μm to about 0.016 ohms/sq at a dry film thickness of about 90 μm, about 0.009 ohms/sq at a dry film thickness of about 90 μm to about 0.017 ohms/sq at a dry film thickness of about 90 μm, about 0.011 ohms/sq at a dry film thickness of about 90 μm to about 0.012 ohms/sq at a dry film thickness of about 90 μm, about 0.011 ohms/sq at a dry film thickness of about 90 μm to about 0.013 ohms/sq at a dry film thickness of about 90 μm, about 0.011 ohms/sq at a dry film thickness of about 90 μm to about 0.014 ohms/sq at a dry film thickness of about 90 μm, about 0.011 ohms/sq at a dry film thickness of about 90 μm to about 0.015 ohms/sq at a dry film thickness of about 90 μm, about 0.011 ohms/sq at a dry film thickness of about 90 μm to about 0.016 ohms/sq at a dry film thickness of about 90 μm, about 0.011 ohms/sq at a dry film thickness of about 90 μm to about 0.017 ohms/sq at a dry film thickness of about 90 μm, about 0.012 ohms/sq at a dry film thickness of about 90 μm to about 0.013 ohms/sq at a dry film thickness of about 90 μm, about 0.012 ohms/sq at a dry film thickness of about 90 μm to about 0.014 ohms/sq at a dry film thickness of about 90 μm, about 0.012 ohms/sq at a dry film thickness of about 90 μm to about 0.015 ohms/sq at a dry film thickness of about 90 μm, about 0.012 ohms/sq at a dry film thickness of about 90 μm to about 0.016 ohms/sq at a dry film thickness of about 90 μm, about 0.012 ohms/sq at a dry film thickness of about 90 μm to about 0.017 ohms/sq at a dry film thickness of about 90 μm, about 0.013 ohms/sq at a dry film thickness of about 90 μm to about 0.014 ohms/sq at a dry film thickness of about 90 μm, about 0.013 ohms/sq at a dry film thickness of about 90 μm to about 0.015 ohms/sq at a dry film thickness of about 90 μm, about 0.013 ohms/sq at a dry film thickness of about 90 μm to about 0.016 ohms/sq at a dry film thickness of about 90 μm, about 0.013 ohms/sq at a dry film thickness of about 90 μm to about 0.017 ohms/sq at a dry film thickness of about 90 μm, about 0.014 ohms/sq at a dry film thickness of about 90 μm to about 0.015 ohms/sq at a dry film thickness of about 90 μm, about 0.014 ohms/sq at a dry film thickness of about 90 μm to about 0.016 ohms/sq at a dry film thickness of about 90 μm, about 0.014 ohms/sq at a dry film thickness of about 90 μm to about 0.017 ohms/sq at a dry film thickness of about 90 μm, about 0.015 ohms/sq at a dry film thickness of about 90 μm to about 0.016 ohms/sq at a dry film thickness of about 90 μm, about 0.015 ohms/sq at a dry film thickness of about 90 μm to about 0.017 ohms/sq at a dry film thickness of about 90 μm, or about 0.016 ohms/sq at a dry film thickness of about 90 μm to about 0.017 ohms/sq at a dry film thickness of about 90 μm, including increments therein. In some embodiments, the conductive ink comprises a sheet resistance of up to about 0.001 ohms/sq at a dry film thickness of about 90 μm, about 0.003 ohms/sq at a dry film thickness of about 90 μm, about 0.005 ohms/sq at a dry film thickness of about 90 μm, about 0.007 ohms/sq at a dry film thickness of about 90 μm, about 0.009 ohms/sq at a dry film thickness of about 90 μm, about 0.011 ohms/sq at a dry film thickness of about 90 μm, about 0.012 ohms/sq at a dry film thickness of about 90 μm, about 0.013 ohms/sq at a dry film thickness of about 90 μm, about 0.014 ohms/sq at a dry film thickness of about 90 μm, about 0.015 ohms/sq at a dry film thickness of about 90 μm, about 0.016 ohms/sq at a dry film thickness of about 90 μm, or about 0.017 ohms/sq at a dry film thickness of about 90 μm. In some embodiments, the conductive ink comprises a sheet resistance of up to at least about 0.001 ohms/sq at a dry film thickness of about 90 μm, about 0.003 ohms/sq at a dry film thickness of about 90 μm, about 0.005 ohms/sq at a dry film thickness of about 90 μm, about 0.007 ohms/sq at a dry film thickness of about 90 μm, about 0.009 ohms/sq at a dry film thickness of about 90 μm, about 0.011 ohms/sq at a dry film thickness of about 90 μm, about 0.012 ohms/sq at a dry film thickness of about 90 μm, about 0.013 ohms/sq at a dry film thickness of about 90 μm, about 0.014 ohms/sq at a dry film thickness of about 90 μm, about 0.015 ohms/sq at a dry film thickness of about 90 μm, or about 0.016 ohms/sq at a dry film thickness of about 90 μm. In some embodiments, the conductive ink comprises a sheet resistance of up to at most about 0.003 ohms/sq at a dry film thickness of about 90 μm, about 0.005 ohms/sq at a dry film thickness of about 90 μm, about 0.007 ohms/sq at a dry film thickness of about 90 μm, about 0.009 ohms/sq at a dry film thickness of about 90 μm, about 0.011 ohms/sq at a dry film thickness of about 90 μm, about 0.012 ohms/sq at a dry film thickness of about 90 μm, about 0.013 ohms/sq at a dry film thickness of about 90 μm, about 0.014 ohms/sq at a dry film thickness of about 90 μm, about 0.015 ohms/sq at a dry film thickness of about 90 μm, about 0.016 ohms/sq at a dry film thickness of about 90 μm, or about 0.017 ohms/sq at a dry film thickness of about 90 μm.

In some embodiments, the conductive ink comprises a sheet resistance of up to about 10 ohms/sq at a dry film thickness of about 200 μm to about 90 ohms/sq at a dry film thickness of about 200 μm. In some embodiments, the sheet resistance of the conductive ink is lower when cured at a higher temperature. In some embodiments, the conductive ink comprises a sheet resistance of up to about 10 ohms/sq at a dry film thickness of about 200 μm to about 20 ohms/sq at a dry film thickness of about 200 μm, about 10 ohms/sq at a dry film thickness of about 200 μm to about 30 ohms/sq at a dry film thickness of about 200 μm, about 10 ohms/sq at a dry film thickness of about 200 μm to about 40 ohms/sq at a dry film thickness of about 200 μm, about 10 ohms/sq at a dry film thickness of about 200 μm to about 50 ohms/sq at a dry film thickness of about 200 μm, about 10 ohms/sq at a dry film thickness of about 200 μm to about 60 ohms/sq at a dry film thickness of about 200 μm, about 10 ohms/sq at a dry film thickness of about 200 μm to about 70 ohms/sq at a dry film thickness of about 200 μm, about 10 ohms/sq at a dry film thickness of about 200 μm to about 80 ohms/sq at a dry film thickness of about 200 μm, about 10 ohms/sq at a dry film thickness of about 200 μm to about 90 ohms/sq at a dry film thickness of about 200 μm, about 20 ohms/sq at a dry film thickness of about 200 μm to about 30 ohms/sq at a dry film thickness of about 200 μm, about 20 ohms/sq at a dry film thickness of about 200 μm to about 40 ohms/sq at a dry film thickness of about 200 μm, about 20 ohms/sq at a dry film thickness of about 200 μm to about 50 ohms/sq at a dry film thickness of about 200 μm, about 20 ohms/sq at a dry film thickness of about 200 μm to about 60 ohms/sq at a dry film thickness of about 200 μm, about 20 ohms/sq at a dry film thickness of about 200 μm to about 70 ohms/sq at a dry film thickness of about 200 μm, about 20 ohms/sq at a dry film thickness of about 200 μm to about 80 ohms/sq at a dry film thickness of about 200 μm, about 20 ohms/sq at a dry film thickness of about 200 μm to about 90 ohms/sq at a dry film thickness of about 200 μm, about 30 ohms/sq at a dry film thickness of about 200 μm to about 40 ohms/sq at a dry film thickness of about 200 μm, about 30 ohms/sq at a dry film thickness of about 200 μm to about 50 ohms/sq at a dry film thickness of about 200 μm, about 30 ohms/sq at a dry film thickness of about 200 μm to about 60 ohms/sq at a dry film thickness of about 200 μm, about 30 ohms/sq at a dry film thickness of about 200 μm to about 70 ohms/sq at a dry film thickness of about 200 μm, about 30 ohms/sq at a dry film thickness of about 200 μm to about 80 ohms/sq at a dry film thickness of about 200 μm, about 30 ohms/sq at a dry film thickness of about 200 μm to about 90 ohms/sq at a dry film thickness of about 200 μm, about 40 ohms/sq at a dry film thickness of about 200 μm to about 50 ohms/sq at a dry film thickness of about 200 μm, about 40 ohms/sq at a dry film thickness of about 200 μm to about 60 ohms/sq at a dry film thickness of about 200 μm, about 40 ohms/sq at a dry film thickness of about 200 μm to about 70 ohms/sq at a dry film thickness of about 200 μm, about 40 ohms/sq at a dry film thickness of about 200 μm to about 80 ohms/sq at a dry film thickness of about 200 μm, about 40 ohms/sq at a dry film thickness of about 200 μm to about 90 ohms/sq at a dry film thickness of about 200 μm, about 50 ohms/sq at a dry film thickness of about 200 μm to about 60 ohms/sq at a dry film thickness of about 200 μm, about 50 ohms/sq at a dry film thickness of about 200 μm to about 70 ohms/sq at a dry film thickness of about 200 μm, about 50 ohms/sq at a dry film thickness of about 200 μm to about 80 ohms/sq at a dry film thickness of about 200 μm, about 50 ohms/sq at a dry film thickness of about 200 μm to about 90 ohms/sq at a dry film thickness of about 200 μm, about 60 ohms/sq at a dry film thickness of about 200 μm to about 70 ohms/sq at a dry film thickness of about 200 μm, about 60 ohms/sq at a dry film thickness of about 200 μm to about 80 ohms/sq at a dry film thickness of about 200 μm, about 60 ohms/sq at a dry film thickness of about 200 μm to about 90 ohms/sq at a dry film thickness of about 200 μm, about 70 ohms/sq at a dry film thickness of about 200 μm to about 80 ohms/sq at a dry film thickness of about 200 μm, about 70 ohms/sq at a dry film thickness of about 200 μm to about 90 ohms/sq at a dry film thickness of about 200 μm, or about 80 ohms/sq at a dry film thickness of about 200 μm to about 90 ohms/sq at a dry film thickness of about 200 μm, including increments therein. In some embodiments, the conductive ink comprises a sheet resistance of up to about 10 ohms/sq at a dry film thickness of about 200 μm, about 20 ohms/sq at a dry film thickness of about 200 μm, about 30 ohms/sq at a dry film thickness of about 200 μm, about 40 ohms/sq at a dry film thickness of about 200 μm, about 50 ohms/sq at a dry film thickness of about 200 μm, about 60 ohms/sq at a dry film thickness of about 200 μm, about 70 ohms/sq at a dry film thickness of about 200 μm, about 80 ohms/sq at a dry film thickness of about 200 μm, or about 90 ohms/sq at a dry film thickness of about 200 μm. In some embodiments, the conductive ink comprises a sheet resistance of up to at least about 10 ohms/sq at a dry film thickness of about 200 μm, about 20 ohms/sq at a dry film thickness of about 200 μm, about 30 ohms/sq at a dry film thickness of about 200 μm, about 40 ohms/sq at a dry film thickness of about 200 μm, about 50 ohms/sq at a dry film thickness of about 200 μm, about 60 ohms/sq at a dry film thickness of about 200 μm, about 70 ohms/sq at a dry film thickness of about 200 μm, or about 80 ohms/sq at a dry film thickness of about 200 μm. In some embodiments, the conductive ink comprises a sheet resistance of up to at most about 20 ohms/sq at a dry film thickness of about 200 μm, about 30 ohms/sq at a dry film thickness of about 200 μm, about 40 ohms/sq at a dry film thickness of about 200 μm, about 50 ohms/sq at a dry film thickness of about 200 μm, about 60 ohms/sq at a dry film thickness of about 200 μm, about 70 ohms/sq at a dry film thickness of about 200 μm, about 80 ohms/sq at a dry film thickness of about 200 μm, or about 90 ohms/sq at a dry film thickness of about 200 μm.

In some embodiments, the ink comprises a sheet resistance of about 0.025 ohms/sq at a range of dry film thicknesses from about 30 μm to about 36 μm.

In some embodiments, the conductive ink printed on a substrate is thermally stable up to about 400° C. In some embodiments, the conductive ink is flexible when dried and applied to a substrate. In some embodiments, the flexibility of the conductive ink is measured by measuring the sheet resistance of the conductive ink when applied to a substrate upon bending. In some embodiments, the sheet resistance of the conductive ink does not decrease upon bending the substrate, folding the substrate, or creasing the substrate. In some embodiments, the sheet resistance of the conductive ink decreases by less than 10%, 9%, 8%, 7%, 6%, 5%, 4%, 3% 2%, 1%, 0.5%, 0.1% or less upon bending the substrate, folding the substrate, or creasing the substrate.

In some embodiments, the conductive ink is adhesive and is resistant to cracking. Cracking of the conductive ink can be measured by making an incision on the coating of the surface of the conductive ink, and by applying an adhesive surface to the incised surface of the conductive ink. In some embodiments, the conductive ink is resistant to cracking and none of the conductive ink is removed from the incised surface of the conductive ink upon application of an adhesive surface to the incised surface. In some embodiments, the conductive ink is resistant to cracking and less than 10%, 9%, 8%, 7%, 6%, 5%, 4%, 3% 2%, 1%, 0.5%, 0.1% or less upon of the conductive ink is removed from the incised surface of the conductive ink upon application of an adhesive surface to the incised surface.

In some embodiments, the conductive ink comprises a conductivity of about 6,300 S/cm to about 15,000 S/cm. In some embodiments, the conductive ink comprises a conductivity of about 6,300 S/cm to about 7,200 S/cm, about 6,300 S/cm to about 8,100 S/cm, about 6,300 S/cm to about 9,000 S/cm, about 6,300 S/cm to about 9,900 S/cm, about 6,300 S/cm to about 10,800 S/cm, about 6,300 S/cm to about 11,700 S/cm, about 6,300 S/cm to about 12,600 S/cm, about 6,300 S/cm to about 13,500 S/cm, about 6,300 S/cm to about 14,400 S/cm, about 6,300 S/cm to about 15,000 S/cm, about 7,200 S/cm to about 8,100 S/cm, about 7,200 S/cm to about 9,000 S/cm, about 7,200 S/cm to about 9,900 S/cm, about 7,200 S/cm to about 10,800 S/cm, about 7,200 S/cm to about 11,700 S/cm, about 7,200 S/cm to about 12,600 S/cm, about 7,200 S/cm to about 13,500 S/cm, about 7,200 S/cm to about 14,400 S/cm, about 7,200 S/cm to about 15,000 S/cm, about 8,100 S/cm to about 9,000 S/cm, about 8,100 S/cm to about 9,900 S/cm, about 8,100 S/cm to about 10,800 S/cm, about 8,100 S/cm to about 11,700 S/cm, about 8,100 S/cm to about 12,600 S/cm, about 8,100 S/cm to about 13,500 S/cm, about 8,100 S/cm to about 14,400 S/cm, about 8,100 S/cm to about 15,000 S/cm, about 9,000 S/cm to about 9,900 S/cm, about 9,000 S/cm to about 10,800 S/cm, about 9,000 S/cm to about 11,700 S/cm, about 9,000 S/cm to about 12,600 S/cm, about 9,000 S/cm to about 13,500 S/cm, about 9,000 S/cm to about 14,400 S/cm, about 9,000 S/cm to about 15,000 S/cm, about 9,900 S/cm to about 10,800 S/cm, about 9,900 S/cm to about 11,700 S/cm, about 9,900 S/cm to about 12,600 S/cm, about 9,900 S/cm to about 13,500 S/cm, about 9,900 S/cm to about 14,400 S/cm, about 9,900 S/cm to about 15,000 S/cm, about 10,800 S/cm to about 11,700 S/cm, about 10,800 S/cm to about 12,600 S/cm, about 10,800 S/cm to about 13,500 S/cm, about 10,800 S/cm to about 14,400 S/cm, about 10,800 S/cm to about 15,000 S/cm, about 11,700 S/cm to about 12,600 S/cm, about 11,700 S/cm to about 13,500 S/cm, about 11,700 S/cm to about 14,400 S/cm, about 11,700 S/cm to about 15,000 S/cm, about 12,600 S/cm to about 13,500 S/cm, about 12,600 S/cm to about 14,400 S/cm, about 12,600 S/cm to about 15,000 S/cm, about 13,500 S/cm to about 14,400 S/cm, about 13,500 S/cm to about 15,000 S/cm, or about 14,400 S/cm to about 15,000 S/cm, including increments therein. In some embodiments, the conductive ink comprises a conductivity of about 6,300 S/cm, about 7,200 S/cm, about 8,100 S/cm, about 9,000 S/cm, about 9,900 S/cm, about 10,800 S/cm, about 11,700 S/cm, about 12,600 S/cm, about 13,500 S/cm, about 14,400 S/cm, or about 15,000 S/cm. In some embodiments, the conductive ink comprises a conductivity of at least about 6,300 S/cm, about 7,200 S/cm, about 8,100 S/cm, about 9,000 S/cm, about 9,900 S/cm, about 10,800 S/cm, about 11,700 S/cm, about 12,600 S/cm, about 13,500 S/cm, or about 14,400 S/cm. In some embodiments, the conductive ink comprises a conductivity of at most about 7,200 S/cm, about 8,100 S/cm, about 9,000 S/cm, about 9,900 S/cm, about 10,800 S/cm, about 11,700 S/cm, about 12,600 S/cm, about 13,500 S/cm, about 14,400 S/cm, or about 15,000 S/cm. In some embodiments, the conductive ink comprises at least 6300 S/cm at a dry film thickness of about 10 μm. In some embodiments, the conductive ink comprises about 10,000 S/cm at a dry film thickness from about 10 μm to about 50 μm. In some embodiments, the conductive ink comprises at least 10000 S/cm at a dry film thickness of from about 10 μm to about 50 μm. In some embodiments, the conductive ink comprises the claimed conductivity when cured at 110° C. for about 30 min. In some embodiments, the conductive ink comprises

In some embodiments, the conductive ink comprises a conductivity of up to about 1,000 S/cm at a dry film thickness of about 100 μm to about 54,000 S/cm at a dry film thickness of about 100 μm. In some embodiments, the conductive ink comprises a conductivity of up to about 1,000 S/cm at a dry film thickness of about 100 μm to about 5,000 S/cm at a dry film thickness of about 100 um, about 1,000 S/cm at a dry film thickness of about 100 μm to about 9,000 S/cm at a dry film thickness of about 100 um, about 1,000 S/cm at a dry film thickness of about 100 μm to about 14,000 S/cm at a dry film thickness of about 100 um, about 1,000 S/cm at a dry film thickness of about 100 μm to about 19,000 S/cm at a dry film thickness of about 100 um, about 1,000 S/cm at a dry film thickness of about 100 μm to about 24,000 S/cm at a dry film thickness of about 100 um, about 1,000 S/cm at a dry film thickness of about 100 μm to about 29,000 S/cm at a dry film thickness of about 100 um, about 1,000 S/cm at a dry film thickness of about 100 μm to about 34,000 S/cm at a dry film thickness of about 100 um, about 1,000 S/cm at a dry film thickness of about 100 μm to about 39,000 S/cm at a dry film thickness of about 100 um, about 1,000 S/cm at a dry film thickness of about 100 μm to about 44,000 S/cm at a dry film thickness of about 100 um, about 1,000 S/cm at a dry film thickness of about 100 μm to about 49,000 S/cm at a dry film thickness of about 100 um, about 1,000 S/cm at a dry film thickness of about 100 μm to about 54,000 S/cm at a dry film thickness of about 100 um, about 5,000 S/cm at a dry film thickness of about 100 μm to about 9,000 S/cm at a dry film thickness of about 100 um, about 5,000 S/cm at a dry film thickness of about 100 μm to about 14,000 S/cm at a dry film thickness of about 100 um, about 5,000 S/cm at a dry film thickness of about 100 μm to about 19,000 S/cm at a dry film thickness of about 100 um, about 5,000 S/cm at a dry film thickness of about 100 μm to about 24,000 S/cm at a dry film thickness of about 100 um, about 5,000 S/cm at a dry film thickness of about 100 μm to about 29,000 S/cm at a dry film thickness of about 100 um, about 5,000 S/cm at a dry film thickness of about 100 μm to about 34,000 S/cm at a dry film thickness of about 100 um, about 5,000 S/cm at a dry film thickness of about 100 μm to about 39,000 S/cm at a dry film thickness of about 100 um, about 5,000 S/cm at a dry film thickness of about 100 μm to about 44,000 S/cm at a dry film thickness of about 100 um, about 5,000 S/cm at a dry film thickness of about 100 μm to about 49,000 S/cm at a dry film thickness of about 100 um, about 5,000 S/cm at a dry film thickness of about 100 μm to about 54,000 S/cm at a dry film thickness of about 100 um, about 9,000 S/cm at a dry film thickness of about 100 μm to about 14,000 S/cm at a dry film thickness of about 100 um, about 9,000 S/cm at a dry film thickness of about 100 μm to about 19,000 S/cm at a dry film thickness of about 100 um, about 9,000 S/cm at a dry film thickness of about 100 μm to about 24,000 S/cm at a dry film thickness of about 100 um, about 9,000 S/cm at a dry film thickness of about 100 μm to about 29,000 S/cm at a dry film thickness of about 100 um, about 9,000 S/cm at a dry film thickness of about 100 μm to about 34,000 S/cm at a dry film thickness of about 100 um, about 9,000 S/cm at a dry film thickness of about 100 μm to about 39,000 S/cm at a dry film thickness of about 100 um, about 9,000 S/cm at a dry film thickness of about 100 μm to about 44,000 S/cm at a dry film thickness of about 100 um, about 9,000 S/cm at a dry film thickness of about 100 μm to about 49,000 S/cm at a dry film thickness of about 100 um, about 9,000 S/cm at a dry film thickness of about 100 um to about 54,000 S/cm at a dry film thickness of about 100 um, about 14,000 S/cm at a dry film thickness of about 100 μm to about 19,000 S/cm at a dry film thickness of about 100 um, about 14,000 S/cm at a dry film thickness of about 100 μm to about 24,000 S/cm at a dry film thickness of about 100 um, about 14,000 S/cm at a dry film thickness of about 100 μm to about 29,000 S/cm at a dry film thickness of about 100 um, about 14,000 S/cm at a dry film thickness of about 100 μm to about 34,000 S/cm at a dry film thickness of about 100 um, about 14,000 S/cm at a dry film thickness of about 100 μm to about 39,000 S/cm at a dry film thickness of about 100 um, about 14,000 S/cm at a dry film thickness of about 100 μm to about 44,000 S/cm at a dry film thickness of about 100 um, about 14,000 S/cm at a dry film thickness of about 100 μm to about 49,000 S/cm at a dry film thickness of about 100 um, about 14,000 S/cm at a dry film thickness of about 100 μm to about 54,000 S/cm at a dry film thickness of about 100 um, about 19,000 S/cm at a dry film thickness of about 100 μm to about 24,000 S/cm at a dry film thickness of about 100 um, about 19,000 S/cm at a dry film thickness of about 100 μm to about 29,000 S/cm at a dry film thickness of about 100 um, about 19,000 S/cm at a dry film thickness of about 100 μm to about 34,000 S/cm at a dry film thickness of about 100 um, about 19,000 S/cm at a dry film thickness of about 100 μm to about 39,000 S/cm at a dry film thickness of about 100 um, about 19,000 S/cm at a dry film thickness of about 100 μm to about 44,000 S/cm at a dry film thickness of about 100 um, about 19,000 S/cm at a dry film thickness of about 100 μm to about 49,000 S/cm at a dry film thickness of about 100 um, about 19,000 S/cm at a dry film thickness of about 100 μm to about 54,000 S/cm at a dry film thickness of about 100 um, about 24,000 S/cm at a dry film thickness of about 100 μm to about 29,000 S/cm at a dry film thickness of about 100 um, about 24,000 S/cm at a dry film thickness of about 100 μm to about 34,000 S/cm at a dry film thickness of about 100 um, about 24,000 S/cm at a dry film thickness of about 100 μm to about 39,000 S/cm at a dry film thickness of about 100 um, about 24,000 S/cm at a dry film thickness of about 100 um to about 44,000 S/cm at a dry film thickness of about 100 um, about 24,000 S/cm at a dry film thickness of about 100 μm to about 49,000 S/cm at a dry film thickness of about 100 um, about 24,000 S/cm at a dry film thickness of about 100 μm to about 54,000 S/cm at a dry film thickness of about 100 um, about 29,000 S/cm at a dry film thickness of about 100 μm to about 34,000 S/cm at a dry film thickness of about 100 um, about 29,000 S/cm at a dry film thickness of about 100 μm to about 39,000 S/cm at a dry film thickness of about 100 um, about 29,000 S/cm at a dry film thickness of about 100 μm to about 44,000 S/cm at a dry film thickness of about 100 um, about 29,000 S/cm at a dry film thickness of about 100 μm to about 49,000 S/cm at a dry film thickness of about 100 um, about 29,000 S/cm at a dry film thickness of about 100 μm to about 54,000 S/cm at a dry film thickness of about 100 um, about 34,000 S/cm at a dry film thickness of about 100 μm to about 39,000 S/cm at a dry film thickness of about 100 um, about 34,000 S/cm at a dry film thickness of about 100 μm to about 44,000 S/cm at a dry film thickness of about 100 um, about 34,000 S/cm at a dry film thickness of about 100 μm to about 49,000 S/cm at a dry film thickness of about 100 um, about 34,000 S/cm at a dry film thickness of about 100 μm to about 54,000 S/cm at a dry film thickness of about 100 um, about 39,000 S/cm at a dry film thickness of about 100 μm to about 44,000 S/cm at a dry film thickness of about 100 um, about 39,000 S/cm at a dry film thickness of about 100 μm to about 49,000 S/cm at a dry film thickness of about 100 um, about 39,000 S/cm at a dry film thickness of about 100 μm to about 54,000 S/cm at a dry film thickness of about 100 um, about 44,000 S/cm at a dry film thickness of about 100 μm to about 49,000 S/cm at a dry film thickness of about 100 um, about 44,000 S/cm at a dry film thickness of about 100 μm to about 54,000 S/cm at a dry film thickness of about 100 um, or about 49,000 S/cm at a dry film thickness of about 100 μm to about 54,000 S/cm at a dry film thickness of about 100 um, including increments therein. In some embodiments, the conductive ink comprises a conductivity of up to about 1,000 S/cm at a dry film thickness of about 100 um, about 5,000 S/cm at a dry film thickness of about 100 um, about 9,000 S/cm at a dry film thickness of about 100 um, about 14,000 S/cm at a dry film thickness of about 100 um, about 19,000 S/cm at a dry film thickness of about 100 um, about 24,000 S/cm at a dry film thickness of about 100 um, about 29,000 S/cm at a dry film thickness of about 100 um, about 34,000 S/cm at a dry film thickness of about 100 um, about 39,000 S/cm at a dry film thickness of about 100 um, about 44,000 S/cm at a dry film thickness of about 100 um, about 49,000 S/cm at a dry film thickness of about 100 um, or about 54,000 S/cm at a dry film thickness of about 100 μm. In some embodiments, the conductive ink comprises a conductivity of up to at least about 1,000 S/cm at a dry film thickness of about 100 um, about 5,000 S/cm at a dry film thickness of about 100 um, about 9,000 S/cm at a dry film thickness of about 100 um, about 14,000 S/cm at a dry film thickness of about 100 um, about 19,000 S/cm at a dry film thickness of about 100 um, about 24,000 S/cm at a dry film thickness of about 100 um, about 29,000 S/cm at a dry film thickness of about 100 um, about 34,000 S/cm at a dry film thickness of about 100 um, about 39,000 S/cm at a dry film thickness of about 100 um, about 44,000 S/cm at a dry film thickness of about 100 um, or about 49,000 S/cm at a dry film thickness of about 100 μm. In some embodiments, the conductive ink comprises a conductivity of up to at most about 5,000 S/cm at a dry film thickness of about 100 um, about 9,000 S/cm at a dry film thickness of about 100 um, about 14,000 S/cm at a dry film thickness of about 100 um, about 19,000 S/cm at a dry film thickness of about 100 um, about 24,000 S/cm at a dry film thickness of about 100 um, about 29,000 S/cm at a dry film thickness of about 100 um, about 34,000 S/cm at a dry film thickness of about 100 um, about 39,000 S/cm at a dry film thickness of about 100 um, about 44,000 S/cm at a dry film thickness of about 100 um, about 49,000 S/cm at a dry film thickness of about 100 um, or about 54,000 S/cm at a dry film thickness of about 100 μm.

In some embodiments, the conductive ink comprises a conductivity of about 15,000 S/cm to about 54,000 S/cm. In some embodiments, the conductive ink comprises a conductivity of about 15,000 S/cm to about 19,000 S/cm, about 15,000 S/cm to about 23,000 S/cm, about 15,000 S/cm to about 27,000 S/cm, about 15,000 S/cm to about 31,000 S/cm, about 15,000 S/cm to about 35,000 S/cm, about 15,000 S/cm to about 39,000 S/cm, about 15,000 S/cm to about 43,000 S/cm, about 15,000 S/cm to about 47,000 S/cm, about 15,000 S/cm to about 51,000 S/cm, about 15,000 S/cm to about 52,000 S/cm, about 15,000 S/cm to about 54,000 S/cm, about 19,000 S/cm to about 23,000 S/cm, about 19,000 S/cm to about 27,000 S/cm, about 19,000 S/cm to about 31,000 S/cm, about 19,000 S/cm to about 35,000 S/cm, about 19,000 S/cm to about 39,000 S/cm, about 19,000 S/cm to about 43,000 S/cm, about 19,000 S/cm to about 47,000 S/cm, about 19,000 S/cm to about 51,000 S/cm, about 19,000 S/cm to about 52,000 S/cm, about 19,000 S/cm to about 54,000 S/cm, about 23,000 S/cm to about 27,000 S/cm, about 23,000 S/cm to about 31,000 S/cm, about 23,000 S/cm to about 35,000 S/cm, about 23,000 S/cm to about 39,000 S/cm, about 23,000 S/cm to about 43,000 S/cm, about 23,000 S/cm to about 47,000 S/cm, about 23,000 S/cm to about 51,000 S/cm, about 23,000 S/cm to about 52,000 S/cm, about 23,000 S/cm to about 54,000 S/cm, about 27,000 S/cm to about 31,000 S/cm, about 27,000 S/cm to about 35,000 S/cm, about 27,000 S/cm to about 39,000 S/cm, about 27,000 S/cm to about 43,000 S/cm, about 27,000 S/cm to about 47,000 S/cm, about 27,000 S/cm to about 51,000 S/cm, about 27,000 S/cm to about 52,000 S/cm, about 27,000 S/cm to about 54,000 S/cm, about 31,000 S/cm to about 35,000 S/cm, about 31,000 S/cm to about 39,000 S/cm, about 31,000 S/cm to about 43,000 S/cm, about 31,000 S/cm to about 47,000 S/cm, about 31,000 S/cm to about 51,000 S/cm, about 31,000 S/cm to about 52,000 S/cm, about 31,000 S/cm to about 54,000 S/cm, about 35,000 S/cm to about 39,000 S/cm, about 35,000 S/cm to about 43,000 S/cm, about 35,000 S/cm to about 47,000 S/cm, about 35,000 S/cm to about 51,000 S/cm, about 35,000 S/cm to about 52,000 S/cm, about 35,000 S/cm to about 54,000 S/cm, about 39,000 S/cm to about 43,000 S/cm, about 39,000 S/cm to about 47,000 S/cm, about 39,000 S/cm to about 51,000 S/cm, about 39,000 S/cm to about 52,000 S/cm, about 39,000 S/cm to about 54,000 S/cm, about 43,000 S/cm to about 47,000 S/cm, about 43,000 S/cm to about 51,000 S/cm, about 43,000 S/cm to about 52,000 S/cm, about 43,000 S/cm to about 54,000 S/cm, about 47,000 S/cm to about 51,000 S/cm, about 47,000 S/cm to about 52,000 S/cm, about 47,000 S/cm to about 54,000 S/cm, about 51,000 S/cm to about 52,000 S/cm, about 51,000 S/cm to about 54,000 S/cm, or about 52,000 S/cm to about 54,000 S/cm, including increments therein. In some embodiments, the conductive ink comprises a conductivity of about 15,000 S/cm, about 19,000 S/cm, about 23,000 S/cm, about 27,000 S/cm, about 31,000 S/cm, about 35,000 S/cm, about 39,000 S/cm, about 43,000 S/cm, about 47,000 S/cm, about 51,000 S/cm, about 52,000 S/cm, or about 54,000 S/cm. In some embodiments, the conductive ink comprises a conductivity of at least about 15,000 S/cm, about 19,000 S/cm, about 23,000 S/cm, about 27,000 S/cm, about 31,000 S/cm, about 35,000 S/cm, about 39,000 S/cm, about 43,000 S/cm, about 47,000 S/cm, about 51,000 S/cm, or about 52,000 S/cm. In some embodiments, the conductive ink comprises a conductivity of at most about 19,000 S/cm, about 23,000 S/cm, about 27,000 S/cm, about 31,000 S/cm, about 35,000 S/cm, about 39,000 S/cm, about 43,000 S/cm, about 47,000 S/cm, about 51,000 S/cm, about 52,000 S/cm, or about 54,000 S/cm.

In some embodiments, the conductive ink comprises a conductivity of about 40000 S/cm. In some embodiments, the conductive ink comprises a conductivity of at least 15000 S/cm at a dry film thickness of about 10 μm. In some embodiments, the conductive ink comprises an average conductivity of about 40,000 S/cm at a dry film thickness of about 10 μm to about 50 μm. In some embodiments, the conductive ink comprises a conductivity of about 40,000 S/cm at a dry film thickness of about 10 μm to about 50 μm. In some embodiments, the conductive ink comprises a conductivity of at least 40,000 S/cm at a dry film thickness of about 10 μm to about 50 μm. In some embodiments, the ink comprises the claimed conductivity when cured at 300° C. for about 30 min.

In some embodiments, the ink comprises the claimed conductivity when applied with a film thickness of 10, 20, 50, 100, or 200 μm.

In some embodiments, the ink is applied at 110° C. into trace lines with a width from 300 μm to 3000 μm, and comprises an average conductivity of about 750000 S. In some embodiments, the ink is applied via screen printing.

In some embodiments, the ink comprises an average conductivity of about 750000 S and is applied at 110 C into trace lines with a width from about 300 μm to about 3,000 μm. In some embodiments, the ink comprises an average conductivity of about 750000 S and is applied at 110 C into trace lines with a width from about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 um, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises an average conductivity of about 750000 S and is applied at 110 C into trace lines with a width from about 300 um, about 600 um, about 900 um, about 1,200 um, about 1,500 um, about 1,800 um, about 2,100 um, about 2,400 um, about 2,700 um, or about 3,000 μm. In some embodiments, the ink comprises an average conductivity of about 750000 S and is applied at 110 C into trace lines with a width from at least about 300 um, about 600 um, about 900 um, about 1,200 um, about 1,500 um, about 1,800 um, about 2,100 um, about 2,400 um, or about 2,700 μm. In some embodiments, the ink comprises an average conductivity of about 750000 S and is applied at 110 C into trace lines with a width from at most about 600 um, about 900 um, about 1,200 um, about 1,500 um, about 1,800 um, about 2,100 um, about 2,400 um, about 2,700 um, or about 3,000 μm. In some embodiments, the ink is applied at 110° C. into trace lines with a width of at least 300 μm and comprises a conductivity of at least 666000 S. In some embodiments, the ink is applied via screen printing.

In some embodiments, the ink comprises a conductivity of at least 830000 S and is applied by screen printing at 110° C. into trace lines with a width of up to about 300 μm to about 3,000 μm. In some embodiments, the ink comprises a conductivity of at least 830000 S and is applied at 110 C into trace lines with a width of up to about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 um, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises a conductivity of at least 830000 S and is applied at 110 C into trace lines with a width of up to about 300 um, about 600 um, about 900 um, about 1,200 um, about 1,500 um, about 1,800 um, about 2,100 um, about 2,400 um, about 2,700 um, or about 3,000 μm. In some embodiments, the ink comprises a conductivity of at least 830000 S and is applied at 110 C into trace lines with a width of up to at least about 300 um, about 600 um, about 900 um, about 1,200 um, about 1,500 um, about 1,800 um, about 2,100 um, about 2,400 um, or about 2,700 μm. In some embodiments, the ink comprises a conductivity of at least 830000 S and is applied at 110 C into trace lines with a width of up to at most about 600 um, about 900 um, about 1,200 um, about 1,500 um, about 1,800 um, about 2,100 um, about 2,400 um, about 2,700 um, or about 3,000 μm. In some embodiments, the ink is applied via screen printing.

In some embodiments, the ink comprises an average conductivity of about 1.42*10\hat{ }6 S and is applied at 300° C. into trace lines with a width from about 300 μm to about 3,000 μm. In some embodiments, the ink comprises an average conductivity of about 1.42*10\hat{ }6 S and is applied at 300° C. into trace lines with a width from about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 um, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises an average conductivity of about 1.42*10\hat{ }6 S and is applied at 300° C. into trace lines with a width from about 300 um, about 600 um, about 900 um, about 1,200 um, about 1,500 um, about 1,800 um, about 2,100 um, about 2,400 um, about 2,700 um, or about 3,000 μm. In some embodiments, the ink comprises an average conductivity of about 10.42*10\hat{ }6 S and is applied at 300° C. into trace lines with a width from at least about 300 um, about 600 um, about 900 um, about 1,200 um, about 1,500 um, about 1,800 um, about 2,100 um, about 2,400 um, or about 2,700 μm. In some embodiments, the ink comprises an average conductivity of about 1.42*10\hat{ }6 S and is applied at 300° C. into trace lines with a width from at most about 600 um, about 900 um, about 1,200 um, about 1,500 um, about 1,800 um, about 2,100 um, about 2,400 um, about 2,700 um, or about 3,000 μm. In some embodiments, the ink is applied via screen printing.

In some embodiments, the ink is applied at 300° C. into trace lines with a width of at least 300 μm and comprises a conductivity of at least 10\hat{ }6 S. In some embodiments, the ink is applied via screen printing.

In some embodiments, the ink comprises a conductivity of at least 2*10\hat{ }6 S and is applied at 300° C. into trace lines with a width of up to about 300 μm to about 3,000 μm. In some embodiments, the ink comprises a conductivity of at least 2*10\hat{ }6 S and is applied at 300° C. into trace lines with a width of up to about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 μm, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises a conductivity of at least 2*10\hat{ }6 S and is applied at 300° C. into trace lines with a width of up to about 300 um, about 600 um, about 900 um, about 1,200 um, about 1,500 um, about 1,800 um, about 2,100 um, about 2,400 um, about 2,700 um, or about 3,000 μm. In some embodiments, the ink comprises a conductivity of at least 2*10\hat{ }6 S and is applied at 300° C. into trace lines with a width of up to at least about 300 um, about 600 um, about 900 um, about 1,200 um, about 1,500 um, about 1,800 um, about 2,100 um, about 2,400 um, or about 2,700 μm. In some embodiments, the ink comprises a conductivity of at least 2*10\hat{ }6 S and is applied at 300° C. into trace lines with a width of up to at most about 600 um, about 900 um, about 1,200 um, about 1,500 um, about 1,800 um, about 2,100 um, about 2,400 um, about 2,700 um, or about 3,000 μm. In some embodiments, the ink is applied via screen printing.

In some embodiments, the ink comprises flat morphology when screen printed, with an average deviation from the edge of the cured ink not exceeding 10 μm. In some embodiments, the ink comprises pores up to about 5 μm in average diameter.

In some embodiments, the ink comprises pores from about 2 μm in diameter to about 7 am in diameter. In some embodiments, the ink comprises pores from about 2 μm in diameter to about 3 μm in diameter, about 2 μm in diameter to about 4 μm in diameter, about 2 μm in diameter to about 5 μm in diameter, about 2 μm in diameter to about 6 μm in diameter, about 2 μm in diameter to about 7 μm in diameter, about 3 μm in diameter to about 4 μm in diameter, about 3 μm in diameter to about 5 μm in diameter, about 3 μm in diameter to about 6 μm in diameter, about 3 μm in diameter to about 7 μm in diameter, about 4 μm in diameter to about 5 μm in diameter, about 4 μm in diameter to about 6 μm in diameter, about 4 μm in diameter to about 7 μm in diameter, about 5 μm in diameter to about 6 μm in diameter, about 5 μm in diameter to about 7 μm in diameter, or about 6 μm in diameter to about 7 μm in diameter, including increments therein. In some embodiments, the ink comprises pores from about 2 μm in diameter, about 3 μm in diameter, about 4 μm in diameter, about 5 μm in diameter, about 6 μm in diameter, or about 7 μm in diameter. In some embodiments, the ink comprises pores from at least about 2 μm in diameter, about 3 μm in diameter, about 4 μm in diameter, about 5 μm in diameter, or about 6 μm in diameter. In some embodiments, the ink comprises pores from at most about 3 μm in diameter, about 4 μm in diameter, about 5 μm in diameter, about 6 μm in diameter, or about 7 μm in diameter.

In some embodiments, the ink comprises channels throughout the cured ink connected by the pores. In some embodiments, the is applied as a continuous film. In some embodiments, the is applied as a continuous film or as a trace line on a substrate. In some embodiments, the substrate comprises silicon, PET, PI, Kapton, glass, or combinations thereof.

In some embodiments, the ink comprises pores up to about 1 μm in average diameter when cured to about 5 μm in average diameter when cured. In some embodiments, the ink comprises pores up to about 1 μm in average diameter when cured to about 2 μm in average diameter when cured, about 1 μm in average diameter when cured to about 3 μm in average diameter when cured, about 1 μm in average diameter when cured to about 4 μm in average diameter when cured, about 1 μm in average diameter when cured to about 5 μm in average diameter when cured, about 2 μm in average diameter when cured to about 3 μm in average diameter when cured, about 2 μm in average diameter when cured to about 4 μm in average diameter when cured, about 2 μm in average diameter when cured to about 5 μm in average diameter when cured, about 3 μm in average diameter when cured to about 4 μm in average diameter when cured, about 3 μm in average diameter when cured to about 5 μm in average diameter when cured, or about 4 μm in average diameter when cured to about 5 μm in average diameter when cured, including increments therein. In some embodiments, the ink comprises pores up to about 1 μm in average diameter when cured, about 2 μm in average diameter when cured, about 3 μm in average diameter when cured, about 4 μm in average diameter when cured, or about 5 μm in average diameter when cured. In some embodiments, the ink comprises pores up to at least about 1 μm in average diameter when cured, about 2 μm in average diameter when cured, about 3 μm in average diameter when cured, or about 4 μm in average diameter when cured. In some embodiments, the ink comprises pores up to at most about 2 μm in average diameter when cured, about 3 μm in average diameter when cured, about 4 μm in average diameter when cured, or about 5 μm in average diameter when cured.

In some embodiments, the ink comprises pores from about 2 μm in diameter when cured to about 7 μm in diameter when cured. In some embodiments, the ink comprises pores from about 2 μm in diameter when cured to about 3 μm in diameter when cured, about 2 μm in diameter when cured to about 4 μm in diameter when cured, about 2 μm in diameter when cured to about 5 μm in diameter when cured, about 2 μm in diameter when cured to about 6 μm in diameter when cured, about 2 μm in diameter when cured to about 7 μm in diameter when cured, about 3 μm in diameter when cured to about 4 μm in diameter when cured, about 3 μm in diameter when cured to about 5 μm in diameter when cured, about 3 μm in diameter when cured to about 6 μm in diameter when cured, about 3 μm in diameter when cured to about 7 μm in diameter when cured, about 4 μm in diameter when cured to about 5 μm in diameter when cured, about 4 μm in diameter when cured to about 6 μm in diameter when cured, about 4 μm in diameter when cured to about 7 μm in diameter when cured, about 5 μm in diameter when cured to about 6 μm in diameter when cured, about 5 μm in diameter when cured to about 7 μm in diameter when cured, or about 6 μm in diameter when cured to about 7 μm in diameter when cured, including increments therein. In some embodiments, the ink comprises pores from about 2 μm in diameter when cured, about 3 μm in diameter when cured, about 4 μm in diameter when cured, about 5 μm in diameter when cured, about 6 μm in diameter when cured, or about 7 μm in diameter when cured. In some embodiments, the ink comprises pores from at least about 2 μm in diameter when cured, about 3 μm in diameter when cured, about 4 μm in diameter when cured, about 5 μm in diameter when cured, or about 6 μm in diameter when cured. In some embodiments, the ink comprises pores from at most about 3 μm in diameter when cured, about 4 μm in diameter when cured, about 5 μm in diameter when cured, about 6 μm in diameter when cured, or about 7 μm in diameter when cured. In some embodiments, the ink comprises channels throughout the cured ink connected by the pores when cured.

In some embodiments, the conductive inks disclosed herein may remain stable for at least about one day, one week, one month, two months, three months, four months, five months, six months, seven months, eight months, nine months, ten months, eleven months, a year or more. Stability can indicate that the conductive inks can be used directly after the at least about one day, one week, one month, two months, three months, four months, five months, six months, seven months, eight months, nine months, ten months, eleven months, a year, or more of storage with no pre-processing steps (e.g., re-dispersal of conductive nanomaterials). Further, the conductive inks can demonstrate no substantial loss of conductivity following storage for at least one day, one week, one month, two months, three months, four months, five months, six months, seven months, eight months, nine months, ten months, eleven months, a year, or more.

In some embodiments, agglomeration may be indicated by a change in particle size distribution over time. In some embodiments, the change in the D10 value of an ink disclosed herein is no more than about 0.5 μm, about 0.6 μm, 0.7 μm, 0.8 μm, 0.9 μm, 1.0 μm, 1.1 μm, 1.2 μm, 1.3 μm, 1.4, μm, 1.5 μm, 1.6 μm, 1.7 μm, 1.8 μm, 1.9 μm, 2.0 μm, 2.1 μm, 2.2 μm, 2.3 μm, 2.4 μm, 2.5 μm, or less after at least about one day, one week, one month, two months, three months, four months, five months, six months, seven months, eight months, nine months, ten months, eleven months, a year or more of storage. In some embodiments, the change in the D10 value of an ink is about 0.4 μm to about 2.2 μm after at least about one day, one week, one month, two months, three months, four months, five months, six months, seven months, eight months, nine months, ten months, eleven months, a year, or more of storage. In some embodiments, the change in the D10 value of an ink is about 0.4 μm to about 0.6 μm, about 0.4 μm to about 0.8 μm, about 0.4 μm to about 1 μm, about 0.4 μm to about 1.2 μm, about 0.4 μm to about 1.4 μm, about 0.4 μm to about 1.6 μm, about 0.4 μm to about 1.8 μm, about 0.4 μm to about 2 μm, about 0.4 μm to about 2.2 μm, about 0.6 μm to about 0.8 μm, about 0.6 μm to about 1 μm, about 0.6 μm to about 1.2 μm, about 0.6 μm to about 1.4 μm, about 0.6 μm to about 1.6 μm, about 0.6 μm to about 1.8 μm, about 0.6 μm to about 2 μm, about 0.6 μm to about 2.2 μm, about 0.8 μm to about 1 μm, about 0.8 μm to about 1.2 μm, about 0.8 μm to about 1.4 μm, about 0.8 μm to about 1.6 μm, about 0.8 μm to about 1.8 μm, about 0.8 μm to about 2 μm, about 0.8 μm to about 2.2 μm, about 1 μm to about 1.2 μm, about 1 μm to about 1.4 μm, about 1 μm to about 1.6 μm, about 1 μm to about 1.8 μm, about 1 μm to about 2 μm, about 1 μm to about 2.2 μm, about 1.2 μm to about 1.4 μm, about 1.2 μm to about 1.6 μm, about 1.2 μm to about 1.8 μm, about 1.2 μm to about 2 μm, about 1.2 μm to about 2.2 μm, about 1.4 μm to about 1.6 μm, about 1.4 μm to about 1.8 μm, about 1.4 μm to about 2 μm, about 1.4 μm to about 2.2 μm, about 1.6 μm to about 1.8 μm, about 1.6 μm to about 2 μm, about 1.6 μm to about 2.2 μm, about 1.8 μm to about 2 μm, about 1.8 μm to about 2.2 μm, or about 2 μm to about 2.2 μm after at least about one day, one week, one month, two months, three months, four months, five months, six months, seven months, eight months, nine months, ten months, eleven months, a year, or more of storage.

In some embodiments, the change in the D10 value of an ink disclosed herein is no more than about about 1% to about 20% after at least about one day, one week, one month, two months, three months, four months, five months, six months, seven months, eight months, nine months, ten months, eleven months, a year, or more of storage. In some embodiments, the change in the D10 value of an ink disclosed herein is no more than about about 1% to about 2%, about 1% to about 3%, about 1% to about 4%, about 1% to about 5%, about 1% to about 6%, about 1% to about 7%, about 1% to about 8%, about 1% to about 9%, about 1% to about 10%, about 1% to about 15%, about 1% to about 20%, about 2% to about 3%, about 2% to about 4%, about 2% to about 5%, about 2% to about 6%, about 2% to about 7%, about 2% to about 8%, about 2% to about 9%, about 2% to about 10%, about 2% to about 15%, about 2% to about 20%, about 3% to about 4%, about 3% to about 5%, about 3% to about 6%, about 3% to about 7%, about 3% to about 8%, about 3% to about 9%, about 3% to about 10%, about 3% to about 15%, about 3% to about 20%, about 4% to about 5%, about 4% to about 6%, about 4% to about 7%, about 4% to about 8%, about 4% to about 9%, about 4% to about 10%, about 4% to about 15%, about 4% to about 20%, about 5% to about 6%, about 5% to about 7%, about 5% to about 8%, about 5% to about 9%, about 5% to about 10%, about 5% to about 15%, about 5% to about 20%, about 6% to about 7%, about 6% to about 8%, about 6% to about 9%, about 6% to about 10%, about 6% to about 15%, about 6% to about 20%, about 7% to about 8%, about 7% to about 9%, about 7% to about 10%, about 7% to about 15%, about 7% to about 20%, about 8% to about 9%, about 8% to about 10%, about 8% to about 15%, about 8% to about 20%, about 9% to about 10%, about 9% to about 15%, about 9% to about 20%, about 10% to about 15%, about 10% to about 20%, or about 15% to about 20% after at least about one day, one week, one month, two months, three months, four months, five months, six months, seven months, eight months, nine months, ten months, eleven months, a year, or more of storage. In some embodiments, the change in the D10 value of an ink disclosed herein is no more than about about 1%, about 2%, about 3%, about 4%, about 5%, about 6%, about 7%, about 8%, about 9%, about 10%, about 15%, or about 20% after at least about one day, one week, one month, two months, three months, four months, five months, six months, seven months, eight months, nine months, ten months, eleven months, a year, or more of storage. In some embodiments, the change in the D10 value of an ink disclosed herein is no more than about at most about 2%, about 3%, about 4%, about 5%, about 6%, about 7%, about 8%, about 9%, about 10%, about 15%, or about 20% after at least about one day, one week, one month, two months, three months, four months, five months, six months, seven months, eight months, nine months, ten months, eleven months, a year, or more of storage.

In some embodiments, agglomeration may be indicated by a change in particle size distribution over time. In some embodiments, the change in the D50 value of an ink disclosed herein is no more than about 0.5 μm, about 0.6 μm, 0.7 μm, 0.8 μm, 0.9 μm, 1.0 μm, 1.1 μm, 1.2 μm, 1.3 μm, 1.4, μm, 1.5 μm, 1.6 μm, 1.7 μm, 1.8 μm, 1.9 μm, 2.0 μm, 2.1 μm, 2.2 μm, 2.3 μm, 2.4 μm, 2.5 μm, or less after at least about one day, one week, one month, two months, three months, four months, five months, six months, seven months, eight months, nine months, ten months, eleven months, a year, or more of storage. In some embodiments, the change in the D50 value of an ink is about 0.4 μm to about 2.2 μm. In some embodiments, the change in the D50 value of an ink is about 0.4 μm to about 0.6 μm, about 0.4 μm to about 0.8 μm, about 0.4 μm to about 1 μm, about 0.4 μm to about 1.2 μm, about 0.4 μm to about 1.4 μm, about 0.4 μm to about 1.6 μm, about 0.4 μm to about 1.8 μm, about 0.4 μm to about 2 μm, about 0.4 μm to about 2.2 μm, about 0.6 μm to about 0.8 μm, about 0.6 μm to about 1 μm, about 0.6 μm to about 1.2 μm, about 0.6 μm to about 1.4 μm, about 0.6 μm to about 1.6 μm, about 0.6 μm to about 1.8 μm, about 0.6 μm to about 2 μm, about 0.6 μm to about 2.2 μm, about 0.8 μm to about 1 μm, about 0.8 μm to about 1.2 μm, about 0.8 μm to about 1.4 μm, about 0.8 μm to about 1.6 μm, about 0.8 μm to about 1.8 μm, about 0.8 μm to about 2 μm, about 0.8 μm to about 2.2 μm, about 1 μm to about 1.2 μm, about 1 μm to about 1.4 μm, about 1 μm to about 1.6 μm, about 1 μm to about 1.8 μm, about 1 μm to about 2 μm, about 1 μm to about 2.2 μm, about 1.2 μm to about 1.4 μm, about 1.2 μm to about 1.6 μm, about 1.2 μm to about 1.8 μm, about 1.2 μm to about 2 μm, about 1.2 μm to about 2.2 μm, about 1.4 μm to about 1.6 μm, about 1.4 μm to about 1.8 μm, about 1.4 μm to about 2 μm, about 1.4 μm to about 2.2 μm, about 1.6 μm to about 1.8 μm, about 1.6 μm to about 2 μm, about 1.6 μm to about 2.2 μm, about 1.8 μm to about 2 μm, about 1.8 μm to about 2.2 μm, or about 2 μm to about 2.2 μm after at least about one day, one week, one month, two months, three months, four months, five months, six months, seven months, eight months, nine months, ten months, eleven months, a year, or more of storage.

In some embodiments, the change in the D50 value of an ink disclosed herein is no more than about about 1% to about 20% after at least about one day, one week, one month, two months, three months, four months, five months, six months, seven months, eight months, nine months, ten months, eleven months, a year, or more of storage. In some embodiments, the change in the D50 value of an ink disclosed herein is no more than about about 1% to about 2%, about 1% to about 3%, about 1% to about 4%, about 1% to about 5%, about 1% to about 6%, about 1% to about 7%, about 1% to about 8%, about 1% to about 9%, about 1% to about 10%, about 1% to about 15%, about 1% to about 20%, about 2% to about 3%, about 2% to about 4%, about 2% to about 5%, about 2% to about 6%, about 2% to about 7%, about 2% to about 8%, about 2% to about 9%, about 2% to about 10%, about 2% to about 15%, about 2% to about 20%, about 3% to about 4%, about 3% to about 5%, about 3% to about 6%, about 3% to about 7%, about 3% to about 8%, about 3% to about 9%, about 3% to about 10%, about 3% to about 15%, about 3% to about 20%, about 4% to about 5%, about 4% to about 6%, about 4% to about 7%, about 4% to about 8%, about 4% to about 9%, about 4% to about 10%, about 4% to about 15%, about 4% to about 20%, about 5% to about 6%, about 5% to about 7%, about 5% to about 8%, about 5% to about 9%, about 5% to about 10%, about 5% to about 15%, about 5% to about 20%, about 6% to about 7%, about 6% to about 8%, about 6% to about 9%, about 6% to about 10%, about 6% to about 15%, about 6% to about 20%, about 7% to about 8%, about 7% to about 9%, about 7% to about 10%, about 7% to about 15%, about 7% to about 20%, about 8% to about 9%, about 8% to about 10%, about 8% to about 15%, about 8% to about 20%, about 9% to about 10%, about 9% to about 15%, about 9% to about 20%, about 10% to about 15%, about 10% to about 20%, or about 15% to about 20% after at least about one day, one week, one month, two months, three months, four months, five months, six months, seven months, eight months, nine months, ten months, eleven months, a year, or more of storage. In some embodiments, the change in the D50 value of an ink disclosed herein is no more than about about 1%, about 2%, about 3%, about 4%, about 5%, about 6%, about 7%, about 8%, about 9%, about 10%, about 15%, or about 20% after at least about one day, one week, one month, two months, three months, four months, five months, six months, seven months, eight months, nine months, ten months, eleven months, a year, or more of storage. In some embodiments, the change in the D50 value of an ink disclosed herein is no more than about at most about 2%, about 3%, about 4%, about 5%, about 6%, about 7%, about 8%, about 9%, about 10%, about 15%, or about 20% after at least about one day, one week, one month, two months, three months, four months, five months, six months, seven months, eight months, nine months, ten months, eleven months, a year, or more of storage.

In some embodiments, agglomeration may be indicated by a change in particle size distribution over time. In some embodiments, the change in the D90 value of an ink disclosed herein is no more than about 0.6 μm, about 0.8 μm, 1.0 μm, 1.2 μm, 1.4 μm, 1.6 μm, 1.8 μm, 2.0 μm, 2.2 μm, 2.4, μm, 2.6 μm, 2.8 μm, 3.0 μm, 3.2 μm, 3.4 μm, 3.6 μm. 3.8 μm, 4.0 μm, or less after at least about one day, one week, one month, two months, three months, four months, five months, six months, seven months, eight months, nine months, ten months, eleven months, a year, or more of storage. In some embodiments, the change in the D90 value of an ink is about 1.4 μm to about 3.6 μm. In some embodiments, the change in the D90 value of an ink is about 1.4 μm to about 1.6 μm, about 1.4 μm to about 1.8 μm, about 1.4 μm to about 2 μm, about 1.4 μm to about 2.2 μm, about 1.4 μm to about 2.4 μm, about 1.4 μm to about 2.6 μm, about 1.4 μm to about 2.8 μm, about 1.4 μm to about 3 μm, about 1.4 μm to about 3.2 μm, about 1.4 μm to about 3.4 μm, about 1.4 μm to about 3.6 μm, about 1.6 μm to about 1.8 μm, about 1.6 μm to about 2 μm, about 1.6 μm to about 2.2 μm, about 1.6 μm to about 2.4 μm, about 1.6 μm to about 2.6 μm, about 1.6 μm to about 2.8 μm, about 1.6 μm to about 3 μm, about 1.6 μm to about 3.2 μm, about 1.6 μm to about 3.4 μm, about 1.6 μm to about 3.6 μm, about 1.8 μm to about 2 μm, about 1.8 μm to about 2.2 μm, about 1.8 μm to about 2.4 μm, about 1.8 μm to about 2.6 μm, about 1.8 μm to about 2.8 μm, about 1.8 μm to about 3 μm, about 1.8 μm to about 3.2 μm, about 1.8 μm to about 3.4 μm, about 1.8 μm to about 3.6 μm, about 2 μm to about 2.2 μm, about 2 μm to about 2.4 μm, about 2 μm to about 2.6 μm, about 2 μm to about 2.8 μm, about 2 μm to about 3 μm, about 2 μm to about 3.2 μm, about 2 μm to about 3.4 μm, about 2 μm to about 3.6 μm, about 2.2 μm to about 2.4 μm, about 2.2 μm to about 2.6 μm, about 2.2 μm to about 2.8 μm, about 2.2 μm to about 3 μm, about 2.2 μm to about 3.2 μm, about 2.2 μm to about 3.4 μm, about 2.2 μm to about 3.6 μm, about 2.4 μm to about 2.6 μm, about 2.4 μm to about 2.8 μm, about 2.4 μm to about 3 μm, about 2.4 μm to about 3.2 μm, about 2.4 μm to about 3.4 μm, about 2.4 μm to about 3.6 μm, about 2.6 μm to about 2.8 μm, about 2.6 μm to about 3 μm, about 2.6 μm to about 3.2 μm, about 2.6 μm to about 3.4 μm, about 2.6 μm to about 3.6 μm, about 2.8 μm to about 3 μm, about 2.8 μm to about 3.2 μm, about 2.8 μm to about 3.4 μm, about 2.8 μm to about 3.6 μm, about 3 μm to about 3.2 μm, about 3 μm to about 3.4 μm, about 3 μm to about 3.6 μm, about 3.2 μm to about 3.4 μm, about 3.2 μm to about 3.6 μm, or about 3.4 μm to about 3.6 μm after at least about one day, one week, one month, two months, three months, four months, five months, six months, seven months, eight months, nine months, ten months, eleven months, a year, or more of storage.

In some embodiments, the change in the D90 value of an ink disclosed herein is no more than about about 1% to about 20% after at least about one day, one week, one month, two months, three months, four months, five months, six months, seven months, eight months, nine months, ten months, eleven months, a year, or more of storage. In some embodiments, the change in the D90 value of an ink disclosed herein is no more than about about 1% to about 2%, about 1% to about 3%, about 1% to about 4%, about 1% to about 5%, about 1% to about 6%, about 1% to about 7%, about 1% to about 8%, about 1% to about 9%, about 1% to about 10%, about 1% to about 15%, about 1% to about 20%, about 2% to about 3%, about 2% to about 4%, about 2% to about 5%, about 2% to about 6%, about 2% to about 7%, about 2% to about 8%, about 2% to about 9%, about 2% to about 10%, about 2% to about 15%, about 2% to about 20%, about 3% to about 4%, about 3% to about 5%, about 3% to about 6%, about 3% to about 7%, about 3% to about 8%, about 3% to about 9%, about 3% to about 10%, about 3% to about 15%, about 3% to about 20%, about 4% to about 5%, about 4% to about 6%, about 4% to about 7%, about 4% to about 8%, about 4% to about 9%, about 4% to about 10%, about 4% to about 15%, about 4% to about 20%, about 5% to about 6%, about 5% to about 7%, about 5% to about 8%, about 5% to about 9%, about 5% to about 10%, about 5% to about 15%, about 5% to about 20%, about 6% to about 7%, about 6% to about 8%, about 6% to about 9%, about 6% to about 10%, about 6% to about 15%, about 6% to about 20%, about 7% to about 8%, about 7% to about 9%, about 7% to about 10%, about 7% to about 15%, about 7% to about 20%, about 8% to about 9%, about 8% to about 10%, about 8% to about 15%, about 8% to about 20%, about 9% to about 10%, about 9% to about 15%, about 9% to about 20%, about 10% to about 15%, about 10% to about 20%, or about 15% to about 20% after at least about one day, one week, one month, two months, three months, four months, five months, six months, seven months, eight months, nine months, ten months, eleven months, a year, or more of storage. In some embodiments, the change in the D90 value of an ink disclosed herein is no more than about about 1%, about 2%, about 3%, about 4%, about 5%, about 6%, about 7%, about 8%, about 9%, about 10%, about 15%, or about 20% after at least about one day, one week, one month, two months, three months, four months, five months, six months, seven months, eight months, nine months, ten months, eleven months, a year, or more of storage. In some embodiments, the change in the D90 value of an ink disclosed herein is no more than about at most about 2%, about 3%, about 4%, about 5%, about 6%, about 7%, about 8%, about 9%, about 10%, about 15%, or about 20% after at least about one day, one week, one month, two months, three months, four months, five months, six months, seven months, eight months, nine months, ten months, eleven months, a year, or more of storage.

In some embodiments, a sheet resistance of a conductive ink as disclosed herein increases by less than about 1%, 2%, 3%, 4%, 5%, 6%, 7%, 8%, 9%, 10%, or less after at least about one day, one week, one month, two months, three months, four months, five months, six months, seven months, eight months, nine months, ten months, eleven months, a year, or more of storage.

In some embodiments, a standard deviation in sheet resistance of a conductive ink as disclosed herein increases by less than about 1%, 2%, 3%, 4%, 5%, 6%, 7%, 8%, 9%, 10%, or less after at least about one day, one week, one month, two months, three months, four months, five months, six months, seven months, eight months, nine months, ten months, eleven months, a year, or more of storage. In some embodiments, a volume resistivity of a conductive ink as disclosed herein increases by less than about 1%, 2%, 3%, 4%, 5%, 6%, 7%, 8%, 9%, 10%, or less after at least a year of storage of the conductive ink.

In some embodiments, a conductivity of an ink as disclosed herein decreases by less than about 1%, 2%, 3%, 4%, 5%, 6%, 7%, 8%, 9%, 10%, or less after at least about one day, one week, one month, two months, three months, four months, five months, six months, seven months, eight months, nine months, ten months, eleven months, a year, or more of storage.

In some embodiments, an adhesive property of a conductive ink as disclosed herein is not affected by storage of the conductive ink. In some embodiments, the adhesive property can be evaluated using an ASTM rating scale. In some embodiments, a rating of 5B indicates that an adhesion is complete (e.g., no rough edges, peeling, detachment). The rating of 5B is the maximum rating for method B of the ASTM adhesion test. In some embodiments, the conductive ink has an adhesion rating of 5B after at least about one day, one week, one month, two months, three months, four months, five months, six months, seven months, eight months, nine months, ten months, eleven months, a year, or more of storage.

In some embodiments, a viscosity of a conductive ink as disclosed herein is about 4,000 cP to about 6,200 cP after at least about one day, one week, one month, two months, three months, four months, five months, six months, seven months, eight months, nine months, ten months, eleven months, a year, or more of storage. In some embodiments, the viscosity of the ink is about 4,000 cP to about 4,200 cP, about 4,000 cP to about 4,400 cP, about 4,000 cP to about 4,600 cP, about 4,000 cP to about 4,800 cP, about 4,000 cP to about 5,000 cP, about 4,000 cP to about 5,200 cP, about 4,000 cP to about 5,400 cP, about 4,000 cP to about 5,600 cP, about 4,000 cP to about 5,800 cP, about 4,000 cP to about 6,000 cP, about 4,000 cP to about 6,200 cP, about 4,200 cP to about 4,400 cP, about 4,200 cP to about 4,600 cP, about 4,200 cP to about 4,800 cP, about 4,200 cP to about 5,000 cP, about 4,200 cP to about 5,200 cP, about 4,200 cP to about 5,400 cP, about 4,200 cP to about 5,600 cP, about 4,200 cP to about 5,800 cP, about 4,200 cP to about 6,000 cP, about 4,200 cP to about 6,200 cP, about 4,400 cP to about 4,600 cP, about 4,400 cP to about 4,800 cP, about 4,400 cP to about 5,000 cP, about 4,400 cP to about 5,200 cP, about 4,400 cP to about 5,400 cP, about 4,400 cP to about 5,600 cP, about 4,400 cP to about 5,800 cP, about 4,400 cP to about 6,000 cP, about 4,400 cP to about 6,200 cP, about 4,600 cP to about 4,800 cP, about 4,600 cP to about 5,000 cP, about 4,600 cP to about 5,200 cP, about 4,600 cP to about 5,400 cP, about 4,600 cP to about 5,600 cP, about 4,600 cP to about 5,800 cP, about 4,600 cP to about 6,000 cP, about 4,600 cP to about 6,200 cP, about 4,800 cP to about 5,000 cP, about 4,800 cP to about 5,200 cP, about 4,800 cP to about 5,400 cP, about 4,800 cP to about 5,600 cP, about 4,800 cP to about 5,800 cP, about 4,800 cP to about 6,000 cP, about 4,800 cP to about 6,200 cP, about 5,000 cP to about 5,200 cP, about 5,000 cP to about 5,400 cP, about 5,000 cP to about 5,600 cP, about 5,000 cP to about 5,800 cP, about 5,000 cP to about 6,000 cP, about 5,000 cP to about 6,200 cP, about 5,200 cP to about 5,400 cP, about 5,200 cP to about 5,600 cP, about 5,200 cP to about 5,800 cP, about 5,200 cP to about 6,000 cP, about 5,200 cP to about 6,200 cP, about 5,400 cP to about 5,600 cP, about 5,400 cP to about 5,800 cP, about 5,400 cP to about 6,000 cP, about 5,400 cP to about 6,200 cP, about 5,600 cP to about 5,800 cP, about 5,600 cP to about 6,000 cP, about 5,600 cP to about 6,200 cP, about 5,800 cP to about 6,000 cP, about 5,800 cP to about 6,200 cP, or about 6,000 cP to about 6,200 cP after at least about one day, one week, one month, two months, three months, four months, five months, six months, seven months, eight months, nine months, ten months, eleven months, a year, or more of storage. In some embodiments, the viscosity of the ink is at least about 4,000 cP, about 4,200 cP, about 4,400 cP, about 4,600 cP, about 4,800 cP, about 5,000 cP, about 5,200 cP, about 5,400 cP, about 5,600 cP, about 5,800 cP, or about 6,000 cP after at least about one day, one week, one month, two months, three months, four months, five months, six months, seven months, eight months, nine months, ten months, eleven months, a year, or more of storage.

In some embodiments, storage as disclosed herein comprises storage at room temperature. In some embodiments, storage as disclosed herein comprises storage at less than room temperature. In some embodiments, room temperature may be about 20° C.

### Reduced Graphene Oxide

The reduced graphene oxide (rGO) used to form the conductive inks herein can be easily dispersed and processed from a wide range of solvents and enabling conductive inks with tunable electronic and mechanical properties for a wide range of applications.

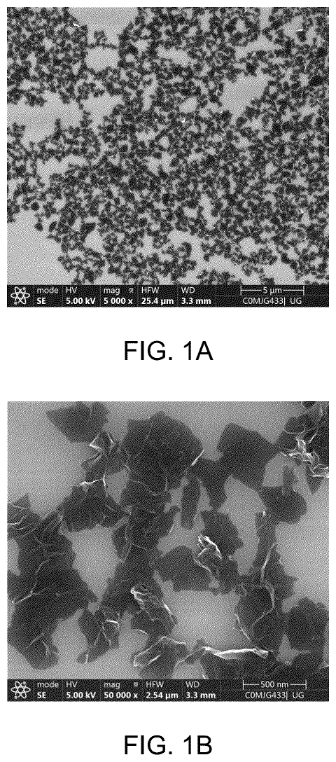

FIG. 1A and FIG. 1B are first and second Scanning Electron Microscope (SEM) images of exemplary reduced graphene oxide sheets coated onto a silicon wafer.

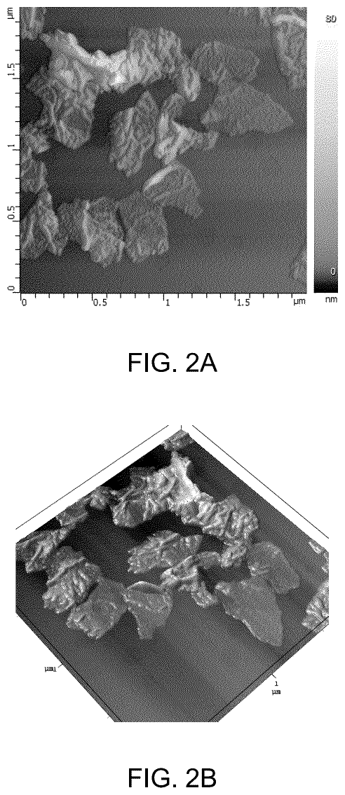

FIG. 2A and FIG. 2B are first and second Atomic Force Microscopy images of exemplary reduced graphene oxide sheets coated onto freshly cleaved mica substrates.

The images also show the individual layers of carbon and show wrinkles and creases in the basal planes, which are characteristic of graphene.

In some embodiments, the reduced graphene oxide sheets are comprised in an amount of about 0.5% wt. In some embodiments, the reduced graphene oxide sheets are comprised in an amount of about 0.5% wt.

In some embodiments, the reduced graphene oxide sheets are comprised in an amount from about 0.1% wt. to about 2.1% wt. In some embodiments, the reduced graphene oxide sheets are comprised in an amount about 0.1% wt. to about 0.3% wt., about 0.1% wt. to about 0.5% wt., about 0.1% wt. to about 0.7% wt., about 0.1% wt. to about 0.9% wt., about 0.1% wt. to about 1.1% wt., about 0.1% wt. to about 1.3% wt., about 0.1% wt. to about 1.5% wt., about 0.1% wt. to about 1.7% wt., about 0.1% wt. to about 1.9% wt., about 0.1% wt. to about 2% wt., about 0.1% wt. to about 2.1% wt., about 0.3% wt. to about 0.5% wt., about 0.3% wt. to about 0.7% wt., about 0.3% wt. to about 0.9% wt., about 0.3% wt. to about 1.1% wt., about 0.3% wt. to about 1.3% wt., about 0.3% wt. to about 1.5% wt., about 0.3% wt. to about 1.7% wt., about 0.3% wt. to about 1.9% wt., about 0.3% wt. to about 2% wt., about 0.3% wt. to about 2.1% wt., about 0.5% wt. to about 0.7% wt., about 0.5% wt. to about 0.9% wt., about 0.5% wt. to about 1.1% wt., about 0.5% wt. to about 1.3% wt., about 0.5% wt. to about 1.5% wt., about 0.5% wt. to about 1.7% wt., about 0.5% wt. to about 1.9% wt., about 0.5% wt. to about 2% wt., about 0.5% wt. to about 2.1% wt., about 0.7% wt. to about 0.9% wt., about 0.7% wt. to about 1.1% wt., about 0.7% wt. to about 1.3% wt., about 0.7% wt. to about 1.5% wt., about 0.7% wt. to about 1.7% wt., about 0.7% wt. to about 1.9% wt., about 0.7% wt. to about 2% wt., about 0.7% wt. to about 2.1% wt., about 0.9% wt. to about 1.1% wt., about 0.9% wt. to about 1.3% wt., about 0.9% wt. to about 1.5% wt., about 0.9% wt. to about 1.7% wt., about 0.9% wt. to about 1.9% wt., about 0.9% wt. to about 2% wt., about 0.9% wt. to about 2.1% wt., about 1.1% wt. to about 1.3% wt., about 1.1% wt. to about 1.5% wt., about 1.1% wt. to about 1.7% wt., about 1.1% wt. to about 1.9% wt., about 1.1% wt. to about 2% wt., about 1.1% wt. to about 2.1% wt., about 1.3% wt. to about 1.5% wt., about 1.3% wt. to about 1.7% wt., about 1.3% wt. to about 1.9% wt., about 1.3% wt. to about 2% wt., about 1.3% wt. to about 2.1% wt., about 1.5% wt. to about 1.7% wt., about 1.5% wt. to about 1.9% wt., about 1.5% wt. to about 2% wt., about 1.5% wt. to about 2.1% wt., about 1.7% wt. to about 1.9% wt., about 1.7% wt. to about 2% wt., about 1.7% wt. to about 2.1% wt., about 1.9% wt. to about 2% wt., about 1.9% wt. to about 2.1% wt., or about 2% wt. to about 2.1% wt., including increments therein. In some embodiments, the reduced graphene oxide sheets are comprised in an amount of about 0.1% wt., about 0.3% wt., about 0.5% wt., about 0.7% wt., about 0.9% wt., about 1.1% wt., about 1.3% wt., about 1.5% wt., about 1.7% wt., about 1.9% wt., about 2% wt., or about 2.1% wt. In some embodiments, the reduced graphene oxide sheets are comprised in an amount of at least about 0.1% wt., about 0.3% wt., about 0.5% wt., about 0.7% wt., about 0.9% wt., about 1.1% wt., about 1.3% wt., about 1.5% wt., about 1.7% wt., about 1.9% wt., or about 2% wt. In some embodiments, the reduced graphene oxide sheets are comprised in an amount of at most about 0.3% wt., about 0.5% wt., about 0.7% wt., about 0.9% wt., about 1.1% wt., about 1.3% wt., about 1.5% wt., about 1.7% wt., about 1.9% wt., about 2% wt., or about 2.1% wt.

In some embodiments, the reduced graphene oxide sheets are comprised in an amount about 0.3% wt. to about 0.7% wt. In some embodiments, the reduced graphene oxide sheets are comprised in an amount about 0.3% wt. to about 0.4% wt., about 0.3% wt. to about 0.5% wt., about 0.3% wt. to about 0.6% wt., about 0.3% wt. to about 0.7% wt., about 0.4% wt. to about 0.5% wt., about 0.4% wt. to about 0.6% wt., about 0.4% wt. to about 0.7% wt., about 0.5% wt. to about 0.6% wt., about 0.5% wt. to about 0.7% wt., or about 0.6% wt. to about 0.7% wt., including increments therein. In some embodiments, the reduced graphene oxide sheets are comprised in an amount of about 0.3% wt., about 0.4% wt., about 0.5% wt., about 0.6% wt., or about 0.7% wt. In some embodiments, the reduced graphene oxide sheets are comprised in an amount of at least about 0.3% wt., about 0.4% wt., about 0.5% wt., or about 0.6% wt. In some embodiments, the reduced graphene oxide sheets are comprised in an amount of at most about 0.4% wt., about 0.5% wt., about 0.6% wt., or about 0.7% wt.

In some embodiments, the reduced graphene oxide sheets are comprised in an amount of up to about 1% wt. In some embodiments, the reduced graphene oxide sheets are comprised in an amount of at least 0.3% wt. In some embodiments, the reduced graphene oxide sheets are comprised in an amount of about 0.5% wt.

### Silver Nanoflakes

In some embodiments, the silver nanoflakes are comprised in an amount of about 30% to about 85%. In some embodiments, the silver nanoflakes are comprised in an amount of about 30% to about 35%, about 30% to about 40%, about 30% to about 45%, about 30% to about 50%, about 30% to about 55%, about 30% to about 60%, about 30% to about 65%, about 30% to about 70%, about 30% to about 75%, about 30% to about 80%, about 30% to about 85%, about 35% to about 40%, about 35% to about 45%, about 35% to about 50%, about 35% to about 55%, about 35% to about 60%, about 35% to about 65%, about 35% to about 70%, about 35% to about 75%, about 35% to about 80%, about 35% to about 85%, about 40% to about 45%, about 40% to about 50%, about 40% to about 55%, about 40% to about 60%, about 40% to about 65%, about 40% to about 70%, about 40% to about 75%, about 40% to about 80%, about 40% to about 85%, about 45% to about 50%, about 45% to about 55%, about 45% to about 60%, about 45% to about 65%, about 45% to about 70%, about 45% to about 75%, about 45% to about 80%, about 45% to about 85%, about 50% to about 55%, about 50% to about 60%, about 50% to about 65%, about 50% to about 70%, about 50% to about 75%, about 50% to about 80%, about 50% to about 85%, about 55% to about 60%, about 55% to about 65%, about 55% to about 70%, about 55% to about 75%, about 55% to about 80%, about 55% to about 85%, about 60% to about 65%, about 60% to about 70%, about 60% to about 75%, about 60% to about 80%, about 60% to about 85%, about 65% to about 70%, about 65% to about 75%, about 65% to about 80%, about 65% to about 85%, about 70% to about 75%, about 70% to about 80%, about 70% to about 85%, about 75% to about 80%, about 75% to about 85%, or about 80% to about 85%, including increments therein. In some embodiments, the silver nanoflakes are comprised in an amount of about 30%, about 35%, about 40%, about 45%, about 50%, about 55%, about 60%, about 65%, about 70%, about 75%, about 80%, or about 85%. In some embodiments, the silver nanoflakes are comprised in an amount of at least about 30%, about 35%, about 40%, about 45%, about 50%, about 55%, about 60%, about 65%, about 70%, about 75%, or about 80%. In some embodiments, the silver nanoflakes are comprised in an amount of at most about 35%, about 40%, about 45%, about 50%, about 55%, about 60%, about 65%, about 70%, about 75%, about 80%, or about 85%.

In some embodiments, the silver nanoflakes comprise a diameter from about 8 μm to about 21 μm. In some embodiments, the silver nanoflakes comprise a diameter from about 8 μm to about 9 μm, about 8 μm to about 10 μm, about 8 μm to about 11 μm, about 8 μm to about 12 μm, about 8 μm to about 13 μm, about 8 μm to about 14 μm, about 8 μm to about 15 μm, about 8 μm to about 16 μm, about 8 μm to about 17 μm, about 8 μm to about 18 μm, about 8 μm to about 19 μm, about 8 μm to about 20 μm, about 8 μm to about 21 μm, about 9 μm to about 10 μm, about 9 μm to about 11 μm, about 9 μm to about 12 μm, about 9 μm to about 13 μm, about 9 μm to about 14 μm, about 9 μm to about 15 μm, about 9 μm to about 16 μm, about 9 μm to about 17 μm, about 9 μm to about 18 μm, about 9 μm to about 19 μm, about 9 μm to about 20 μm, about 9 μm to about 21 μm, about 10 μm to about 11 μm, about 10 μm to about 12 μm, about 10 μm to about 13 μm, about 10 μm to about 14 μm, about 10 μm to about 15 μm, about 10 μm to about 16 μm, about 10 μm to about 17 μm, about 10 μm to about 18 μm, about 10 μm to about 19 μm, about 10 μm to about 20 μm, about 10 μm to about 21 μm, about 11 μm to about 12 μm, about 11 μm to about 13 μm, about 11 μm to about 14 μm, about 11 μm to about 15 μm, about 11 μm to about 16 μm, about 11 μm to about 17 μm, about 11 μm to about 18 μm, about 11 μm to about 19 μm, about 11 μm to about 20 μm, about 11 μm to about 21 μm, about 12 μm to about 13 μm, about 12 μm to about 14 μm, about 12 μm to about 15 μm, about 12 μm to about 16 μm, about 12 μm to about 17 μm, about 12 μm to about 18 μm, about 12 μm to about 19 μm, about 12 μm to about 20 μm, about 12 μm to about 21 μm, about 13 μm to about 14 μm, about 13 μm to about 15 μm, about 13 μm to about 16 μm, about 13 μm to about 17 μm, about 13 μm to about 18 μm, about 13 μm to about 19 μm, about 13 μm to about 20 μm, about 13 μm to about 21 μm, about 14 μm to about 15 μm, about 14 μm to about 16 μm, about 14 μm to about 17 μm, about 14 μm to about 18 μm, about 14 μm to about 19 μm, about 14 μm to about 20 μm, about 14 μm to about 21 μm, about 15 μm to about 16 μm, about 15 μm to about 17 μm, about 15 μm to about 18 μm, about 15 μm to about 19 μm, about 15 μm to about 20 μm, about 15 μm to about 21 μm, about 16 μm to about 17 μm, about 16 μm to about 18 μm, about 16 μm to about 19 μm, about 16 μm to about 20 μm, about 16 μm to about 21 μm, about 17 μm to about 18 μm, about 17 μm to about 19 μm, about 17 μm to about 20 μm, about 17 μm to about 21 μm, about 18 μm to about 19 μm, about 18 μm to about 20 μm, about 18 μm to about 21 μm, about 19 μm to about 20 μm, about 20 μm to about 21 μm, or about 20 μm to about 21 μm, including increments therein. In some embodiments, the silver nanoflakes comprise a diameter from about 8 μm, about 9 μm, about 10 μm, about 11 μm, about 12 μm, about 13 μm, about 14 μm, about 15 μm, about 16 μm, about 17 μm, about 18 μm, about 19 μm, about 20 μm, or about 21 μm. In some embodiments, the silver nanoflakes comprise a diameter from at least about 8 μm, about 9 μm, about 10 μm, about 11 μm, about 12 μm, about 13 μm, about 14 μm, about 15 μm, about 16 μm, about 17 μm, about 18 μm, about 19 μm, or about 20 μm. In some embodiments, the silver nanoflakes comprise a diameter from at most about 9 μm, about 10 μm, about 11 μm, about 12 μm, about 13 μm, about 14 μm, about 15 μm, about 16 μm, about 17 μm, about 18 μm, about 19 μm, about 20 μm, or about 21 μm.

In some embodiments, the silver nanoflakes comprise an average particle diameter distribution of about 12 μm to about 16 μm. In some embodiments, the silver nanoflakes comprise an average particle diameter distribution of about 12 μm to about 12.5 μm, about 12 μm to about 13 μm, about 12 μm to about 13.5 μm, about 12 μm to about 14 μm, about 12 μm to about 14.5 μm, about 12 μm to about 15 μm, about 12 μm to about 15.6 μm, about 12 μm to about 16 μm, about 12.5 μm to about 13 μm, about 12.5 μm to about 13.5 μm, about 12.5 μm to about 14 μm, about 12.5 μm to about 14.5 μm, about 12.5 μm to about 15 μm, about 12.5 μm to about 15.6 μm, about 12.5 μm to about 16 μm, about 13 μm to about 13.5 μm, about 13 μm to about 14 μm, about 13 μm to about 14.5 μm, about 13 μm to about 15 μm, about 13 μm to about 15.6 μm, about 13 μm to about 16 μm, about 13.5 μm to about 14 μm, about 13.5 μm to about 14.5 μm, about 13.5 μm to about 15 μm, about 13.5 μm to about 15.6 μm, about 13.5 μm to about 16 μm, about 14 μm to about 14.5 μm, about 14 μm to about 15 μm, about 14 μm to about 15.6 μm, about 14 μm to about 16 μm, about 14.5 μm to about 15 μm, about 14.5 μm to about 15.6 μm, about 14.5 μm to about 16 μm, about 15 μm to about 15.6 μm, about 15 μm to about 16 μm, or about 15.6 μm to about 16 μm, including increments therein. In some embodiments, the silver nanoflakes comprise an average particle diameter distribution of about 12 μm, about 12.5 μm, about 13 μm, about 13.5 μm, about 14 μm, about 14.5 μm, about 15 μm, about 15.6 μm, or about 16 μm. In some embodiments, the silver nanoflakes comprise an average particle diameter distribution of at least about 12 μm, about 12.5 μm, about 13 μm, about 13.5 μm, about 14 μm, about 14.5 μm, about 15 μm, or about 15.6 μm. In some embodiments, the silver nanoflakes comprise an average particle diameter distribution of at most about 12.5 μm, about 13 μm, about 13.5 μm, about 14 μm, about 14.5 μm, about 15 μm, about 15.6 μm, or about 16 μm.

In some embodiments, the silver nanoflakes comprise an average particle diameter distribution of about 14.34 μm. In some embodiments, the silver nanoflakes comprise a median particle diameter of about 14.6 μm. In some embodiments, the silver nanoflakes comprise a D10 diameter of about 8.14 μm. In some embodiments, the silver nanoflakes comprise a D90 diameter of about 20.3 μm.

In some embodiments, the ink does not show streaks when printed with a diameter of up to 20 μm.

In some embodiments, the ink does not show streaks when printed with a diameter of about 1 μm to about 20 μm. In some embodiments, the ink does not show streaks when printed with a diameter of about 1 μm to about 3 μm, about 1 μm to about 5 μm, about 1 μm to about 7 μm, about 1 μm to about 9 μm, about 1 μm to about 11 μm, about 1 μm to about 13 μm, about 1 μm to about 15 μm, about 1 μm to about 17 μm, about 1 μm to about 18 μm, about 1 μm to about 19 μm, about 1 μm to about 20 μm, about 3 μm to about 5 μm, about 3 μm to about 7 μm, about 3 μm to about 9 μm, about 3 μm to about 11 μm, about 3 μm to about 13 μm, about 3 μm to about 15 μm, about 3 μm to about 17 μm, about 3 μm to about 18 μm, about 3 μm to about 19 μm, about 3 μm to about 20 μm, about 5 μm to about 7 μm, about 5 μm to about 9 μm, about 5 μm to about 11 μm, about 5 μm to about 13 μm, about 5 μm to about 15 μm, about 5 μm to about 17 μm, about 5 μm to about 18 μm, about 5 μm to about 19 μm, about 5 μm to about 20 μm, about 7 μm to about 9 μm, about 7 μm to about 11 μm, about 7 μm to about 13 μm, about 7 μm to about 15 μm, about 7 μm to about 17 μm, about 7 μm to about 18 μm, about 7 μm to about 19 μm, about 7 μm to about 20 μm, about 9 μm to about 11 μm, about 9 μm to about 13 μm, about 9 μm to about 15 μm, about 9 μm to about 17 μm, about 9 μm to about 18 μm, about 9 μm to about 19 μm, about 9 μm to about 20 μm, about 11 μm to about 13 μm, about 11 μm to about 15 μm, about 11 μm to about 17 μm, about 11 μm to about 18 μm, about 11 μm to about 19 μm, about 11 μm to about 20 μm, about 13 μm to about 15 μm, about 13 μm to about 17 μm, about 13 μm to about 18 μm, about 13 μm to about 19 μm, about 13 μm to about 20 μm, about 15 μm to about 17 μm, about 15 μm to about 18 μm, about 15 μm to about 19 μm, about 15 μm to about 20 μm, about 17 μm to about 18 μm, about 17 μm to about 19 μm, about 17 μm to about 20 μm, about 18 μm to about 19 μm, about 18 μm to about 20 μm, or about 19 μm to about 20 μm, including increments therein. In some embodiments, the ink does not show streaks when printed with a diameter of about 1 μm, about 3 μm, about 5 μm, about 7 μm, about 9 μm, about 11 μm, about 13 μm, about 15 μm, about 17 μm, about 18 μm, about 19 μm, or about 20 μm. In some embodiments, the ink does not show streaks when printed with a diameter of at least about 1 μm, about 3 μm, about 5 μm, about 7 μm, about 9 μm, about 11 μm, about 13 μm, about 15 μm, about 17 μm, about 18 μm, or about 19 μm. In some embodiments, the ink does not show streaks when printed with a diameter of at most about 3 μm, about 5 μm, about 7 μm, about 9 μm, about 11 μm, about 13 μm, about 15 μm, about 17 μm, about 18 μm, about 19 μm, or about 20 μm.

In some embodiments, the ink comprises a silver content of about 84% wt. when cured. In some embodiments, the ink comprises silver content of about 80% wt. to about 90% wt. when cured. In some embodiments, the ink comprises silver content of at least 80% wt. when cured. In some embodiments, the ink comprises silver content of up to 90% wt. when cured.

In some embodiments, the ink comprises silver content of about 80% wt to about 89% wt. In some embodiments, the ink comprises silver content of about 80% wt to about 81% wt, about 80% wt to about 82% wt, about 80% wt to about 83% wt, about 80% wt to about 84% wt, about 80% wt to about 85% wt, about 80% wt to about 86% wt, about 80% wt to about 87% wt, about 80% wt to about 88% wt, about 80% wt to about 89% wt, about 80% wt to about 80% wt, about 81% wt to about 82% wt, about 81% wt to about 83% wt, about 81% wt to about 84% wt, about 81% wt to about 85% wt, about 81% wt to about 86% wt, about 81% wt to about 87% wt, about 81% wt to about 88% wt, about 81% wt to about 89% wt, about 81% wt to about 80% wt, about 82% wt to about 83% wt, about 82% wt to about 84% wt, about 82% wt to about 85% wt, about 82% wt to about 86% wt, about 82% wt to about 87% wt, about 82% wt to about 88% wt, about 82% wt to about 89% wt, about 82% wt to about 80% wt, about 83% wt to about 84% wt, about 83% wt to about 85% wt, about 83% wt to about 86% wt, about 83% wt to about 87% wt, about 83% wt to about 88% wt, about 83% wt to about 89% wt, about 83% wt to about 80% wt, about 84% wt to about 85% wt, about 84% wt to about 86% wt, about 84% wt to about 87% wt, about 84% wt to about 88% wt, about 84% wt to about 89% wt, about 84% wt to about 80% wt, about 85% wt to about 86% wt, about 85% wt to about 87% wt, about 85% wt to about 88% wt, about 85% wt to about 89% wt, about 85% wt to about 80% wt, about 86% wt to about 87% wt, about 86% wt to about 88% wt, about 86% wt to about 89% wt, about 86% wt to about 80% wt, about 87% wt to about 88% wt, about 87% wt to about 89% wt, about 87% wt to about 80% wt, about 88% wt to about 89% wt, about 88% wt to about 80% wt, or about 89% wt to about 80% wt, including increments therein. In some embodiments, the ink comprises silver content of about 80% wt, about 81% wt, about 82% wt, about 83% wt, about 84% wt, about 85% wt, about 86% wt, about 87% wt, about 88% wt, about 89% wt, or about 80% wt. In some embodiments, the ink comprises silver content of at least about 80% wt, about 81% wt, about 82% wt, about 83% wt, about 84% wt, about 85% wt, about 86% wt, about 87% wt, about 88% wt, or about 89% wt. In some embodiments, the ink comprises silver content of at most about 81% wt, about 82% wt, about 83% wt, about 84% wt, about 85% wt, about 86% wt, about 87% wt, about 88% wt, about 89% wt, or about 80% wt.

In some embodiments, the combination of silver nanoflakes and graphene results in an increase in conductivity of the conductive ink by at least about 1,000 S/cm to about 6,500 S/cm. In some embodiments, the combination of silver nanoflakes and graphene results in an increase in conductivity of the conductive ink by at least about 1,000 S/cm to about 1,500 S/cm, about 1,000 S/cm to about 2,000 S/cm, about 1,000 S/cm to about 2,500 S/cm, about 1,000 S/cm to about 3,000 S/cm, about 1,000 S/cm to about 3,500 S/cm, about 1,000 S/cm to about 4,000 S/cm, about 1,000 S/cm to about 4,500 S/cm, about 1,000 S/cm to about 5,000 S/cm, about 1,000 S/cm to about 5,500 S/cm, about 1,000 S/cm to about 6,000 S/cm, about 1,000 S/cm to about 6,500 S/cm, about 1,500 S/cm to about 2,000 S/cm, about 1,500 S/cm to about 2,500 S/cm, about 1,500 S/cm to about 3,000 S/cm, about 1,500 S/cm to about 3,500 S/cm, about 1,500 S/cm to about 4,000 S/cm, about 1,500 S/cm to about 4,500 S/cm, about 1,500 S/cm to about 5,000 S/cm, about 1,500 S/cm to about 5,500 S/cm, about 1,500 S/cm to about 6,000 S/cm, about 1,500 S/cm to about 6,500 S/cm, about 2,000 S/cm to about 2,500 S/cm, about 2,000 S/cm to about 3,000 S/cm, about 2,000 S/cm to about 3,500 S/cm, about 2,000 S/cm to about 4,000 S/cm, about 2,000 S/cm to about 4,500 S/cm, about 2,000 S/cm to about 5,000 S/cm, about 2,000 S/cm to about 5,500 S/cm, about 2,000 S/cm to about 6,000 S/cm, about 2,000 S/cm to about 6,500 S/cm, about 2,500 S/cm to about 3,000 S/cm, about 2,500 S/cm to about 3,500 S/cm, about 2,500 S/cm to about 4,000 S/cm, about 2,500 S/cm to about 4,500 S/cm, about 2,500 S/cm to about 5,000 S/cm, about 2,500 S/cm to about 5,500 S/cm, about 2,500 S/cm to about 6,000 S/cm, about 2,500 S/cm to about 6,500 S/cm, about 3,000 S/cm to about 3,500 S/cm, about 3,000 S/cm to about 4,000 S/cm, about 3,000 S/cm to about 4,500 S/cm, about 3,000 S/cm to about 5,000 S/cm, about 3,000 S/cm to about 5,500 S/cm, about 3,000 S/cm to about 6,000 S/cm, about 3,000 S/cm to about 6,500 S/cm, about 3,500 S/cm to about 4,000 S/cm, about 3,500 S/cm to about 4,500 S/cm, about 3,500 S/cm to about 5,000 S/cm, about 3,500 S/cm to about 5,500 S/cm, about 3,500 S/cm to about 6,000 S/cm, about 3,500 S/cm to about 6,500 S/cm, about 4,000 S/cm to about 4,500 S/cm, about 4,000 S/cm to about 5,000 S/cm, about 4,000 S/cm to about 5,500 S/cm, about 4,000 S/cm to about 6,000 S/cm, about 4,000 S/cm to about 6,500 S/cm, about 4,500 S/cm to about 5,000 S/cm, about 4,500 S/cm to about 5,500 S/cm, about 4,500 S/cm to about 6,000 S/cm, about 4,500 S/cm to about 6,500 S/cm, about 5,000 S/cm to about 5,500 S/cm, about 5,000 S/cm to about 6,000 S/cm, about 5,000 S/cm to about 6,500 S/cm, about 5,500 S/cm to about 6,000 S/cm, about 5,500 S/cm to about 6,500 S/cm, or about 6,000 S/cm to about 6,500 S/cm, including increments therein. In some embodiments, the combination of silver nanoflakes and graphene results in an increase in conductivity of the conductive ink by at least about 1,000 S/cm, about 1,500 S/cm, about 2,000 S/cm, about 2,500 S/cm, about 3,000 S/cm, about 3,500 S/cm, about 4,000 S/cm, about 4,500 S/cm, about 5,000 S/cm, about 5,500 S/cm, about 6,000 S/cm, or about 6,500 S/cm. In some embodiments, the combination of silver nanoflakes and graphene results in an increase in conductivity of the conductive ink by at least at least about 1,000 S/cm, about 1,500 S/cm, about 2,000 S/cm, about 2,500 S/cm, about 3,000 S/cm, about 3,500 S/cm, about 4,000 S/cm, about 4,500 S/cm, about 5,000 S/cm, about 5,500 S/cm, or about 6,000 S/cm. In some embodiments, the combination of silver nanoflakes and graphene results in an increase in conductivity of the conductive ink by at least at most about 1,500 S/cm, about 2,000 S/cm, about 2,500 S/cm, about 3,000 S/cm, about 3,500 S/cm, about 4,000 S/cm, about 4,500 S/cm, about 5,000 S/cm, about 5,500 S/cm, about 6,000 S/cm, or about 6,500 S/cm.

In some embodiments, the combination of silver nanoflakes and graphene results in an increase in conductivity of the conductive ink by at least about 10% to about 220%, when compared to formulations produced without silver. In some embodiments, the combination of silver nanoflakes and graphene results in an increase in conductivity of the conductive ink by at least about 10% to about 20%, about 10% to about 40%, about 10% to about 60%, about 10% to about 80%, about 10% to about 100%, about 10% to about 120%, about 10% to about 140%, about 10% to about 160%, about 10% to about 180%, about 10% to about 200%, about 10% to about 220%, about 20% to about 40%, about 20% to about 60%, about 20% to about 80%, about 20% to about 100%, about 20% to about 120%, about 20% to about 140%, about 20% to about 160%, about 20% to about 180%, about 20% to about 200%, about 20% to about 220%, about 40% to about 60%, about 40% to about 80%, about 40% to about 100%, about 40% to about 120%, about 40% to about 140%, about 40% to about 160%, about 40% to about 180%, about 40% to about 200%, about 40% to about 220%, about 60% to about 80%, about 60% to about 100%, about 60% to about 120%, about 60% to about 140%, about 60% to about 160%, about 60% to about 180%, about 60% to about 200%, about 60% to about 220%, about 80% to about 100%, about 80% to about 120%, about 80% to about 140%, about 80% to about 160%, about 80% to about 180%, about 80% to about 200%, about 80% to about 220%, about 100% to about 120%, about 100% to about 140%, about 100% to about 160%, about 100% to about 180%, about 100% to about 200%, about 100% to about 220%, about 120% to about 140%, about 120% to about 160%, about 120% to about 180%, about 120% to about 200%, about 120% to about 220%, about 140% to about 160%, about 140% to about 180%, about 140% to about 200%, about 140% to about 220%, about 160% to about 180%, about 160% to about 200%, about 160% to about 220%, about 180% to about 200%, about 180% to about 220%, or about 200% to about 220%, including increments therein. In some embodiments, the combination of silver nanoflakes and graphene results in an increase in conductivity of the conductive ink by at least about 10%, about 20%, about 40%, about 60%, about 80%, about 100%, about 120%, about 140%, about 160%, about 180%, about 200%, or about 220%. In some embodiments, the combination of silver nanoflakes and graphene results in an increase in conductivity of the conductive ink by at least at least about 10%, about 20%, about 40%, about 60%, about 80%, about 100%, about 120%, about 140%, about 160%, about 180%, or about 200%. In some embodiments, the combination of silver nanoflakes and graphene results in an increase in conductivity of the conductive ink by at least at most about 20%, about 40%, about 60%, about 80%, about 100%, about 120%, about 140%, about 160%, about 180%, about 200%, or about 220%.

In some embodiments, the combination of silver nanoflakes and graphene results in an increase in viscosity of the conductive ink by at least about 1,000 cP to about 5,000 cP. In some embodiments, the combination of silver flakes and ultra-graphene results in an increase in viscosity of the conductive ink by at least about 1,000 cP to about 1,500 cP, about 1,000 cP to about 2,000 cP, about 1,000 cP to about 2,500 cP, about 1,000 cP to about 3,000 cP, about 1,000 cP to about 3,500 cP, about 1,000 cP to about 4,000 cP, about 1,000 cP to about 4,500 cP, about 1,000 cP to about 5,000 cP, about 1,500 cP to about 2,000 cP, about 1,500 cP to about 2,500 cP, about 1,500 cP to about 3,000 cP, about 1,500 cP to about 3,500 cP, about 1,500 cP to about 4,000 cP, about 1,500 cP to about 4,500 cP, about 1,500 cP to about 5,000 cP, about 2,000 cP to about 2,500 cP, about 2,000 cP to about 3,000 cP, about 2,000 cP to about 3,500 cP, about 2,000 cP to about 4,000 cP, about 2,000 cP to about 4,500 cP, about 2,000 cP to about 5,000 cP, about 2,500 cP to about 3,000 cP, about 2,500 cP to about 3,500 cP, about 2,500 cP to about 4,000 cP, about 2,500 cP to about 4,500 cP, about 2,500 cP to about 5,000 cP, about 3,000 cP to about 3,500 cP, about 3,000 cP to about 4,000 cP, about 3,000 cP to about 4,500 cP, about 3,000 cP to about 5,000 cP, about 3,500 cP to about 4,000 cP, about 3,500 cP to about 4,500 cP, about 3,500 cP to about 5,000 cP, about 4,000 cP to about 4,500 cP, about 4,000 cP to about 5,000 cP, or about 4,500 cP to about 5,000 cP, including increments therein. In some embodiments, the combination of silver flakes and ultra-graphene results in an increase in viscosity of the conductive ink by at least about 1,000 cP, about 1,500 cP, about 2,000 cP, about 2,500 cP, about 3,000 cP, about 3,500 cP, about 4,000 cP, about 4,500 cP, or about 5,000 cP. In some embodiments, the combination of silver flakes and ultra-graphene results in an increase in viscosity of the conductive ink by at least about 1,000 cP, about 1,500 cP, about 2,000 cP, about 2,500 cP, about 3,000 cP, about 3,500 cP, about 4,000 cP, or about 4,500 cP. In some embodiments, the combination of silver flakes and ultra-graphene results in an increase in viscosity of the conductive ink by at least at most about 1,500 cP, about 2,000 cP, about 2,500 cP, about 3,000 cP, about 3,500 cP, about 4,000 cP, about 4,500 cP, or about 5,000 cP.

In some embodiments, the combination of silver flakes and ultra-graphene results in an increase in viscosity of the conductive ink by at least about 10% to about 220%. In some embodiments, the combination of silver flakes and ultra-graphene results in an increase in viscosity of the conductive ink by at least about 10% to about 20%, about 10% to about 40%, about 10% to about 60%, about 10% to about 80%, about 10% to about 100%, about 10% to about 120%, about 10% to about 140%, about 10% to about 160%, about 10% to about 180%, about 10% to about 200%, about 10% to about 220%, about 20% to about 40%, about 20% to about 60%, about 20% to about 80%, about 20% to about 100%, about 20% to about 120%, about 20% to about 140%, about 20% to about 160%, about 20% to about 180%, about 20% to about 200%, about 20% to about 220%, about 40% to about 60%, about 40% to about 80%, about 40% to about 100%, about 40% to about 120%, about 40% to about 140%, about 40% to about 160%, about 40% to about 180%, about 40% to about 200%, about 40% to about 220%, about 60% to about 80%, about 60% to about 100%, about 60% to about 120%, about 60% to about 140%, about 60% to about 160%, about 60% to about 180%, about 60% to about 200%, about 60% to about 220%, about 80% to about 100%, about 80% to about 120%, about 80% to about 140%, about 80% to about 160%, about 80% to about 180%, about 80% to about 200%, about 80% to about 220%, about 100% to about 120%, about 100% to about 140%, about 100% to about 160%, about 100% to about 180%, about 100% to about 200%, about 100% to about 220%, about 120% to about 140%, about 120% to about 160%, about 120% to about 180%, about 120% to about 200%, about 120% to about 220%, about 140% to about 160%, about 140% to about 180%, about 140% to about 200%, about 140% to about 220%, about 160% to about 180%, about 160% to about 200%, about 160% to about 220%, about 180% to about 200%, about 180% to about 220%, or about 200% to about 220%, including increments therein. In some embodiments, the combination of silver flakes and ultra-graphene results in an increase in viscosity of the conductive ink by at least about 10%, about 20%, about 40%, about 60%, about 80%, about 100%, about 120%, about 140%, about 160%, about 180%, about 200%, or about 220%. In some embodiments, the combination of silver flakes and ultra-graphene results in an increase in viscosity of the conductive ink by at least at least about 10%, about 20%, about 40%, about 60%, about 80%, about 100%, about 120%, about 140%, about 160%, about 180%, or about 200%. In some embodiments, the combination of silver flakes and ultra-graphene results in an increase in viscosity of the conductive ink by at least at most about 20%, about 40%, about 60%, about 80%, about 100%, about 120%, about 140%, about 160%, about 180%, about 200%, or about 220%.

### Solvent

In some embodiments, the solvent comprises Dowanol PnP, 2-ethyl-1-hexanol, DEGBE, 2-ethyl-1-butanol, 2-methyl-1-pentanol, PGMEA, Hexamine, Cycloheptylamine, Isoamyl amine, 3-Methoxypropylamine, PCBTF, ethylene glycol, isopropanol, ethyl acetate, chloroform, DMF, NMP, THF, dichlorobenzene, or combinations thereof. In some embodiments, the solvent comprises Propylene glycol propyl ether. In some embodiments, the solvent comprises 2-ethyl-1-hexanol. In some embodiments, the solvent comprises Propylene glycol propyl ether. In some embodiments, the solvent comprises 2-ethyl-1-hexanol. In some embodiments, the solvent comprises propylene glycol propyl ether, and 2-ethyl-1-hexanol.

In some embodiments, the solvent is comprised in an amount of about 10% wt to about 90% wt. In some embodiments, the solvent is comprised in an amount of about 10% wt to about 20% wt, about 10% wt to about 30% wt, about 10% wt to about 40% wt, about 10% wt to about 50% wt, about 10% wt to about 60% wt, about 10% wt to about 70% wt, about 10% wt to about 80% wt, about 10% wt to about 90% wt, about 20% wt to about 30% wt, about 20% wt to about 40% wt, about 20% wt to about 50% wt, about 20% wt to about 60% wt, about 20% wt to about 70% wt, about 20% wt to about 80% wt, about 20% wt to about 90% wt, about 30% wt to about 40% wt, about 30% wt to about 50% wt, about 30% wt to about 60% wt, about 30% wt to about 70% wt, about 30% wt to about 80% wt, about 30% wt to about 90% wt, about 40% wt to about 50% wt, about 40% wt to about 60% wt, about 40% wt to about 70% wt, about 40% wt to about 80% wt, about 40% wt to about 90% wt, about 50% wt to about 60% wt, about 50% wt to about 70% wt, about 50% wt to about 80% wt, about 50% wt to about 90% wt, about 60% wt to about 70% wt, about 60% wt to about 80% wt, about 60% wt to about 90% wt, about 70% wt to about 80% wt, about 70% wt to about 90% wt, or about 80% wt to about 90% wt, including increments therein. In some embodiments, the solvent is comprised in an amount of about 10% wt, about 20% wt, about 30% wt, about 40% wt, about 50% wt, about 60% wt, about 70% wt, about 80% wt, or about 90% wt. In some embodiments, the solvent is comprised in an amount of at least about 10% wt, about 20% wt, about 30% wt, about 40% wt, about 50% wt, about 60% wt, about 70% wt, or about 80% wt. In some embodiments, the solvent is comprised in an amount of at most about 20% wt, about 30% wt, about 40% wt, about 50% wt, about 60% wt, about 70% wt, about 80% wt, or about 90% wt.

In some embodiments, the solvent comprises Propylene glycol propyl ether in an amount of about 10% wt to about 90% wt. In some embodiments, the solvent comprises Propylene glycol propyl ether in an amount of about 10% wt to about 20% wt, about 10% wt to about 30% wt, about 10% wt to about 40% wt, about 10% wt to about 50% wt, about 10% wt to about 60% wt, about 10% wt to about 70% wt, about 10% wt to about 80% wt, about 10% wt to about 90% wt, about 20% wt to about 30% wt, about 20% wt to about 40% wt, about 20% wt to about 50% wt, about 20% wt to about 60% wt, about 20% wt to about 70% wt, about 20% wt to about 80% wt, about 20% wt to about 90% wt, about 30% wt to about 40% wt, about 30% wt to about 50% wt, about 30% wt to about 60% wt, about 30% wt to about 70% wt, about 30% wt to about 80% wt, about 30% wt to about 90% wt, about 40% wt to about 50% wt, about 40% wt to about 60% wt, about 40% wt to about 70% wt, about 40% wt to about 80% wt, about 40% wt to about 90% wt, about 50% wt to about 60% wt, about 50% wt to about 70% wt, about 50% wt to about 80% wt, about 50% wt to about 90% wt, about 60% wt to about 70% wt, about 60% wt to about 80% wt, about 60% wt to about 90% wt, about 70% wt to about 80% wt, about 70% wt to about 90% wt, or about 80% wt to about 90% wt, including increments therein. In some embodiments, the solvent comprises Propylene glycol propyl ether in an amount of about 10% wt, about 20% wt, about 30% wt, about 40% wt, about 50% wt, about 60% wt, about 70% wt, about 80% wt, or about 90% wt.

In some embodiments, the solvent comprises Propylene glycol propyl ether in an amount of at least about 10% wt, about 20% wt, about 30% wt, about 40% wt, about 50% wt, about 60% wt, about 70% wt, or about 80% wt. In some embodiments, the solvent comprises Propylene glycol propyl ether in an amount of at most about 20% wt, about 30% wt, about 40% wt, about 50% wt, about 60% wt, about 70% wt, about 80% wt, or about 90% wt.

In some embodiments, the solvent comprises Propylene glycol propyl ether in an amount of about 15% wt. In some embodiments, the solvent comprises Propylene glycol propyl ether in an amount of at least about 10% wt. In some embodiments, the solvent comprises Propylene glycol propyl ether in an amount up to 20% wt. In some embodiments, the solvent comprises Propylene glycol propyl ether in an amount up to 90% wt.

In some embodiments, the solvent comprises Propylene glycol propyl ether in an amount of about 13% wt to about 17% wt. In some embodiments, the solvent comprises Propylene glycol propyl ether in an amount of about 13% wt to about 14% wt, about 13% wt to about 15% wt, about 13% wt to about 16% wt, about 13% wt to about 17% wt, about 14% wt to about 15% wt, about 14% wt to about 16% wt, about 14% wt to about 17% wt, about 15% wt to about 16% wt, about 15% wt to about 17% wt, or about 16% wt to about 17% wt, including increments therein. In some embodiments, the solvent comprises Propylene glycol propyl ether in an amount of about 13% wt, about 14% wt, about 15% wt, about 16% wt, or about 17% wt. In some embodiments, the solvent comprises Propylene glycol propyl ether in an amount of at least about 13% wt, about 14% wt, about 15% wt, or about 16% wt. In some embodiments, the solvent comprises Propylene glycol propyl ether in an amount of at most about 14% wt, about 15% wt, about 16% wt, or about 17% wt.

### Dispersing Agents

In some embodiments, the dispersing agent comprises Poly THF in an amount of about 0.5% wt to about 20% wt. In some embodiments, the dispersing agent comprises Poly THF in an amount of about 0.5% wt to about 2% wt, about 0.5% wt to about 4% wt, about 0.5% wt to about 6% wt, about 0.5% wt to about 8% wt, about 0.5% wt to about 10% wt, about 0.5% wt to about 12% wt, about 0.5% wt to about 14% wt, about 0.5% wt to about 16% wt, about 0.5% wt to about 18% wt, about 0.5% wt to about 20% wt, about 2% wt to about 4% wt, about 2% wt to about 6% wt, about 2% wt to about 8% wt, about 2% wt to about 10% wt, about 2% wt to about 12% wt, about 2% wt to about 14% wt, about 2% wt to about 16% wt, about 2% wt to about 18% wt, about 2% wt to about 20% wt, about 4% wt to about 6% wt, about 4% wt to about 8% wt, about 4% wt to about 10% wt, about 4% wt to about 12% wt, about 4% wt to about 14% wt, about 4% wt to about 16% wt, about 4% wt to about 18% wt, about 4% wt to about 20% wt, about 6% wt to about 8% wt, about 6% wt to about 10% wt, about 6% wt to about 12% wt, about 6% wt to about 14% wt, about 6% wt to about 16% wt, about 6% wt to about 18% wt, about 6% wt to about 20% wt, about 8% wt to about 10% wt, about 8% wt to about 12% wt, about 8% wt to about 14% wt, about 8% wt to about 16% wt, about 8% wt to about 18% wt, about 8% wt to about 20% wt, about 10% wt to about 12% wt, about 10% wt to about 14% wt, about 10% wt to about 16% wt, about 10% wt to about 18% wt, about 10% wt to about 20% wt, about 12% wt to about 14% wt, about 12% wt to about 16% wt, about 12% wt to about 18% wt, about 12% wt to about 20% wt, about 14% wt to about 16% wt, about 14% wt to about 18% wt, about 14% wt to about 20% wt, about 16% wt to about 18% wt, about 16% wt to about 20% wt, or about 18% wt to about 20% wt, including increments therein. In some embodiments, the dispersing agent comprises Poly THF in an amount of about 0.5% wt, about 2% wt, about 4% wt, about 6% wt, about 8% wt, about 10% wt, about 12% wt, about 14% wt, about 16% wt, about 18% wt, or about 20% wt. In some embodiments, the dispersing agent comprises Poly THF in an amount of at least about 0.5% wt, about 2% wt, about 4% wt, about 6% wt, about 8% wt, about 10% wt, about 12% wt, about 14% wt, about 16% wt, or about 18% wt. In some embodiments, the dispersing agent comprises Poly THF in an amount of at most about 2% wt, about 4% wt, about 6% wt, about 8% wt, about 10% wt, about 12% wt, about 14% wt, about 16% wt, about 18% wt, or about 20% wt. In some embodiments, the dispersing agent comprises Poly THF in an amount of about 0.5% wt. to about 20% wt. In some embodiments, the dispersing agent comprises Poly THF in an amount about 0.5% wt. to about 2% wt. In some embodiments, the dispersing agent comprises Poly THF in an amount of about 1% wt. In some embodiments, the dispersing agent comprises Poly THF in an amount of at least 1% wt. In some embodiments, the dispersing agent comprises Poly THF in an amount up to 10% wt. In some embodiments, the dispersing agent comprises Poly THF in an amount up to 20% wt. In some embodiments, the dispersing agent comprises Poly THF 2k, referring to the average molecular weight of the polymer.

### Binder

In some embodiments, the binder comprises Poly Vinyl Pyrrolidone in an amount of about 0.5% wt to about 10.5% wt. In some embodiments, the binder comprises Poly Vinyl Pyrrolidone in an amount of about 0.5% wt to about 1% wt, about 0.5% wt to about 1.5% wt, about 0.5% wt to about 2.5% wt, about 0.5% wt to about 3.5% wt, about 0.5% wt to about 4.5% wt, about 0.5% wt to about 5.5% wt, about 0.5% wt to about 6.5% wt, about 0.5% wt to about 7.5% wt, about 0.5% wt to about 8.5% wt, about 0.5% wt to about 9.5% wt, about 0.5% wt to about 10.5% wt, about 1% wt to about 1.5% wt, about 1% wt to about 2.5% wt, about 1% wt to about 3.5% wt, about 1% wt to about 4.5% wt, about 1% wt to about 5.5% wt, about 1% wt to about 6.5% wt, about 1% wt to about 7.5% wt, about 1% wt to about 8.5% wt, about 1% wt to about 9.5% wt, about 1% wt to about 10.5% wt, about 1.5% wt to about 2.5% wt, about 1.5% wt to about 3.5% wt, about 1.5% wt to about 4.5% wt, about 1.5% wt to about 5.5% wt, about 1.5% wt to about 6.5% wt, about 1.5% wt to about 7.5% wt, about 1.5% wt to about 8.5% wt, about 1.5% wt to about 9.5% wt, about 1.5% wt to about 10.5% wt, about 2.5% wt to about 3.5% wt, about 2.5% wt to about 4.5% wt, about 2.5% wt to about 5.5% wt, about 2.5% wt to about 6.5% wt, about 2.5% wt to about 7.5% wt, about 2.5% wt to about 8.5% wt, about 2.5% wt to about 9.5% wt, about 2.5% wt to about 10.5% wt, about 3.5% wt to about 4.5% wt, about 3.5% wt to about 5.5% wt, about 3.5% wt to about 6.5% wt, about 3.5% wt to about 7.5% wt, about 3.5% wt to about 8.5% wt, about 3.5% wt to about 9.5% wt, about 3.5% wt to about 10.5% wt, about 4.5% wt to about 5.5% wt, about 4.5% wt to about 6.5% wt, about 4.5% wt to about 7.5% wt, about 4.5% wt to about 8.5% wt, about 4.5% wt to about 9.5% wt, about 4.5% wt to about 10.5% wt, about 5.5% wt to about 6.5% wt, about 5.5% wt to about 7.5% wt, about 5.5% wt to about 8.5% wt, about 5.5% wt to about 9.5% wt, about 5.5% wt to about 10.5% wt, about 6.5% wt to about 7.5% wt, about 6.5% wt to about 8.5% wt, about 6.5% wt to about 9.5% wt, about 6.5% wt to about 10.5% wt, about 7.5% wt to about 8.5% wt, about 7.5% wt to about 9.5% wt, about 7.5% wt to about 10.5% wt, about 8.5% wt to about 9.5% wt, about 8.5% wt to about 10.5% wt, or about 9.5% wt to about 10.5% wt, including increments therein. In some embodiments, the binder comprises Poly Vinyl Pyrrolidone in an amount of about 0.5% wt, about 1% wt, about 1.5% wt, about 2.5% wt, about 3.5% wt, about 4.5% wt, about 5.5% wt, about 6.5% wt, about 7.5% wt, about 8.5% wt, about 9.5% wt, or about 10.5% wt. In some embodiments, the binder comprises Poly Vinyl Pyrrolidone in an amount of at least about 0.5% wt, about 1% wt, about 1.5% wt, about 2.5% wt, about 3.5% wt, about 4.5% wt, about 5.5% wt, about 6.5% wt, about 7.5% wt, about 8.5% wt, or about 9.5% wt. In some embodiments, the binder comprises Poly Vinyl Pyrrolidone in an amount of at most about 1% wt, about 1.5% wt, about 2.5% wt, about 3.5% wt, about 4.5% wt, about 5.5% wt, about 6.5% wt, about 7.5% wt, about 8.5% wt, about 9.5% wt, or about 10.5% wt.

In some embodiments, the binder comprises Poly Vinyl Pyrrolidone in an amount of about 10.5% wt. In some embodiments, the binder comprises Poly Vinyl Pyrrolidone 15k in an amount of about 10.5% wt. In some embodiments, the binder comprises Poly Vinyl Pyrrolidone in an amount of about 8% wt. to about 12% wt. In some embodiments, the binder comprises Poly Vinyl Pyrrolidone 15k in an amount of about 8% wt. to about 12% wt. In some embodiments, the binder comprises Poly Vinyl Pyrrolidone in an amount of at least 5% wt. In some embodiments, the binder comprises Poly Vinyl Pyrrolidone in an amount up to 20% wt. In some embodiments, the Poly Vinyl Pyrrolidone is PVP 15k.

### Method of Preparing a Conductive Ink

The embodiments disclosed herein comprise an ink formulation that works for roll-to-roll coating, screen printing, extruder printing, flexography, slot-die, and knife-over-edge printing

A method of preparing a conductive ink, the method comprising: preparing a mixture comprising: reduced graphene oxide sheets, wherein: at least about 90% of the graphene sheets consist of a single layer; the graphene sheets have an oxygen content of at most about 6% wt; or both; silver nanoflakes; a solvent; a dispersing agent; and a binder; and mixing the mixture at a high shear rate as to exfoliate the graphene oxide sheets and form a substantially uniform dispersion between the reduced graphene oxide sheets and the silver nanoflakes to form the conductive ink.

In some embodiments, the conductive ink consists of reduced graphene oxide sheets, silver nanoflakes, a solvent, a dispersing agent, and a binder. In some embodiments, the conductive ink consists essentially of reduced graphene oxide sheets, silver nanoflakes, a solvent, a dispersing agent, and a binder. In some embodiments, the conductive ink comprises a softener. In some embodiments, the conductive ink does not comprise a surfactant. In some embodiments, the conductive ink does not comprise a defoamer. In some embodiments, the conductive ink does not comprise ultra graphene.

The specific components of the conductive ink herein enable its unexpectedly improved elasticity, adhesion, thermal stability, coating uniformity, chemical stability, tunable viscosity, and conductivity. The ink exhibits superior stability and coats evenly without leaving holes, and has a smooth surface.

In some embodiments, the graphene comprises reduced graphene oxide. In some embodiments, the graphene comprises activated reduced graphene oxide. In some embodiments, at least about 85%, 86%, 87%, 88%, 89%, 90%, 91%, 92%, 93%, 94%, 95%, 96%, 97%, 98% or more of the graphene sheets consist of a single layer of graphene. In some embodiments, the high content of single layer graphene sheets within the conductive ink improves the conductivity of the conductive ink when dry. In some embodiments, a percentage of the reduced graphene oxide that consists of a single layer is determined by atomic force microscopy (AFM). In some embodiments, the graphene sheets have an oxygen content of at most about 2%, 3%, 4%, 5%, 6%, 7%, 8%, 9%, or 10%, including increments therein. In some embodiments, the low oxygen content of the graphene sheets within the conductive ink improves the conductivity of the conductive ink when dry.

The silver nanoflakes disclosed herein enable the unexpectedly improved elasticity, adhesion, thermal stability, chemical stability, conductivity and viscosity of the formulation.

Furthermore, the combination of silver flakes and ultragraphene unexpectedly improved elasticity, adhesion, thermal stability, chemical stability, conductivity and viscosity of the formulation. In some embodiments, the silver nanoflakes comprise 11-F material. In some embodiments, the combination of silver flakes and ultragraphene results in an increase in conductivity of the conductive ink. In some embodiments, the combination of silver flakes and ultragraphene results in an increase in viscosity of the conductive ink.

In some embodiments, the solvent comprises Propylene glycol n-propyl ether (Dowanol PnP), 2-ethyl-1-hexanol, Diethylene glycol butyl ether (DEGBE), 2-ethyl-1-butanol, 2-methyl-1-pentanol, Propylene glycol methyl ether acetate (PGMEA), Hexamine, Cycloheptylamine, Isoamyl amine, 3-Methoxypropylamine, and Parachlorobenzotrifluoride (PCBTF), or any combination thereof. In some embodiments, the solvent comprises ethylene glycol, isopropanol, ethyl acetate, chloroform, Dimethylformamide (DMF), N-methyl-2-pyrrolidone (NMP), Tetrahydrofuran (THF), and dichlorobenzene, or any combination thereof. In some embodiments, the solvent comprises Propylene glycol n-propyl ether (PNP) or 2-ethyl-1-hexanol. In some embodiments, the solvent increases the stability of the graphene within the inks herein. In some embodiments, the solvent is volatile. In some embodiments, the solvent has a vapor pressure at 20° C. of about 20 Pa to about 250 Pa. In some embodiments, the solvent has a boiling point of about 110° C. to about 200° C. In some embodiments, the vapor pressure and the boiling point of the solvent enable the inks herein to dry slowly and thus prevent cracking. In some embodiments, the high boiling point of the solvent increases the drying time of the conductive ink, increases the time for coating a substrate with the conductive ink, and may permit even drying of the conductive ink across the surface of the ink applied to the substrate. In some embodiments, the even drying of the ink across the surface of the ink applied to the substrate may prevent the edges from drying prior to the bulk of the conductive ink, and may prevent capillary flow of suspend reduced graphene oxide particles outward from the bulk of the conductive ink to the edges of the conductive ink as applied to the substrate, and may permit for an even coating of the conductive ink on a substrate with a uniform or substantially uniform dispersion of graphene oxide particles throughout the conductive ink applied to the substrate. In some embodiments, the slow, even drying of the ink across the surface of the ink applied to the substrate may allow for a highly uniform coating of the conductive ink applied to a substrate, improving the conductivity of the final product produced with the conductive ink applied to a substrate.

The specific dispersing agents herein enable the unexpectedly improved elasticity, adhesion, thermal stability, and chemical stability, or a combination thereof. In some embodiments, the dispersing agent is a solid at room temperature, e.g., 20° C.-25° C. In some embodiments, the dispersing agent increases the viscosity of the ink. In some embodiments, the dispersing agent stabilizes the reduced graphene oxide sheets in the ink. In some embodiments, the dispersing agent prevents agglomeration of the reduced graphene oxide sheets in the ink. In some embodiments, the dispersing agent prevents cracking of the ink when cured. In some embodiments, the dispersing agent prevents the formation of agglomerated particles of reduced graphene oxide sheets or silver nanoflakes when the ink is cured. In some embodiments, the dispersing agent increases the flexibility of the ink when cured. In some embodiments, the dispersing agent increases the elasticity of polymer chains in the ink. In some embodiments, the dispersing agent comprising the dispersing agent is at room temperature, which helps thicken the ink, the dispersing agent helps stabilize reduced graphene oxide in solution, and the dispersing agent helps slow down the drying at room temperature to prevent cracking and island formation, or a combination thereof. In some embodiments, the dispersing agent serves as a long and soft segment to give flexibility and elasticity to polymer chains. In some embodiments, the dispersing agent comprises polytetrahydrofuran (Poly THF), C7GOL, Cerol 601 wax, and ethyl cellulose. In some embodiments, the dispersing agent comprises Poly THF.

The specific binders herein enable the unexpectedly improved elasticity, adhesion, thermal stability, and chemical stability, or a combination thereof. In some embodiments, the binder is a polymeric binder. In some embodiments, the polymeric binder is a thermoplastic copolymer. In some embodiments, the binder comprises Poly Vinyl Pyrrolidone, a thermoplastic copolymer, Paraloid B72, Paraloid B66, or combinations thereof. In some embodiments, the binder comprises Poly Vinyl Pyrrolidone 10k, Poly Vinyl Pyrrolidone 15k, Poly Vinyl Pyrrolidone 29k, Poly Vinyl Pyrrolidone 360k, or Poly Vinyl Pyrrolidone 120k. In some embodiments, Poly Vinyl Pyrrolidone 120k comprises the average molecular weight of the Poly Vinyl Pyrrolidone polymer. In some embodiments, the binder comprises Poly Vinyl Pyrrolidone. In some embodiments, the binder comprises polyvinylpyrrolidone, ethyl methacrylate, butyl methacrylate, or any combination thereof. In some embodiments, the binder is polyvinylpyrrolidone (PVP) with different molecular weights, including at least one of PVP 10k, PVP 29k, PVP 360k, and PVP 120k, or a combination thereof. In some embodiments, the binder comprises at least one of PVP 10k, PVP 29k, PVP 360k, and PVP 120k, and at least one thermoplastic copolymer. In some embodiments, the binder comprises at least one of PVP 10k, PVP 29k, PVP 360k, and PVP 120k, and at least one of Paraloid B72 and Paraloid B66, or a combination thereof.

The specific softeners provided herein enable the unexpectedly improved elasticity, adhesion, thermal stability, and chemical stability, or a combination thereof. In some embodiments, the conductive ink further comprises a softening agent. In some embodiments, the softening agent increases the flexibility of the cured ink. In some embodiments, the softening agent reduces the brittleness of the cured ink. In some embodiments, the softener maintains the flexibility of the formulation by keeping the binder (e.g., PVP) from becoming brittle once cured. In some embodiments, the softener comprises diethylene glycol.

In some embodiments, the conductive ink has a particle size of about 8 μm to about 20.5 μm. In some embodiments, the conductive ink has a particle size of about 8 μm to about 21 μm. In some embodiments, the conductive ink has a particle size of about 8 μm to about 9 μm, about 8 μm to about 10 μm, about 8 μm to about 11 μm, about 8 μm to about 12 μm, about 8 μm to about 13 μm, about 8 μm to about 14 μm, about 8 μm to about 16 μm, about 8 μm to about 18 μm, about 8 μm to about 19 μm, about 8 μm to about 20 μm, about 8 μm to about 21 μm, about 9 μm to about 10 μm, about 9 μm to about 11 μm, about 9 μm to about 12 μm, about 9 μm to about 13 μm, about 9 μm to about 14 μm, about 9 μm to about 16 μm, about 9 μm to about 18 μm, about 9 μm to about 19 μm, about 9 μm to about 20 μm, about 9 μm to about 21 μm, about 10 μm to about 11 μm, about 10 μm to about 12 μm, about 10 μm to about 13 μm, about 10 μm to about 14 μm, about 10 μm to about 16 μm, about 10 μm to about 18 μm, about 10 μm to about 19 μm, about 10 μm to about 20 μm, about 10 μm to about 21 μm, about 11 μm to about 12 μm, about 11 μm to about 13 μm, about 11 μm to about 14 μm, about 11 μm to about 16 μm, about 11 μm to about 18 μm, about 11 μm to about 19 μm, about 11 μm to about 20 μm, about 11 μm to about 21 μm, about 12 μm to about 13 μm, about 12 μm to about 14 μm, about 12 μm to about 16 μm, about 12 μm to about 18 μm, about 12 μm to about 19 μm, about 12 μm to about 20 μm, about 12 μm to about 21 μm, about 13 μm to about 14 μm, about 13 μm to about 16 μm, about 13 μm to about 18 μm, about 13 μm to about 19 μm, about 13 μm to about 20 μm, about 13 μm to about 21 μm, about 14 μm to about 16 μm, about 14 μm to about 18 μm, about 14 μm to about 19 μm, about 14 μm to about 20 μm, about 14 μm to about 21 μm, about 16 μm to about 18 μm, about 16 μm to about 19 μm, about 16 μm to about 20 μm, about 16 μm to about 21 μm, about 18 μm to about 19 μm, about 18 μm to about 20 μm, about 18 μm to about 21 μm, about 19 μm to about 20 μm, about 19 μm to about 21 μm, or about 20 μm to about 21 μm, including increments therein. In some embodiments, the conductive ink has a particle size of about 8 μm, about 9 μm, about 10 μm, about 11 μm, about 12 μm, about 13 μm, about 14 μm, about 16 μm, about 18 μm, about 19 μm, about 20 μm, or about 21 μm. In some embodiments, the conductive ink has a particle size of at least about 8 μm, about 9 μm, about 10 μm, about 11 μm, about 12 μm, about 13 μm, about 14 μm, about 16 μm, about 18 μm, about 19 μm, or about 20 μm. In some embodiments, the conductive ink has a particle size of at most about 9 μm, about 10 μm, about 11 μm, about 12 μm, about 13 μm, about 14 μm, about 16 μm, about 18 μm, about 19 μm, about 20 μm, or about 21 μm.

The viscosity of the conductive ink can be tuned by adjusting the shear mixing time, wherein longer shearing times reduce viscosity.

In some embodiments, the conductive ink has a viscosity of about 1,000 cP to about 100,000 cP. In some embodiments, the conductive ink has a viscosity of about about 1,000 cP to about 4,000 cP, about 1,000 cP to about 4,500 cP, about 1,000 cP to about 10,000 cP, about 1,000 cP to about 20,000 cP, about 1,000 cP to about 30,000 cP, about 1,000 cP to about 40,000 cP, about 1,000 cP to about 50,000 cP, about 1,000 cP to about 60,000 cP, about 1,000 cP to about 75,000 cP, about 1,000 cP to about 90,000 cP, about 1,000 cP to about 100,000 cP, about 4,000 cP to about 4,500 cP, about 4,000 cP to about 10,000 cP, about 4,000 cP to about 20,000 cP, about 4,000 cP to about 30,000 cP, about 4,000 cP to about 40,000 cP, about 4,000 cP to about 50,000 cP, about 4,000 cP to about 60,000 cP, about 4,000 cP to about 75,000 cP, about 4,000 cP to about 90,000 cP, about 4,000 cP to about 100,000 cP, about 4,500 cP to about 10,000 cP, about 4,500 cP to about 20,000 cP, about 4,500 cP to about 30,000 cP, about 4,500 cP to about 40,000 cP, about 4,500 cP to about 50,000 cP, about 4,500 cP to about 60,000 cP, about 4,500 cP to about 75,000 cP, about 4,500 cP to about 90,000 cP, about 4,500 cP to about 100,000 cP, about 10,000 cP to about 20,000 cP, about 10,000 cP to about 30,000 cP, about 10,000 cP to about 40,000 cP, about 10,000 cP to about 50,000 cP, about 10,000 cP to about 60,000 cP, about 10,000 cP to about 75,000 cP, about 10,000 cP to about 90,000 cP, about 10,000 cP to about 100,000 cP, about 20,000 cP to about 30,000 cP, about 20,000 cP to about 40,000 cP, about 20,000 cP to about 50,000 cP, about 20,000 cP to about 60,000 cP, about 20,000 cP to about 75,000 cP, about 20,000 cP to about 90,000 cP, about 20,000 cP to about 100,000 cP, about 30,000 cP to about 40,000 cP, about 30,000 cP to about 50,000 cP, about 30,000 cP to about 60,000 cP, about 30,000 cP to about 75,000 cP, about 30,000 cP to about 90,000 cP, about 30,000 cP to about 100,000 cP, about 40,000 cP to about 50,000 cP, about 40,000 cP to about 60,000 cP, about 40,000 cP to about 75,000 cP, about 40,000 cP to about 90,000 cP, about 40,000 cP to about 100,000 cP, about 50,000 cP to about 60,000 cP, about 50,000 cP to about 75,000 cP, about 50,000 cP to about 90,000 cP, about 50,000 cP to about 100,000 cP, about 60,000 cP to about 75,000 cP, about 60,000 cP to about 90,000 cP, about 60,000 cP to about 100,000 cP, about 75,000 cP to about 90,000 cP, about 75,000 cP to about 100,000 cP, or about 90,000 cP to about 100,000 cP, including increments therein. In some embodiments, the conductive ink has a viscosity of about 1,000 cP, about 4,000 cP, about 4,500 cP, about 10,000 cP, about 20,000 cP, about 30,000 cP, about 40,000 cP, about 50,000 cP, about 60,000 cP, about 75,000 cP, about 90,000 cP, or about 100,000 cP. In some embodiments, the conductive ink has a viscosity of at least about 1,000 cP, about 4,000 cP, about 4,500 cP, about 10,000 cP, about 20,000 cP, about 30,000 cP, about 40,000 cP, about 50,000 cP, about 60,000 cP, about 75,000 cP, or about 90,000 cP. In some embodiments, the conductive ink has a viscosity of about at most about 4,000 cP, about 4,500 cP, about 10,000 cP, about 20,000 cP, about 30,000 cP, about 40,000 cP, about 50,000 cP, about 60,000 cP, about 75,000 cP, about 90,000 cP, or about 100,000 cP. In some embodiments, the viscosity is measured at a shear rate of 100 s\hat{ }−1 at 25° C. In some embodiments, viscosity is measured with a spindle 52z, wherein the conductive ink is mixed for at least 0, 1, 2, 3, or 4 hours, and is mixed in accordance with method AE6-80 mm, TMI1.

In some embodiments, the conductive ink, when wet, has a w/w concentration of the graphene of about 0.1% to about 10%. In some embodiments, the conductive ink, when wet, has a w/w concentration of the graphene of about 0.1% to about 0.5%, about 0.1% to about 1%, about 0.1% to about 2%, about 0.1% to about 3%, about 0.1% to about 4%, about 0.1% to about 5%, about 0.1% to about 6%, about 0.1% to about 7%, about 0.1% to about 8%, about 0.1% to about 9%, about 0.1% to about 10%, about 0.5% to about 1%, about 0.5% to about 2%, about 0.5% to about 3%, about 0.5% to about 4%, about 0.5% to about 5%, about 0.5% to about 6%, about 0.5% to about 7%, about 0.5% to about 8%, about 0.5% to about 9%, about 0.5% to about 10%, about 1% to about 2%, about 1% to about 3%, about 1% to about 4%, about 1% to about 5%, about 1% to about 6%, about 1% to about 7%, about 1% to about 8%, about 1% to about 9%, about 1% to about 10%, about 2% to about 3%, about 2% to about 4%, about 2% to about 5%, about 2% to about 6%, about 2% to about 7%, about 2% to about 8%, about 2% to about 9%, about 2% to about 10%, about 3% to about 4%, about 3% to about 5%, about 3% to about 6%, about 3% to about 7%, about 3% to about 8%, about 3% to about 9%, about 3% to about 10%, about 4% to about 5%, about 4% to about 6%, about 4% to about 7%, about 4% to about 8%, about 4% to about 9%, about 4% to about 10%, about 5% to about 6%, about 5% to about 7%, about 5% to about 8%, about 5% to about 9%, about 5% to about 10%, about 6% to about 7%, about 6% to about 8%, about 6% to about 9%, about 6% to about 10%, about 7% to about 8%, about 7% to about 9%, about 7% to about 10%, about 8% to about 9%, about 8% to about 10%, or about 9% to about 10%, including increments therein. In some embodiments, the conductive ink, when wet, has a w/w concentration of the graphene of about 0.1%, about 0.5%, about 1%, about 2%, about 3%, about 4%, about 5%, about 6%, about 7%, about 8%, about 9%, or about 10%. In some embodiments, the conductive ink, when wet, has a w/w concentration of the graphene of at least about 0.1%, about 0.5%, about 1%, about 2%, about 3%, about 4%, about 5%, about 6%, about 7%, about 8%, or about 9%. In some embodiments, the conductive ink, when wet, has a w/w concentration of the graphene of at most about 0.5%, about 1%, about 2%, about 3%, about 4%, about 5%, about 6%, about 7%, about 8%, about 9%, or about 10%. In some embodiments, the low concentration of the graphene oxide herein, in addition to the additional elements of the conductive ink, reduces the cost of the conductive inks herein while maintaining a high conductivity and low resistance.

In some embodiments, the conductive ink, when wet, has a w/w concentration of the binder of about 5% to about 60%. In some embodiments, the conductive ink, when wet, has a w/w concentration of the binder of about 5% to about 10%, about 5% to about 15%, about 5% to about 20%, about 5% to about 25%, about 5% to about 30%, about 5% to about 35%, about 5% to about 40%, about 5% to about 45%, about 5% to about 50%, about 5% to about 55%, about 5% to about 60%, about 10% to about 15%, about 10% to about 20%, about 10% to about 25%, about 10% to about 30%, about 10% to about 35%, about 10% to about 40%, about 10% to about 45%, about 10% to about 50%, about 10% to about 55%, about 10% to about 60%, about 15% to about 20%, about 15% to about 25%, about 15% to about 30%, about 15% to about 35%, about 15% to about 40%, about 15% to about 45%, about 15% to about 50%, about 15% to about 55%, about 15% to about 60%, about 20% to about 25%, about 20% to about 30%, about 20% to about 35%, about 20% to about 40%, about 20% to about 45%, about 20% to about 50%, about 20% to about 55%, about 20% to about 60%, about 25% to about 30%, about 25% to about 35%, about 25% to about 40%, about 25% to about 45%, about 25% to about 50%, about 25% to about 55%, about 25% to about 60%, about 30% to about 35%, about 30% to about 40%, about 30% to about 45%, about 30% to about 50%, about 30% to about 55%, about 30% to about 60%, about 35% to about 40%, about 35% to about 45%, about 35% to about 50%, about 35% to about 55%, about 35% to about 60%, about 40% to about 45%, about 40% to about 50%, about 40% to about 55%, about 40% to about 60%, about 45% to about 50%, about 45% to about 55%, about 45% to about 60%, about 50% to about 55%, about 50% to about 60%, or about 55% to about 60%, including increments therein. In some embodiments, the conductive ink, when wet, has a w/w concentration of the binder of about 5%, about 10%, about 15%, about 20%, about 25%, about 30%, about 35%, about 40%, about 45%, about 50%, about 55%, or about 60%. In some embodiments, the conductive ink, when wet, has a w/w concentration of the binder of at least about 5%, about 10%, about 15%, about 20%, about 25%, about 30%, about 35%, about 40%, about 45%, about 50%, or about 55%. In some embodiments, the conductive ink, when wet, has a w/w concentration of the binder of at most about 10%, about 15%, about 20%, about 25%, about 30%, about 35%, about 40%, about 45%, about 50%, about 55%, or about 60%.

In some embodiments, the conductive ink, when wet, has a w/w concentration of the dispersing agent of about 1% to about 20%. In some embodiments, the conductive ink, when wet, has a w/w concentration of the dispersing agent of about 1% to about 3%, about 1% to about 5%, about 1% to about 7%, about 1% to about 9%, about 1% to about 11%, about 1% to about 13%, about 1% to about 15%, about 1% to about 17%, about 1% to about 18%, about 1% to about 19%, about 1% to about 20%, about 3% to about 5%, about 3% to about 7%, about 3% to about 9%, about 3% to about 11%, about 3% to about 13%, about 3% to about 15%, about 3% to about 17%, about 3% to about 18%, about 3% to about 19%, about 3% to about 20%, about 5% to about 7%, about 5% to about 9%, about 5% to about 11%, about 5% to about 13%, about 5% to about 15%, about 5% to about 17%, about 5% to about 18%, about 5% to about 19%, about 5% to about 20%, about 7% to about 9%, about 7% to about 11%, about 7% to about 13%, about 7% to about 15%, about 7% to about 17%, about 7% to about 18%, about 7% to about 19%, about 7% to about 20%, about 9% to about 11%, about 9% to about 13%, about 9% to about 15%, about 9% to about 17%, about 9% to about 18%, about 9% to about 19%, about 9% to about 20%, about 11% to about 13%, about 11% to about 15%, about 11% to about 17%, about 11% to about 18%, about 11% to about 19%, about 11% to about 20%, about 13% to about 15%, about 13% to about 17%, about 13% to about 18%, about 13% to about 19%, about 13% to about 20%, about 15% to about 17%, about 15% to about 18%, about 15% to about 19%, about 15% to about 20%, about 17% to about 18%, about 17% to about 19%, about 17% to about 20%, about 18% to about 19%, about 18% to about 20%, or about 19% to about 20%, including increments therein. In some embodiments, the conductive ink, when wet, has a w/w concentration of the dispersing agent of about 1%, about 3%, about 5%, about 7%, about 9%, about 11%, about 13%, about 15%, about 17%, about 18%, about 19%, or about 20%. In some embodiments, the conductive ink, when wet, has a w/w concentration of the dispersing agent of at least about 1%, about 3%, about 5%, about 7%, about 9%, about 11%, about 13%, about 15%, about 17%, about 18%, or about 19%. In some embodiments, the conductive ink, when wet, has a w/w concentration of the dispersing agent of at most about 3%, about 5%, about 7%, about 9%, about 11%, about 13%, about 15%, about 17%, about 18%, about 19%, or about 20%.

In some embodiments, the conductive ink, when wet, has a w/w concentration of the solvent of about 20% to about 90%. In some embodiments, the conductive ink, when wet, has a w/w concentration of the solvent of about 20% to about 30%, about 20% to about 40%, about 20% to about 50%, about 20% to about 60%, about 20% to about 70%, about 20% to about 80%, about 20% to about 90%, about 30% to about 40%, about 30% to about 50%, about 30% to about 60%, about 30% to about 70%, about 30% to about 80%, about 30% to about 90%, about 40% to about 50%, about 40% to about 60%, about 40% to about 70%, about 40% to about 80%, about 40% to about 90%, about 50% to about 60%, about 50% to about 70%, about 50% to about 80%, about 50% to about 90%, about 60% to about 70%, about 60% to about 80%, about 60% to about 90%, about 70% to about 80%, about 70% to about 90%, or about 80% to about 90%, including increments therein. In some embodiments, the conductive ink, when wet, has a w/w concentration of the solvent of about 20%, about 30%, about 40%, about 50%, about 60%, about 70%, about 80%, or about 90%. In some embodiments, the conductive ink, when wet, has a w/w concentration of the solvent of at least about 20%, about 30%, about 40%, about 50%, about 60%, about 70%, or about 80%. In some embodiments, the conductive ink, when wet, has a w/w concentration of the solvent of at most about 30%, about 40%, about 50%, about 60%, about 70%, about 80%, or about 90%.

In some embodiments, the conductive ink further comprises a softening agent. In some embodiments, the softening agent increases the flexibility of the cured ink. In some embodiments, the softening agent reduces the brittleness of the cured ink. In some embodiments, the softening agent comprises diethylene glycol. In some embodiments, the conductive ink, when wet, has a w/w concentration of the softening agent of about 5% to about 80%. In some embodiments, the conductive ink, when wet, has a w/w concentration of the softening agent of about 5% to about 15%, about 5% to about 25%, about 5% to about 35%, about 5% to about 45%, about 5% to about 55%, about 5% to about 65%, about 5% to about 75%, about 5% to about 80%, about 15% to about 25%, about 15% to about 35%, about 15% to about 45%, about 15% to about 55%, about 15% to about 65%, about 15% to about 75%, about 15% to about 80%, about 25% to about 35%, about 25% to about 45%, about 25% to about 55%, about 25% to about 65%, about 25% to about 75%, about 25% to about 80%, about 35% to about 45%, about 35% to about 55%, about 35% to about 65%, about 35% to about 75%, about 35% to about 80%, about 45% to about 55%, about 45% to about 65%, about 45% to about 75%, about 45% to about 80%, about 55% to about 65%, about 55% to about 75%, about 55% to about 80%, about 65% to about 75%, about 65% to about 80%, or about 75% to about 80%, including increments therein. In some embodiments, the conductive ink, when wet, has a w/w concentration of the softening agent of about 5%, about 15%, about 25%, about 35%, about 45%, about 55%, about 65%, about 75%, or about 80%. In some embodiments, the conductive ink, when wet, has a w/w concentration of the softening agent of at least about 5%, about 15%, about 25%, about 35%, about 45%, about 55%, about 65%, or about 75%. In some embodiments, the conductive ink, when wet, has a w/w concentration of the softening agent of at most about 15%, about 25%, about 35%, about 45%, about 55%, about 65%, about 75%, or about 80%.

In some embodiments, the method further comprises applying the conductive ink as a continuous film or as a trace line on a substrate. In some embodiments, the substrate comprises silicon, PET, PI, Kapton, glass, or combinations thereof.

In some embodiments, the mixing the dispersion at a high shear rate comprises mixing the mixture at a rate of at least 200 Hz.

In some embodiments, the mixing the dispersion at a high shear rate comprises mixing the mixture at a rate of at least about 200 Hz to about 600 Hz. In some embodiments, the mixing the dispersion at a high shear rate comprises mixing the mixture at a rate of at least about 200 Hz to about 300 Hz, about 200 Hz to about 400 Hz, about 200 Hz to about 500 Hz, about 200 Hz to about 600 Hz, about 300 Hz to about 400 Hz, about 300 Hz to about 500 Hz, about 300 Hz to about 600 Hz, about 400 Hz to about 500 Hz, about 400 Hz to about 600 Hz, or about 500 Hz to about 600 Hz, including increments therein. In some embodiments, the mixing the dispersion at a high shear rate comprises mixing the mixture at a rate of at least about 200 Hz, about 300 Hz, about 400 Hz, about 500 Hz, or about 600 Hz. In some embodiments, the mixing the dispersion at a high shear rate comprises mixing the mixture at a rate of at least at least about 200 Hz, about 300 Hz, about 400 Hz, or about 500 Hz. In some embodiments, the mixing the dispersion at a high shear rate comprises mixing the mixture at a rate of at least at most about 300 Hz, about 400 Hz, about 500 Hz, or about 600 Hz.

In some embodiments, the mixing the dispersion at a high shear rate comprises mixing the mixture at a rate of at least 200 Hz for at least 30 minutes. In some embodiments, the mixing the dispersion at a high shear rate comprises mixing the mixture at a rate of at least 200 Hz for at 1, 2, 3, 4, 5, 6, 7, 8, 9, 10, 11, 12, 13, 14, 15, 16, 17, 18, 19, 20, 21, 22, 23, 24, 25, 26, 27, 28, 29 or 30 minutes.

In some embodiments, the method further comprises curing the conductive ink at a temperature of 110° C. for up to 30 minutes. In some embodiments, the method further comprises curing the conductive ink at a temperature of 110° C. for 1, 2, 3, 4, 5, 6, 7, 8, 9, 10, 11, 12, 13, 14, 15, 16, 17, 18, 19, 20, 21, 22, 23, 24, 25, 26, 27, 28, 29 or 30 minutes.

In some embodiments, the method further comprises curing the conductive ink at a temperature of 300° C. for up to 30 minutes. In some embodiments, the method further comprises curing the conductive ink at a temperature of 300° C. for 1, 2, 3, 4, 5, 6, 7, 8, 9, 10, 11, 12, 13, 14, 15, 16, 17, 18, 19, 20, 21, 22, 23, 24, 25, 26, 27, 28, 29 or 30 minutes.

In some embodiments, curing the conductive ink at a temperature exceeding 100° C. increases the conductivity of the cured ink. In some embodiments, the conductivity of the cured ink is increased by curing the conductive ink at a temperature exceeding about 100° C. to about 300° C. In some embodiments, the conductivity of the cured ink is increased by curing the conductive ink at a temperature exceeding about 100° C. to about 120° C., about 100° C. to about 140° C., about 100° C. to about 160° C., about 100° C. to about 180° C., about 100° C. to about 200° C., about 100° C. to about 220° C., about 100° C. to about 240° C., about 100° C. to about 260° C., about 100° C. to about 280° C., about 100° C. to about 290° C., about 100° C. to about 300° C., about 120° C. to about 140° C., about 120° C. to about 160° C., about 120° C. to about 180° C., about 120° C. to about 200° C., about 120° C. to about 220° C., about 120° C. to about 240° C., about 120° C. to about 260° C., about 120° C. to about 280° C., about 120° C. to about 290° C., about 120° C. to about 300° C., about 140° C. to about 160° C., about 140° C. to about 180° C., about 140° C. to about 200° C., about 140° C. to about 220° C., about 140° C. to about 240° C., about 140° C. to about 260° C., about 140° C. to about 280° C., about 140° C. to about 290° C., about 140° C. to about 300° C., about 160° C. to about 180° C., about 160° C. to about 200° C., about 160° C. to about 220° C., about 160° C. to about 240° C., about 160° C. to about 260° C., about 160° C. to about 280° C., about 160° C. to about 290° C., about 160° C. to about 300° C., about 180° C. to about 200° C., about 180° C. to about 220° C., about 180° C. to about 240° C., about 180° C. to about 260° C., about 180° C. to about 280° C., about 180° C. to about 290° C., about 180° C. to about 300° C., about 200° C. to about 220° C., about 200° C. to about 240° C., about 200° C. to about 260° C., about 200° C. to about 280° C., about 200° C. to about 290° C., about 200° C. to about 300° C., about 220° C. to about 240° C., about 220° C. to about 260° C., about 220° C. to about 280° C., about 220° C. to about 290° C., about 220° C. to about 300° C., about 240° C. to about 260° C., about 240° C. to about 280° C., about 240° C. to about 290° C., about 240° C. to about 300° C., about 260° C. to about 280° C., about 260° C. to about 290° C., about 260° C. to about 300° C., about 280° C. to about 290° C., about 280° C. to about 300° C., or about 290° C. to about 300° C., including increments therein. In some embodiments, the conductivity of the cured ink is increased by curing the conductive ink at a temperature exceeding about 100° C., about 120° C., about 140° C., about 160° C., about 180° C., about 200° C., about 220° C., about 240° C., about 260° C., about 280° C., about 290° C., or about 300° C. In some embodiments, the conductivity of the cured ink is increased by curing the conductive ink at a temperature exceeding at least about 100° C., about 120° C., about 140° C., about 160° C., about 180° C., about 200° C., about 220° C., about 240° C., about 260° C., about 280° C., or about 290° C. In some embodiments, the conductivity of the cured ink is increased by curing the conductive ink at a temperature exceeding at most about 120° C., about 140° C., about 160° C., about 180° C., about 200° C., about 220° C., about 240° C., about 260° C., about 280° C., about 290° C., or about 300° C.

In some embodiments, curing the conductive ink at a temperature of 300° C. increases the conductivity of the cured ink.

In some embodiments, curing the conductive ink at a temperature of 300° C. increases the conductivity of the cured ink by about 10% to about 120%. In some embodiments, curing the conductive ink at a temperature of 300° C. increases the conductivity of the cured ink by about 10% to about 20%, about 10% to about 30%, about 10% to about 40%, about 10% to about 50%, about 10% to about 60%, about 10% to about 70%, about 10% to about 80%, about 10% to about 90%, about 10% to about 100%, about 10% to about 110%, about 10% to about 120%, about 20% to about 30%, about 20% to about 40%, about 20% to about 50%, about 20% to about 60%, about 20% to about 70%, about 20% to about 80%, about 20% to about 90%, about 20% to about 100%, about 20% to about 110%, about 20% to about 120%, about 30% to about 40%, about 30% to about 50%, about 30% to about 60%, about 30% to about 70%, about 30% to about 80%, about 30% to about 90%, about 30% to about 100%, about 30% to about 110%, about 30% to about 120%, about 40% to about 50%, about 40% to about 60%, about 40% to about 70%, about 40% to about 80%, about 40% to about 90%, about 40% to about 100%, about 40% to about 110%, about 40% to about 120%, about 50% to about 60%, about 50% to about 70%, about 50% to about 80%, about 50% to about 90%, about 50% to about 100%, about 50% to about 110%, about 50% to about 120%, about 60% to about 70%, about 60% to about 80%, about 60% to about 90%, about 60% to about 100%, about 60% to about 110%, about 60% to about 120%, about 70% to about 80%, about 70% to about 90%, about 70% to about 100%, about 70% to about 110%, about 70% to about 120%, about 80% to about 90%, about 80% to about 100%, about 80% to about 110%, about 80% to about 120%, about 90% to about 100%, about 90% to about 110%, about 90% to about 120%, about 100% to about 110%, about 100% to about 120%, or about 110% to about 120%, including increments therein. In some embodiments, curing the conductive ink at a temperature of 300° C. increases the conductivity of the cured ink by about 10%, about 20%, about 30%, about 40%, about 50%, about 60%, about 70%, about 80%, about 90%, about 100%, about 110%, or about 120%. In some embodiments, curing the conductive ink at a temperature of 300° C. increases the conductivity of the cured ink by at least about 10%, about 20%, about 30%, about 40%, about 50%, about 60%, about 70%, about 80%, about 90%, about 100%, or about 110%. In some embodiments, curing the conductive ink at a temperature of 300° C. increases the conductivity of the cured ink by at most about 20%, about 30%, about 40%, about 50%, about 60%, about 70%, about 80%, about 90%, about 100%, about 110%, or about 120%.

### Method—Characterization of Conductive Inks

The embodiments disclosed herein comprise an ink formulation that works for roll-to-roll coating and knife over edge printing.

The conductive inks herein exhibit level 5B adhesion (ideal adhesion), enabling its use on a wide array of substrates, such as, for example, Polyimide (PI or Kaptan), glass, aluminum, and polyethylene terephthalate (PET). Further, while the components in many current conductive inks separate and form non-dispersible clumps, the conductive inks herein exhibit a shelf life of over 1 year, wherein the components of the ink remain in solution. Further, unlike many current conductive inks, the conductive inks herein inks can be produced and supplied in large volumes. Additionally, the conductive inks herein improve the efficiency and speed of forming printed conductive materials, as they can be cured at any temperature, and at curing times as low as 30 minutes or less at temperatures below 300° C. In some embodiments, the conductive inks can be cured within 30 minutes at a temperature of 100 C. Finally, the conductive inks herein are water soluble, and produce consistent, continuous coatings when dried.

In some embodiments, the conductive ink has a solid content of about 70% wt to about 80% wt. In some embodiments, the conductive ink has a solid content of about 70% wt to about 71% wt, about 70% wt to about 72% wt, about 70% wt to about 73% wt, about 70% wt to about 74% wt, about 70% wt to about 75% wt, about 70% wt to about 76% wt, about 70% wt to about 77% wt, about 70% wt to about 78% wt, about 70% wt to about 79% wt, about 70% wt to about 80% wt, about 71% wt to about 72% wt, about 71% wt to about 73% wt, about 71% wt to about 74% wt, about 71% wt to about 75% wt, about 71% wt to about 76% wt, about 71% wt to about 77% wt, about 71% wt to about 78% wt, about 71% wt to about 79% wt, about 71% wt to about 80% wt, about 72% wt to about 73% wt, about 72% wt to about 74% wt, about 72% wt to about 75% wt, about 72% wt to about 76% wt, about 72% wt to about 77% wt, about 72% wt to about 78% wt, about 72% wt to about 79% wt, about 72% wt to about 80% wt, about 73% wt to about 74% wt, about 73% wt to about 75% wt, about 73% wt to about 76% wt, about 73% wt to about 77% wt, about 73% wt to about 78% wt, about 73% wt to about 79% wt, about 73% wt to about 80% wt, about 74% wt to about 75% wt, about 74% wt to about 76% wt, about 74% wt to about 77% wt, about 74% wt to about 78% wt, about 74% wt to about 79% wt, about 74% wt to about 80% wt, about 75% wt to about 76% wt, about 75% wt to about 77% wt, about 75% wt to about 78% wt, about 75% wt to about 79% wt, about 75% wt to about 80% wt, about 76% wt to about 77% wt, about 76% wt to about 78% wt, about 76% wt to about 79% wt, about 76% wt to about 80% wt, about 77% wt to about 78% wt, about 77% wt to about 79% wt, about 77% wt to about 80% wt, about 78% wt to about 79% wt, about 78% wt to about 80% wt, or about 79% wt to about 80% wt, including increments therein. In some embodiments, the conductive ink has a solid content of about 70% wt, about 71% wt, about 72% wt, about 73% wt, about 74% wt, about 75% wt, about 76% wt, about 77% wt, about 78% wt, about 79% wt, or about 80% wt. In some embodiments, the conductive ink has a solid content of at least about 70% wt, about 71% wt, about 72% wt, about 73% wt, about 74% wt, about 75% wt, about 76% wt, about 77% wt, about 78% wt, or about 79% wt. In some embodiments, the conductive ink has a solid content of about at most about 71% wt, about 72% wt, about 73% wt, about 74% wt, about 75% wt, about 76% wt, about 77% wt, about 78% wt, about 79% wt, or about 80% wt. In some embodiments, the conductive ink has a solid content of about 75% wt. In some embodiments, the conductive ink has a solid content of at least 70% wt. In some embodiments, the conductive ink has a solid content of up to 80% wt.

In some embodiments, the ink is a shear-thinning fluid. In some embodiments, the ink is suitable for screen printing, extruder printing, flexography application, slot-die application, and knife-over-edge coating application. In some embodiments, the ink is suitable for screen printing. In some embodiments, the ink does not leave pin holes when applied. In some embodiments, the ink does not separate when cured. In some embodiments, the ink does not shrink when cured. In some embodiments, the ink does not reduce its surface area when cured. In some embodiments, the ink has a wet film thickness that is less than a wet film thickness. In some embodiments, a change in dry film thickness correlates to a change in wet film thickness with a differential of about 0.5. In some embodiments, the ink is adhesive. In some embodiments, the ink comprises a 5B adhesion on PET, PI, Kapton, or glass. In some embodiments, the ink is stable at room temperature, e.g., 20° C.-25° C.

In some embodiments, the ink cures at 300° C. In some embodiments, the ink cures at 300° C. within about 30 minutes. In some embodiments, the ink cures at 300° C. within about 1, 2, 3, 4, 5, 6, 7, 8, 9, 10, 11, 12, 13, 14, 15, 16, 17, 18, 19, 20, 21, 22, 23, 24, 25, 26, 27, 28, 29, or 30 minutes.

In some embodiments, the conductive ink comprises a sheet resistance of at least about 0.017 ohms/sq.

In some embodiments, the conductive ink comprises a sheet resistance of up to about 0.006 ohms/sq to about 0.084 ohms/sq. In some embodiments, the conductive ink comprises a sheet resistance of up to about 0.006 ohms/sq to about 0.012 ohms/sq, about 0.006 ohms/sq to about 0.018 ohms/sq, about 0.006 ohms/sq to about 0.024 ohms/sq, about 0.006 ohms/sq to about 0.03 ohms/sq, about 0.006 ohms/sq to about 0.036 ohms/sq, about 0.006 ohms/sq to about 0.042 ohms/sq, about 0.006 ohms/sq to about 0.048 ohms/sq, about 0.006 ohms/sq to about 0.054 ohms/sq, about 0.006 ohms/sq to about 0.06 ohms/sq, about 0.006 ohms/sq to about 0.072 ohms/sq, about 0.006 ohms/sq to about 0.084 ohms/sq, about 0.012 ohms/sq to about 0.018 ohms/sq, about 0.012 ohms/sq to about 0.024 ohms/sq, about 0.012 ohms/sq to about 0.03 ohms/sq, about 0.012 ohms/sq to about 0.036 ohms/sq, about 0.012 ohms/sq to about 0.042 ohms/sq, about 0.012 ohms/sq to about 0.048 ohms/sq, about 0.012 ohms/sq to about 0.054 ohms/sq, about 0.012 ohms/sq to about 0.06 ohms/sq, about 0.012 ohms/sq to about 0.072 ohms/sq, about 0.012 ohms/sq to about 0.084 ohms/sq, about 0.018 ohms/sq to about 0.024 ohms/sq, about 0.018 ohms/sq to about 0.03 ohms/sq, about 0.018 ohms/sq to about 0.036 ohms/sq, about 0.018 ohms/sq to about 0.042 ohms/sq, about 0.018 ohms/sq to about 0.048 ohms/sq, about 0.018 ohms/sq to about 0.054 ohms/sq, about 0.018 ohms/sq to about 0.06 ohms/sq, about 0.018 ohms/sq to about 0.072 ohms/sq, about 0.018 ohms/sq to about 0.084 ohms/sq, about 0.024 ohms/sq to about 0.03 ohms/sq, about 0.024 ohms/sq to about 0.036 ohms/sq, about 0.024 ohms/sq to about 0.042 ohms/sq, about 0.024 ohms/sq to about 0.048 ohms/sq, about 0.024 ohms/sq to about 0.054 ohms/sq, about 0.024 ohms/sq to about 0.06 ohms/sq, about 0.024 ohms/sq to about 0.072 ohms/sq, about 0.024 ohms/sq to about 0.084 ohms/sq, about 0.03 ohms/sq to about 0.036 ohms/sq, about 0.03 ohms/sq to about 0.042 ohms/sq, about 0.03 ohms/sq to about 0.048 ohms/sq, about 0.03 ohms/sq to about 0.054 ohms/sq, about 0.03 ohms/sq to about 0.06 ohms/sq, about 0.03 ohms/sq to about 0.072 ohms/sq, about 0.03 ohms/sq to about 0.084 ohms/sq, about 0.036 ohms/sq to about 0.042 ohms/sq, about 0.036 ohms/sq to about 0.048 ohms/sq, about 0.036 ohms/sq to about 0.054 ohms/sq, about 0.036 ohms/sq to about 0.06 ohms/sq, about 0.036 ohms/sq to about 0.072 ohms/sq, about 0.036 ohms/sq to about 0.084 ohms/sq, about 0.042 ohms/sq to about 0.048 ohms/sq, about 0.042 ohms/sq to about 0.054 ohms/sq, about 0.042 ohms/sq to about 0.06 ohms/sq, about 0.042 ohms/sq to about 0.072 ohms/sq, about 0.042 ohms/sq to about 0.084 ohms/sq, about 0.048 ohms/sq to about 0.054 ohms/sq, about 0.048 ohms/sq to about 0.06 ohms/sq, about 0.048 ohms/sq to about 0.072 ohms/sq, about 0.048 ohms/sq to about 0.084 ohms/sq, about 0.054 ohms/sq to about 0.06 ohms/sq, about 0.054 ohms/sq to about 0.072 ohms/sq, about 0.054 ohms/sq to about 0.084 ohms/sq, about 0.06 ohms/sq to about 0.072 ohms/sq, about 0.06 ohms/sq to about 0.084 ohms/sq, or about 0.072 ohms/sq to about 0.084 ohms/sq, including increments therein. In some embodiments, the conductive ink comprises a sheet resistance of up to about 0.006 ohms/sq, about 0.012 ohms/sq, about 0.018 ohms/sq, about 0.024 ohms/sq, about 0.03 ohms/sq, about 0.036 ohms/sq, about 0.042 ohms/sq, about 0.048 ohms/sq, about 0.054 ohms/sq, about 0.06 ohms/sq, about 0.072 ohms/sq, or about 0.084 ohms/sq. In some embodiments, the conductive ink comprises a sheet resistance of up to about at least about 0.006 ohms/sq, about 0.012 ohms/sq, about 0.018 ohms/sq, about 0.024 ohms/sq, about 0.03 ohms/sq, about 0.036 ohms/sq, about 0.042 ohms/sq, about 0.048 ohms/sq, about 0.054 ohms/sq, about 0.06 ohms/sq, or about 0.072 ohms/sq. In some embodiments, the conductive ink comprises a sheet resistance of up to about at most about 0.012 ohms/sq, about 0.018 ohms/sq, about 0.024 ohms/sq, about 0.03 ohms/sq, about 0.036 ohms/sq, about 0.042 ohms/sq, about 0.048 ohms/sq, about 0.054 ohms/sq, about 0.06 ohms/sq, about 0.072 ohms/sq, or about 0.084 ohms/sq.

In some embodiments, the conductive ink comprises a sheet resistance of up to about 0.01 ohms/sq at a dry film thickness of about 20 μm to about 0.08 ohms/sq at a dry film thickness of about 20 μm. In some embodiments, the conductive ink comprises a sheet resistance of up to about 0.01 ohms/sq at a dry film thickness of about 20 μm to about 0.02 ohms/sq at a dry film thickness of about 20 μm, about 0.01 ohms/sq at a dry film thickness of about 20 μm to about 0.03 ohms/sq at a dry film thickness of about 20 μm, about 0.01 ohms/sq at a dry film thickness of about 20 μm to about 0.04 ohms/sq at a dry film thickness of about 20 μm, about 0.01 ohms/sq at a dry film thickness of about 20 μm to about 0.05 ohms/sq at a dry film thickness of about 20 μm, about 0.01 ohms/sq at a dry film thickness of about 20 μm to about 0.06 ohms/sq at a dry film thickness of about 20 μm, about 0.01 ohms/sq at a dry film thickness of about 20 μm to about 0.07 ohms/sq at a dry film thickness of about 20 μm, about 0.01 ohms/sq at a dry film thickness of about 20 μm to about 0.08 ohms/sq at a dry film thickness of about 20 μm, about 0.02 ohms/sq at a dry film thickness of about 20 μm to about 0.03 ohms/sq at a dry film thickness of about 20 μm, about 0.02 ohms/sq at a dry film thickness of about 20 μm to about 0.04 ohms/sq at a dry film thickness of about 20 μm, about 0.02 ohms/sq at a dry film thickness of about 20 μm to about 0.05 ohms/sq at a dry film thickness of about 20 μm, about 0.02 ohms/sq at a dry film thickness of about 20 μm to about 0.06 ohms/sq at a dry film thickness of about 20 μm, about 0.02 ohms/sq at a dry film thickness of about 20 μm to about 0.07 ohms/sq at a dry film thickness of about 20 μm, about 0.02 ohms/sq at a dry film thickness of about 20 μm to about 0.08 ohms/sq at a dry film thickness of about 20 μm, about 0.03 ohms/sq at a dry film thickness of about 20 μm to about 0.04 ohms/sq at a dry film thickness of about 20 μm, about 0.03 ohms/sq at a dry film thickness of about 20 μm to about 0.05 ohms/sq at a dry film thickness of about 20 μm, about 0.03 ohms/sq at a dry film thickness of about 20 μm to about 0.06 ohms/sq at a dry film thickness of about 20 μm, about 0.03 ohms/sq at a dry film thickness of about 20 μm to about 0.07 ohms/sq at a dry film thickness of about 20 μm, about 0.03 ohms/sq at a dry film thickness of about 20 μm to about 0.08 ohms/sq at a dry film thickness of about 20 μm, about 0.04 ohms/sq at a dry film thickness of about 20 μm to about 0.05 ohms/sq at a dry film thickness of about 20 μm, about 0.04 ohms/sq at a dry film thickness of about 20 μm to about 0.06 ohms/sq at a dry film thickness of about 20 μm, about 0.04 ohms/sq at a dry film thickness of about 20 μm to about 0.07 ohms/sq at a dry film thickness of about 20 μm, about 0.04 ohms/sq at a dry film thickness of about 20 μm to about 0.08 ohms/sq at a dry film thickness of about 20 μm, about 0.05 ohms/sq at a dry film thickness of about 20 μm to about 0.06 ohms/sq at a dry film thickness of about 20 μm, about 0.05 ohms/sq at a dry film thickness of about 20 μm to about 0.07 ohms/sq at a dry film thickness of about 20 μm, about 0.05 ohms/sq at a dry film thickness of about 20 μm to about 0.08 ohms/sq at a dry film thickness of about 20 μm, about 0.06 ohms/sq at a dry film thickness of about 20 μm to about 0.07 ohms/sq at a dry film thickness of about 20 μm, about 0.06 ohms/sq at a dry film thickness of about 20 μm to about 0.08 ohms/sq at a dry film thickness of about 20 μm, or about 0.07 ohms/sq at a dry film thickness of about 20 μm to about 0.08 ohms/sq at a dry film thickness of about 20 μm, including increments therein. In some embodiments, the conductive ink comprises a sheet resistance of up to about 0.01 ohms/sq at a dry film thickness of about 20 μm, about 0.02 ohms/sq at a dry film thickness of about 20 μm, about 0.03 ohms/sq at a dry film thickness of about 20 μm, about 0.04 ohms/sq at a dry film thickness of about 20 μm, about 0.05 ohms/sq at a dry film thickness of about 20 μm, about 0.06 ohms/sq at a dry film thickness of about 20 μm, about 0.07 ohms/sq at a dry film thickness of about 20 μm, or about 0.08 ohms/sq at a dry film thickness of about 20 μm. In some embodiments, the conductive ink comprises a sheet resistance of up to at least about 0.01 ohms/sq at a dry film thickness of about 20 μm, about 0.02 ohms/sq at a dry film thickness of about 20 μm, about 0.03 ohms/sq at a dry film thickness of about 20 μm, about 0.04 ohms/sq at a dry film thickness of about 20 μm, about 0.05 ohms/sq at a dry film thickness of about 20 μm, about 0.06 ohms/sq at a dry film thickness of about 20 μm, or about 0.07 ohms/sq at a dry film thickness of about 20 μm. In some embodiments, the conductive ink comprises a sheet resistance of up to at most about 0.02 ohms/sq at a dry film thickness of about 20 μm, about 0.03 ohms/sq at a dry film thickness of about 20 μm, about 0.04 ohms/sq at a dry film thickness of about 20 μm, about 0.05 ohms/sq at a dry film thickness of about 20 μm, about 0.06 ohms/sq at a dry film thickness of about 20 μm, about 0.07 ohms/sq at a dry film thickness of about 20 μm, or about 0.08 ohms/sq at a dry film thickness of about 20 μm. In some embodiments, the conductive ink comprises a sheet resistance of up to about 0.01 ohms/sq at a dry film thickness of about 30 μm to about 0.025 ohms/sq at a dry film thickness of about 30 μm. In some embodiments, the conductive ink comprises a sheet resistance of up to about 0.01 ohms/sq at a dry film thickness of about 30 μm to about 0.015 ohms/sq at a dry film thickness of about 30 μm, about 0.01 ohms/sq at a dry film thickness of about 30 μm to about 0.02 ohms/sq at a dry film thickness of about 30 μm, about 0.01 ohms/sq at a dry film thickness of about 30 μm to about 0.025 ohms/sq at a dry film thickness of about 30 μm, about 0.015 ohms/sq at a dry film thickness of about 30 μm to about 0.02 ohms/sq at a dry film thickness of about 30 μm, about 0.015 ohms/sq at a dry film thickness of about 30 μm to about 0.025 ohms/sq at a dry film thickness of about 30 μm, or about 0.02 ohms/sq at a dry film thickness of about 30 μm to about 0.025 ohms/sq at a dry film thickness of about 30 μm, including increments therein. In some embodiments, the conductive ink comprises a sheet resistance of up to about 0.01 ohms/sq at a dry film thickness of about 30 μm, about 0.015 ohms/sq at a dry film thickness of about 30 μm, about 0.02 ohms/sq at a dry film thickness of about 30 μm, or about 0.025 ohms/sq at a dry film thickness of about 30 μm. In some embodiments, the conductive ink comprises a sheet resistance of up to at least about 0.01 ohms/sq at a dry film thickness of about 30 μm, about 0.015 ohms/sq at a dry film thickness of about 30 μm, or about 0.02 ohms/sq at a dry film thickness of about 30 μm. In some embodiments, the conductive ink comprises a sheet resistance of up to at most about 0.015 ohms/sq at a dry film thickness of about 30 μm, about 0.02 ohms/sq at a dry film thickness of about 30 μm, or about 0.025 ohms/sq at a dry film thickness of about 30 μm.

In some embodiments, the conductive ink comprises a sheet resistance of up to about 0.01 ohms/sq at a dry film thickness of about 36 μm to about 0.028 ohms/sq at a dry film thickness of about 36 μm. In some embodiments, the conductive ink comprises a sheet resistance of up to about 0.01 ohms/sq at a dry film thickness of about 36 μm to about 0.015 ohms/sq at a dry film thickness of about 36 μm, about 0.01 ohms/sq at a dry film thickness of about 36 μm to about 0.02 ohms/sq at a dry film thickness of about 36 μm, about 0.01 ohms/sq at a dry film thickness of about 36 μm to about 0.025 ohms/sq at a dry film thickness of about 36 μm, about 0.01 ohms/sq at a dry film thickness of about 36 μm to about 0.026 ohms/sq at a dry film thickness of about 36 μm, about 0.01 ohms/sq at a dry film thickness of about 36 μm to about 0.027 ohms/sq at a dry film thickness of about 36 μm, about 0.01 ohms/sq at a dry film thickness of about 36 μm to about 0.028 ohms/sq at a dry film thickness of about 36 μm, about 0.015 ohms/sq at a dry film thickness of about 36 μm to about 0.02 ohms/sq at a dry film thickness of about 36 μm, about 0.015 ohms/sq at a dry film thickness of about 36 μm to about 0.025 ohms/sq at a dry film thickness of about 36 μm, about 0.015 ohms/sq at a dry film thickness of about 36 μm to about 0.026 ohms/sq at a dry film thickness of about 36 μm, about 0.015 ohms/sq at a dry film thickness of about 36 μm to about 0.027 ohms/sq at a dry film thickness of about 36 μm, about 0.015 ohms/sq at a dry film thickness of about 36 μm to about 0.028 ohms/sq at a dry film thickness of about 36 μm, about 0.02 ohms/sq at a dry film thickness of about 36 μm to about 0.025 ohms/sq at a dry film thickness of about 36 μm, about 0.02 ohms/sq at a dry film thickness of about 36 μm to about 0.026 ohms/sq at a dry film thickness of about 36 μm, about 0.02 ohms/sq at a dry film thickness of about 36 μm to about 0.027 ohms/sq at a dry film thickness of about 36 μm, about 0.02 ohms/sq at a dry film thickness of about 36 μm to about 0.028 ohms/sq at a dry film thickness of about 36 μm, about 0.025 ohms/sq at a dry film thickness of about 36 μm to about 0.026 ohms/sq at a dry film thickness of about 36 μm, about 0.025 ohms/sq at a dry film thickness of about 36 μm to about 0.027 ohms/sq at a dry film thickness of about 36 μm, about 0.025 ohms/sq at a dry film thickness of about 36 μm to about 0.028 ohms/sq at a dry film thickness of about 36 μm, about 0.026 ohms/sq at a dry film thickness of about 36 μm to about 0.027 ohms/sq at a dry film thickness of about 36 μm, about 0.026 ohms/sq at a dry film thickness of about 36 μm to about 0.028 ohms/sq at a dry film thickness of about 36 μm, or about 0.027 ohms/sq at a dry film thickness of about 36 μm to about 0.028 ohms/sq at a dry film thickness of about 36 μm, including increments therein. In some embodiments, the conductive ink comprises a sheet resistance of up to about 0.01 ohms/sq at a dry film thickness of about 36 μm, about 0.015 ohms/sq at a dry film thickness of about 36 μm, about 0.02 ohms/sq at a dry film thickness of about 36 μm, about 0.025 ohms/sq at a dry film thickness of about 36 μm, about 0.026 ohms/sq at a dry film thickness of about 36 μm, about 0.027 ohms/sq at a dry film thickness of about 36 μm, or about 0.028 ohms/sq at a dry film thickness of about 36 μm. In some embodiments, the conductive ink comprises a sheet resistance of up to at least about 0.01 ohms/sq at a dry film thickness of about 36 μm, about 0.015 ohms/sq at a dry film thickness of about 36 μm, about 0.02 ohms/sq at a dry film thickness of about 36 μm, about 0.025 ohms/sq at a dry film thickness of about 36 μm, about 0.026 ohms/sq at a dry film thickness of about 36 μm, or about 0.027 ohms/sq at a dry film thickness of about 36 μm. In some embodiments, the conductive ink comprises a sheet resistance of up to at most about 0.015 ohms/sq at a dry film thickness of about 36 μm, about 0.02 ohms/sq at a dry film thickness of about 36 μm, about 0.025 ohms/sq at a dry film thickness of about 36 μm, about 0.026 ohms/sq at a dry film thickness of about 36 μm, about 0.027 ohms/sq at a dry film thickness of about 36 μm, or about 0.028 ohms/sq at a dry film thickness of about 36 μm.

In some embodiments, the conductive ink comprises a sheet resistance of up to about 0.01 ohms/sq at a dry film thickness of about 40 μm to about 0.027 ohms/sq at a dry film thickness of about 40 μm. In some embodiments, the conductive ink comprises a sheet resistance of up to about 0.01 ohms/sq at a dry film thickness of about 40 μm to about 0.015 ohms/sq at a dry film thickness of about 40 μm, about 0.01 ohms/sq at a dry film thickness of about 40 μm to about 0.02 ohms/sq at a dry film thickness of about 40 μm, about 0.01 ohms/sq at a dry film thickness of about 40 μm to about 0.025 ohms/sq at a dry film thickness of about 40 μm, about 0.01 ohms/sq at a dry film thickness of about 40 μm to about 0.026 ohms/sq at a dry film thickness of about 40 μm, about 0.01 ohms/sq at a dry film thickness of about 40 μm to about 0.027 ohms/sq at a dry film thickness of about 40 μm, about 0.015 ohms/sq at a dry film thickness of about 40 μm to about 0.02 ohms/sq at a dry film thickness of about 40 μm, about 0.015 ohms/sq at a dry film thickness of about 40 μm to about 0.025 ohms/sq at a dry film thickness of about 40 μm, about 0.015 ohms/sq at a dry film thickness of about 40 μm to about 0.026 ohms/sq at a dry film thickness of about 40 μm, about 0.015 ohms/sq at a dry film thickness of about 40 μm to about 0.027 ohms/sq at a dry film thickness of about 40 μm, about 0.02 ohms/sq at a dry film thickness of about 40 μm to about 0.025 ohms/sq at a dry film thickness of about 40 μm, about 0.02 ohms/sq at a dry film thickness of about 40 μm to about 0.026 ohms/sq at a dry film thickness of about 40 μm, about 0.02 ohms/sq at a dry film thickness of about 40 μm to about 0.027 ohms/sq at a dry film thickness of about 40 μm, about 0.025 ohms/sq at a dry film thickness of about 40 μm to about 0.026 ohms/sq at a dry film thickness of about 40 μm, about 0.025 ohms/sq at a dry film thickness of about 40 μm to about 0.027 ohms/sq at a dry film thickness of about 40 μm, or about 0.026 ohms/sq at a dry film thickness of about 40 μm to about 0.027 ohms/sq at a dry film thickness of about 40 μm, including increments therein. In some embodiments, the conductive ink comprises a sheet resistance of up to about 0.01 ohms/sq at a dry film thickness of about 40 μm, about 0.015 ohms/sq at a dry film thickness of about 40 μm, about 0.02 ohms/sq at a dry film thickness of about 40 μm, about 0.025 ohms/sq at a dry film thickness of about 40 μm, about 0.026 ohms/sq at a dry film thickness of about 40 μm, or about 0.027 ohms/sq at a dry film thickness of about 40 μm. In some embodiments, the conductive ink comprises a sheet resistance of up to at least about 0.01 ohms/sq at a dry film thickness of about 40 μm, about 0.015 ohms/sq at a dry film thickness of about 40 μm, about 0.02 ohms/sq at a dry film thickness of about 40 μm, about 0.025 ohms/sq at a dry film thickness of about 40 μm, or about 0.026 ohms/sq at a dry film thickness of about 40 μm. In some embodiments, the conductive ink comprises a sheet resistance of up to at most about 0.015 ohms/sq at a dry film thickness of about 40 μm, about 0.02 ohms/sq at a dry film thickness of about 40 μm, about 0.025 ohms/sq at a dry film thickness of about 40 μm, about 0.026 ohms/sq at a dry film thickness of about 40 μm, or about 0.027 ohms/sq at a dry film thickness of about 40 μm.

In some embodiments, the conductive ink comprises a sheet resistance of up to about 0.01 ohms/sq at a dry film thickness of about 65 μm to about 0.023 ohms/sq at a dry film thickness of about 65 μm. In some embodiments, the conductive ink comprises a sheet resistance of up to about 0.01 ohms/sq at a dry film thickness of about 65 μm to about 0.015 ohms/sq at a dry film thickness of about 65 μm, about 0.01 ohms/sq at a dry film thickness of about 65 μm to about 0.02 ohms/sq at a dry film thickness of about 65 μm, about 0.01 ohms/sq at a dry film thickness of about 65 μm to about 0.021 ohms/sq at a dry film thickness of about 65 μm, about 0.01 ohms/sq at a dry film thickness of about 65 μm to about 0.022 ohms/sq at a dry film thickness of about 65 μm, about 0.01 ohms/sq at a dry film thickness of about 65 μm to about 0.023 ohms/sq at a dry film thickness of about 65 μm, about 0.015 ohms/sq at a dry film thickness of about 65 μm to about 0.02 ohms/sq at a dry film thickness of about 65 μm, about 0.015 ohms/sq at a dry film thickness of about 65 μm to about 0.021 ohms/sq at a dry film thickness of about 65 μm, about 0.015 ohms/sq at a dry film thickness of about 65 μm to about 0.022 ohms/sq at a dry film thickness of about 65 μm, about 0.015 ohms/sq at a dry film thickness of about 65 μm to about 0.023 ohms/sq at a dry film thickness of about 65 μm, about 0.02 ohms/sq at a dry film thickness of about 65 μm to about 0.021 ohms/sq at a dry film thickness of about 65 μm, about 0.02 ohms/sq at a dry film thickness of about 65 μm to about 0.022 ohms/sq at a dry film thickness of about 65 μm, about 0.02 ohms/sq at a dry film thickness of about 65 μm to about 0.023 ohms/sq at a dry film thickness of about 65 μm, about 0.021 ohms/sq at a dry film thickness of about 65 μm to about 0.022 ohms/sq at a dry film thickness of about 65 μm, about 0.021 ohms/sq at a dry film thickness of about 65 μm to about 0.023 ohms/sq at a dry film thickness of about 65 μm, or about 0.022 ohms/sq at a dry film thickness of about 65 μm to about 0.023 ohms/sq at a dry film thickness of about 65 μm, including increments therein. In some embodiments, the conductive ink comprises a sheet resistance of up to about 0.01 ohms/sq at a dry film thickness of about 65 μm, about 0.015 ohms/sq at a dry film thickness of about 65 μm, about 0.02 ohms/sq at a dry film thickness of about 65 μm, about 0.021 ohms/sq at a dry film thickness of about 65 μm, about 0.022 ohms/sq at a dry film thickness of about 65 μm, or about 0.023 ohms/sq at a dry film thickness of about 65 μm. In some embodiments, the conductive ink comprises a sheet resistance of up to at least about 0.01 ohms/sq at a dry film thickness of about 65 μm, about 0.015 ohms/sq at a dry film thickness of about 65 μm, about 0.02 ohms/sq at a dry film thickness of about 65 μm, about 0.021 ohms/sq at a dry film thickness of about 65 μm, or about 0.022 ohms/sq at a dry film thickness of about 65 μm. In some embodiments, the conductive ink comprises a sheet resistance of up to at most about 0.015 ohms/sq at a dry film thickness of about 65 μm, about 0.02 ohms/sq at a dry film thickness of about 65 μm, about 0.021 ohms/sq at a dry film thickness of about 65 μm, about 0.022 ohms/sq at a dry film thickness of about 65 μm, or about 0.023 ohms/sq at a dry film thickness of about 65 μm.

In some embodiments, the conductive ink comprises a sheet resistance of up to about 0.001 ohms/sq at a dry film thickness of about 90 μm to about 0.017 ohms/sq at a dry film thickness of about 90 μm. In some embodiments, the conductive ink comprises a sheet resistance of up to about 0.001 ohms/sq at a dry film thickness of about 90 μm to about 0.003 ohms/sq at a dry film thickness of about 90 μm, about 0.001 ohms/sq at a dry film thickness of about 90 μm to about 0.005 ohms/sq at a dry film thickness of about 90 μm, about 0.001 ohms/sq at a dry film thickness of about 90 μm to about 0.007 ohms/sq at a dry film thickness of about 90 μm, about 0.001 ohms/sq at a dry film thickness of about 90 μm to about 0.009 ohms/sq at a dry film thickness of about 90 μm, about 0.001 ohms/sq at a dry film thickness of about 90 μm to about 0.011 ohms/sq at a dry film thickness of about 90 μm, about 0.001 ohms/sq at a dry film thickness of about 90 μm to about 0.012 ohms/sq at a dry film thickness of about 90 μm, about 0.001 ohms/sq at a dry film thickness of about 90 μm to about 0.013 ohms/sq at a dry film thickness of about 90 μm, about 0.001 ohms/sq at a dry film thickness of about 90 μm to about 0.014 ohms/sq at a dry film thickness of about 90 μm, about 0.001 ohms/sq at a dry film thickness of about 90 μm to about 0.015 ohms/sq at a dry film thickness of about 90 μm, about 0.001 ohms/sq at a dry film thickness of about 90 μm to about 0.016 ohms/sq at a dry film thickness of about 90 μm, about 0.001 ohms/sq at a dry film thickness of about 90 μm to about 0.017 ohms/sq at a dry film thickness of about 90 μm, about 0.003 ohms/sq at a dry film thickness of about 90 μm to about 0.005 ohms/sq at a dry film thickness of about 90 μm, about 0.003 ohms/sq at a dry film thickness of about 90 μm to about 0.007 ohms/sq at a dry film thickness of about 90 μm, about 0.003 ohms/sq at a dry film thickness of about 90 μm to about 0.009 ohms/sq at a dry film thickness of about 90 μm, about 0.003 ohms/sq at a dry film thickness of about 90 μm to about 0.011 ohms/sq at a dry film thickness of about 90 μm, about 0.003 ohms/sq at a dry film thickness of about 90 μm to about 0.012 ohms/sq at a dry film thickness of about 90 μm, about 0.003 ohms/sq at a dry film thickness of about 90 μm to about 0.013 ohms/sq at a dry film thickness of about 90 μm, about 0.003 ohms/sq at a dry film thickness of about 90 μm to about 0.014 ohms/sq at a dry film thickness of about 90 μm, about 0.003 ohms/sq at a dry film thickness of about 90 μm to about 0.015 ohms/sq at a dry film thickness of about 90 μm, about 0.003 ohms/sq at a dry film thickness of about 90 μm to about 0.016 ohms/sq at a dry film thickness of about 90 μm, about 0.003 ohms/sq at a dry film thickness of about 90 μm to about 0.017 ohms/sq at a dry film thickness of about 90 μm, about 0.005 ohms/sq at a dry film thickness of about 90 μm to about 0.007 ohms/sq at a dry film thickness of about 90 μm, about 0.005 ohms/sq at a dry film thickness of about 90 μm to about 0.009 ohms/sq at a dry film thickness of about 90 μm, about 0.005 ohms/sq at a dry film thickness of about 90 μm to about 0.011 ohms/sq at a dry film thickness of about 90 μm, about 0.005 ohms/sq at a dry film thickness of about 90 μm to about 0.012 ohms/sq at a dry film thickness of about 90 μm, about 0.005 ohms/sq at a dry film thickness of about 90 μm to about 0.013 ohms/sq at a dry film thickness of about 90 μm, about 0.005 ohms/sq at a dry film thickness of about 90 μm to about 0.014 ohms/sq at a dry film thickness of about 90 μm, about 0.005 ohms/sq at a dry film thickness of about 90 μm to about 0.015 ohms/sq at a dry film thickness of about 90 μm, about 0.005 ohms/sq at a dry film thickness of about 90 μm to about 0.016 ohms/sq at a dry film thickness of about 90 μm, about 0.005 ohms/sq at a dry film thickness of about 90 μm to about 0.017 ohms/sq at a dry film thickness of about 90 μm, about 0.007 ohms/sq at a dry film thickness of about 90 μm to about 0.009 ohms/sq at a dry film thickness of about 90 μm, about 0.007 ohms/sq at a dry film thickness of about 90 μm to about 0.011 ohms/sq at a dry film thickness of about 90 μm, about 0.007 ohms/sq at a dry film thickness of about 90 μm to about 0.012 ohms/sq at a dry film thickness of about 90 μm, about 0.007 ohms/sq at a dry film thickness of about 90 μm to about 0.013 ohms/sq at a dry film thickness of about 90 μm, about 0.007 ohms/sq at a dry film thickness of about 90 μm to about 0.014 ohms/sq at a dry film thickness of about 90 μm, about 0.007 ohms/sq at a dry film thickness of about 90 μm to about 0.015 ohms/sq at a dry film thickness of about 90 μm, about 0.007 ohms/sq at a dry film thickness of about 90 μm to about 0.016 ohms/sq at a dry film thickness of about 90 μm, about 0.007 ohms/sq at a dry film thickness of about 90 μm to about 0.017 ohms/sq at a dry film thickness of about 90 μm, about 0.009 ohms/sq at a dry film thickness of about 90 μm to about 0.011 ohms/sq at a dry film thickness of about 90 μm, about 0.009 ohms/sq at a dry film thickness of about 90 μm to about 0.012 ohms/sq at a dry film thickness of about 90 μm, about 0.009 ohms/sq at a dry film thickness of about 90 μm to about 0.013 ohms/sq at a dry film thickness of about 90 μm, about 0.009 ohms/sq at a dry film thickness of about 90 μm to about 0.014 ohms/sq at a dry film thickness of about 90 μm, about 0.009 ohms/sq at a dry film thickness of about 90 μm to about 0.015 ohms/sq at a dry film thickness of about 90 μm, about 0.009 ohms/sq at a dry film thickness of about 90 μm to about 0.016 ohms/sq at a dry film thickness of about 90 μm, about 0.009 ohms/sq at a dry film thickness of about 90 μm to about 0.017 ohms/sq at a dry film thickness of about 90 μm, about 0.011 ohms/sq at a dry film thickness of about 90 μm to about 0.012 ohms/sq at a dry film thickness of about 90 μm, about 0.011 ohms/sq at a dry film thickness of about 90 μm to about 0.013 ohms/sq at a dry film thickness of about 90 μm, about 0.011 ohms/sq at a dry film thickness of about 90 μm to about 0.014 ohms/sq at a dry film thickness of about 90 μm, about 0.011 ohms/sq at a dry film thickness of about 90 μm to about 0.015 ohms/sq at a dry film thickness of about 90 μm, about 0.011 ohms/sq at a dry film thickness of about 90 μm to about 0.016 ohms/sq at a dry film thickness of about 90 μm, about 0.011 ohms/sq at a dry film thickness of about 90 μm to about 0.017 ohms/sq at a dry film thickness of about 90 μm, about 0.012 ohms/sq at a dry film thickness of about 90 μm to about 0.013 ohms/sq at a dry film thickness of about 90 μm, about 0.012 ohms/sq at a dry film thickness of about 90 μm to about 0.014 ohms/sq at a dry film thickness of about 90 μm, about 0.012 ohms/sq at a dry film thickness of about 90 μm to about 0.015 ohms/sq at a dry film thickness of about 90 μm, about 0.012 ohms/sq at a dry film thickness of about 90 μm to about 0.016 ohms/sq at a dry film thickness of about 90 μm, about 0.012 ohms/sq at a dry film thickness of about 90 μm to about 0.017 ohms/sq at a dry film thickness of about 90 μm, about 0.013 ohms/sq at a dry film thickness of about 90 μm to about 0.014 ohms/sq at a dry film thickness of about 90 μm, about 0.013 ohms/sq at a dry film thickness of about 90 μm to about 0.015 ohms/sq at a dry film thickness of about 90 μm, about 0.013 ohms/sq at a dry film thickness of about 90 μm to about 0.016 ohms/sq at a dry film thickness of about 90 μm, about 0.013 ohms/sq at a dry film thickness of about 90 μm to about 0.017 ohms/sq at a dry film thickness of about 90 μm, about 0.014 ohms/sq at a dry film thickness of about 90 μm to about 0.015 ohms/sq at a dry film thickness of about 90 μm, about 0.014 ohms/sq at a dry film thickness of about 90 μm to about 0.016 ohms/sq at a dry film thickness of about 90 μm, about 0.014 ohms/sq at a dry film thickness of about 90 μm to about 0.017 ohms/sq at a dry film thickness of about 90 μm, about 0.015 ohms/sq at a dry film thickness of about 90 μm to about 0.016 ohms/sq at a dry film thickness of about 90 μm, about 0.015 ohms/sq at a dry film thickness of about 90 μm to about 0.017 ohms/sq at a dry film thickness of about 90 μm, or about 0.016 ohms/sq at a dry film thickness of about 90 μm to about 0.017 ohms/sq at a dry film thickness of about 90 μm, including increments therein. In some embodiments, the conductive ink comprises a sheet resistance of up to about 0.001 ohms/sq at a dry film thickness of about 90 μm, about 0.003 ohms/sq at a dry film thickness of about 90 μm, about 0.005 ohms/sq at a dry film thickness of about 90 μm, about 0.007 ohms/sq at a dry film thickness of about 90 μm, about 0.009 ohms/sq at a dry film thickness of about 90 μm, about 0.011 ohms/sq at a dry film thickness of about 90 μm, about 0.012 ohms/sq at a dry film thickness of about 90 μm, about 0.013 ohms/sq at a dry film thickness of about 90 μm, about 0.014 ohms/sq at a dry film thickness of about 90 μm, about 0.015 ohms/sq at a dry film thickness of about 90 μm, about 0.016 ohms/sq at a dry film thickness of about 90 μm, or about 0.017 ohms/sq at a dry film thickness of about 90 μm. In some embodiments, the conductive ink comprises a sheet resistance of up to at least about 0.001 ohms/sq at a dry film thickness of about 90 μm, about 0.003 ohms/sq at a dry film thickness of about 90 μm, about 0.005 ohms/sq at a dry film thickness of about 90 μm, about 0.007 ohms/sq at a dry film thickness of about 90 μm, about 0.009 ohms/sq at a dry film thickness of about 90 μm, about 0.011 ohms/sq at a dry film thickness of about 90 μm, about 0.012 ohms/sq at a dry film thickness of about 90 μm, about 0.013 ohms/sq at a dry film thickness of about 90 μm, about 0.014 ohms/sq at a dry film thickness of about 90 μm, about 0.015 ohms/sq at a dry film thickness of about 90 μm, or about 0.016 ohms/sq at a dry film thickness of about 90 μm. In some embodiments, the conductive ink comprises a sheet resistance of up to at most about 0.003 ohms/sq at a dry film thickness of about 90 μm, about 0.005 ohms/sq at a dry film thickness of about 90 μm, about 0.007 ohms/sq at a dry film thickness of about 90 μm, about 0.009 ohms/sq at a dry film thickness of about 90 μm, about 0.011 ohms/sq at a dry film thickness of about 90 μm, about 0.012 ohms/sq at a dry film thickness of about 90 μm, about 0.013 ohms/sq at a dry film thickness of about 90 μm, about 0.014 ohms/sq at a dry film thickness of about 90 μm, about 0.015 ohms/sq at a dry film thickness of about 90 μm, about 0.016 ohms/sq at a dry film thickness of about 90 μm, or about 0.017 ohms/sq at a dry film thickness of about 90 μm.

In some embodiments, the conductive ink comprises a sheet resistance of up to about 10 ohms/sq at a dry film thickness of about 200 μm to about 90 ohms/sq at a dry film thickness of about 200 μm. In some embodiments, the conductive ink comprises a sheet resistance of up to about 10 ohms/sq at a dry film thickness of about 200 μm to about 20 ohms/sq at a dry film thickness of about 200 μm, about 10 ohms/sq at a dry film thickness of about 200 μm to about 30 ohms/sq at a dry film thickness of about 200 μm, about 10 ohms/sq at a dry film thickness of about 200 μm to about 40 ohms/sq at a dry film thickness of about 200 μm, about 10 ohms/sq at a dry film thickness of about 200 μm to about 50 ohms/sq at a dry film thickness of about 200 μm, about 10 ohms/sq at a dry film thickness of about 200 μm to about 60 ohms/sq at a dry film thickness of about 200 μm, about 10 ohms/sq at a dry film thickness of about 200 μm to about 70 ohms/sq at a dry film thickness of about 200 μm, about 10 ohms/sq at a dry film thickness of about 200 μm to about 80 ohms/sq at a dry film thickness of about 200 μm, about 10 ohms/sq at a dry film thickness of about 200 μm to about 90 ohms/sq at a dry film thickness of about 200 μm, about 20 ohms/sq at a dry film thickness of about 200 μm to about 30 ohms/sq at a dry film thickness of about 200 μm, about 20 ohms/sq at a dry film thickness of about 200 μm to about 40 ohms/sq at a dry film thickness of about 200 μm, about 20 ohms/sq at a dry film thickness of about 200 μm to about 50 ohms/sq at a dry film thickness of about 200 μm, about 20 ohms/sq at a dry film thickness of about 200 μm to about 60 ohms/sq at a dry film thickness of about 200 μm, about 20 ohms/sq at a dry film thickness of about 200 μm to about 70 ohms/sq at a dry film thickness of about 200 μm, about 20 ohms/sq at a dry film thickness of about 200 μm to about 80 ohms/sq at a dry film thickness of about 200 μm, about 20 ohms/sq at a dry film thickness of about 200 μm to about 90 ohms/sq at a dry film thickness of about 200 μm, about 30 ohms/sq at a dry film thickness of about 200 μm to about 40 ohms/sq at a dry film thickness of about 200 μm, about 30 ohms/sq at a dry film thickness of about 200 μm to about 50 ohms/sq at a dry film thickness of about 200 μm, about 30 ohms/sq at a dry film thickness of about 200 μm to about 60 ohms/sq at a dry film thickness of about 200 μm, about 30 ohms/sq at a dry film thickness of about 200 μm to about 70 ohms/sq at a dry film thickness of about 200 μm, about 30 ohms/sq at a dry film thickness of about 200 μm to about 80 ohms/sq at a dry film thickness of about 200 μm, about 30 ohms/sq at a dry film thickness of about 200 μm to about 90 ohms/sq at a dry film thickness of about 200 μm, about 40 ohms/sq at a dry film thickness of about 200 μm to about 50 ohms/sq at a dry film thickness of about 200 μm, about 40 ohms/sq at a dry film thickness of about 200 μm to about 60 ohms/sq at a dry film thickness of about 200 μm, about 40 ohms/sq at a dry film thickness of about 200 μm to about 70 ohms/sq at a dry film thickness of about 200 μm, about 40 ohms/sq at a dry film thickness of about 200 μm to about 80 ohms/sq at a dry film thickness of about 200 μm, about 40 ohms/sq at a dry film thickness of about 200 μm to about 90 ohms/sq at a dry film thickness of about 200 μm, about 50 ohms/sq at a dry film thickness of about 200 μm to about 60 ohms/sq at a dry film thickness of about 200 μm, about 50 ohms/sq at a dry film thickness of about 200 μm to about 70 ohms/sq at a dry film thickness of about 200 μm, about 50 ohms/sq at a dry film thickness of about 200 μm to about 80 ohms/sq at a dry film thickness of about 200 μm, about 50 ohms/sq at a dry film thickness of about 200 μm to about 90 ohms/sq at a dry film thickness of about 200 μm, about 60 ohms/sq at a dry film thickness of about 200 μm to about 70 ohms/sq at a dry film thickness of about 200 μm, about 60 ohms/sq at a dry film thickness of about 200 μm to about 80 ohms/sq at a dry film thickness of about 200 μm, about 60 ohms/sq at a dry film thickness of about 200 μm to about 90 ohms/sq at a dry film thickness of about 200 μm, about 70 ohms/sq at a dry film thickness of about 200 μm to about 80 ohms/sq at a dry film thickness of about 200 μm, about 70 ohms/sq at a dry film thickness of about 200 μm to about 90 ohms/sq at a dry film thickness of about 200 μm, or about 80 ohms/sq at a dry film thickness of about 200 μm to about 90 ohms/sq at a dry film thickness of about 200 μm, including increments therein. In some embodiments, the conductive ink comprises a sheet resistance of up to about 10 ohms/sq at a dry film thickness of about 200 μm, about 20 ohms/sq at a dry film thickness of about 200 μm, about 30 ohms/sq at a dry film thickness of about 200 μm, about 40 ohms/sq at a dry film thickness of about 200 μm, about 50 ohms/sq at a dry film thickness of about 200 μm, about 60 ohms/sq at a dry film thickness of about 200 μm, about 70 ohms/sq at a dry film thickness of about 200 μm, about 80 ohms/sq at a dry film thickness of about 200 μm, or about 90 ohms/sq at a dry film thickness of about 200 μm. In some embodiments, the conductive ink comprises a sheet resistance of up to at least about 10 ohms/sq at a dry film thickness of about 200 μm, about 20 ohms/sq at a dry film thickness of about 200 μm, about 30 ohms/sq at a dry film thickness of about 200 μm, about 40 ohms/sq at a dry film thickness of about 200 μm, about 50 ohms/sq at a dry film thickness of about 200 μm, about 60 ohms/sq at a dry film thickness of about 200 μm, about 70 ohms/sq at a dry film thickness of about 200 μm, or about 80 ohms/sq at a dry film thickness of about 200 μm. In some embodiments, the conductive ink comprises a sheet resistance of up to at most about 20 ohms/sq at a dry film thickness of about 200 μm, about 30 ohms/sq at a dry film thickness of about 200 μm, about 40 ohms/sq at a dry film thickness of about 200 μm, about 50 ohms/sq at a dry film thickness of about 200 μm, about 60 ohms/sq at a dry film thickness of about 200 μm, about 70 ohms/sq at a dry film thickness of about 200 μm, about 80 ohms/sq at a dry film thickness of about 200 μm, or about 90 ohms/sq at a dry film thickness of about 200 μm.

In some embodiments, the ink comprises a sheet resistance of about 0.025 ohms/sq at a range of dry film thicknesses from about 30 μm to about 36 μm.

In some embodiments, the conductive ink printed on a substrate is thermally stable up to about 400° C. In some embodiments, the conductive ink is flexible when dried and applied to a substrate. In some embodiments, flexibility of the conductive ink is measured by measuring the sheet resistance of the conductive ink when applied to a substrate upon bending. In some embodiments, the sheet resistance of the conductive ink does not decrease upon bending the substrate, folding the substrate, or creasing the substrate. In some embodiments, the sheet resistance of the conductive ink decreases by less than 10%, 9%, 8%, 7%, 6%, 5%, 4%, 3% 2%, 1%, 0.5%, 0.1% or less upon bending the substrate, folding the substrate, or creasing the substrate.

In some embodiments, the conductive ink is adhesive and is resistant to cracking. Cracking of the conductive ink can be measured by making an incision on the coating of the surface of the conductive ink, and by applying an adhesive surface to the incised surface of the conductive ink. In some embodiments, the conductive ink is resistant to cracking, and none of the conductive ink is removed from the incised surface of the conductive ink upon application of an adhesive surface to the incised surface. In some embodiments, the conductive ink is resistant to cracking and less than 10%, 9%, 8%, 7%, 6%, 5%, 4%, 3% 2%, 1%, 0.5%, 0.1% or less upon of the conductive ink is removed from the incised surface of the conductive ink upon application of an adhesive surface to the incised surface.

In some embodiments, the conductive ink comprises a conductivity of about 6,300 S/cm to about 15,000 S/cm. In some embodiments, the conductive ink comprises a conductivity of about 6,300 S/cm to about 7,200 S/cm, about 6,300 S/cm to about 8,100 S/cm, about 6,300 S/cm to about 9,000 S/cm, about 6,300 S/cm to about 9,900 S/cm, about 6,300 S/cm to about 10,800 S/cm, about 6,300 S/cm to about 11,700 S/cm, about 6,300 S/cm to about 12,600 S/cm, about 6,300 S/cm to about 13,500 S/cm, about 6,300 S/cm to about 14,400 S/cm, about 6,300 S/cm to about 15,000 S/cm, about 7,200 S/cm to about 8,100 S/cm, about 7,200 S/cm to about 9,000 S/cm, about 7,200 S/cm to about 9,900 S/cm, about 7,200 S/cm to about 10,800 S/cm, about 7,200 S/cm to about 11,700 S/cm, about 7,200 S/cm to about 12,600 S/cm, about 7,200 S/cm to about 13,500 S/cm, about 7,200 S/cm to about 14,400 S/cm, about 7,200 S/cm to about 15,000 S/cm, about 8,100 S/cm to about 9,000 S/cm, about 8,100 S/cm to about 9,900 S/cm, about 8,100 S/cm to about 10,800 S/cm, about 8,100 S/cm to about 11,700 S/cm, about 8,100 S/cm to about 12,600 S/cm, about 8,100 S/cm to about 13,500 S/cm, about 8,100 S/cm to about 14,400 S/cm, about 8,100 S/cm to about 15,000 S/cm, about 9,000 S/cm to about 9,900 S/cm, about 9,000 S/cm to about 10,800 S/cm, about 9,000 S/cm to about 11,700 S/cm, about 9,000 S/cm to about 12,600 S/cm, about 9,000 S/cm to about 13,500 S/cm, about 9,000 S/cm to about 14,400 S/cm, about 9,000 S/cm to about 15,000 S/cm, about 9,900 S/cm to about 10,800 S/cm, about 9,900 S/cm to about 11,700 S/cm, about 9,900 S/cm to about 12,600 S/cm, about 9,900 S/cm to about 13,500 S/cm, about 9,900 S/cm to about 14,400 S/cm, about 9,900 S/cm to about 15,000 S/cm, about 10,800 S/cm to about 11,700 S/cm, about 10,800 S/cm to about 12,600 S/cm, about 10,800 S/cm to about 13,500 S/cm, about 10,800 S/cm to about 14,400 S/cm, about 10,800 S/cm to about 15,000 S/cm, about 11,700 S/cm to about 12,600 S/cm, about 11,700 S/cm to about 13,500 S/cm, about 11,700 S/cm to about 14,400 S/cm, about 11,700 S/cm to about 15,000 S/cm, about 12,600 S/cm to about 13,500 S/cm, about 12,600 S/cm to about 14,400 S/cm, about 12,600 S/cm to about 15,000 S/cm, about 13,500 S/cm to about 14,400 S/cm, about 13,500 S/cm to about 15,000 S/cm, or about 14,400 S/cm to about 15,000 S/cm, including increments therein. In some embodiments, the conductive ink comprises a conductivity of about 6,300 S/cm, about 7,200 S/cm, about 8,100 S/cm, about 9,000 S/cm, about 9,900 S/cm, about 10,800 S/cm, about 11,700 S/cm, about 12,600 S/cm, about 13,500 S/cm, about 14,400 S/cm, or about 15,000 S/cm. In some embodiments, the conductive ink comprises a conductivity of at least about 6,300 S/cm, about 7,200 S/cm, about 8,100 S/cm, about 9,000 S/cm, about 9,900 S/cm, about 10,800 S/cm, about 11,700 S/cm, about 12,600 S/cm, about 13,500 S/cm, or about 14,400 S/cm. In some embodiments, the conductive ink comprises a conductivity of at most about 7,200 S/cm, about 8,100 S/cm, about 9,000 S/cm, about 9,900 S/cm, about 10,800 S/cm, about 11,700 S/cm, about 12,600 S/cm, about 13,500 S/cm, about 14,400 S/cm, or about 15,000 S/cm. In some embodiments, the conductive ink comprises at least 6300 S/cm at a dry film thickness of about 10 μm. In some embodiments, the conductive ink comprises about 10,000 S/cm at a dry film thickness from about 10 μm to about 50 μm. In some embodiments, the conductive ink comprises of at least 10000 S/cm at a dry film thickness of from about 10 μm to about 50 μm. In some embodiments, the conductive ink comprises the claimed conductivity when cured at 110° C. for about 30 min. In some embodiments, the conductive ink comprises

In some embodiments, the conductive ink comprises a conductivity of up to about 1,000 S/cm at a dry film thickness of about 100 μm to about 54,000 S/cm at a dry film thickness of about 100 μm. In some embodiments, the conductive ink comprises a conductivity of up to about 1,000 S/cm at a dry film thickness of about 100 μm to about 5,000 S/cm at a dry film thickness of about 100 um, about 1,000 S/cm at a dry film thickness of about 100 μm to about 9,000 S/cm at a dry film thickness of about 100 um, about 1,000 S/cm at a dry film thickness of about 100 μm to about 14,000 S/cm at a dry film thickness of about 100 um, about 1,000 S/cm at a dry film thickness of about 100 μm to about 19,000 S/cm at a dry film thickness of about 100 um, about 1,000 S/cm at a dry film thickness of about 100 μm to about 24,000 S/cm at a dry film thickness of about 100 um, about 1,000 S/cm at a dry film thickness of about 100 μm to about 29,000 S/cm at a dry film thickness of about 100 um, about 1,000 S/cm at a dry film thickness of about 100 μm to about 34,000 S/cm at a dry film thickness of about 100 um, about 1,000 S/cm at a dry film thickness of about 100 μm to about 39,000 S/cm at a dry film thickness of about 100 um, about 1,000 S/cm at a dry film thickness of about 100 μm to about 44,000 S/cm at a dry film thickness of about 100 um, about 1,000 S/cm at a dry film thickness of about 100 μm to about 49,000 S/cm at a dry film thickness of about 100 um, about 1,000 S/cm at a dry film thickness of about 100 μm to about 54,000 S/cm at a dry film thickness of about 100 um, about 5,000 S/cm at a dry film thickness of about 100 μm to about 9,000 S/cm at a dry film thickness of about 100 um, about 5,000 S/cm at a dry film thickness of about 100 μm to about 14,000 S/cm at a dry film thickness of about 100 um, about 5,000 S/cm at a dry film thickness of about 100 μm to about 19,000 S/cm at a dry film thickness of about 100 um, about 5,000 S/cm at a dry film thickness of about 100 μm to about 24,000 S/cm at a dry film thickness of about 100 um, about 5,000 S/cm at a dry film thickness of about 100 μm to about 29,000 S/cm at a dry film thickness of about 100 um, about 5,000 S/cm at a dry film thickness of about 100 μm to about 34,000 S/cm at a dry film thickness of about 100 um, about 5,000 S/cm at a dry film thickness of about 100 μm to about 39,000 S/cm at a dry film thickness of about 100 um, about 5,000 S/cm at a dry film thickness of about 100 μm to about 44,000 S/cm at a dry film thickness of about 100 um, about 5,000 S/cm at a dry film thickness of about 100 μm to about 49,000 S/cm at a dry film thickness of about 100 um, about 5,000 S/cm at a dry film thickness of about 100 μm to about 54,000 S/cm at a dry film thickness of about 100 um, about 9,000 S/cm at a dry film thickness of about 100 μm to about 14,000 S/cm at a dry film thickness of about 100 um, about 9,000 S/cm at a dry film thickness of about 100 μm to about 19,000 S/cm at a dry film thickness of about 100 um, about 9,000 S/cm at a dry film thickness of about 100 μm to about 24,000 S/cm at a dry film thickness of about 100 um, about 9,000 S/cm at a dry film thickness of about 100 μm to about 29,000 S/cm at a dry film thickness of about 100 um, about 9,000 S/cm at a dry film thickness of about 100 μm to about 34,000 S/cm at a dry film thickness of about 100 um, about 9,000 S/cm at a dry film thickness of about 100 μm to about 39,000 S/cm at a dry film thickness of about 100 um, about 9,000 S/cm at a dry film thickness of about 100 μm to about 44,000 S/cm at a dry film thickness of about 100 um, about 9,000 S/cm at a dry film thickness of about 100 μm to about 49,000 S/cm at a dry film thickness of about 100 um, about 9,000 S/cm at a dry film thickness of about 100 μm to about 54,000 S/cm at a dry film thickness of about 100 um, about 14,000 S/cm at a dry film thickness of about 100 μm to about 19,000 S/cm at a dry film thickness of about 100 um, about 14,000 S/cm at a dry film thickness of about 100 μm to about 24,000 S/cm at a dry film thickness of about 100 um, about 14,000 S/cm at a dry film thickness of about 100 μm to about 29,000 S/cm at a dry film thickness of about 100 um, about 14,000 S/cm at a dry film thickness of about 100 μm to about 34,000 S/cm at a dry film thickness of about 100 um, about 14,000 S/cm at a dry film thickness of about 100 μm to about 39,000 S/cm at a dry film thickness of about 100 um, about 14,000 S/cm at a dry film thickness of about 100 μm to about 44,000 S/cm at a dry film thickness of about 100 um, about 14,000 S/cm at a dry film thickness of about 100 μm to about 49,000 S/cm at a dry film thickness of about 100 um, about 14,000 S/cm at a dry film thickness of about 100 μm to about 54,000 S/cm at a dry film thickness of about 100 um, about 19,000 S/cm at a dry film thickness of about 100 μm to about 24,000 S/cm at a dry film thickness of about 100 um, about 19,000 S/cm at a dry film thickness of about 100 μm to about 29,000 S/cm at a dry film thickness of about 100 um, about 19,000 S/cm at a dry film thickness of about 100 μm to about 34,000 S/cm at a dry film thickness of about 100 um, about 19,000 S/cm at a dry film thickness of about 100 μm to about 39,000 S/cm at a dry film thickness of about 100 um, about 19,000 S/cm at a dry film thickness of about 100 μm to about 44,000 S/cm at a dry film thickness of about 100 um, about 19,000 S/cm at a dry film thickness of about 100 μm to about 49,000 S/cm at a dry film thickness of about 100 um, about 19,000 S/cm at a dry film thickness of about 100 μm to about 54,000 S/cm at a dry film thickness of about 100 um, about 24,000 S/cm at a dry film thickness of about 100 μm to about 29,000 S/cm at a dry film thickness of about 100 um, about 24,000 S/cm at a dry film thickness of about 100 μm to about 34,000 S/cm at a dry film thickness of about 100 um, about 24,000 S/cm at a dry film thickness of about 100 μm to about 39,000 S/cm at a dry film thickness of about 100 um, about 24,000 S/cm at a dry film thickness of about 100 μm to about 44,000 S/cm at a dry film thickness of about 100 um, about 24,000 S/cm at a dry film thickness of about 100 μm to about 49,000 S/cm at a dry film thickness of about 100 um, about 24,000 S/cm at a dry film thickness of about 100 μm to about 54,000 S/cm at a dry film thickness of about 100 um, about 29,000 S/cm at a dry film thickness of about 100 μm to about 34,000 S/cm at a dry film thickness of about 100 um, about 29,000 S/cm at a dry film thickness of about 100 μm to about 39,000 S/cm at a dry film thickness of about 100 um, about 29,000 S/cm at a dry film thickness of about 100 μm to about 44,000 S/cm at a dry film thickness of about 100 um, about 29,000 S/cm at a dry film thickness of about 100 μm to about 49,000 S/cm at a dry film thickness of about 100 um, about 29,000 S/cm at a dry film thickness of about 100 μm to about 54,000 S/cm at a dry film thickness of about 100 um, about 34,000 S/cm at a dry film thickness of about 100 μm to about 39,000 S/cm at a dry film thickness of about 100 um, about 34,000 S/cm at a dry film thickness of about 100 μm to about 44,000 S/cm at a dry film thickness of about 100 um, about 34,000 S/cm at a dry film thickness of about 100 μm to about 49,000 S/cm at a dry film thickness of about 100 um, about 34,000 S/cm at a dry film thickness of about 100 μm to about 54,000 S/cm at a dry film thickness of about 100 um, about 39,000 S/cm at a dry film thickness of about 100 μm to about 44,000 S/cm at a dry film thickness of about 100 um, about 39,000 S/cm at a dry film thickness of about 100 μm to about 49,000 S/cm at a dry film thickness of about 100 um, about 39,000 S/cm at a dry film thickness of about 100 μm to about 54,000 S/cm at a dry film thickness of about 100 um, about 44,000 S/cm at a dry film thickness of about 100 μm to about 49,000 S/cm at a dry film thickness of about 100 um, about 44,000 S/cm at a dry film thickness of about 100 μm to about 54,000 S/cm at a dry film thickness of about 100 μm, or about 49,000 S/cm at a dry film thickness of about 100 μm to about 54,000 S/cm at a dry film thickness of about 100 μm, including increments therein. In some embodiments, the conductive ink comprises a conductivity of up to about 1,000 S/cm at a dry film thickness of about 100 μm, about 5,000 S/cm at a dry film thickness of about 100 um, about 9,000 S/cm at a dry film thickness of about 100 um, about 14,000 S/cm at a dry film thickness of about 100 um, about 19,000 S/cm at a dry film thickness of about 100 um, about 24,000 S/cm at a dry film thickness of about 100 um, about 29,000 S/cm at a dry film thickness of about 100 um, about 34,000 S/cm at a dry film thickness of about 100 um, about 39,000 S/cm at a dry film thickness of about 100 um, about 44,000 S/cm at a dry film thickness of about 100 um, about 49,000 S/cm at a dry film thickness of about 100 μm, or about 54,000 S/cm at a dry film thickness of about 100 μm. In some embodiments, the conductive ink comprises a conductivity of up to at least about 1,000 S/cm at a dry film thickness of about 100 um, about 5,000 S/cm at a dry film thickness of about 100 um, about 9,000 S/cm at a dry film thickness of about 100 um, about 14,000 S/cm at a dry film thickness of about 100 um, about 19,000 S/cm at a dry film thickness of about 100 um, about 24,000 S/cm at a dry film thickness of about 100 um, about 29,000 S/cm at a dry film thickness of about 100 um, about 34,000 S/cm at a dry film thickness of about 100 um, about 39,000 S/cm at a dry film thickness of about 100 um, about 44,000 S/cm at a dry film thickness of about 100 um, or about 49,000 S/cm at a dry film thickness of about 100 μm. In some embodiments, the conductive ink comprises a conductivity of up to at most about 5,000 S/cm at a dry film thickness of about 100 um, about 9,000 S/cm at a dry film thickness of about 100 um, about 14,000 S/cm at a dry film thickness of about 100 um, about 19,000 S/cm at a dry film thickness of about 100 um, about 24,000 S/cm at a dry film thickness of about 100 um, about 29,000 S/cm at a dry film thickness of about 100 um, about 34,000 S/cm at a dry film thickness of about 100 um, about 39,000 S/cm at a dry film thickness of about 100 um, about 44,000 S/cm at a dry film thickness of about 100 um, about 49,000 S/cm at a dry film thickness of about 100 μm, or about 54,000 S/cm at a dry film thickness of about 100 μm.

In some embodiments, the conductive ink comprises a conductivity of about 15,000 S/cm to about 54,000 S/cm. In some embodiments, the conductive ink comprises a conductivity of about 15,000 S/cm to about 19,000 S/cm, about 15,000 S/cm to about 23,000 S/cm, about 15,000 S/cm to about 27,000 S/cm, about 15,000 S/cm to about 31,000 S/cm, about 15,000 S/cm to about 35,000 S/cm, about 15,000 S/cm to about 39,000 S/cm, about 15,000 S/cm to about 43,000 S/cm, about 15,000 S/cm to about 47,000 S/cm, about 15,000 S/cm to about 51,000 S/cm, about 15,000 S/cm to about 52,000 S/cm, about 15,000 S/cm to about 54,000 S/cm, about 19,000 S/cm to about 23,000 S/cm, about 19,000 S/cm to about 27,000 S/cm, about 19,000 S/cm to about 31,000 S/cm, about 19,000 S/cm to about 35,000 S/cm, about 19,000 S/cm to about 39,000 S/cm, about 19,000 S/cm to about 43,000 S/cm, about 19,000 S/cm to about 47,000 S/cm, about 19,000 S/cm to about 51,000 S/cm, about 19,000 S/cm to about 52,000 S/cm, about 19,000 S/cm to about 54,000 S/cm, about 23,000 S/cm to about 27,000 S/cm, about 23,000 S/cm to about 31,000 S/cm, about 23,000 S/cm to about 35,000 S/cm, about 23,000 S/cm to about 39,000 S/cm, about 23,000 S/cm to about 43,000 S/cm, about 23,000 S/cm to about 47,000 S/cm, about 23,000 S/cm to about 51,000 S/cm, about 23,000 S/cm to about 52,000 S/cm, about 23,000 S/cm to about 54,000 S/cm, about 27,000 S/cm to about 31,000 S/cm, about 27,000 S/cm to about 35,000 S/cm, about 27,000 S/cm to about 39,000 S/cm, about 27,000 S/cm to about 43,000 S/cm, about 27,000 S/cm to about 47,000 S/cm, about 27,000 S/cm to about 51,000 S/cm, about 27,000 S/cm to about 52,000 S/cm, about 27,000 S/cm to about 54,000 S/cm, about 31,000 S/cm to about 35,000 S/cm, about 31,000 S/cm to about 39,000 S/cm, about 31,000 S/cm to about 43,000 S/cm, about 31,000 S/cm to about 47,000 S/cm, about 31,000 S/cm to about 51,000 S/cm, about 31,000 S/cm to about 52,000 S/cm, about 31,000 S/cm to about 54,000 S/cm, about 35,000 S/cm to about 39,000 S/cm, about 35,000 S/cm to about 43,000 S/cm, about 35,000 S/cm to about 47,000 S/cm, about 35,000 S/cm to about 51,000 S/cm, about 35,000 S/cm to about 52,000 S/cm, about 35,000 S/cm to about 54,000 S/cm, about 39,000 S/cm to about 43,000 S/cm, about 39,000 S/cm to about 47,000 S/cm, about 39,000 S/cm to about 51,000 S/cm, about 39,000 S/cm to about 52,000 S/cm, about 39,000 S/cm to about 54,000 S/cm, about 43,000 S/cm to about 47,000 S/cm, about 43,000 S/cm to about 51,000 S/cm, about 43,000 S/cm to about 52,000 S/cm, about 43,000 S/cm to about 54,000 S/cm, about 47,000 S/cm to about 51,000 S/cm, about 47,000 S/cm to about 52,000 S/cm, about 47,000 S/cm to about 54,000 S/cm, about 51,000 S/cm to about 52,000 S/cm, about 51,000 S/cm to about 54,000 S/cm, or about 52,000 S/cm to about 54,000 S/cm, including increments therein. In some embodiments, the conductive ink comprises a conductivity of about 15,000 S/cm, about 19,000 S/cm, about 23,000 S/cm, about 27,000 S/cm, about 31,000 S/cm, about 35,000 S/cm, about 39,000 S/cm, about 43,000 S/cm, about 47,000 S/cm, about 51,000 S/cm, about 52,000 S/cm, or about 54,000 S/cm. In some embodiments, the conductive ink comprises a conductivity of at least about 15,000 S/cm, about 19,000 S/cm, about 23,000 S/cm, about 27,000 S/cm, about 31,000 S/cm, about 35,000 S/cm, about 39,000 S/cm, about 43,000 S/cm, about 47,000 S/cm, about 51,000 S/cm, or about 52,000 S/cm. In some embodiments, the conductive ink comprises a conductivity of at most about 19,000 S/cm, about 23,000 S/cm, about 27,000 S/cm, about 31,000 S/cm, about 35,000 S/cm, about 39,000 S/cm, about 43,000 S/cm, about 47,000 S/cm, about 51,000 S/cm, about 52,000 S/cm, or about 54,000 S/cm.

In some embodiments, the conductive ink comprises a conductivity of about 40000 S/cm. In some embodiments, the conductive ink comprises a conductivity of at least 15000 S/cm at a dry film thickness of about 10 μm. In some embodiments, the conductive ink comprises an average conductivity of about 40,000 S/cm at a dry film thickness of about 10 μm to about 50 μm. In some embodiments, the conductive ink comprises a conductivity of about 40,000 S/cm at a dry film thickness of about 10 μm to about 50 μm. In some embodiments, the conductive ink comprises a conductivity of at least 40,000 S/cm at a dry film thickness of about 10 μm to about 50 μm. In some embodiments, the ink comprises the claimed conductivity when cured at 300° C. for about 30 min.

In some embodiments, the ink comprises the claimed conductivity when applied with a film thickness of 10, 20, 50, 100, or 200 μm.

In some embodiments, the ink is applied at 110° C. into trace lines with a width from 300 μm to 3000 μm, and comprises an average conductivity of about 750000 S. In some embodiments, the ink is applied via screen printing.

In some embodiments, the ink comprises an average conductivity of about 750000 S and is applied at 110° C. into trace lines with a width from about 300 μm to about 3,000 μm. In some embodiments, the ink comprises an average conductivity of about 750000 S and is applied at 110 C into trace lines with a width from about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 um, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises an average conductivity of about 750000 S and is applied at 110 C into trace lines with a width from about 300 um, about 600 um, about 900 um, about 1,200 um, about 1,500 um, about 1,800 um, about 2,100 um, about 2,400 um, about 2,700 um, or about 3,000 μm. In some embodiments, the ink comprises an average conductivity of about 750000 S and is applied at 110 C into trace lines with a width from at least about 300 um, about 600 um, about 900 um, about 1,200 um, about 1,500 um, about 1,800 um, about 2,100 um, about 2,400 um, or about 2,700 μm. In some embodiments, the ink comprises an average conductivity of about 750000 S and is applied at 110 C into trace lines with a width from at most about 600 um, about 900 um, about 1,200 um, about 1,500 um, about 1,800 um, about 2,100 um, about 2,400 um, about 2,700 um, or about 3,000 μm. In some embodiments, the ink is applied at 110 C into trace lines with a width of at least 300 μm and comprises a conductivity of at least 666000 S. In some embodiments, the ink is applied via screen printing.

In some embodiments, the ink comprises a conductivity of at least 830000 S and is applied at 110 C into trace lines with a width of up to about 300 μm to about 3,000 μm. In some embodiments, the ink comprises a conductivity of at least 830000 S and is applied at 110 C into trace lines with a width of up to about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 μm, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises a conductivity of at least 830000 S and is applied at 110 C into trace lines with a width of up to about 300 um, about 600 um, about 900 um, about 1,200 um, about 1,500 um, about 1,800 um, about 2,100 um, about 2,400 um, about 2,700 um, or about 3,000 μm. In some embodiments, the ink comprises a conductivity of at least 830000 S and is applied at 110 C into trace lines with a width of up to at least about 300 um, about 600 um, about 900 um, about 1,200 um, about 1,500 um, about 1,800 um, about 2,100 um, about 2,400 um, or about 2,700 μm. In some embodiments, the ink comprises a conductivity of at least 830000 S and is applied at 110 C into trace lines with a width of up to at most about 600 um, about 900 um, about 1,200 um, about 1,500 um, about 1,800 um, about 2,100 um, about 2,400 um, about 2,700 um, or about 3,000 μm. In some embodiments, the ink is applied via screen printing.

In some embodiments, the ink comprises an average conductivity of about 1.42*10\hat{ }6 S and is applied at 300° C. into trace lines with a width from about 300 μm to about 3,000 μm. In some embodiments, the ink comprises an average conductivity of about 1.42*10\hat{ }6 S and is applied at 300° C. into trace lines with a width from about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 μm, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises an average conductivity of about 1.42*10\hat{ }6 S and is applied at 300° C. into trace lines with a width from about 300 um, about 600 um, about 900 um, about 1,200 um, about 1,500 um, about 1,800 um, about 2,100 um, about 2,400 um, about 2,700 um, or about 3,000 μm. In some embodiments, the ink comprises an average conductivity of about 10.42*10\hat{ }6 S and is applied at 300° C. into trace lines with a width from at least about 300 um, about 600 um, about 900 um, about 1,200 um, about 1,500 um, about 1,800 um, about 2,100 um, about 2,400 um, or about 2,700 μm. In some embodiments, the ink comprises an average conductivity of about 1.42*10\hat{ }6 S and is applied at 300° C. into trace lines with a width from at most about 600 um, about 900 um, about 1,200 um, about 1,500 um, about 1,800 um, about 2,100 um, about 2,400 um, about 2,700 um, or about 3,000 μm. In some embodiments, the ink is applied via screen printing.

In some embodiments, the ink is applied at 300° C. into trace lines with a width of at least 300 μm and comprises a conductivity of at least 10\hat{ }6 S. In some embodiments, the ink is applied via screen printing.

In some embodiments, the ink comprises a conductivity of at least 2*10\hat{ }6 S and is applied at 300° C. into trace lines with a width of up to about 300 μm to about 3,000 μm. In some embodiments, the ink comprises a conductivity of at least 2*10\hat{ }6 S and is applied at 300° C. into trace lines with a width of up to about 300 μm to about 600 um, about 300 μm to about 900 um, about 300 μm to about 1,200 um, about 300 μm to about 1,500 um, about 300 μm to about 1,800 um, about 300 μm to about 2,100 um, about 300 μm to about 2,400 um, about 300 μm to about 2,700 um, about 300 μm to about 3,000 um, about 600 μm to about 900 μm, about 600 μm to about 1,200 um, about 600 μm to about 1,500 um, about 600 μm to about 1,800 um, about 600 μm to about 2,100 um, about 600 μm to about 2,400 um, about 600 μm to about 2,700 um, about 600 μm to about 3,000 um, about 900 μm to about 1,200 um, about 900 μm to about 1,500 um, about 900 μm to about 1,800 um, about 900 μm to about 2,100 um, about 900 μm to about 2,400 um, about 900 μm to about 2,700 um, about 900 μm to about 3,000 um, about 1,200 μm to about 1,500 um, about 1,200 μm to about 1,800 um, about 1,200 μm to about 2,100 um, about 1,200 μm to about 2,400 um, about 1,200 μm to about 2,700 um, about 1,200 μm to about 3,000 um, about 1,500 μm to about 1,800 um, about 1,500 μm to about 2,100 um, about 1,500 μm to about 2,400 um, about 1,500 μm to about 2,700 um, about 1,500 μm to about 3,000 um, about 1,800 μm to about 2,100 um, about 1,800 μm to about 2,400 um, about 1,800 μm to about 2,700 um, about 1,800 μm to about 3,000 um, about 2,100 μm to about 2,400 um, about 2,100 μm to about 2,700 um, about 2,100 μm to about 3,000 um, about 2,400 μm to about 2,700 um, about 2,400 μm to about 3,000 um, or about 2,700 μm to about 3,000 um, including increments therein. In some embodiments, the ink comprises a conductivity of at least 2*10\hat{ }6 S and is applied at 300° C. into trace lines with a width of up to about 300 um, about 600 um, about 900 um, about 1,200 um, about 1,500 um, about 1,800 um, about 2,100 um, about 2,400 um, about 2,700 um, or about 3,000 μm. In some embodiments, the ink comprises a conductivity of at least 2*10\hat{ }6 S and is applied at 300° C. into trace lines with a width of up to at least about 300 um, about 600 um, about 900 um, about 1,200 um, about 1,500 um, about 1,800 um, about 2,100 um, about 2,400 um, or about 2,700 μm. In some embodiments, the ink comprises a conductivity of at least 2*10\hat{ }6 S and is applied at 300° C. into trace lines with a width of up to at most about 600 μm, about 900 μm, about 1,200 um, about 1,500 um, about 1,800 um, about 2,100 um, about 2,400 um, about 2,700 um, or about 3,000 μm. In some embodiments, the ink is applied via screen printing.

In some embodiments, the ink comprises flat morphology when screen printed, with an average deviation from the edge of the cured ink not exceeding 10 μm. In some embodiments, the ink comprises pores up to about 5 μm in average diameter.

In some embodiments, the ink comprises pores from about 2 μm in diameter to about 7 μm in diameter. In some embodiments, the ink comprises pores from about 2 μm in diameter to about 3 μm in diameter, about 2 μm in diameter to about 4 μm in diameter, about 2 μm in diameter to about 5 μm in diameter, about 2 μm in diameter to about 6 μm in diameter, about 2 μm in diameter to about 7 μm in diameter, about 3 μm in diameter to about 4 μm in diameter, about 3 μm in diameter to about 5 μm in diameter, about 3 μm in diameter to about 6 μm in diameter, about 3 μm in diameter to about 7 μm in diameter, about 4 μm in diameter to about 5 μm in diameter, about 4 μm in diameter to about 6 μm in diameter, about 4 μm in diameter to about 7 μm in diameter, about 5 μm in diameter to about 6 μm in diameter, about 5 μm in diameter to about 7 μm in diameter, or about 6 μm in diameter to about 7 μm in diameter, including increments therein. In some embodiments, the ink comprises pores from about 2 μm in diameter, about 3 μm in diameter, about 4 μm in diameter, about 5 μm in diameter, about 6 μm in diameter, or about 7 μm in diameter. In some embodiments, the ink comprises pores from at least about 2 μm in diameter, about 3 μm in diameter, about 4 μm in diameter, about 5 μm in diameter, or about 6 μm in diameter. In some embodiments, the ink comprises pores from at most about 3 μm in diameter, about 4 μm in diameter, about 5 μm in diameter, about 6 μm in diameter, or about 7 μm in diameter.

In some embodiments, the ink comprises channels throughout the cured ink connected by the pores. In some embodiments, the is applied as a continuous film. In some embodiments, the is applied as a continuous film or as a trace line on a substrate. In some embodiments, the substrate comprises silicon, PET, PI, Kapton, glass, or combinations thereof.

In some embodiments, the ink comprises pores up to about 1 μm in average diameter when cured to about 5 μm in average diameter when cured. In some embodiments, the ink comprises pores up to about 1 μm in average diameter when cured to about 2 μm in average diameter when cured, about 1 μm in average diameter when cured to about 3 μm in average diameter when cured, about 1 μm in average diameter when cured to about 4 μm in average diameter when cured, about 1 μm in average diameter when cured to about 5 μm in average diameter when cured, about 2 μm in average diameter when cured to about 3 μm in average diameter when cured, about 2 μm in average diameter when cured to about 4 μm in average diameter when cured, about 2 μm in average diameter when cured to about 5 μm in average diameter when cured, about 3 μm in average diameter when cured to about 4 μm in average diameter when cured, about 3 μm in average diameter when cured to about 5 μm in average diameter when cured, or about 4 μm in average diameter when cured to about 5 μm in average diameter when cured, including increments therein. In some embodiments, the ink comprises pores up to about 1 μm in average diameter when cured, about 2 μm in average diameter when cured, about 3 μm in average diameter when cured, about 4 μm in average diameter when cured, or about 5 μm in average diameter when cured. In some embodiments, the ink comprises pores up to at least about 1 μm in average diameter when cured, about 2 μm in average diameter when cured, about 3 μm in average diameter when cured, or about 4 μm in average diameter when cured. In some embodiments, the ink comprises pores up to at most about 2 μm in average diameter when cured, about 3 μm in average diameter when cured, about 4 μm in average diameter when cured, or about 5 μm in average diameter when cured.

In some embodiments, the ink comprises pores from about 2 μm in diameter when cured to about 7 μm in diameter when cured. In some embodiments, the ink comprises pores from about 2 μm in diameter when cured to about 3 μm in diameter when cured, about 2 μm in diameter when cured to about 4 μm in diameter when cured, about 2 μm in diameter when cured to about 5 μm in diameter when cured, about 2 μm in diameter when cured to about 6 μm in diameter when cured, about 2 μm in diameter when cured to about 7 μm in diameter when cured, about 3 μm in diameter when cured to about 4 μm in diameter when cured, about 3 μm in diameter when cured to about 5 μm in diameter when cured, about 3 μm in diameter when cured to about 6 μm in diameter when cured, about 3 μm in diameter when cured to about 7 μm in diameter when cured, about 4 μm in diameter when cured to about 5 μm in diameter when cured, about 4 μm in diameter when cured to about 6 μm in diameter when cured, about 4 μm in diameter when cured to about 7 μm in diameter when cured, about 5 μm in diameter when cured to about 6 μm in diameter when cured, about 5 μm in diameter when cured to about 7 μm in diameter when cured, or about 6 μm in diameter when cured to about 7 μm in diameter when cured, including increments therein. In some embodiments, the ink comprises pores from about 2 μm in diameter when cured, about 3 μm in diameter when cured, about 4 μm in diameter when cured, about 5 μm in diameter when cured, about 6 μm in diameter when cured, or about 7 μm in diameter when cured. In some embodiments, the ink comprises pores from at least about 2 μm in diameter when cured, about 3 μm in diameter when cured, about 4 μm in diameter when cured, about 5 μm in diameter when cured, or about 6 μm in diameter when cured. In some embodiments, the ink comprises pores from at most about 3 μm in diameter when cured, about 4 μm in diameter when cured, about 5 μm in diameter when cured, about 6 μm in diameter when cured, or about 7 μm in diameter when cured. In some embodiments, the ink comprises channels throughout the cured ink connected by the pores when cured.

In some embodiments, the conductive ink, when wet, has a w/w concentration of the dispersing agent of about 1% to about 20%. In some embodiments, the conductive ink, when wet, has a w/w concentration of the dispersing agent of about 1% to about 3%, about 1% to about 5%, about 1% to about 7%, about 1% to about 9%, about 1% to about 11%, about 1% to about 13%, about 1% to about 15%, about 1% to about 17%, about 1% to about 18%, about 1% to about 19%, about 1% to about 20%, about 3% to about 5%, about 3% to about 7%, about 3% to about 9%, about 3% to about 11%, about 3% to about 13%, about 3% to about 15%, about 3% to about 17%, about 3% to about 18%, about 3% to about 19%, about 3% to about 20%, about 5% to about 7%, about 5% to about 9%, about 5% to about 11%, about 5% to about 13%, about 5% to about 15%, about 5% to about 17%, about 5% to about 18%, about 5% to about 19%, about 5% to about 20%, about 7% to about 9%, about 7% to about 11%, about 7% to about 13%, about 7% to about 15%, about 7% to about 17%, about 7% to about 18%, about 7% to about 19%, about 7% to about 20%, about 9% to about 11%, about 9% to about 13%, about 9% to about 15%, about 9% to about 17%, about 9% to about 18%, about 9% to about 19%, about 9% to about 20%, about 11% to about 13%, about 11% to about 15%, about 11% to about 17%, about 11% to about 18%, about 11% to about 19%, about 11% to about 20%, about 13% to about 15%, about 13% to about 17%, about 13% to about 18%, about 13% to about 19%, about 13% to about 20%, about 15% to about 17%, about 15% to about 18%, about 15% to about 19%, about 15% to about 20%, about 17% to about 18%, about 17% to about 19%, about 17% to about 20%, about 18% to about 19%, about 18% to about 20%, or about 19% to about 20%, including increments therein. In some embodiments, the conductive ink, when wet, has a w/w concentration of the dispersing agent of about 1%, about 3%, about 5%, about 7%, about 9%, about 11%, about 13%, about 15%, about 17%, about 18%, about 19%, or about 20%. In some embodiments, the conductive ink, when wet, has a w/w concentration of the dispersing agent of at least about 1%, about 3%, about 5%, about 7%, about 9%, about 11%, about 13%, about 15%, about 17%, about 18%, or about 19%. In some embodiments, the conductive ink, when wet, has a w/w concentration of the dispersing agent of at most about 3%, about 5%, about 7%, about 9%, about 11%, about 13%, about 15%, about 17%, about 18%, about 19%, or about 20%.

In some embodiments, the silver nanoflakes are comprised in an amount of about 30% wt. to about 70% wt. In some embodiments, the silver nanoflakes are comprised in an amount of at least 30% wt. In some embodiments, the silver nanoflakes are comprised in an amount up to 70% wt. In some embodiments, the silver nanoflakes are comprised in an amount of about 55% wt. to about 65% wt. In some embodiments, the silver nanoflakes are comprised in an amount of about 62.5% wt. In some embodiments, the ink comprises silver content of about 84% wt. when cured. In some embodiments, the ink comprises silver content of about 80% wt. to about 90% wt. when cured. In some embodiments, the ink comprises silver content of at least 80% wt. when cured. In some embodiments, the ink comprises silver content of up to 90% wt. when cured.

In some embodiments, the silver nanoflakes range from about 8 μm to about 21 μm in diameter. In some embodiments, the silver nanoflakes comprise an average particle diameter distribution of 12 μm to 16 μm. In some embodiments, the silver nanoflakes comprise an average particle diameter distribution of about 14.34 μm. In some embodiments, the silver nanoflakes comprise a median particle diameter of about 14.6 μm. In some embodiments, the silver nanoflakes comprise a D10 diameter of about 8.14 μm. In some embodiments, the silver nanoflakes comprise a D90 diameter of about 20.3 μm. In some embodiments, the ink does not show streaks when printed with a diameter of up to 20 μm.

In some embodiments, the ink does not show streaks when printed with a diameter of about 1 μm to about 20 μm. In some embodiments, the ink does not show streaks when printed with a diameter of about 1 μm to about 3 μm, about 1 μm to about 5 μm, about 1 μm to about 7 μm, about 1 μm to about 9 μm, about 1 μm to about 11 μm, about 1 μm to about 13 μm, about 1 μm to about 15 μm, about 1 μm to about 17 μm, about 1 μm to about 18 μm, about 1 μm to about 19 μm, about 1 μm to about 20 μm, about 3 μm to about 5 μm, about 3 μm to about 7 μm, about 3 μm to about 9 μm, about 3 μm to about 11 μm, about 3 μm to about 13 μm, about 3 μm to about 15 μm, about 3 μm to about 17 μm, about 3 μm to about 18 μm, about 3 μm to about 19 μm, about 3 μm to about 20 μm, about 5 μm to about 7 μm, about 5 μm to about 9 μm, about 5 μm to about 11 μm, about 5 μm to about 13 μm, about 5 μm to about 15 μm, about 5 μm to about 17 μm, about 5 μm to about 18 μm, about 5 μm to about 19 μm, about 5 μm to about 20 μm, about 7 μm to about 9 μm, about 7 μm to about 11 μm, about 7 μm to about 13 μm, about 7 μm to about 15 μm, about 7 μm to about 17 μm, about 7 μm to about 18 μm, about 7 μm to about 19 μm, about 7 μm to about 20 μm, about 9 μm to about 11 μm, about 9 μm to about 13 μm, about 9 μm to about 15 μm, about 9 μm to about 17 μm, about 9 μm to about 18 μm, about 9 μm to about 19 μm, about 9 μm to about 20 μm, about 11 μm to about 13 μm, about 11 μm to about 15 μm, about 11 μm to about 17 μm, about 11 μm to about 18 μm, about 11 μm to about 19 μm, about 11 μm to about 20 μm, about 13 μm to about 15 μm, about 13 μm to about 17 μm, about 13 μm to about 18 μm, about 13 μm to about 19 μm, about 13 μm to about 20 μm, about 15 μm to about 17 μm, about 15 μm to about 18 μm, about 15 μm to about 19 μm, about 15 μm to about 20 μm, about 17 μm to about 18 μm, about 17 μm to about 19 μm, about 17 μm to about 20 μm, about 18 μm to about 19 μm, about 18 μm to about 20 μm, or about 19 μm to about 20 μm, including increments therein. In some embodiments, the ink does not show streaks when printed with a diameter of about 1 μm, about 3 μm, about 5 μm, about 7 μm, about 9 μm, about 11 μm, about 13 μm, about 15 μm, about 17 μm, about 18 μm, about 19 μm, or about 20 μm. In some embodiments, the ink does not show streaks when printed with a diameter of at least about 1 μm, about 3 μm, about 5 μm, about 7 μm, about 9 μm, about 11 μm, about 13 μm, about 15 μm, about 17 μm, about 18 μm, or about 19 μm. In some embodiments, the ink does not show streaks when printed with a diameter of at most about 3 μm, about 5 μm, about 7 μm, about 9 μm, about 11 μm, about 13 μm, about 15 μm, about 17 μm, about 18 μm, about 19 μm, or about 20 μm. μμ

In some embodiments, the binder comprises Poly Vinyl Pyrrolidone, a thermoplastic copolymers, Paraloid B72, Paraloid B66, or combinations thereof. In some embodiments, the binder comprises Poly Vinyl Pyrrolidone, and at least one of Paraloid B72, and Paraloid B66. In some embodiments, the binder comprises Poly Vinyl Pyrrolidone, and Paraloid B72, and Paraloid B66. In some embodiments, the binder comprises Poly Vinyl Pyrrolidone 10k, Poly Vinyl Pyrrolidone 15k, Poly Vinyl Pyrrolidone 29k, Poly Vinyl Pyrrolidone 360k, or Poly Vinyl Pyrrolidone 120k, referring to the average molecular weight to the Poly Vinyl Pyrrolidone polymer. In some embodiments, the binder comprises Poly Vinyl Pyrrolidone in an amount of about 10.5% wt. In some embodiments, the binder comprises Poly Vinyl Pyrrolidone 15k in an amount of about 10.5% wt. In some embodiments, the binder comprises Poly Vinyl Pyrrolidone in an amount of about 8% wt. to about 12% wt. In some embodiments, the binder comprises Poly Vinyl Pyrrolidone 15k in an amount of about 8% wt. to about 12% wt. In some embodiments, the binder comprises Poly Vinyl Pyrrolidone in an amount of at least 5% wt. In some embodiments, the binder comprises Poly Vinyl Pyrrolidone in an amount up to 20% wt. In some embodiments, the Poly Vinyl Pyrrolidone is PVP 15k. In some embodiments, the solvent comprises Dowanol PnP, 2-ethyl-1-hexanol, DEGBE, 2-ethyl-1-butanol, 2-methyl-1-pentanol, PGMEA, Hexamine, Cycloheptylamine, Isoamyl amine, 3-Methoxypropylamine, PCBTF, ethylene glycol, isopropanol, ethyl acetate, chloroform, DMF, NMP, THF, dichlorobenzene, or combinations thereof. In some embodiments, the solvent comprises Propylene glycol propyl ether. In some embodiments, the solvent comprises 2-ethyl-1-hexanol. In some embodiments, the solvent comprises Propylene glycol propyl ether, and 2-ethyl-1-hexanol. In some embodiments, the solvent is comprised in an amount of about 10% wt. to about 90% wt. In some embodiments, the solvent comprises Propylene glycol propyl ether in an amount of about 15% wt. In some embodiments, the solvent comprises Propylene glycol propyl ether in an amount of about 13% wt. to 17% wt. In some embodiments, the solvent comprises Propylene glycol propyl ether in an amount of at least 10% wt. In some embodiments, the solvent comprises Propylene glycol propyl ether in an amount up to 20% wt. In some embodiments, the solvent comprises Propylene glycol propyl ether in an amount up to 90% wt. In some embodiments, the reduced graphene oxide sheets are comprised in an amount of about 0.5% wt. In some embodiments, the reduced graphene oxide sheets are comprised in an amount from about 0.1% wt. to about 2% wt. In some embodiments, the reduced graphene oxide sheets are comprised in an amount from about 0.3% wt. to about 0.7% wt. In some embodiments, the reduced graphene oxide sheets are comprised in an amount of at least 0.3% wt. In some embodiments, the reduced graphene oxide sheets are comprised in an amount of up to about 1% wt. In some embodiments, the ink comprises a solid content of about 75% wt. In some embodiments, the ink comprises a solid content of about 70% wt. to 80% wt. In some embodiments, the ink comprises a solid content of at least 70% wt. In some embodiments, the ink comprises a solid content up to 80% wt. In some embodiments, the ink comprises a viscosity from about 1000 cP to about 10000 cP. In some embodiments, the ink comprises a viscosity of 4000 cP to about 10000 cP. In some embodiments, the ink comprises a viscosity of at least 4500 cP. In some embodiments, the ink comprises a viscosity of at least 4500 cP at 200 s\hat{ }−1 at 25° C. In some embodiments, the ink comprises a viscosity of at least 10000 cP at 100 s\hat{ }−1 at 25° C. In some embodiments, the ink comprises a viscosity of at least 12000 cP at 100 s\hat{ }−1 at 25° C. In some embodiments, the ink is a shear thinning fluid. In some embodiments, the method further comprises applying the conductive ink to a substrate via screen printing, extruder printing, flexography application, slot-die application, knife-over-edge coating application. In some embodiments, the method further comprises applying the conductive ink to a substrate via screen printing. In some embodiments, the ink does not leave pin holes when applied. In some embodiments, the ink does not separate when cured. In some embodiments, the ink does not shrink when cured. In some embodiments, the ink does not reduce its surface area when cured. In some embodiments, the ink has a wet film thickness, which is less than a wet film thickness. In some embodiments, a change in dry film thickness correlates to a change in wet film thickness with a differential of about 0.5. In some embodiments, the ink is adhesive. In some embodiments, the ink comprises a 5B adhesion on PET, PI, Kapton, or glass. In some embodiments, the ink is stable at room temperature, e.g., 20° C.-25° C. In some embodiments, the ink cures at 300° C. In some embodiments, the ink cures at 300° C. within about 30 m. In some embodiments, the ink comprises a sheet resistance of at least 0.017 ohms/sq. In some embodiments, the ink comprises a sheet resistance of up to 0.084 ohms/sq. In some embodiments, the ink comprises a sheet resistance of up to 0.08 ohms/sq at a dry film thickness of about 20 μm. In some embodiments, the ink comprises a sheet resistance of up to 0.025 ohms/sq at a dry film thickness of about 30 μm. In some embodiments, the ink comprises a sheet resistance of up to 0.028 ohms/sq at a dry film thickness of about 36 μm. In some embodiments, the ink comprises a sheet resistance of up to 0.027 ohms/sq at a dry film thickness of about 40 μm. In some embodiments, the ink comprises a sheet resistance of up to 0.023 ohms/sq at a dry film thickness of about 65 μm. In some embodiments, the ink comprises a sheet resistance of up to 0.017 ohms/sq at a dry film thickness of about 90 μm. In some embodiments, the ink comprises a sheet resistance of up to 90 ohms/sq at a dry film thickness of about 200 μm. In some embodiments, the ink comprises a sheet resistance of about 0.025 at a range of dry film thicknesses from about 30 μm to about 36 μm. In some embodiments, the ink comprises a conductivity of about 6300 S/cm to about 15000 S/cm. In some embodiments, the ink comprises a conductivity of at least 6300 S/cm at a dry film thickness of about 10 μm. In some embodiments, the ink comprises a conductivity of about 10000 S/cm at a dry film thickness of from about 10 μm to about 50 μm. In some embodiments, the ink comprises an average conductivity of about 10000 S/cm at a dry film thickness of from about 10 μm to about 50 μm. In some embodiments, the ink comprises a conductivity of at least 10000 S/cm at a dry film thickness of from about 10 μm to about 50 μm. In some embodiments, the ink comprises the claimed conductivity when cured at 110° C. In some embodiments, the ink comprises the claimed conductivity when cured at 110 C for about 30 min. In some embodiments, the ink comprises a conductivity of up to 54000 S/cm at a dry film thickness of about 100 μm. In some embodiments, the ink comprises a conductivity of about 15000 S/cm to about 54000 S/cm. In some embodiments, the ink comprises a conductivity of about 40000 S/cm. In some embodiments, the ink comprises a conductivity of at least 15000 S/cm at a dry film thickness of about 10 μm. In some embodiments, the ink comprises a conductivity of about 40000 S/cm at a dry film thickness of from about 10 μm to about 50 μm. In some embodiments, the ink comprises an average conductivity of about 40000 S/cm at a dry film thickness of from about 10 μm to about 50 μm. In some embodiments, the ink comprises a conductivity of at least 40000 S/cm at a dry film thickness of from about 10 μm to about 50 μm. In some embodiments, the ink comprises the claimed conductivity when cured at 300° C. In some embodiments, the ink comprises the claimed conductivity when cured at 300° C. for about 30 min. In some embodiments, the ink comprises the conductivity of any of the preceding claims when applied with a film thickness of 10, 20, 50, 100, or 200 μm. In some embodiments, the ink is applied at 110° C. into trace lines with a width from 300 μm to 3000 μm, and comprises an average conductivity of about 750000 S. In some embodiments, the ink is applied at 110° C. into trace lines with a width of at least 300 μm and comprises a conductivity of at least 666000 S. In some embodiments, the ink is applied at 110° C. into trace lines with a width of up to 3000 μm and comprises a conductivity of at least 830000 S. In some embodiments, the ink is applied at 300° C. into trace lines with a width from 300 μm to 3000 μm, and comprises an average conductivity of about 1.42*10\hat{ }6 S. In some embodiments, the ink is applied at 300° C. into trace lines with a width of at least 300 μm and comprises a conductivity of at least 10\hat{ }6 S. In some embodiments, the ink is applied at 300° C. into trace lines with a width of up to 3000 μm and comprises a conductivity of at least 2*10\hat{ }6 S. In some embodiments, the ink comprises flat morphology when screen printed, with an average deviation from the edge of the cured ink not exceeding 10 μm. In some embodiments, the ink comprises pores up to about 5 μm in average diameter upon curing. In some embodiments, the ink comprises pores from about 2 μm to about 7 μm in diameter upon curing. In some embodiments, the ink comprises channels throughout the cured ink connected by the pores upon curing. In some embodiments, the ink is applied via screen printing.

### Method—Reduced Graphene Oxide

The reduced graphene oxide (rGO) used to form the conductive inks herein can be easily dispersed and processed from a wide range of solvents and enabling conductive inks with tunable electronic and mechanical properties for a wide range of applications.

FIG. 1A and FIG. 1B are first and second Scanning Electron Microscope (SEM) images of exemplary reduced graphene oxide sheets coated onto a silicon wafer.

FIG. 2A and FIG. 2B are first and second Atomic Force Microscopy images of exemplary reduced graphene oxide sheets coated onto freshly cleaved mica substrates.

The images also show the individual layers of carbon and show wrinkles and creases in the basal planes, which is characteristic of graphene.

In some embodiments, the reduced graphene oxide sheets are comprised in an amount of about 0.5% wt. In some embodiments, the reduced graphene oxide sheets are comprised in an amount of about 0.5% wt.

In some embodiments, the reduced graphene oxide sheets are comprised in an amount about 0.1% wt to about 2.1% wt. In some embodiments, the reduced graphene oxide sheets are comprised in an amount about 0.1% wt to about 0.3% wt, about 0.1% wt to about 0.5% wt, about 0.1% wt to about 0.7% wt, about 0.1% wt to about 0.9% wt, about 0.1% wt to about 1.1% wt, about 0.1% wt to about 1.3% wt, about 0.1% wt to about 1.5% wt, about 0.1% wt to about 1.7% wt, about 0.1% wt to about 1.9% wt, about 0.1% wt to about 2% wt, about 0.1% wt to about 2.1% wt, about 0.3% wt to about 0.5% wt, about 0.3% wt to about 0.7% wt, about 0.3% wt to about 0.9% wt, about 0.3% wt to about 1.1% wt, about 0.3% wt to about 1.3% wt, about 0.3% wt to about 1.5% wt, about 0.3% wt to about 1.7% wt, about 0.3% wt to about 1.9% wt, about 0.3% wt to about 2% wt, about 0.3% wt to about 2.1% wt, about 0.5% wt to about 0.7% wt, about 0.5% wt to about 0.9% wt, about 0.5% wt to about 1.1% wt, about 0.5% wt to about 1.3% wt, about 0.5% wt to about 1.5% wt, about 0.5% wt to about 1.7% wt, about 0.5% wt to about 1.9% wt, about 0.5% wt to about 2% wt, about 0.5% wt to about 2.1% wt, about 0.7% wt to about 0.9% wt, about 0.7% wt to about 1.1% wt, about 0.7% wt to about 1.3% wt, about 0.7% wt to about 1.5% wt, about 0.7% wt to about 1.7% wt, about 0.7% wt to about 1.9% wt, about 0.7% wt to about 2% wt, about 0.7% wt to about 2.1% wt, about 0.9% wt to about 1.1% wt, about 0.9% wt to about 1.3% wt, about 0.9% wt to about 1.5% wt, about 0.9% wt to about 1.7% wt, about 0.9% wt to about 1.9% wt, about 0.9% wt to about 2% wt, about 0.9% wt to about 2.1% wt, about 1.1% wt to about 1.3% wt, about 1.1% wt to about 1.5% wt, about 1.1% wt to about 1.7% wt, about 1.1% wt to about 1.9% wt, about 1.1% wt to about 2% wt, about 1.1% wt to about 2.1% wt, about 1.3% wt to about 1.5% wt, about 1.3% wt to about 1.7% wt, about 1.3% wt to about 1.9% wt, about 1.3% wt to about 2% wt, about 1.3% wt to about 2.1% wt, about 1.5% wt to about 1.7% wt, about 1.5% wt to about 1.9% wt, about 1.5% wt to about 2% wt, about 1.5% wt to about 2.1% wt, about 1.7% wt to about 1.9% wt, about 1.7% wt to about 2% wt, about 1.7% wt to about 2.1% wt, about 1.9% wt to about 2% wt, about 1.9% wt to about 2.1% wt, or about 2% wt to about 2.1% wt, including increments therein. In some embodiments, the reduced graphene oxide sheets are comprised in an amount of about 0.1% wt, about 0.3% wt, about 0.5% wt, about 0.7% wt, about 0.9% wt, about 1.1% wt, about 1.3% wt, about 1.5% wt, about 1.7% wt, about 1.9% wt, about 2% wt, or about 2.1% wt. In some embodiments, the reduced graphene oxide sheets are comprised in an amount at least about 0.1% wt, about 0.3% wt, about 0.5% wt, about 0.7% wt, about 0.9% wt, about 1.1% wt, about 1.3% wt, about 1.5% wt, about 1.7% wt, about 1.9% wt, or about 2% wt. In some embodiments, the reduced graphene oxide sheets are comprised in an amount at most about 0.3% wt, about 0.5% wt, about 0.7% wt, about 0.9% wt, about 1.1% wt, about 1.3% wt, about 1.5% wt, about 1.7% wt, about 1.9% wt, about 2% wt, or about 2.1% wt.

In some embodiments, the reduced graphene oxide sheets are comprised in an amount of about 0.3% wt. to about 0.7% wt. In some embodiments, the reduced graphene oxide sheets are comprised in an amount about 0.3% wt. to about 0.4% wt., about 0.3% wt. to about 0.5% wt., about 0.3% wt. to about 0.6% wt., about 0.3% wt. to about 0.7% wt., about 0.4% wt. to about 0.5% wt., about 0.4% wt. to about 0.6% wt., about 0.4% wt. to about 0.7% wt., about 0.5% wt. to about 0.6% wt., about 0.5% wt. to about 0.7% wt., or about 0.6% wt. to about 0.7% wt., including increments therein. In some embodiments, the reduced graphene oxide sheets are comprised in an amount about 0.3% wt., about 0.4% wt., about 0.5% wt., about 0.6% wt., or about 0.7% wt. In some embodiments, the reduced graphene oxide sheets are comprised in an amount at least about 0.3% wt., about 0.4% wt., about 0.5% wt., or about 0.6% wt. In some embodiments, the reduced graphene oxide sheets are comprised in an amount at most about 0.4% wt., about 0.5% wt., about 0.6% wt., or about 0.7% wt.

In some embodiments, the reduced graphene oxide sheets are comprised in an amount of up to about 1% wt. In some embodiments, the reduced graphene oxide sheets are comprised in an amount of at least 0.3% wt. In some embodiments, the reduced graphene oxide sheets are comprised in an amount of about 0.5% wt.

### Method—Silver Nanoflakes

In some embodiments, the silver nanoflakes are comprised in an amount of about 30% to about 85%. In some embodiments, the silver nanoflakes are comprised in an amount of about 30% to about 35%, about 30% to about 40%, about 30% to about 45%, about 30% to about 50%, about 30% to about 55%, about 30% to about 60%, about 30% to about 65%, about 30% to about 70%, about 30% to about 75%, about 30% to about 80%, about 30% to about 85%, about 35% to about 40%, about 35% to about 45%, about 35% to about 50%, about 35% to about 55%, about 35% to about 60%, about 35% to about 65%, about 35% to about 70%, about 35% to about 75%, about 35% to about 80%, about 35% to about 85%, about 40% to about 45%, about 40% to about 50%, about 40% to about 55%, about 40% to about 60%, about 40% to about 65%, about 40% to about 70%, about 40% to about 75%, about 40% to about 80%, about 40% to about 85%, about 45% to about 50%, about 45% to about 55%, about 45% to about 60%, about 45% to about 65%, about 45% to about 70%, about 45% to about 75%, about 45% to about 80%, about 45% to about 85%, about 50% to about 55%, about 50% to about 60%, about 50% to about 65%, about 50% to about 70%, about 50% to about 75%, about 50% to about 80%, about 50% to about 85%, about 55% to about 60%, about 55% to about 65%, about 55% to about 70%, about 55% to about 75%, about 55% to about 80%, about 55% to about 85%, about 60% to about 65%, about 60% to about 70%, about 60% to about 75%, about 60% to about 80%, about 60% to about 85%, about 65% to about 70%, about 65% to about 75%, about 65% to about 80%, about 65% to about 85%, about 70% to about 75%, about 70% to about 80%, about 70% to about 85%, about 75% to about 80%, about 75% to about 85%, or about 80% to about 85%, including increments therein. In some embodiments, the silver nanoflakes are comprised in an amount of about 30%, about 35%, about 40%, about 45%, about 50%, about 55%, about 60%, about 65%, about 70%, about 75%, about 80%, or about 85%. In some embodiments, the silver nanoflakes are comprised in an amount of at least about 30%, about 35%, about 40%, about 45%, about 50%, about 55%, about 60%, about 65%, about 70%, about 75%, or about 80%. In some embodiments, the silver nanoflakes are comprised in an amount of at most about 35%, about 40%, about 45%, about 50%, about 55%, about 60%, about 65%, about 70%, about 75%, about 80%, or about 85%.

In some embodiments, the silver nanoflakes comprise a diameter from about 8 μm to about 21 μm. In some embodiments, the silver nanoflakes comprise a diameter from about 8 μm to about 9 μm, about 8 μm to about 10 μm, about 8 μm to about 11 μm, about 8 μm to about 12 μm, about 8 μm to about 13 μm, about 8 μm to about 14 μm, about 8 μm to about 15 μm, about 8 μm to about 16 μm, about 8 μm to about 17 μm, about 8 μm to about 18 μm, about 8 μm to about 19 μm, about 8 μm to about 20 μm, about 8 μm to about 21 μm, about 9 μm to about 10 μm, about 9 μm to about 11 μm, about 9 μm to about 12 μm, about 9 μm to about 13 μm, about 9 μm to about 14 μm, about 9 μm to about 15 μm, about 9 μm to about 16 μm, about 9 μm to about 17 μm, about 9 μm to about 18 μm, about 9 μm to about 19 μm, about 9 μm to about 20 μm, about 9 μm to about 21 μm, about 10 μm to about 11 μm, about 10 μm to about 12 μm, about 10 μm to about 13 μm, about 10 μm to about 14 μm, about 10 μm to about 15 μm, about 10 μm to about 16 μm, about 10 μm to about 17 μm, about 10 μm to about 18 μm, about 10 μm to about 19 μm, about 10 μm to about 20 μm, about 10 μm to about 21 μm, about 11 μm to about 12 μm, about 11 μm to about 13 μm, about 11 μm to about 14 μm, about 11 μm to about 15 μm, about 11 μm to about 16 μm, about 11 μm to about 17 μm, about 11 μm to about 18 μm, about 11 μm to about 19 μm, about 11 μm to about 20 μm, about 11 μm to about 21 μm, about 12 μm to about 13 μm, about 12 μm to about 14 μm, about 12 μm to about 15 μm, about 12 μm to about 16 μm, about 12 μm to about 17 μm, about 12 μm to about 18 μm, about 12 μm to about 19 μm, about 12 μm to about 20 μm, about 12 μm to about 21 μm, about 13 μm to about 14 μm, about 13 μm to about 15 μm, about 13 μm to about 16 μm, about 13 μm to about 17 μm, about 13 μm to about 18 μm, about 13 μm to about 19 μm, about 13 μm to about 20 μm, about 13 μm to about 21 μm, about 14 μm to about 15 μm, about 14 μm to about 16 μm, about 14 μm to about 17 μm, about 14 μm to about 18 μm, about 14 μm to about 19 μm, about 14 μm to about 20 μm, about 14 μm to about 21 μm, about 15 μm to about 16 μm, about 15 μm to about 17 μm, about 15 μm to about 18 μm, about 15 μm to about 19 μm, about 15 μm to about 20 μm, about 15 μm to about 21 μm, about 16 μm to about 17 μm, about 16 μm to about 18 μm, about 16 μm to about 19 μm, about 16 μm to about 20 μm, about 16 μm to about 21 μm, about 17 μm to about 18 μm, about 17 μm to about 19 μm, about 17 μm to about 20 μm, about 17 μm to about 21 μm, about 18 μm to about 19 μm, about 18 μm to about 20 μm, about 18 μm to about 21 μm, about 19 μm to about 20 μm, about 20 μm to about 21 μm, or about 20 μm to about 21 μm, including increments therein. In some embodiments, the silver nanoflakes comprise a diameter from about 8 μm, about 9 μm, about 10 μm, about 11 μm, about 12 μm, about 13 μm, about 14 μm, about 15 μm, about 16 μm, about 17 μm, about 18 μm, about 19 μm, about 20 μm, or about 21 μm. In some embodiments, the silver nanoflakes comprise a diameter from at least about 8 μm, about 9 μm, about 10 μm, about 11 μm, about 12 μm, about 13 μm, about 14 μm, about 15 μm, about 16 μm, about 17 μm, about 18 μm, about 19 μm, or about 20 μm. In some embodiments, the silver nanoflakes comprise a diameter from at most about 9 μm, about 10 μm, about 11 μm, about 12 μm, about 13 μm, about 14 μm, about 15 μm, about 16 μm, about 17 μm, about 18 μm, about 19 μm, about 20 μm, or about 21 μm.

In some embodiments, the silver nanoflakes comprise an average particle diameter distribution of about 12 μm to about 16 μm. In some embodiments, the silver nanoflakes comprise an average particle diameter distribution of about 12 μm to about 12.5 μm, about 12 μm to about 13 μm, about 12 μm to about 13.5 μm, about 12 μm to about 14 μm, about 12 μm to about 14.5 μm, about 12 μm to about 15 μm, about 12 μm to about 15.6 μm, about 12 μm to about 16 μm, about 12.5 μm to about 13 μm, about 12.5 μm to about 13.5 μm, about 12.5 μm to about 14 μm, about 12.5 μm to about 14.5 μm, about 12.5 μm to about 15 μm, about 12.5 μm to about 15.6 μm, about 12.5 μm to about 16 μm, about 13 μm to about 13.5 μm, about 13 μm to about 14 μm, about 13 μm to about 14.5 μm, about 13 μm to about 15 μm, about 13 μm to about 15.6 μm, about 13 μm to about 16 μm, about 13.5 μm to about 14 μm, about 13.5 μm to about 14.5 μm, about 13.5 μm to about 15 μm, about 13.5 μm to about 15.6 μm, about 13.5 μm to about 16 μm, about 14 μm to about 14.5 μm, about 14 μm to about 15 μm, about 14 μm to about 15.6 μm, about 14 μm to about 16 μm, about 14.5 μm to about 15 μm, about 14.5 μm to about 15.6 μm, about 14.5 μm to about 16 μm, about 15 μm to about 15.6 μm, about 15 μm to about 16 μm, or about 15.6 μm to about 16 μm, including increments therein. In some embodiments, the silver nanoflakes comprise an average particle diameter distribution of about 12 μm, about 12.5 μm, about 13 μm, about 13.5 μm, about 14 μm, about 14.5 μm, about 15 μm, about 15.6 μm, or about 16 μm. In some embodiments, the silver nanoflakes comprise an average particle diameter distribution of at least about 12 μm, about 12.5 μm, about 13 μm, about 13.5 μm, about 14 μm, about 14.5 μm, about 15 μm, or about 15.6 μm. In some embodiments, the silver nanoflakes comprise an average particle diameter distribution of at most about 12.5 μm, about 13 μm, about 13.5 μm, about 14 μm, about 14.5 μm, about 15 μm, about 15.6 μm, or about 16 μm.

In some embodiments, the silver nanoflakes comprise an average particle diameter distribution of about 14.34 μm. In some embodiments, the silver nanoflakes comprise a median particle diameter of about 14.6 μm. In some embodiments, the silver nanoflakes comprise a D10 diameter of about 8.14 μm. In some embodiments, the silver nanoflakes comprise a D90 diameter of about 20.3 μm.

In some embodiments, the ink does not show streaks when printed with a diameter of up to 20 μm.

In some embodiments, the ink does not show streaks when printed with a diameter of about 1 μm to about 20 μm. In some embodiments, the ink does not show streaks when printed with a diameter of about 1 μm to about 3 μm, about 1 μm to about 5 μm, about 1 μm to about 7 μm, about 1 μm to about 9 μm, about 1 μm to about 11 μm, about 1 μm to about 13 μm, about 1 μm to about 15 μm, about 1 μm to about 17 μm, about 1 μm to about 18 μm, about 1 μm to about 19 μm, about 1 μm to about 20 μm, about 3 μm to about 5 μm, about 3 μm to about 7 μm, about 3 μm to about 9 μm, about 3 μm to about 11 μm, about 3 μm to about 13 μm, about 3 μm to about 15 μm, about 3 μm to about 17 μm, about 3 μm to about 18 μm, about 3 μm to about 19 μm, about 3 μm to about 20 μm, about 5 μm to about 7 μm, about 5 μm to about 9 μm, about 5 μm to about 11 μm, about 5 μm to about 13 μm, about 5 μm to about 15 μm, about 5 μm to about 17 μm, about 5 μm to about 18 μm, about 5 μm to about 19 μm, about 5 μm to about 20 μm, about 7 μm to about 9 μm, about 7 μm to about 11 μm, about 7 μm to about 13 μm, about 7 μm to about 15 μm, about 7 μm to about 17 μm, about 7 μm to about 18 μm, about 7 μm to about 19 μm, about 7 μm to about 20 μm, about 9 μm to about 11 μm, about 9 μm to about 13 μm, about 9 μm to about 15 μm, about 9 μm to about 17 μm, about 9 μm to about 18 μm, about 9 μm to about 19 μm, about 9 μm to about 20 μm, about 11 μm to about 13 μm, about 11 μm to about 15 μm, about 11 μm to about 17 μm, about 11 μm to about 18 μm, about 11 μm to about 19 μm, about 11 μm to about 20 μm, about 13 μm to about 15 μm, about 13 μm to about 17 μm, about 13 μm to about 18 μm, about 13 μm to about 19 μm, about 13 μm to about 20 μm, about 15 μm to about 17 μm, about 15 μm to about 18 μm, about 15 μm to about 19 μm, about 15 μm to about 20 μm, about 17 μm to about 18 μm, about 17 μm to about 19 μm, about 17 μm to about 20 μm, about 18 μm to about 19 μm, about 18 μm to about 20 μm, or about 19 μm to about 20 μm, including increments therein. In some embodiments, the ink does not show streaks when printed with a diameter of about 1 μm, about 3 μm, about 5 μm, about 7 μm, about 9 μm, about 11 μm, about 13 μm, about 15 μm, about 17 μm, about 18 μm, about 19 μm, or about 20 μm. In some embodiments, the ink does not show streaks when printed with a diameter of at least about 1 μm, about 3 μm, about 5 μm, about 7 μm, about 9 μm, about 11 μm, about 13 μm, about 15 μm, about 17 μm, about 18 μm, or about 19 μm. In some embodiments, the ink does not show streaks when printed with a diameter of at most about 3 μm, about 5 μm, about 7 μm, about 9 μm, about 11 μm, about 13 μm, about 15 μm, about 17 μm, about 18 μm, about 19 μm, or about 20 μm.

In some embodiments, the ink comprises silver content of about 84% wt. when cured. In some embodiments, the ink comprises silver content of about 80% wt. to about 90% wt. when cured. In some embodiments, the ink comprises silver content of at least 80% wt. when cured. In some embodiments, the ink comprises silver content of up to 90% wt. when cured.

In some embodiments, the ink comprises silver content of about 80% wt to about 89% wt. In some embodiments, the ink comprises silver content of about 80% wt to about 81% wt, about 80% wt to about 82% wt, about 80% wt to about 83% wt, about 80% wt to about 84% wt, about 80% wt to about 85% wt, about 80% wt to about 86% wt, about 80% wt to about 87% wt, about 80% wt to about 88% wt, about 80% wt to about 89% wt, about 80% wt to about 80% wt, about 81% wt to about 82% wt, about 81% wt to about 83% wt, about 81% wt to about 84% wt, about 81% wt to about 85% wt, about 81% wt to about 86% wt, about 81% wt to about 87% wt, about 81% wt to about 88% wt, about 81% wt to about 89% wt, about 81% wt to about 80% wt, about 82% wt to about 83% wt, about 82% wt to about 84% wt, about 82% wt to about 85% wt, about 82% wt to about 86% wt, about 82% wt to about 87% wt, about 82% wt to about 88% wt, about 82% wt to about 89% wt, about 82% wt to about 80% wt, about 83% wt to about 84% wt, about 83% wt to about 85% wt, about 83% wt to about 86% wt, about 83% wt to about 87% wt, about 83% wt to about 88% wt, about 83% wt to about 89% wt, about 83% wt to about 80% wt, about 84% wt to about 85% wt, about 84% wt to about 86% wt, about 84% wt to about 87% wt, about 84% wt to about 88% wt, about 84% wt to about 89% wt, about 84% wt to about 80% wt, about 85% wt to about 86% wt, about 85% wt to about 87% wt, about 85% wt to about 88% wt, about 85% wt to about 89% wt, about 85% wt to about 80% wt, about 86% wt to about 87% wt, about 86% wt to about 88% wt, about 86% wt to about 89% wt, about 86% wt to about 80% wt, about 87% wt to about 88% wt, about 87% wt to about 89% wt, about 87% wt to about 80% wt, about 88% wt to about 89% wt, about 88% wt to about 80% wt, or about 89% wt to about 80% wt, including increments therein. In some embodiments, the ink comprises silver content of about 80% wt, about 81% wt, about 82% wt, about 83% wt, about 84% wt, about 85% wt, about 86% wt, about 87% wt, about 88% wt, about 89% wt, or about 80% wt. In some embodiments, the ink comprises silver content of at least about 80% wt, about 81% wt, about 82% wt, about 83% wt, about 84% wt, about 85% wt, about 86% wt, about 87% wt, about 88% wt, or about 89% wt. In some embodiments, the ink comprises silver content of at most about 81% wt, about 82% wt, about 83% wt, about 84% wt, about 85% wt, about 86% wt, about 87% wt, about 88% wt, about 89% wt, or about 80% wt.

In some embodiments, the combination of silver flakes and ultra-graphene results in an increase in conductivity of the conductive ink by at least about 1,000 S/cm to about 6,500 S/cm. In some embodiments, the combination of silver flakes and ultra-graphene results in an increase in conductivity of the conductive ink by at least about 1,000 S/cm to about 1,500 S/cm, about 1,000 S/cm to about 2,000 S/cm, about 1,000 S/cm to about 2,500 S/cm, about 1,000 S/cm to about 3,000 S/cm, about 1,000 S/cm to about 3,500 S/cm, about 1,000 S/cm to about 4,000 S/cm, about 1,000 S/cm to about 4,500 S/cm, about 1,000 S/cm to about 5,000 S/cm, about 1,000 S/cm to about 5,500 S/cm, about 1,000 S/cm to about 6,000 S/cm, about 1,000 S/cm to about 6,500 S/cm, about 1,500 S/cm to about 2,000 S/cm, about 1,500 S/cm to about 2,500 S/cm, about 1,500 S/cm to about 3,000 S/cm, about 1,500 S/cm to about 3,500 S/cm, about 1,500 S/cm to about 4,000 S/cm, about 1,500 S/cm to about 4,500 S/cm, about 1,500 S/cm to about 5,000 S/cm, about 1,500 S/cm to about 5,500 S/cm, about 1,500 S/cm to about 6,000 S/cm, about 1,500 S/cm to about 6,500 S/cm, about 2,000 S/cm to about 2,500 S/cm, about 2,000 S/cm to about 3,000 S/cm, about 2,000 S/cm to about 3,500 S/cm, about 2,000 S/cm to about 4,000 S/cm, about 2,000 S/cm to about 4,500 S/cm, about 2,000 S/cm to about 5,000 S/cm, about 2,000 S/cm to about 5,500 S/cm, about 2,000 S/cm to about 6,000 S/cm, about 2,000 S/cm to about 6,500 S/cm, about 2,500 S/cm to about 3,000 S/cm, about 2,500 S/cm to about 3,500 S/cm, about 2,500 S/cm to about 4,000 S/cm, about 2,500 S/cm to about 4,500 S/cm, about 2,500 S/cm to about 5,000 S/cm, about 2,500 S/cm to about 5,500 S/cm, about 2,500 S/cm to about 6,000 S/cm, about 2,500 S/cm to about 6,500 S/cm, about 3,000 S/cm to about 3,500 S/cm, about 3,000 S/cm to about 4,000 S/cm, about 3,000 S/cm to about 4,500 S/cm, about 3,000 S/cm to about 5,000 S/cm, about 3,000 S/cm to about 5,500 S/cm, about 3,000 S/cm to about 6,000 S/cm, about 3,000 S/cm to about 6,500 S/cm, about 3,500 S/cm to about 4,000 S/cm, about 3,500 S/cm to about 4,500 S/cm, about 3,500 S/cm to about 5,000 S/cm, about 3,500 S/cm to about 5,500 S/cm, about 3,500 S/cm to about 6,000 S/cm, about 3,500 S/cm to about 6,500 S/cm, about 4,000 S/cm to about 4,500 S/cm, about 4,000 S/cm to about 5,000 S/cm, about 4,000 S/cm to about 5,500 S/cm, about 4,000 S/cm to about 6,000 S/cm, about 4,000 S/cm to about 6,500 S/cm, about 4,500 S/cm to about 5,000 S/cm, about 4,500 S/cm to about 5,500 S/cm, about 4,500 S/cm to about 6,000 S/cm, about 4,500 S/cm to about 6,500 S/cm, about 5,000 S/cm to about 5,500 S/cm, about 5,000 S/cm to about 6,000 S/cm, about 5,000 S/cm to about 6,500 S/cm, about 5,500 S/cm to about 6,000 S/cm, about 5,500 S/cm to about 6,500 S/cm, or about 6,000 S/cm to about 6,500 S/cm, including increments therein. In some embodiments, the combination of silver flakes and ultra-graphene results in an increase in conductivity of the conductive ink by at least about 1,000 S/cm, about 1,500 S/cm, about 2,000 S/cm, about 2,500 S/cm, about 3,000 S/cm, about 3,500 S/cm, about 4,000 S/cm, about 4,500 S/cm, about 5,000 S/cm, about 5,500 S/cm, about 6,000 S/cm, or about 6,500 S/cm. In some embodiments, the combination of silver flakes and ultra-graphene results in an increase in conductivity of the conductive ink by at least at least about 1,000 S/cm, about 1,500 S/cm, about 2,000 S/cm, about 2,500 S/cm, about 3,000 S/cm, about 3,500 S/cm, about 4,000 S/cm, about 4,500 S/cm, about 5,000 S/cm, about 5,500 S/cm, or about 6,000 S/cm. In some embodiments, the combination of silver flakes and ultra-graphene results in an increase in conductivity of the conductive ink by at least at most about 1,500 S/cm, about 2,000 S/cm, about 2,500 S/cm, about 3,000 S/cm, about 3,500 S/cm, about 4,000 S/cm, about 4,500 S/cm, about 5,000 S/cm, about 5,500 S/cm, about 6,000 S/cm, or about 6,500 S/cm.

In some embodiments, the combination of silver flakes and ultra-graphene results in an increase in conductivity of the conductive ink by at least about 10% to about 220%. In some embodiments, the combination of silver flakes and ultra-graphene results in an increase in conductivity of the conductive ink by at least about 10% to about 20%, about 10% to about 40%, about 10% to about 60%, about 10% to about 80%, about 10% to about 100%, about 10% to about 120%, about 10% to about 140%, about 10% to about 160%, about 10% to about 180%, about 10% to about 200%, about 10% to about 220%, about 20% to about 40%, about 20% to about 60%, about 20% to about 80%, about 20% to about 100%, about 20% to about 120%, about 20% to about 140%, about 20% to about 160%, about 20% to about 180%, about 20% to about 200%, about 20% to about 220%, about 40% to about 60%, about 40% to about 80%, about 40% to about 100%, about 40% to about 120%, about 40% to about 140%, about 40% to about 160%, about 40% to about 180%, about 40% to about 200%, about 40% to about 220%, about 60% to about 80%, about 60% to about 100%, about 60% to about 120%, about 60% to about 140%, about 60% to about 160%, about 60% to about 180%, about 60% to about 200%, about 60% to about 220%, about 80% to about 100%, about 80% to about 120%, about 80% to about 140%, about 80% to about 160%, about 80% to about 180%, about 80% to about 200%, about 80% to about 220%, about 100% to about 120%, about 100% to about 140%, about 100% to about 160%, about 100% to about 180%, about 100% to about 200%, about 100% to about 220%, about 120% to about 140%, about 120% to about 160%, about 120% to about 180%, about 120% to about 200%, about 120% to about 220%, about 140% to about 160%, about 140% to about 180%, about 140% to about 200%, about 140% to about 220%, about 160% to about 180%, about 160% to about 200%, about 160% to about 220%, about 180% to about 200%, about 180% to about 220%, or about 200% to about 220%, including increments therein. In some embodiments, the combination of silver flakes and ultra-graphene results in an increase in conductivity of the conductive ink by at least about 10%, about 20%, about 40%, about 60%, about 80%, about 100%, about 120%, about 140%, about 160%, about 180%, about 200%, or about 220%. In some embodiments, the combination of silver flakes and ultra-graphene results in an increase in conductivity of the conductive ink by at least at least about 10%, about 20%, about 40%, about 60%, about 80%, about 100%, about 120%, about 140%, about 160%, about 180%, or about 200%. In some embodiments, the combination of silver flakes and ultra-graphene results in an increase in conductivity of the conductive ink by at least at most about 20%, about 40%, about 60%, about 80%, about 100%, about 120%, about 140%, about 160%, about 180%, about 200%, or about 220%.

In some embodiments, the combination of silver flakes and ultra-graphene results in an increase in viscosity of the conductive ink by at least about 1,000 cP to about 5,000 cP. In some embodiments, the combination of silver flakes and ultra-graphene results in an increase in viscosity of the conductive ink by at least about 1,000 cP to about 1,500 cP, about 1,000 cP to about 2,000 cP, about 1,000 cP to about 2,500 cP, about 1,000 cP to about 3,000 cP, about 1,000 cP to about 3,500 cP, about 1,000 cP to about 4,000 cP, about 1,000 cP to about 4,500 cP, about 1,000 cP to about 5,000 cP, about 1,500 cP to about 2,000 cP, about 1,500 cP to about 2,500 cP, about 1,500 cP to about 3,000 cP, about 1,500 cP to about 3,500 cP, about 1,500 cP to about 4,000 cP, about 1,500 cP to about 4,500 cP, about 1,500 cP to about 5,000 cP, about 2,000 cP to about 2,500 cP, about 2,000 cP to about 3,000 cP, about 2,000 cP to about 3,500 cP, about 2,000 cP to about 4,000 cP, about 2,000 cP to about 4,500 cP, about 2,000 cP to about 5,000 cP, about 2,500 cP to about 3,000 cP, about 2,500 cP to about 3,500 cP, about 2,500 cP to about 4,000 cP, about 2,500 cP to about 4,500 cP, about 2,500 cP to about 5,000 cP, about 3,000 cP to about 3,500 cP, about 3,000 cP to about 4,000 cP, about 3,000 cP to about 4,500 cP, about 3,000 cP to about 5,000 cP, about 3,500 cP to about 4,000 cP, about 3,500 cP to about 4,500 cP, about 3,500 cP to about 5,000 cP, about 4,000 cP to about 4,500 cP, about 4,000 cP to about 5,000 cP, or about 4,500 cP to about 5,000 cP, including increments therein. In some embodiments, the combination of silver flakes and ultra-graphene results in an increase in viscosity of the conductive ink by at least about 1,000 cP, about 1,500 cP, about 2,000 cP, about 2,500 cP, about 3,000 cP, about 3,500 cP, about 4,000 cP, about 4,500 cP, or about 5,000 cP. In some embodiments, the combination of silver flakes and ultra-graphene results in an increase in viscosity of the conductive ink by at least about 1,000 cP, about 1,500 cP, about 2,000 cP, about 2,500 cP, about 3,000 cP, about 3,500 cP, about 4,000 cP, or about 4,500 cP. In some embodiments, the combination of silver flakes and ultra-graphene results in an increase in viscosity of the conductive ink by at least at most about 1,500 cP, about 2,000 cP, about 2,500 cP, about 3,000 cP, about 3,500 cP, about 4,000 cP, about 4,500 cP, or about 5,000 cP.

In some embodiments, the combination of silver flakes and ultra-graphene results in an increase in viscosity of the conductive ink by at least about 10% to about 220%. In some embodiments, the combination of silver flakes and ultra-graphene results in an increase in viscosity of the conductive ink by at least about 10% to about 20%, about 10% to about 40%, about 10% to about 60%, about 10% to about 80%, about 10% to about 100%, about 10% to about 120%, about 10% to about 140%, about 10% to about 160%, about 10% to about 180%, about 10% to about 200%, about 10% to about 220%, about 20% to about 40%, about 20% to about 60%, about 20% to about 80%, about 20% to about 100%, about 20% to about 120%, about 20% to about 140%, about 20% to about 160%, about 20% to about 180%, about 20% to about 200%, about 20% to about 220%, about 40% to about 60%, about 40% to about 80%, about 40% to about 100%, about 40% to about 120%, about 40% to about 140%, about 40% to about 160%, about 40% to about 180%, about 40% to about 200%, about 40% to about 220%, about 60% to about 80%, about 60% to about 100%, about 60% to about 120%, about 60% to about 140%, about 60% to about 160%, about 60% to about 180%, about 60% to about 200%, about 60% to about 220%, about 80% to about 100%, about 80% to about 120%, about 80% to about 140%, about 80% to about 160%, about 80% to about 180%, about 80% to about 200%, about 80% to about 220%, about 100% to about 120%, about 100% to about 140%, about 100% to about 160%, about 100% to about 180%, about 100% to about 200%, about 100% to about 220%, about 120% to about 140%, about 120% to about 160%, about 120% to about 180%, about 120% to about 200%, about 120% to about 220%, about 140% to about 160%, about 140% to about 180%, about 140% to about 200%, about 140% to about 220%, about 160% to about 180%, about 160% to about 200%, about 160% to about 220%, about 180% to about 200%, about 180% to about 220%, or about 200% to about 220%, including increments therein. In some embodiments, the combination of silver flakes and ultra-graphene results in an increase in viscosity of the conductive ink by at least about 10%, about 20%, about 40%, about 60%, about 80%, about 100%, about 120%, about 140%, about 160%, about 180%, about 200%, or about 220%. In some embodiments, the combination of silver flakes and ultra-graphene results in an increase in viscosity of the conductive ink by at least at least about 10%, about 20%, about 40%, about 60%, about 80%, about 100%, about 120%, about 140%, about 160%, about 180%, or about 200%. In some embodiments, the combination of silver flakes and ultra-graphene results in an increase in viscosity of the conductive ink by at least at most about 20%, about 40%, about 60%, about 80%, about 100%, about 120%, about 140%, about 160%, about 180%, about 200%, or about 220%.

### Method—Solvent

In some embodiments, the solvent comprises Dowanol PnP, 2-ethyl-1-hexanol, DEGBE, 2-ethyl-1-butanol, 2-methyl-1-pentanol, PGMEA, Hexamine, Cycloheptylamine, Isoamyl amine, 3-Methoxypropylamine, PCBTF, ethylene glycol, isopropanol, ethyl acetate, chloroform, DMF, NMP, THF, dichlorobenzene, or combinations thereof. In some embodiments, the solvent comprises Propylene glycol propyl ether. In some embodiments, the solvent comprises 2-ethyl-1-hexanol.

In some embodiments, the solvent is comprised in an amount of about 10% wt to about 90% wt. In some embodiments, the solvent is comprised in an amount of about 10% wt to about 20% wt, about 10% wt to about 30% wt, about 10% wt to about 40% wt, about 10% wt to about 50% wt, about 10% wt to about 60% wt, about 10% wt to about 70% wt, about 10% wt to about 80% wt, about 10% wt to about 90% wt, about 20% wt to about 30% wt, about 20% wt to about 40% wt, about 20% wt to about 50% wt, about 20% wt to about 60% wt, about 20% wt to about 70% wt, about 20% wt to about 80% wt, about 20% wt to about 90% wt, about 30% wt to about 40% wt, about 30% wt to about 50% wt, about 30% wt to about 60% wt, about 30% wt to about 70% wt, about 30% wt to about 80% wt, about 30% wt to about 90% wt, about 40% wt to about 50% wt, about 40% wt to about 60% wt, about 40% wt to about 70% wt, about 40% wt to about 80% wt, about 40% wt to about 90% wt, about 50% wt to about 60% wt, about 50% wt to about 70% wt, about 50% wt to about 80% wt, about 50% wt to about 90% wt, about 60% wt to about 70% wt, about 60% wt to about 80% wt, about 60% wt to about 90% wt, about 70% wt to about 80% wt, about 70% wt to about 90% wt, or about 80% wt to about 90% wt, including increments therein. In some embodiments, the solvent is comprised in an amount of about 10% wt, about 20% wt, about 30% wt, about 40% wt, about 50% wt, about 60% wt, about 70% wt, about 80% wt, or about 90% wt. In some embodiments, the solvent is comprised in an amount of at least about 10% wt, about 20% wt, about 30% wt, about 40% wt, about 50% wt, about 60% wt, about 70% wt, or about 80% wt. In some embodiments, the solvent is comprised in an amount of at most about 20% wt, about 30% wt, about 40% wt, about 50% wt, about 60% wt, about 70% wt, about 80% wt, or about 90% wt.

In some embodiments, the solvent comprises Propylene glycol propyl ether in an amount of about 10% wt to about 90% wt. In some embodiments, the solvent comprises Propylene glycol propyl ether in an amount of about 10% wt to about 20% wt, about 10% wt to about 30% wt, about 10% wt to about 40% wt, about 10% wt to about 50% wt, about 10% wt to about 60% wt, about 10% wt to about 70% wt, about 10% wt to about 80% wt, about 10% wt to about 90% wt, about 20% wt to about 30% wt, about 20% wt to about 40% wt, about 20% wt to about 50% wt, about 20% wt to about 60% wt, about 20% wt to about 70% wt, about 20% wt to about 80% wt, about 20% wt to about 90% wt, about 30% wt to about 40% wt, about 30% wt to about 50% wt, about 30% wt to about 60% wt, about 30% wt to about 70% wt, about 30% wt to about 80% wt, about 30% wt to about 90% wt, about 40% wt to about 50% wt, about 40% wt to about 60% wt, about 40% wt to about 70% wt, about 40% wt to about 80% wt, about 40% wt to about 90% wt, about 50% wt to about 60% wt, about 50% wt to about 70% wt, about 50% wt to about 80% wt, about 50% wt to about 90% wt, about 60% wt to about 70% wt, about 60% wt to about 80% wt, about 60% wt to about 90% wt, about 70% wt to about 80% wt, about 70% wt to about 90% wt, or about 80% wt to about 90% wt, including increments therein. In some embodiments, the solvent comprises Propylene glycol propyl ether in an amount of about 10% wt, about 20% wt, about 30% wt, about 40% wt, about 50% wt, about 60% wt, about 70% wt, about 80% wt, or about 90% wt. In some embodiments, the solvent comprises Propylene glycol propyl ether in an amount of at least about 10% wt, about 20% wt, about 30% wt, about 40% wt, about 50% wt, about 60% wt, about 70% wt, or about 80% wt. In some embodiments, the solvent comprises Propylene glycol propyl ether in an amount of at most about 20% wt, about 30% wt, about 40% wt, about 50% wt, about 60% wt, about 70% wt, about 80% wt, or about 90% wt.

In some embodiments, the solvent comprises Propylene glycol propyl ether in an amount of about 15% wt. In some embodiments, the solvent comprises Propylene glycol propyl ether in an amount of at least about 10% wt. In some embodiments, the solvent comprises Propylene glycol propyl ether in an amount up to 20% wt. In some embodiments, the solvent comprises Propylene glycol propyl ether in an amount up to 90% wt.

In some embodiments, the solvent comprises Propylene glycol propyl ether in an amount of about 13% wt to about 17% wt. In some embodiments, the solvent comprises Propylene glycol propyl ether in an amount of about 13% wt to about 14% wt, about 13% wt to about 15% wt, about 13% wt to about 16% wt, about 13% wt to about 17% wt, about 14% wt to about 15% wt, about 14% wt to about 16% wt, about 14% wt to about 17% wt, about 15% wt to about 16% wt, about 15% wt to about 17% wt, or about 16% wt to about 17% wt, including increments therein. In some embodiments, the solvent comprises Propylene glycol propyl ether in an amount of about 13% wt, about 14% wt, about 15% wt, about 16% wt, or about 17% wt. In some embodiments, the solvent comprises Propylene glycol propyl ether in an amount of at least about 13% wt, about 14% wt, about 15% wt, or about 16% wt. In some embodiments, the solvent comprises Propylene glycol propyl ether in an amount of at most about 14% wt, about 15% wt, about 16% wt, or about 17% wt.

### Method—Dispersing Agents

In some embodiments, the dispersing agent comprises polytetrahydrofuran (Poly THF) in an amount of about 0.5% wt to about 20% wt. In some embodiments, the dispersing agent comprises Poly THF in an amount of about 0.5% wt to about 2% wt, about 0.5% wt to about 4% wt, about 0.5% wt to about 6% wt, about 0.5% wt to about 8% wt, about 0.5% wt to about 10% wt, about 0.5% wt to about 12% wt, about 0.5% wt to about 14% wt, about 0.5% wt to about 16% wt, about 0.5% wt to about 18% wt, about 0.5% wt to about 20% wt, about 2% wt to about 4% wt, about 2% wt to about 6% wt, about 2% wt to about 8% wt, about 2% wt to about 10% wt, about 2% wt to about 12% wt, about 2% wt to about 14% wt, about 2% wt to about 16% wt, about 2% wt to about 18% wt, about 2% wt to about 20% wt, about 4% wt to about 6% wt, about 4% wt to about 8% wt, about 4% wt to about 10% wt, about 4% wt to about 12% wt, about 4% wt to about 14% wt, about 4% wt to about 16% wt, about 4% wt to about 18% wt, about 4% wt to about 20% wt, about 6% wt to about 8% wt, about 6% wt to about 10% wt, about 6% wt to about 12% wt, about 6% wt to about 14% wt, about 6% wt to about 16% wt, about 6% wt to about 18% wt, about 6% wt to about 20% wt, about 8% wt to about 10% wt, about 8% wt to about 12% wt, about 8% wt to about 14% wt, about 8% wt to about 16% wt, about 8% wt to about 18% wt, about 8% wt to about 20% wt, about 10% wt to about 12% wt, about 10% wt to about 14% wt, about 10% wt to about 16% wt, about 10% wt to about 18% wt, about 10% wt to about 20% wt, about 12% wt to about 14% wt, about 12% wt to about 16% wt, about 12% wt to about 18% wt, about 12% wt to about 20% wt, about 14% wt to about 16% wt, about 14% wt to about 18% wt, about 14% wt to about 20% wt, about 16% wt to about 18% wt, about 16% wt to about 20% wt, or about 18% wt to about 20% wt, including increments therein. In some embodiments, the dispersing agent comprises Poly THF in an amount of about 0.5% wt, about 2% wt, about 4% wt, about 6% wt, about 8% wt, about 10% wt, about 12% wt, about 14% wt, about 16% wt, about 18% wt, or about 20% wt. In some embodiments, the dispersing agent comprises Poly THF in an amount of at least about 0.5% wt, about 2% wt, about 4% wt, about 6% wt, about 8% wt, about 10% wt, about 12% wt, about 14% wt, about 16% wt, or about 18% wt. In some embodiments, the dispersing agent comprises Poly THF in an amount of at most about 2% wt, about 4% wt, about 6% wt, about 8% wt, about 10% wt, about 12% wt, about 14% wt, about 16% wt, about 18% wt, or about 20% wt. In some embodiments, the dispersing agent comprises Poly THF in an amount of about 0.5% wt. to about 20% wt. In some embodiments, the dispersing agent comprises Poly THF in an amount about 0.5% wt. to about 2% wt. In some embodiments, the dispersing agent comprises Poly THF in an amount of about 1% wt. In some embodiments, the dispersing agent comprises Poly THF in an amount of at least 1% wt. In some embodiments, the dispersing agent comprises Poly THF in an amount up to 10% wt. In some embodiments, the dispersing agent comprises Poly THF in an amount up to 20% wt. In some embodiments, the dispersing agent comprises Poly THF 2k, referring to the average molecular weight of the polymer.

### Method—Binder

In some embodiments, the binder comprises Poly Vinyl Pyrrolidone in an amount of about 0.5% wt to about 10.5% wt. In some embodiments, the binder comprises Poly Vinyl Pyrrolidone in an amount of about 0.5% wt to about 1% wt, about 0.5% wt to about 1.5% wt, about 0.5% wt to about 2.5% wt, about 0.5% wt to about 3.5% wt, about 0.5% wt to about 4.5% wt, about 0.5% wt to about 5.5% wt, about 0.5% wt to about 6.5% wt, about 0.5% wt to about 7.5% wt, about 0.5% wt to about 8.5% wt, about 0.5% wt to about 9.5% wt, about 0.5% wt to about 10.5% wt, about 1% wt to about 1.5% wt, about 1% wt to about 2.5% wt, about 1% wt to about 3.5% wt, about 1% wt to about 4.5% wt, about 1% wt to about 5.5% wt, about 1% wt to about 6.5% wt, about 1% wt to about 7.5% wt, about 1% wt to about 8.5% wt, about 1% wt to about 9.5% wt, about 1% wt to about 10.5% wt, about 1.5% wt to about 2.5% wt, about 1.5% wt to about 3.5% wt, about 1.5% wt to about 4.5% wt, about 1.5% wt to about 5.5% wt, about 1.5% wt to about 6.5% wt, about 1.5% wt to about 7.5% wt, about 1.5% wt to about 8.5% wt, about 1.5% wt to about 9.5% wt, about 1.5% wt to about 10.5% wt, about 2.5% wt to about 3.5% wt, about 2.5% wt to about 4.5% wt, about 2.5% wt to about 5.5% wt, about 2.5% wt to about 6.5% wt, about 2.5% wt to about 7.5% wt, about 2.5% wt to about 8.5% wt, about 2.5% wt to about 9.5% wt, about 2.5% wt to about 10.5% wt, about 3.5% wt to about 4.5% wt, about 3.5% wt to about 5.5% wt, about 3.5% wt to about 6.5% wt, about 3.5% wt to about 7.5% wt, about 3.5% wt to about 8.5% wt, about 3.5% wt to about 9.5% wt, about 3.5% wt to about 10.5% wt, about 4.5% wt to about 5.5% wt, about 4.5% wt to about 6.5% wt, about 4.5% wt to about 7.5% wt, about 4.5% wt to about 8.5% wt, about 4.5% wt to about 9.5% wt, about 4.5% wt to about 10.5% wt, about 5.5% wt to about 6.5% wt, about 5.5% wt to about 7.5% wt, about 5.5% wt to about 8.5% wt, about 5.5% wt to about 9.5% wt, about 5.5% wt to about 10.5% wt, about 6.5% wt to about 7.5% wt, about 6.5% wt to about 8.5% wt, about 6.5% wt to about 9.5% wt, about 6.5% wt to about 10.5% wt, about 7.5% wt to about 8.5% wt, about 7.5% wt to about 9.5% wt, about 7.5% wt to about 10.5% wt, about 8.5% wt to about 9.5% wt, about 8.5% wt to about 10.5% wt, or about 9.5% wt to about 10.5% wt, including increments therein. In some embodiments, the binder comprises Poly Vinyl Pyrrolidone in an amount of about 0.5% wt, about 1% wt, about 1.5% wt, about 2.5% wt, about 3.5% wt, about 4.5% wt, about 5.5% wt, about 6.5% wt, about 7.5% wt, about 8.5% wt, about 9.5% wt, or about 10.5% wt. In some embodiments, the binder comprises Poly Vinyl Pyrrolidone in an amount of at least about 0.5% wt, about 1% wt, about 1.5% wt, about 2.5% wt, about 3.5% wt, about 4.5% wt, about 5.5% wt, about 6.5% wt, about 7.5% wt, about 8.5% wt, or about 9.5% wt. In some embodiments, the binder comprises Poly Vinyl Pyrrolidone in an amount of at most about 1% wt, about 1.5% wt, about 2.5% wt, about 3.5% wt, about 4.5% wt, about 5.5% wt, about 6.5% wt, about 7.5% wt, about 8.5% wt, about 9.5% wt, or about 10.5% wt.

In some embodiments, the binder comprises Poly Vinyl Pyrrolidone in an amount of about 10.5% wt. In some embodiments, the binder comprises Poly Vinyl Pyrrolidone 15k in an amount of about 10.5% wt. In some embodiments, the binder comprises Poly Vinyl Pyrrolidone in an amount of about 8% wt. to about 12% wt. In some embodiments, the binder comprises Poly Vinyl Pyrrolidone 15k in an amount of about 8% wt. to about 12% wt. In some embodiments, the binder comprises Poly Vinyl Pyrrolidone in an amount of at least 5% wt. In some embodiments, the binder comprises Poly Vinyl Pyrrolidone in an amount up to 20% wt. In some embodiments, the Poly Vinyl Pyrrolidone is PVP 15k.

### Terms and Definitions

Unless otherwise defined, all technical terms used herein have the same meaning as commonly understood by one of ordinary skill in the art to which this disclosure belongs.

As used herein, the term “single layer graphene” refers to graphene or reduced graphene oxide that consists of single sheets of graphene that are not aggregated into multi-layer graphene. Single sheets of graphene are separated from one another such that the 2-dimensional structured sheets are not stacked into multi-layer or graphite-like structures, but may still have partial physical contact (e.g., interconnected sheets that form a three-dimensional network). For example, single-layer graphene may be formed by high-efficiency exfoliation from graphite according to the methods disclosed herein.

As used herein, the singular forms “a,” “an,” and “the” include plural references unless the context clearly dictates otherwise. Any reference to “or” herein is intended to encompass “and/or” unless otherwise stated.

As used herein, the term “about” in reference to a percentage can refer to an amount that is greater or less than the stated percentage by 10%, 5%, or 1%, including increments therein, and includes the stated amount. Unless specifically stated otherwise, the term “about” in reference to a percentage refers to an amount that is greater or less than the stated percentage by 10%.

As used herein, the term “substantially” as used herein in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the phrases “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

As used herein, the term “solid content” refers to a percentage of a dispersion or ink remaining after being dried, wherein volatile solvents are vaporized.

As used herein, the term the dispersing agent is also referred to as a “dispersing aid”, “wetting agent,” or “softener.”

Exemplary conductive ink 1A is referred to in the figure legends as AgC50.

AgC50-1, AgC50-2, AgC50-3 referred to in the figure legends are different batches of AgC50.

Exemplary conductive ink 1B is referred to in the figure legends as AgC56.

AgC56-1, AgC56-2, Ag56-3 referred to in the figure legends are different batches of AgC56.

### EXAMPLES

The following illustrative examples are representative of embodiments of the compositions and methods described herein and are not meant to be limiting in any way. Per below, a range of formulations for the exemplary conductive ink #1 is provided:

Upper and Lower Limits

| | | | | | | Poly Vinyl | | | | Propylene | | | |
|---|---|---|---|---|---|---|---|---|---|---|---|---|---|
| | | | | | | Pyrrolidone | | Poly | | glycol propyl | | Diethylene | |
| Solid Content | | Silver flake | | rGO | | K15 TCI | | (THF) 2k | | ether | | Glycol | |
| Low % | High % | Low % | High % | Low % | High % | Low % | High % | Low % | High % | Low % | High % | Low % | High % |
| 35 | 80 | 30 | 80 | 0.1 | 10.0 | 5 | 60 | 1 | 20 | 20 | 90 | 5 | 80 |

### Example 1: Formulation, Preparation Conditions, and Physical Properties of Exemplary Conductive Ink #1

The following table shows the formulation of exemplary formulas 1 and 2 conductive ink

| | | | Dry | | | | | | Poly Vinyl | | | Propylene | |
|---|---|---|---|---|---|---|---|---|---|---|---|---|---|
| | | | film | | | | | | Pyrrol- | PVP | Poly | glycol | Dieth- |
| | Total | | silver | Solid | Silver | | | | idone | 10k | (THF) | propyl | ylene |
| | Amount | Ink | content | Content | Flake | | rGO | | K15 TCI | TCI | 2k | ether | Glycol |
| ID | (gms) | type | (%) | (%) | ID | (%) | ID | (%) | (%) | (%) | (%) | (%) | (%) |
| Con- | 1000 | UG/AgF | 84 | 74.58 | 11 F | 62.6 | UG061522 | 0.5 | 10.45 | — | 1 | 15 | 10.45 |
| ductive | | | | | | | | | | | | | |
| ink 1A | | | | | | | | | | | | | |
| Con- | N/A | UG/AgF | 84.25 | 74.98 | 11-F | 62.68 | N/A | 0.49 | — | 10.29 | 1.52 | 14.74 | 10.28 |
| ductive | | | | | | | | | | | | | |
| ink 1B | | | | | | | | | | | | | |

| | | | Conductive | Conductive | Conductive |
|---|---|---|---|---|---|
| Component | | | Ink 1 Range | Ink 1A | ink 2B |
| Graphene | Reduced graphene | % | 0.1-10.0 | 0.5 | 0.49 |
| | oxide | | | | |
| Binder | Polyvinyl- | % | 5-60 | 10.45 | — |
| | pyrrolidone | | | | |
| | K15 TCI | | | | |
| Binder | Polyvinyl- | % | — | — | 10.29% |
| | pyrrolidone | | | | |
| | 10 k TCI | | | | |
| Binder | Poly (THF) 2k | % | 1-20 | 1 | 1.52% |
| Silver | 11F | % | 30-80 | 62.6 | 62.68 |
| Nanoflakes | | | | | |
| Dispersing | Diethylene | % | 5-80 | 10.45 | 10.28 |
| Agent | Glycol | | | | |
| Solvent | Propylene glycol | % | 20-90 | 15 | 14.74 |
| | propyl ether | | | | |

The following table highlights preparation conditions and physical properties of the resulting exemplary conductive ink #1:

| Mixing | | Viscosity at room temp (25° C.) | | |
|---|---|---|---|---|
| | Time | | shear | |
| Method | (hrs) | spindle | rate (s⁻¹) | cP |
| AE6-80 mm, | 4 | 52z | 200 | 4524 |
| TML1 | | | | |

### Example 2: Silver Flakes Conductive Adhesive without Graphene (Conductive Ink #2)

The conductive ink #2 comprises the following formula:

| | | Dry | | | | | PVP | | | |
|---|---|---|---|---|---|---|---|---|---|---|
| | | silver | Solid | | | Ultra | 10k | poly | | |
| | Ink | content | Content | Silver flakes | | graphene | TCI | THF | PnP | DEG |
| ID | type | (%) | (%) | Material | (%) | (%) | (%) | (%) | (%) | (%) |
| Condutive | Ag | 84.90% | 76.52% | 11-F | 64.97% | 0.00% | 10.49% | 1.06% | 12.99% | 10.49% |
| ink #2 | Flakes | | | | | | | | | |

As shown above conductive ink #2 comprises 0.00% graphene and 64.97% Silver nanoflakes.

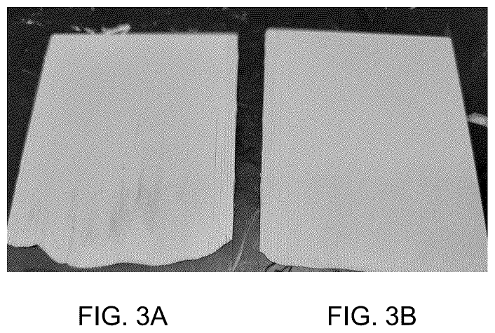

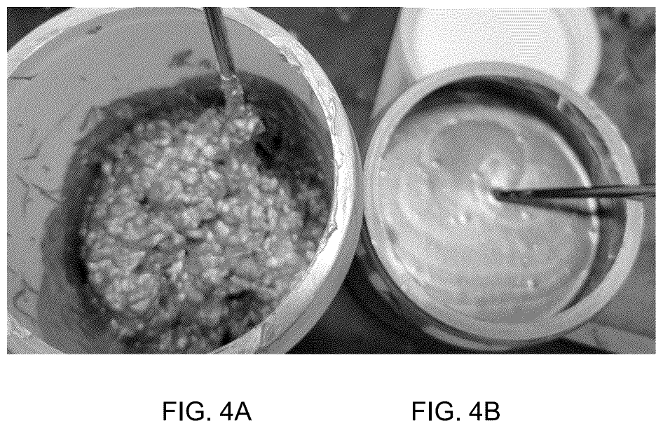

FIG. 3A Conductive ink #2 Ag Flakes only without ultra-graphene image of solution processed graphene sheets of before mixing. FIG. 4A Conductive ink #2 only image of solution processed graphene sheets 24 hours after mixing. As shown in the photograph of Conductive ink #2 24 hours after mixing, irreversible aggregation is seen Conductive ink #2 in the formulation without graphene.

From the samples shown in in FIGS. 3A and 4A, the following stability measurements can be calculated:

| | | | | 4-point | | 4-point | | ASTM |
|---|---|---|---|---|---|---|---|---|
| | | | | probe | | probe | | cross |
| | | Viscosity | Dry | sheet | | volume | Conduc- | hatch |
| | Ink | 200(1/s) | thickness | resistance | stdev | resistivity | tivity | adhesion |
| ID | type | cP | (μm) | (Ω/□) | (Ω/□) | (Ω-cm) | (S/cm) | 0-5B |
| Conductive | Ag | 3858 | 53.8 | 0.03436 | 0.00066 | 0.00018 | 5410.32 | 5B |
| ink #2 | Flakes | | | | | | | |

As can be extrapolated from the data, the conductive ink #2 embodiments viscosity measurements are 3858 cP at 200 s\hat{ }−1 at 25 C. Furthermore, the conductive ink #2 embodiments conductivity measurements are 5410.32 (S/cm) for conductive ink #2.

### Example 3: Silver Conductive Adhesive with the Graphene Oxide

The Ag Flakes with the Graphene Oxide (AgC60) comprises the following formula:

| | | dry | | | | | PVP | | | |
|---|---|---|---|---|---|---|---|---|---|---|
| | | silver | Solid | | | Ultra | 10k | poly | | |
| | Ink | content | Content | Silver flakes | | graphene | TCI | THF | PnP | DEG |
| ID | type | (%) | (%) | Material | (%) | (%) | (%) | (%) | (%) | (%) |
| Conductive | UG + Ag | 84.25% | 74.98% | 11-F | 62.68% | 0.49% | 10.29% | 1.52% | 14.74% | 10.28% |
| ink #1B | Flakes | | | | | | | | | |
| | (201) | | | | | | | | | |

As shown above conductive ink #1B comprises 0.49% graphene and 62.68% Silver nanoflakes.

FIG. 3B shows images of silver nanoflakes and graphene solution processed graphene sheets of an exemplary conductive ink #1 before mixing. FIG. 4B shows images of silver nanoflakes and graphene solution of solution processed graphene sheets of an exemplary conductive ink #1 24 hours after mixing. As shown in the photograph of conductive ink #1 24 hours after mixing has minimal or no aggregation.

From the samples shown in in FIGS. 3B and 41B, the following stability measurements can be calculated:

| | | | | 4-point | | 4-point | | ASTM |
|---|---|---|---|---|---|---|---|---|
| | | | | probe | | probe | | cross |
| | | Viscosity | Dry | sheet | | volume | Conduc- | hatch |
| | Ink | 200 (1/s) | thickness | resistance | stdev | resistivity | tivity | adhesion |
| ID | type | (cP) | (μm) | (Ω/□) | (Ω/□) | (Ω-cm) | (S/cm) | (0-5B) |
| Conductive | UG + Ag | 7906 | 27.6 | 0.03513 | 0.00197 | 9.7E−05 | 10313.5 | 5B |
| ink #1B | Flakes | | | | | | | |

As can be extrapolated from the data, the conductive ink #1B embodiment comprises 0.49% more Graphene Oxide than the conductive ink #2. This increase in graphene oxide in combination with other ingredients in the formulation, stabilizes the high-density silver flakes in formulation 201, which is illustrated by the corresponding increase in viscosity and conductivity. The viscosity measurements are 7906 cP at 200 s\hat{ }−1 at 25° C. for conductive ink #1B vs 3858 at 200 s\hat{ }−1 at 25° C. seen in conductive ink #2, which is about a 2.5× increase in viscosity. Furthermore, the conductivity measurements are 10313.5 (S/cm) for conductive ink #1B vs. 5410.32 (S/cm) for conductive ink #2, which is about a 1.9× increase in conductivity.

### Example 4: Characterization of Exemplary Conductive Ink #1

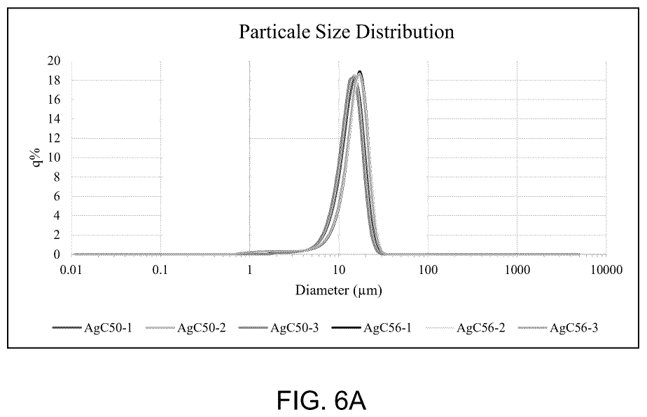

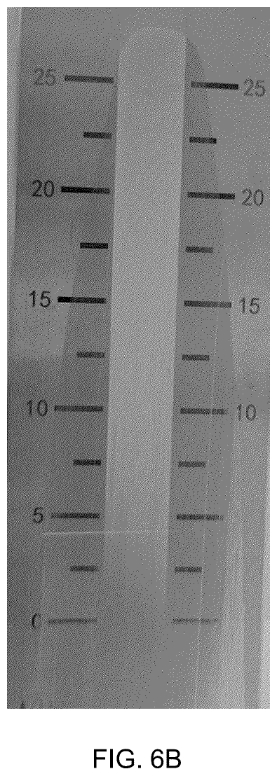

FIG. 6A is a particle size distribution of an exemplary conductive ink #1. FIG. 6B is an image of an exemplary conductive ink #1 on a Hegman gauge with a streak at a particle size of about 20 μm. As shown the the exemplary conductive ink #1 has a mono-modal particle size distribution with a median particle size of about 14.6 μm, a mean particle size of about 14.34 μm, and a maximum size of about 20.5 μm, wherein 90% of the particles had a size of less than about 20.3 μm.

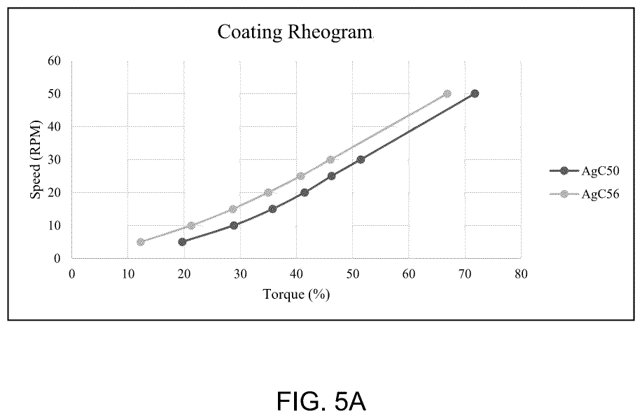

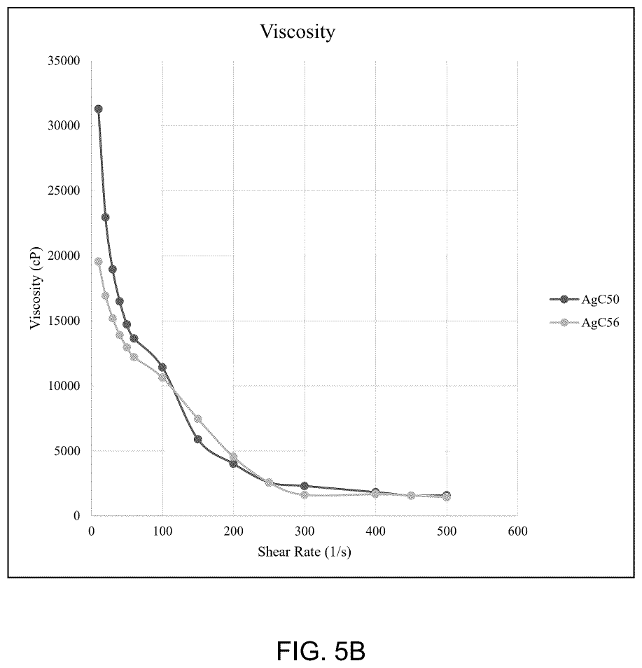

FIG. 5B is a shear rate vs viscosity graph of an exemplary conductive ink #1. Although the Rheogram appears linear or Newtonian, the exemplary conductive ink #1 exhibits slight curvature, shear thinning, and/or pseudoplastic orientation. The ink is suitable for extruder printing or screen printing. FIG. 5A is a torque vs. speed graph of an exemplary conductive ink #1.

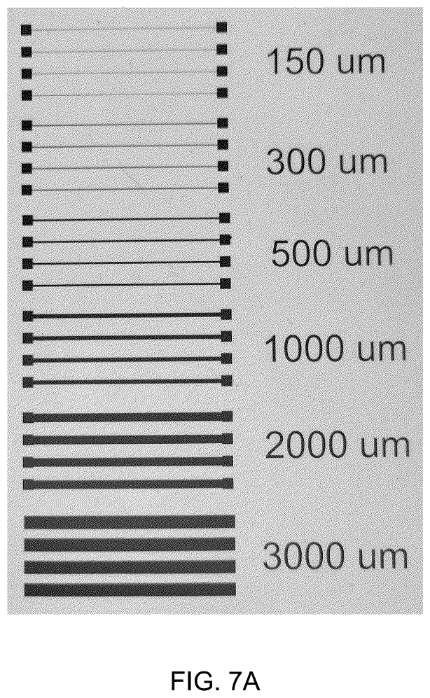

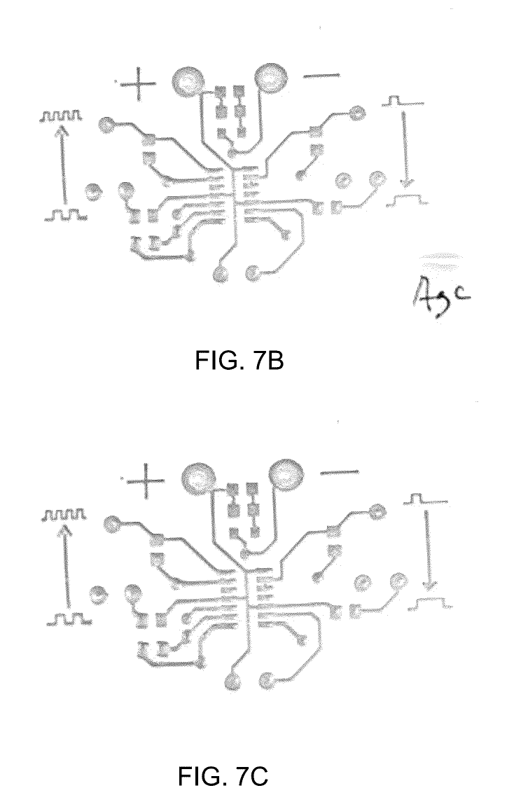

FIG. 7A shows a photograph of exemplary conductive ink #1 screen printed onto a dog and bone structure on including Polyethylene terephthalate (PET). FIG. 7B shows a photograph of exemplary conductive ink #1 screen pattern printed with Nova extruder print on polyimide (PI). FIG. 7C shows a photograph of exemplary conductive ink #1 screen pattern printed with Nova extruder print on PCB. In some embodiments, as shown, ink traces having thicknesses of 150 um, 300 um, 500 um, 1,000 um, 2,000 um, and 3,000 μm can be printed in one pass, without gaps or separation. In some embodiments, the ink is stable for use and is patternable using screen printing, extruder printing and other techniques. In some embodiments, the printed exemplary conductive ink #1 does not comprise pin holes, and the exemplary conductive ink #1 does not separate or shrink when it dries. In some embodiments, the exemplary conductive ink #1 has 5B adhesion on many substrates, including polyethylene terephthalate (PET), polyimide (PI or Kapton), and glass.

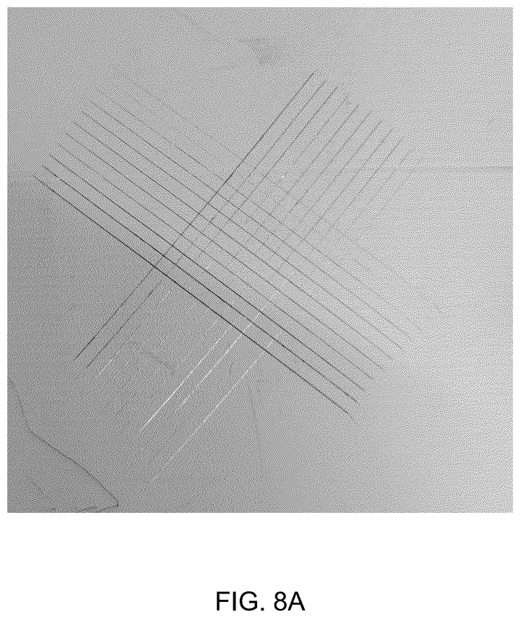

FIG. 8A shows a photograph of the adhesion test result of an exemplary conductive ink #1. In some embodiments, the coated ink has 5B adhesion on many substrates, including polyethylene terephthalate (PET), Polyimide (PI or Kapton), Aluminum, and glass. Adhesion tests were performed following ASTM protocols. Exemplary conductive ink #1 was coated using Mayer rods onto Kapton film. Curing conditions used were 300° C. for 30 minutes until the coating was dry. A cross-hatch pattern with 1 mm blade spacing was cut, then a tape peel test was performed using D3359-17 tape.

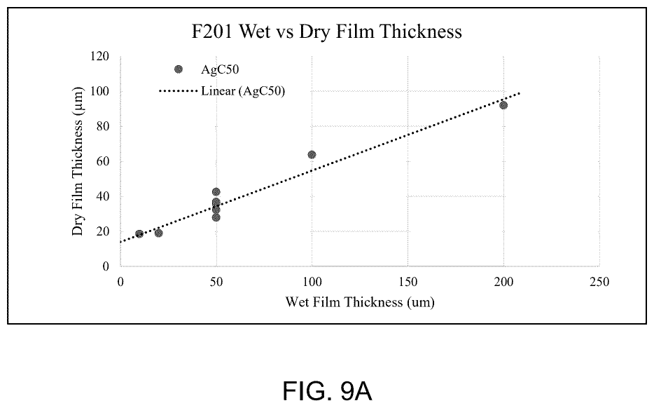

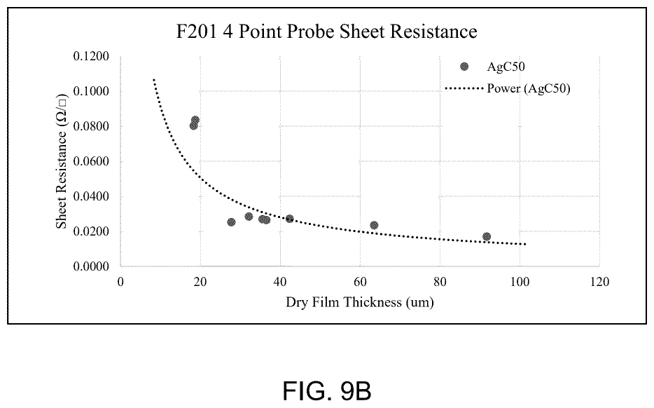

Per FIG. 9A-FIG. 9B, a 5 mil thick Polyimide substrate was coated with various thicknesses of the exemplary third conductive ink by a Mayer rods, wherein the coated substrates were cured at 110° C. until dry. As expected, the results show an increase in sheet resistance associated with a decrease in dry thickness, wherein the average conductivity for exemplary conductive ink #1 is about 10,000 S/cm.

From the data in FIGS. 9A-9B, the following sheet resistance can be calculated:

| | | | | 4 point | | average | | |
|---|---|---|---|---|---|---|---|---|
| | | | | probe | | 4 point | | |
| | | | | sheet | | probe | | |
| | | | DFT | resistance | | volume | Conduc- | |
| | | WFT | average | average | stdev | resistivity | tivity | Coating |
| ID | Substrate | (μm) | (μm) | (Ω/□) | (Ω/□) | (Ω-cm) | (S/cm) | method |
| AgC50 | 5-50-KHN-5 | 10 | 18.4 | 0.0801 | 0.00619 | 0.00014745 | 6781.99 | MR#6 |
| AgC50 | 5-50-KHN-5 | 20 | 18.8 | 0.0834 | 0.00538 | 0.00015683 | 6376.17 | MR#12 |
| AgC50 | 5-50-KHN-5 | 50 | 27.8 | 0.0252 | 0.00125 | 0.00006998 | 14290.07 | MR#28 |
| AgC50 | 5-50-KHN-5 | 50 | 27.8 | 0.0252 | 0.00125 | 0.00006998 | 14290.07 | MR#28 |
| AgC50 | 5-50-KHN-5 | 50 | 32.2 | 0.0284 | 0.00274 | 9.13944E−05 | 10941.59 | MR#28 |
| AgC50 | 5-50-KHN-5 | 50 | 35.6 | 0.0268 | 0.00099 | 9.55E−05 | 10470.23 | MR#28 |
| AgC50 | 5-50-KHN-5 | 50 | 36.6 | 0.0263 | 0.00053 | 9.63845E−05 | 10375.12 | MR#28 |
| AgC50 | 5-50-KHN-5 | 50 | 42.4 | 0.0270 | 0.00037 | 0.000114536 | 8730.88 | MR#28 |
| AgC50 | 5-50-KHN-5 | 100 | 63.6 | 0.0233 | 0.00047 | 0.00014812 | 6751.14 | MR#52 |
| AgC50 | 5-50-KHN-5 | 200 | 91.8 | 0.0169 | 0.00169 | 0.00015472 | 6463.25 | MR#200 |

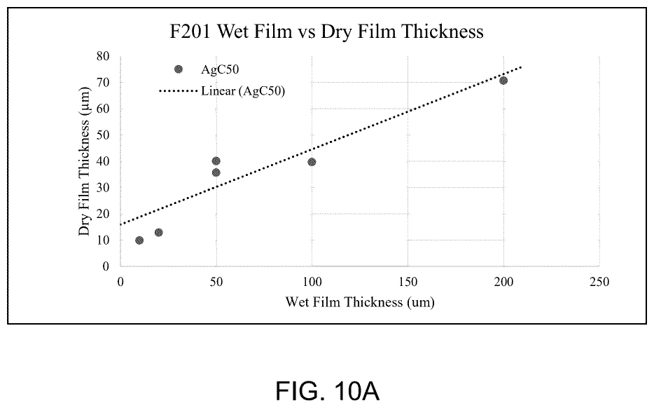

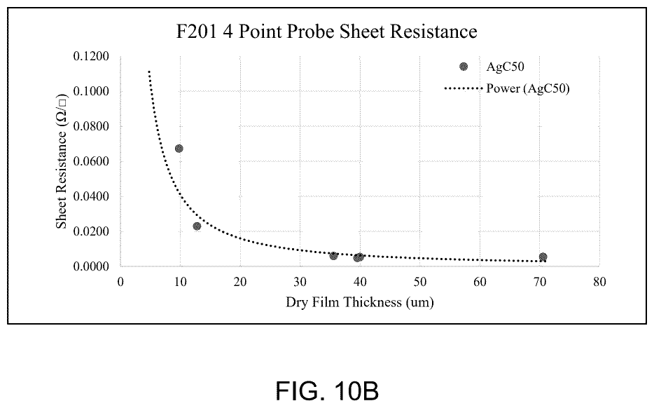

Per FIG. 10A-FIG. 10B, a 5 mil thick Polyimide substrate was coated with various thicknesses of the exemplary third conductive ink by Mayer rods, wherein the coated substrates were cured at 300° C. until dry. As expected, the results show an increase in sheet resistance associated to a decrease in dry thickness, wherein the average conductivity for exemplary conductive ink #1 is about 40,000 S/cm.

From the data in FIG. 10A-10B, the following sheet resistance can be calculated:

| | | | | 4 point | | average | | | |
|---|---|---|---|---|---|---|---|---|---|
| | | | | probe | | 4 point | | ASTM | |
| | | | | sheet | | probe | | cross | |
| | | | DFT | resistance | | volume | Conduc- | hatch | |
| | | WFT | average | average | stdev | resistivity | tivity | adhesion | Coating |
| ID | Substrate | (μm) | (μm) | (Ω/□) | (Ω/□) | (Ω-cm) | (S/cm) | 0-5B | method |
| AgC50 | 5-50-KHN-5 | 10 | 9.8 | 0.0671 | 0.01301 | 0.00006576 | 15205.88 | | MR#6 |
| AgC50 | 5-50-KHN-5 | 20 | 12.8 | 0.0228 | 0.00057 | 0.00002921 | 34235.76 | | MR#12 |
| AgC50 | 5-50-KHN-5 | 50 | 40 | 0.0053 | 0.00066 | 0.00002104 | 47517.75 | 5B | MR#28 |
| AgC50 | 5-50-KHN-5 | 50 | 40 | 0.0053 | 0.00066 | 0.00002104 | 47517.75 | 5B | MR#28 |
| AgC50 | 5-50-KHN-5 | 50 | 35.6 | 0.0058 | 0.00011 | 0.00002077 | 48144.35 | | MR#28 |
| AgC50 | 5-50-KHN-5 | 100 | 39.6 | 0.0047 | 0.00020 | 0.00001856 | 53889.68 | | MR#52 |
| AgC50 | 5-50-KHN-5 | 200 | 70.6 | 0.0053 | 0.00131 | 0.00003733 | 26789.38 | | MR#200 |

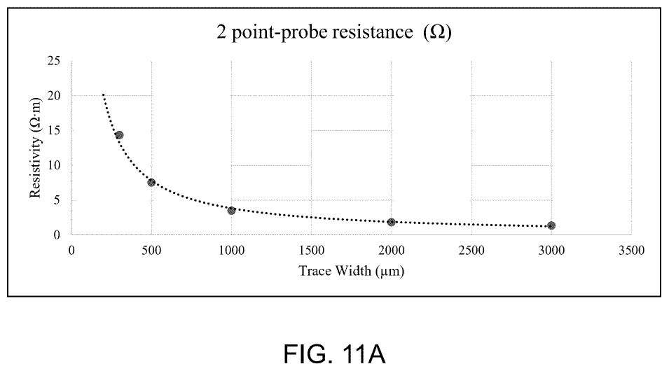

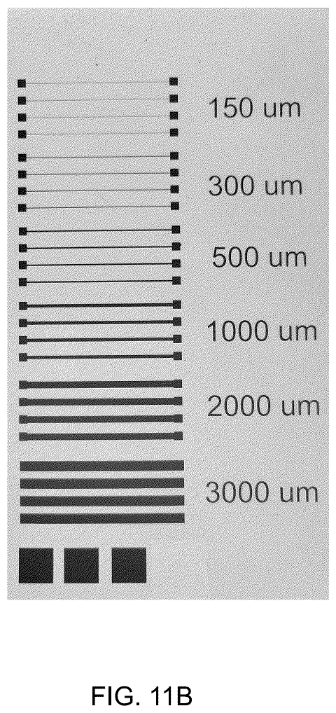

FIG. 11A, shows a trace width vs. resistivity for a substrate covered with the exemplary conductive ink #1 cured at 110° C., wherein the exemplary conductive ink #1 can be successfully printed into traces with a line width from 150 to 3000 micrometers, wherein the average electrical conductivity is 754,000 (S). FIG. 11B shows an image of the exemplary conductive ink #1 cured at 110° C. on a Hegman gauge. In some embodiments, as shown, ink traces having thicknesses of 150 um, 300 um, 500 μm, 1,000 um, 2,000 um, and 3,000 m can be printed in one pass, without gaps or separation. As shown, the ink traces have a length of about 4 cm.

The following formula

$$R = ρ \frac{L}{T \cdot W}$$

shows the relationship between trace dimensions, resistivity and resistance where: ρ=resistivity (Ω·m), R=resistance (Ω), L=trace length (i), W=trace width (m), and T=trace dry thickness (in).

From the data in FIG. 11A-11B, the following data can be calculated:

Conductive Ink #1 305 poly45 15 um 1.1 DIA CAP
Emulsion, PET, 110° C. 10 min, 2.23.23

| | | | | 2 point- | | Conduc- |
|---|---|---|---|---|---|---|
| Trace | Trace | Trace | Dry | probe | | tivity |
| width | width | length | thickness | resistance | Resistivity | (S) or |
| (m) | (um) | (m) | (mm) | (Ω) | (Ω · m) | (1/Ω · m) |
| 0.0003 | 300 | 0.04 | 0.000014 | 14.3 | 1.5E−06 | 666033.2 |
| 0.0005 | 500 | 0.04 | 0.000014 | 7.5 | 1.31E−06 | 761972.5 |
| 0.001 | 1000 | 0.04 | 0.000014 | 3.45 | 1.21E−06 | 828331.3 |
| 0.002 | 2000 | 0.04 | 0.000014 | 1.8 | 1.26E−06 | 794879.4 |
| 0.003 | 3000 | 0.04 | 0.000014 | 1.325 | 1.39E−06 | 719518.6 |

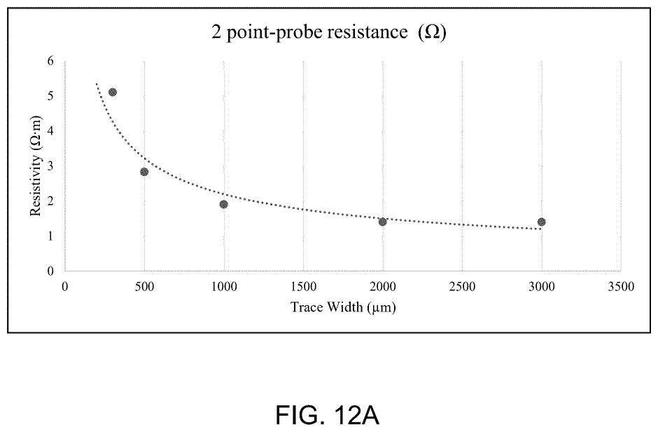

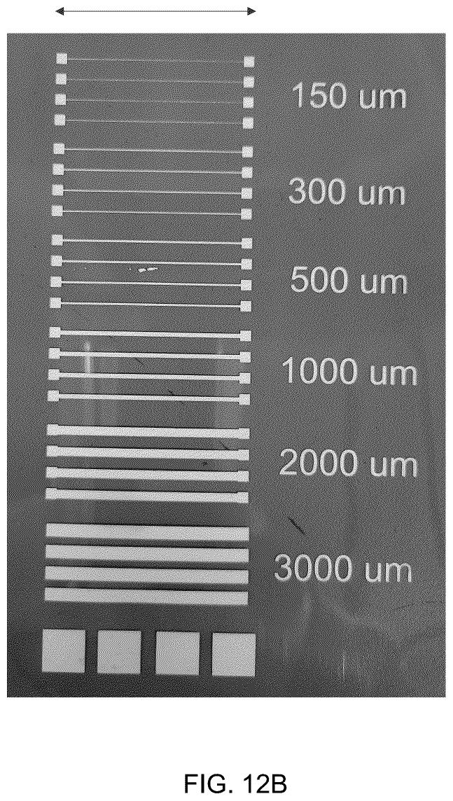

FIG. 12A, shows a trace width vs. resistivity for a substrate covered with the exemplary conductive ink #1 cured at 300° C., wherein the exemplary conductive ink #1 can be successfully printed into traces with a line width from 150 to 3000 micrometers, wherein the average electrical conductance is 1,420,000 (S). FIG. 12B shows an image of the exemplary conductive ink #1 cured at 300° C. on a Hegman gauge. In some embodiments, as shown, ink traces having thicknesses of 150 um, 300 um, 500 um, 1,000 um, 2,000 um, and 3,000 μm can be printed in one pass, without gaps or separation. As shown, the ink traces have a length of about 4 cm.

The following formula

$$R = ρ \frac{L}{T \cdot W}$$

shows the relationship between trace dimensions, resistivity and resistance where: ρ=resistivity (Ω·m), R=resistance (Ω), L=trace length (m), W=trace width (m), and T=trace dry thickness (m).

From the data in FIGS. 12A-12B, the following data can be calculated:

Conductive Ink #1, 230 PE 10-15 um 1.1 DIA ACE
Emulsion, PI, 300° C. 30 min, 2.28.23

| | | | | 2-point- | | Conduc- |
|---|---|---|---|---|---|---|
| Trace | Trace | Trace | Dry | probe | | tivity |
| width | width | length | thickness | resistance | Resistivity | (S) or |
| (m) | (um) | (m) | (m) | (Ω) | (Ω · m) | (1/Ω · m) |
| 0.0003 | 300 | 0.04 | 0.000014 | 5.1 | 5.36E−07 | 1874200 |
| 0.0005 | 500 | 0.04 | 0.000014 | 2.825 | 4.94E−07 | 2023223 |
| 0.001 | 1000 | 0.04 | 0.000014 | 1.9 | 6.65E−07 | 1503759 |
| 0.002 | 2000 | 0.04 | 0.000014 | 1.4 | 9.8E−07 | 1020408 |
| 0.003 | 3000 | 0.04 | 0.000014 | 1.4 | 1.47E−06 | 680272.1 |

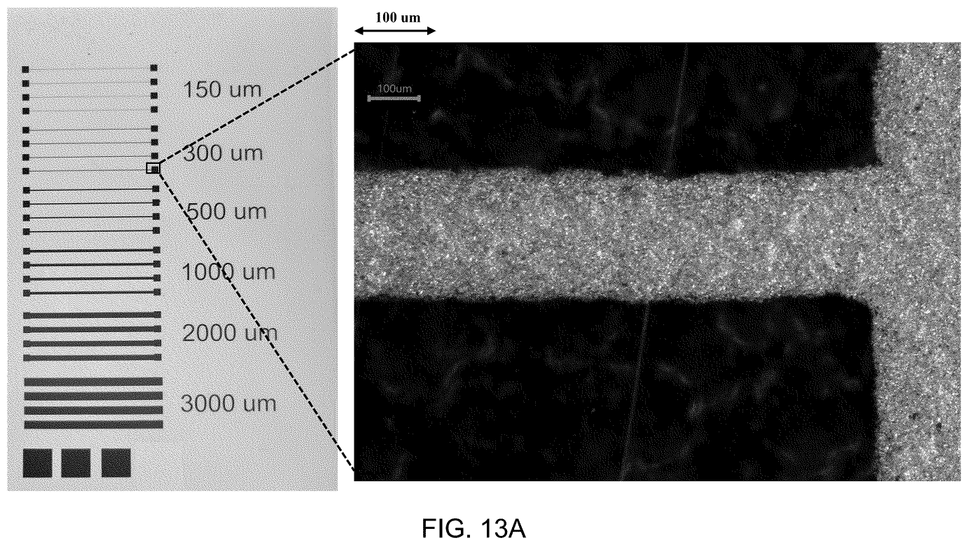

FIG. 13A shows a photograph of an exemplary conductive ink #1 screen printed onto a silicon wafer with a Meyer rod. In some embodiments, as shown, ink traces having thicknesses of 150 um, 300 um, 500 um, 1,000 um, 2,000 um, and 3,000 μm can be printed in one pass, without gaps or separation. In some embodiments, the rheological properties of graphene ink can be tuned to produce well-defined patterns with excellent flat morphology. As shown, the image demonstrates the fine patterning capability of the ink. FIG. 13B shows a photograph of traces of different widths of the conductive ink #1 screen printed onto a silicon wafer and a high magnification photograph of a printed electrical contact point.

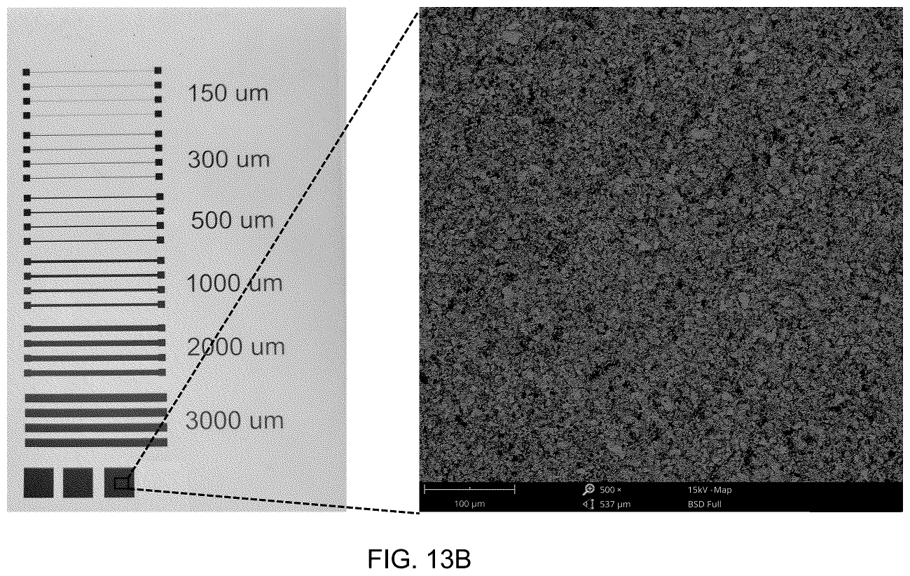

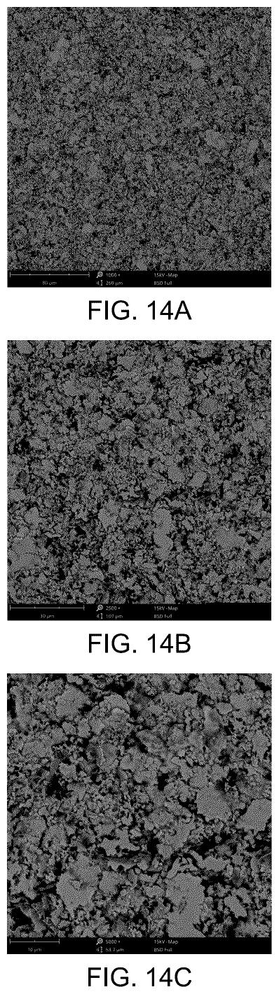

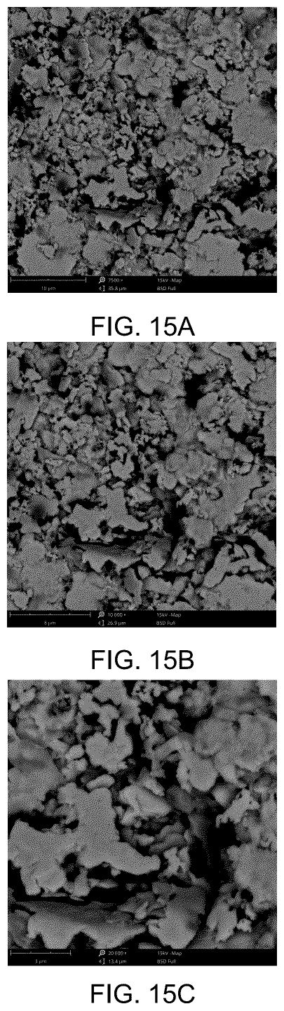

FIG. 14A shows an SEM image at 500× magnification of screen-printed exemplary conductive ink #1. As shown, the images illustrate the uniformity of the printed features. FIG. 14B-14C show 1000×, 2500×, and 5000× magnification SEM images of a substrate coated with the exemplary conductive ink #1. As shown, the exemplary conductive ink #1 screen print has a dense film microstructure. FIG. 15A-15C show 7500×, 10,000×, and 20,000× magnification SEM images of gold coated with the exemplary conductive ink #1. As shown, the exemplary conductive ink #1 screen print has a dense film microstructure.

### Example 5: Conductive Ink Formulation Stability

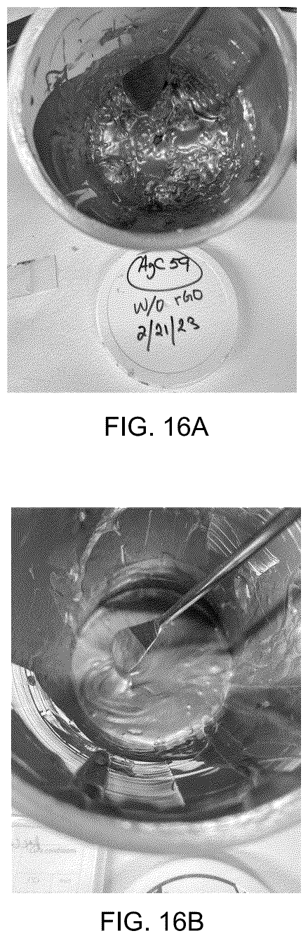

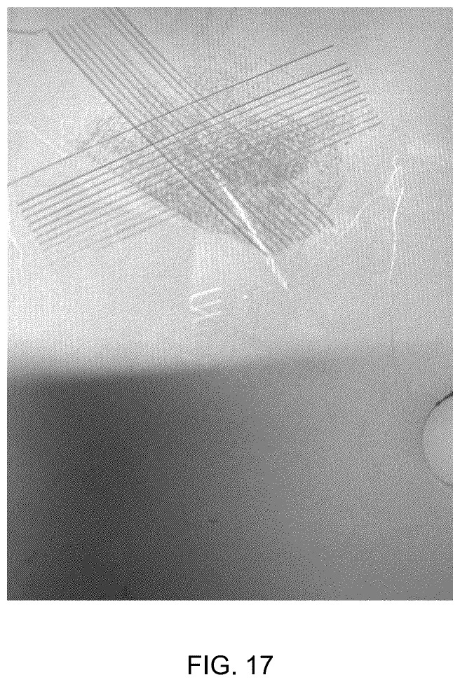

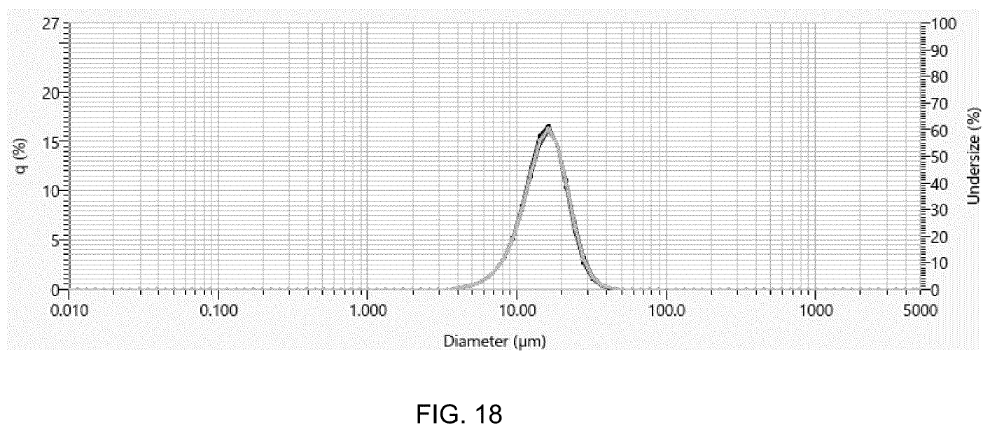

An exemplary conductive ink was evaluated for long-term stability. The properties of the exemplary conductive ink were not substantially impacted by storage for approximately one year. From the samples shown in FIGS. 16A-16B, 17, and the data shown in FIG. 18, the following stability measurements can be determined:

| | | | | | 4-point | | 4-point | | ASTM |
|---|---|---|---|---|---|---|---|---|---|
| Viscosity | Particle | | | | probe | | probe | | cross |
| 200 | size distribution | | | Dry | sheet | | volume | Conduc- | hatch |
| (1/s) | D10 | D50 | D90 | thickness | resistance | Stdev | resistivity | tivity | adhesion |
| cP | (μm) | (μm) | (μm) | (μm) | (Ω/□) | (Ω/□) | (Ω-cm) | (S/cm) | 0-5B |
| 6707 | 8.23511 | 14.7090 | 20.4767 | 37 | 0.0217 | 0.000218 | 0.00008 | 12427.11 | 5B |
| 5667 | 9.46120 | 15.46386 | 23.15402 | 33.4 | 0.0209 | 0.00043 | 0.00007 | 14346.32 | 5B |

FIG. 16A is a picture of a conductive ink of the same formulation as the exemplary conductive ink, but without graphene sheets. As shown in FIG. 16A, a substantial agglomeration of the conductive ink occurred. By contrast, FIG. 16B is a picture of a conductive ink comprising graphene, which showed minimal agglomeration, indicative of the stability of the exemplary dispersion.

FIG. 17 shows the result of an adhesion test using a cross-hatch adhesion test following the ASTM standard method. As shown in FIG. 17, the adhesion test resulted in no detrimental effect on the material (e.g., no peeling, loss of adhesion, edge roughening).

FIG. 18 shows the result of a particle size distribution analysis of the illustrative conductive ink after being kept in storage for about a year.

### Example 6: Conductive Ink Patterning

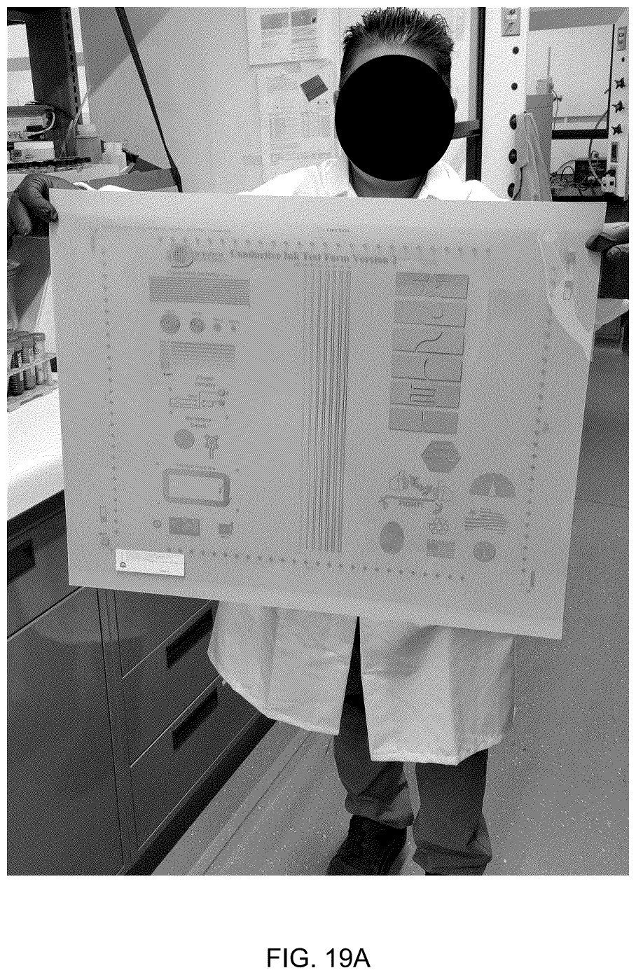

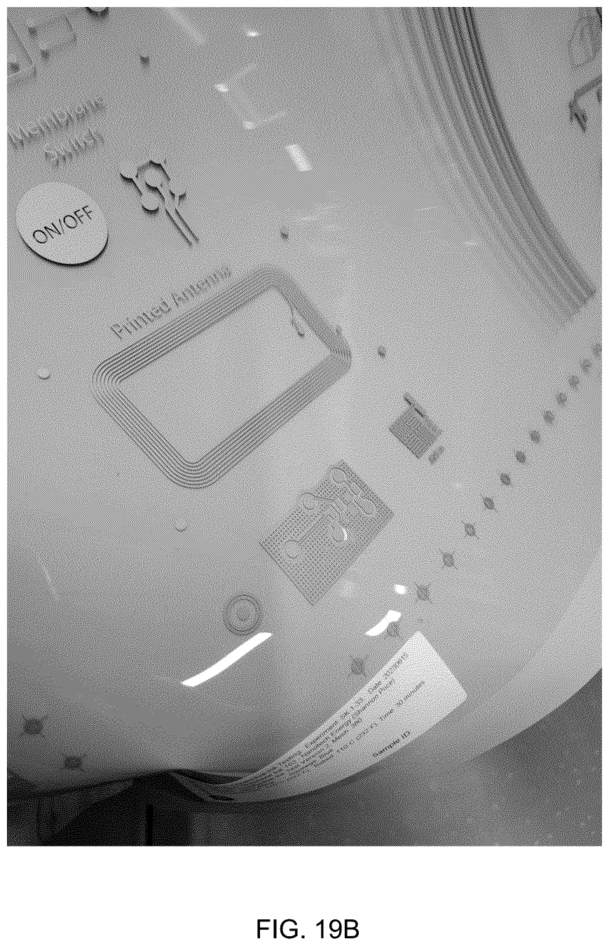

FIGS. 19A-B show the result of screen-printing a conductive ink in a variety of shapes on a polyethylene terephthalate (PET) substrate. For example, in FIG. 19A, a variety of shapes and patterns of varying size and density were printed. For example, in FIG. 19B, a membrane switch pattern, antenna, and circuit patterns were printed using the conductive ink of the instant disclosure.

While preferred embodiments of the present disclosure have been shown and described herein, it will be obvious to those skilled in the art that such embodiments are provided by way of example only. Numerous variations, changes, and substitutions will now occur to those skilled in the art without departing from the disclosure. It should be understood that various alternatives to the embodiments of the disclosure described herein may be employed in practicing the disclosure.

1. A conductive ink comprising:
reduced graphene oxide sheets, wherein:
at least about 90% of the reduced graphene sheets consist of a single layer,
the reduced graphene sheets have an oxygen content of at most about 6% wt, or both;
silver nanoflakes;
a solvent;
a dispersing agent; and
a binder.

2. The conductive ink of claim 1, further comprising a softening agent that performs one or more of (a) increasing flexibility of the conductive ink, once cured, (b) reducing brittleness of the conductive ink, once cured.

3. The conductive ink of claim 2, wherein the softening agent comprises diethylene glycol.

4. The conductive ink of claim 2, wherein the softening agent has a concentration of 5-80% wt.

5. The conductive ink of claim 1, wherein the dispersing agent performs one or more of:
(a) increasing viscosity of the conductive ink,
(b) stabilizing the reduced graphene oxide sheets in the conductive ink,
(c) preventing agglomeration of the reduced graphene oxide sheets in the conductive ink,
(d) preventing cracking of the conductive ink when cured,
(e) preventing formation of agglomerated particles of the reduced graphene oxide sheets or the silver nanoflakes when the conductive ink is cured,
(f) increasing flexibility of the conductive ink when cured, and
(g) increasing elasticity of polymer chains in the conductive ink.

6. The conductive ink of claim 1, wherein the dispersing agent is selected from the group consisting of Poly THF, C7GOL, Cerol 601 wax, and ethyl cellulose.

7. The conductive ink of claim 1, wherein the dispersing agent has a concentration of about 0.5-20% wt.

8. The conductive ink of claim 1, wherein the silver nanoflakes are comprised in an amount of about 30-70% wt.

9. The conductive ink of claim 1, wherein the conductive ink has a silver content of about 80-90% wt. when cured.

10. The conductive ink of claim 1, wherein the silver nanoflakes have a diameter ranging 8-21 micrometers.

11. The conductive ink of claim 1, wherein the binder comprises one or more materials selected from the group consisting of polyvinylpyrrolidone, a thermoplastic copolymer, Paraloid B72, and Paraloid B66, or combinations thereof.

12. The conductive ink of claim 1, wherein the binder has a concentration of about 8-12% wt.

13. The conductive ink of claim 1, wherein the solvent is selected from the group consisting of Dowanol PnP, 2-ethyl-1-hexanol, diethylene glycol butyl ether (DEGBE), 2-ethyl-1-butanol, 2-methyl-1-pentanol, PGMEA, hexamine, cycloheptylamine, Isoamyl amine, 3-methoxypropylamine, para-chlorobenzotrifluoride (PCBTF), ethylene glycol, isopropanol, ethyl acetate, chloroform, dimethylformamide (DMF), n-methyl-2-pyrrolidone (NMP), tetrahydrofuran (THF), and dichlorobenzene.

14. The conductive ink of claim 1, wherein the solvent has a concentration of about 10-90% wt.

15. The conductive ink of claim 1, wherein the reduced graphene oxide sheets have a concentration of about 0.1-1% wt.

16. The conductive ink of claim 1, wherein the conductive ink has a solid content of about 70-80% wt.

17. The conductive ink of claim 1, wherein the conductive ink has a viscosity from about 1000-10,000 cP.

18. The conductive ink of claim 1, wherein the conductive ink has a sheet resistance of at least 0.017 ohms/sq.

19. The conductive ink of claim 1, wherein the conductive ink has a conductivity of about 6,300-15,000 S/cm.

20. A method of preparing a conductive ink, the method comprising:
(a) preparing a mixture comprising:
(i) reduced graphene oxide sheets, wherein:
(1) at least about 90% of the reduced graphene sheets consist of a single layer,
(2) the reduced graphene sheets have an oxygen content of at most about 6% wt, or
(3) both,
(ii) silver nanoflakes,
(iii) a solvent,
(iv) a dispersing agent, and
(v) a binder; and
(b) mixing the mixture at a high shear rate to exfoliate the graphene oxide sheets and form a substantially uniform dispersion between the reduced graphene oxide sheets and the silver nanoflakes to form the conductive ink.
